(19) United States
(12) Patent Application Publication
(10) Pub. No.: US 2025/0136623 A1
(43) Pub. Date: May 1, 2025

(54) LIGHT EMITTING ELEMENT, FUSED POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: TAEIL KIM, Yongin-si (KR); Hirokazu MIYASHITA, Yongin-si (KR); SUN YOUNG PAK, Yongin-si (KR); JUNHA PARK, Yongin-si (KR); MinJae SUNG, Yongin-si (KR); MUN-KI SIM, Yongin-si (KR); MINJUNG JUNG, Yongin-si (KR); Giwoong HAN, Yongin-si (KR); Seonhyoung HUR, Yongin-si (KR)

(73) Assignee: Samsung Display Co., Ltd., Yongin-si (KR)

(21) Appl. No.: 18/625,378

(22) Filed: Apr. 3, 2024

(30) Foreign Application Priority Data
Jul. 17, 2023 (KR) 10-2023-0092717

(51) Int. Cl. C07F 5/02; C09K 11/06; H10K 50/11; H10K 85/30; H10K 85/60

(52) U.S. Cl. CPC C07F 5/02; C09K 11/06; H10K 50/11; H10K 85/346; H10K 85/658; C09K 2211/1018

(57) ABSTRACT

Embodiments provide a fused polycyclic compound, a light emitting element including the fused polycyclic compound, and a display device including the light emitting element. The light emitting element includes a first electrode, a second electrode disposed on the first electrode, and an emission layer disposed between the first electrode and the second electrode. The emission layer includes the fused polycyclic compound, which is represented by Formula 1 and is explained in the specification.

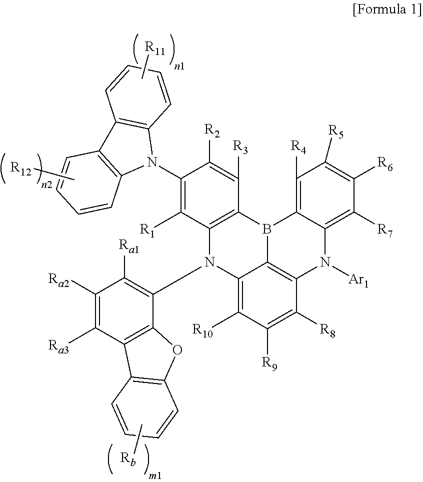

### CROSS-REFERENCE TO RELATED APPLICATION(S)

This application claims priority to and benefits of Korean Patent Application No. 10-2023-0092717 under 35 U.S.C. § 119, filed on Jul. 17, 2023, in the Korean Intellectual Property Office, the entire contents of which are incorporated herein by reference.

### BACKGROUND

### 1. Technical Field

The disclosure relates to a light emitting element, a fused polycyclic compound used in the light emitting element, and a display device including the light emitting element.

### 2. Description of the Related Art

Active development continues for an organic electroluminescence display as an image display. The organic electroluminescence display is different from a liquid crystal display and is a so-called self-luminescent display in which holes and electrons injected from a first electrode and a second electrode recombine in an emission layer so that a light emitting material including an organic compound in the emission layer emits light to achieve display.

In the application of an organic electroluminescence device to a display, the decrease of a driving voltage, and the increase of the emission efficiency and lifetime of the organic electroluminescence device are required, and continuous development on materials is required for an organic electroluminescence device that is capable of stably achieving such characteristics.

In order to accomplish an organic electroluminescence device with high efficiency, techniques on phosphorescence emission which uses energy in a triplet state or to fluorescence emission which uses the generating phenomenon of singlet excitons by the collision of triplet excitons (triplet-triplet annihilation, TTA) are being developed. Development is presently directed to a thermally activated delayed fluorescence (TADF) material which uses delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having improved emission efficiency and element lifetime.

The disclosure provides a fused polycyclic compound which may improve the emission efficiency and element lifetime of a light emitting element.

The disclosure provides a display device having excellent display quality by including a light emitting element having improved emission efficiency and lifetime.

Embodiments provide a light emitting element which may include a first electrode, a second electrode disposed on the first electrode, and an emission layer disposed between the first electrode and the second electrode and including a first compound represented by Formula 1.

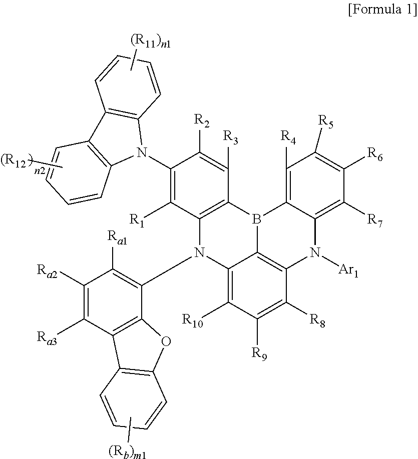

In Formula 1, R₁ to R₁₀ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,

Rₐ₁ to Rₐ₃ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
except that at least one of Rₐ₁ to Rₐ₃ may each independently be a substituted or unsubstituted aryl group of 6 to 30 ring-forming carbon atoms or a substituted or unsubstituted heteroaryl group of 2 to 30 ring-forming carbon atoms,
R_{b}, R₁₁, and R₁₂ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
Ar₁ may be a substituted or unsubstituted aryl group of 6 to 30 ring-forming carbon atoms or a substituted or unsubstituted heteroaryl group of 2 to 30 ring-forming carbon atoms, and m1, n1 and n2 may each independently be an integer from 0 to 4.

In an embodiment, the first compound may be represented by one of Formula 2-1 to Formula 2-3.

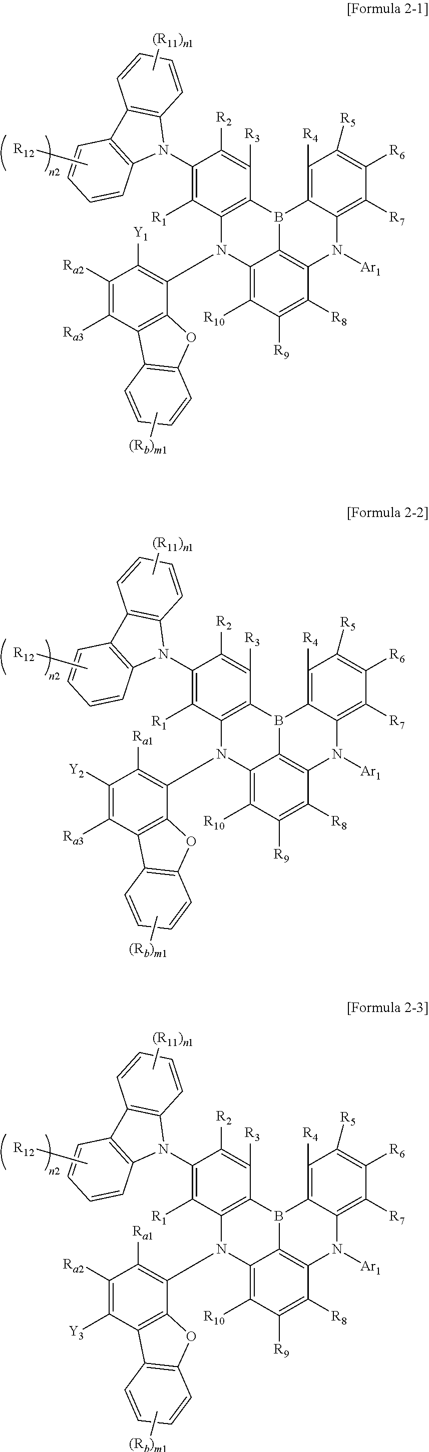

In Formula 2-1 to Formula 2-3, Y₁ to Y₃ may each independently be a substituted or unsubstituted aryl group of 6 to 30 ring-forming carbon atoms or a substituted or unsubstituted heteroaryl group of 2 to 30 ring-forming carbon atoms.

In Formula 2-1 to Formula 2-3, Ar₁, R₁ to R₁₂, Rₐ₁ to Rₐ₃, R_{b}, m1, n1, and n2 may be the same as defined in Formula 1.

In an embodiment, the first compound may be represented by Formula 3.

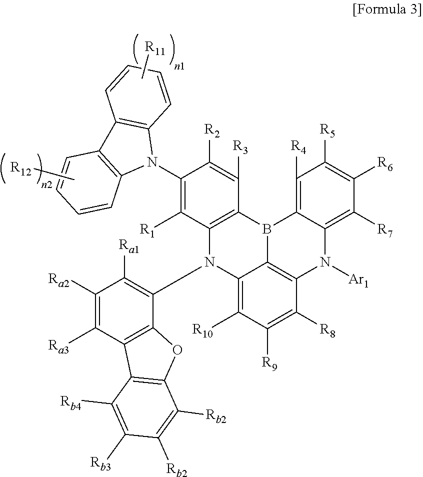

In Formula 3, R_{b1} to R_{b4} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted cycloalkyl group of 3 to 20 ring-forming carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
except that at least one of R_{b1} to R_{b4} may each independently be a substituted or unsubstituted aryl group of 6 to 30 ring-forming carbon atoms or a substituted or unsubstituted heteroaryl group of 2 to 30 ring-forming carbon atoms.

In Formula 3, Ar₁, R₁ to R₁₂, Rₐ₁ to Rₐ₃, n1, and n2 may be the same as defined in Formula 1.

In an embodiment, the first compound may be represented by Formula 4-1 or Formula 4-2.

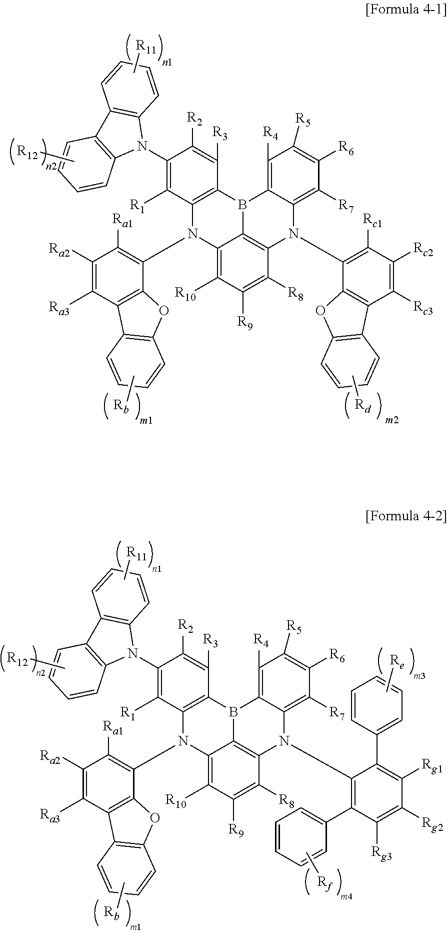

In Formula 4-1 and Formula 4-2, R_{c1} to R_{c3}, R_{d}, Rₑ, R_{f}, and R_{g1} to R_{g3} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m2 may be an integer from 0 to 4, and m3 and m4 may each independently be an integer from 0 to 5, and
wherein in Formula 4-1, at least one of R_{c1} to R_{c3} may each independently be a substituted or unsubstituted aryl group of 6 to 30 ring-forming carbon atoms or a substituted or unsubstituted heteroaryl group of 2 to 30 ring-forming carbon atoms.

In Formula 4-1 and Formula 4-2, R₁ to R₁₂, Rₐ₁ to Rₐ₃, R_{b}, m1, n1, and n2 may be the same as defined in Formula 1.

In an embodiment, the first compound may be represented by Formula 5.

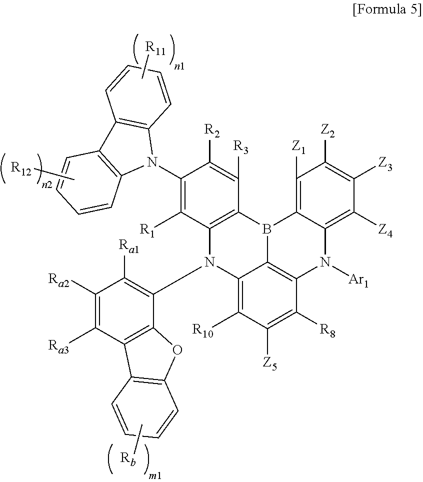

In Formula 5, Z₁ to Z₅ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
except that at least one of Z₁ to Z₅ may each independently be a substituted or unsubstituted alkyl group of 1 to 10 carbon atoms, or a group represented by one of Formula A-1 to Formula A-5.

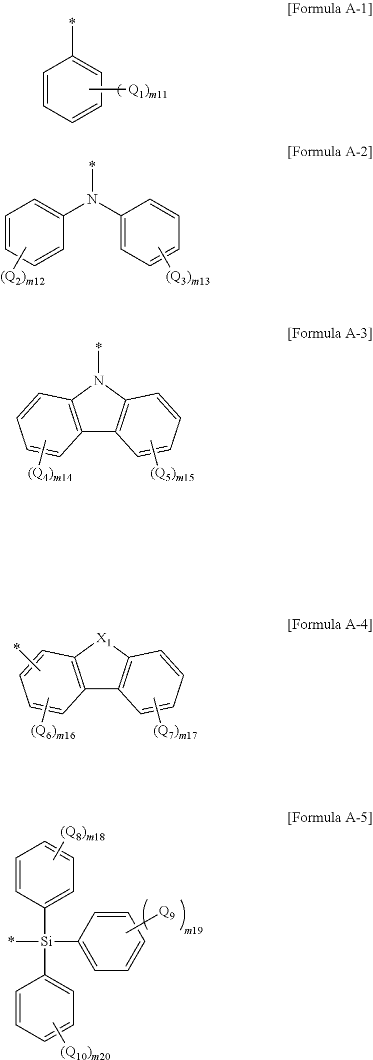

In Formula A-1 to Formula A-5, X₁ may be O, S, Se, N(Q₁₁), or C(Q₁₂)(Q₁₃); and Q₁₁ to Q₁₃ may each independently be a hydrogen atom, a deuterium atom, a halogen atom, a cyano group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11 to m13, and m18 to m20 may each independently be an integer from 0 to 5; m14, m15, and m17 may each independently be an integer from 0 to 4; and m16 may be an integer from 0 to 3.

In Formula 5, Ar₁, R₁ to R₃, R₈, R₁₀ to R₁₂, Rₐ₁ to Rₐ₃, R_{b}, m1, n1, and n2 may be the same as defined in Formula 1.

In an embodiment, at least one of Z₁ to Z₅ may each independently be a group selected from Substituent Group 1.

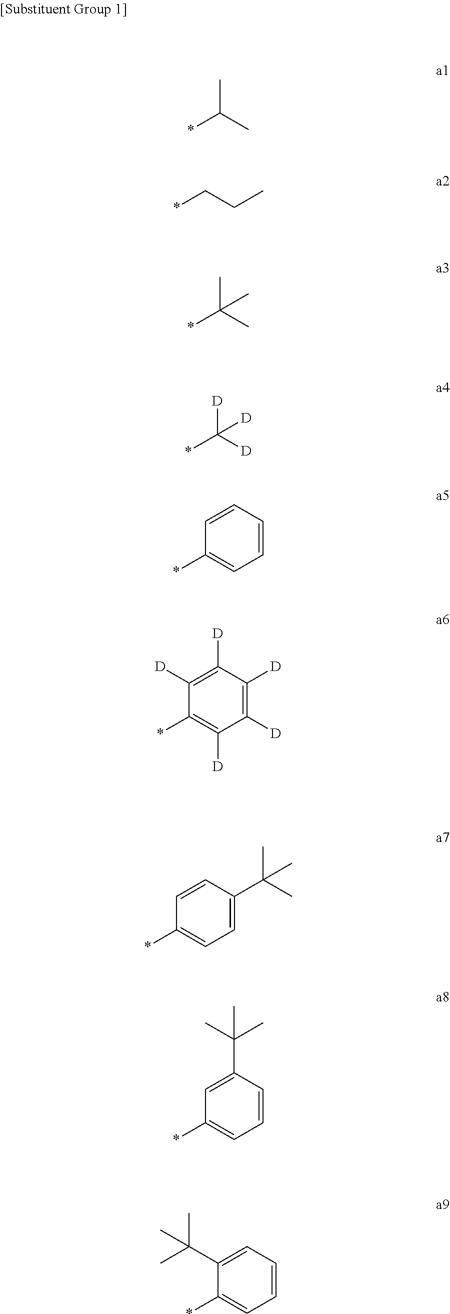

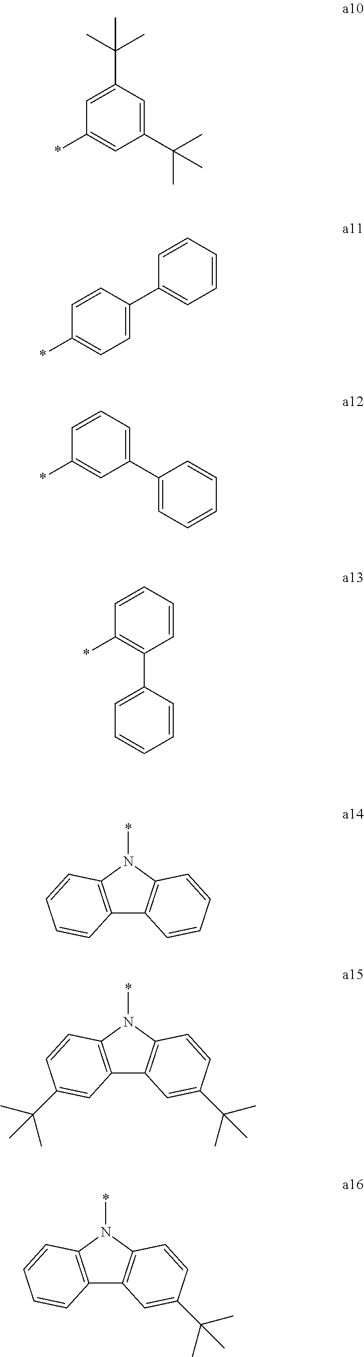

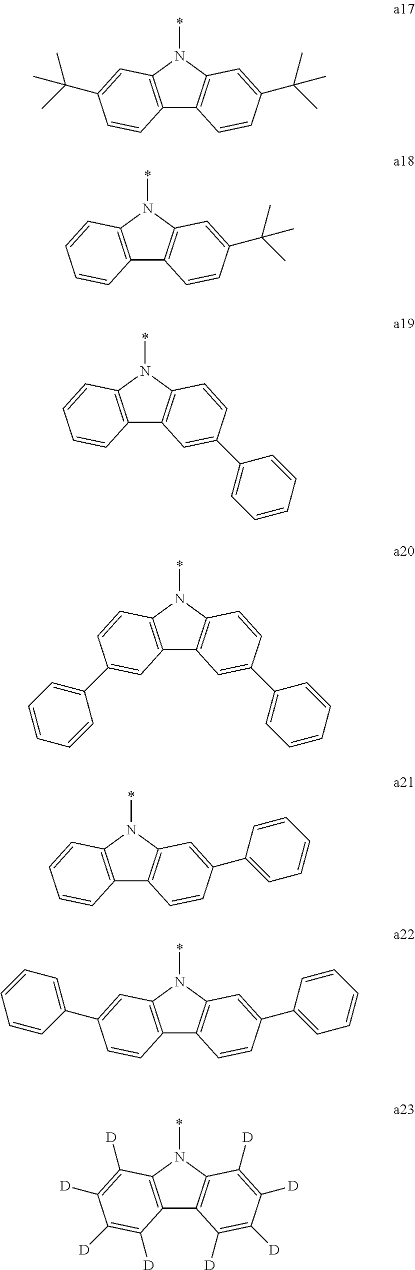

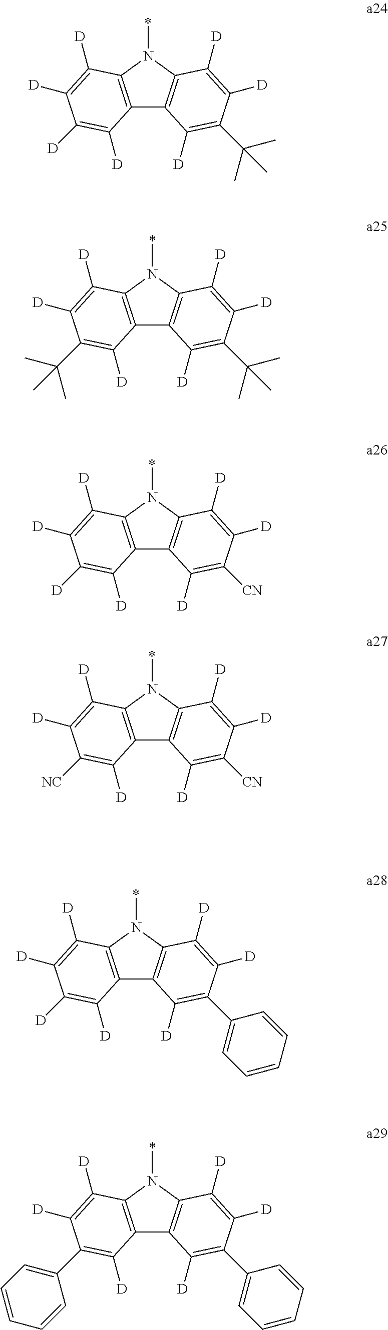

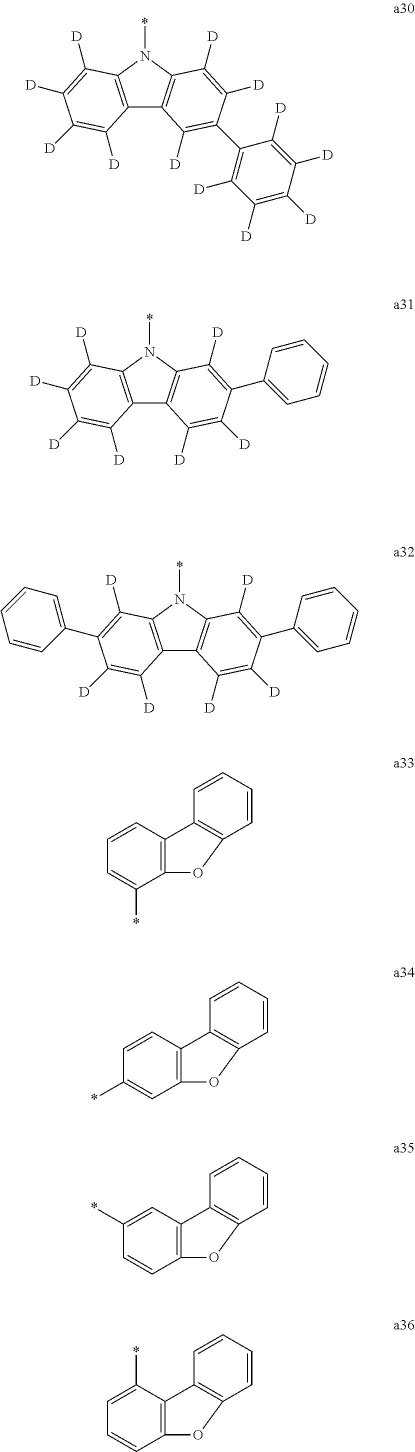

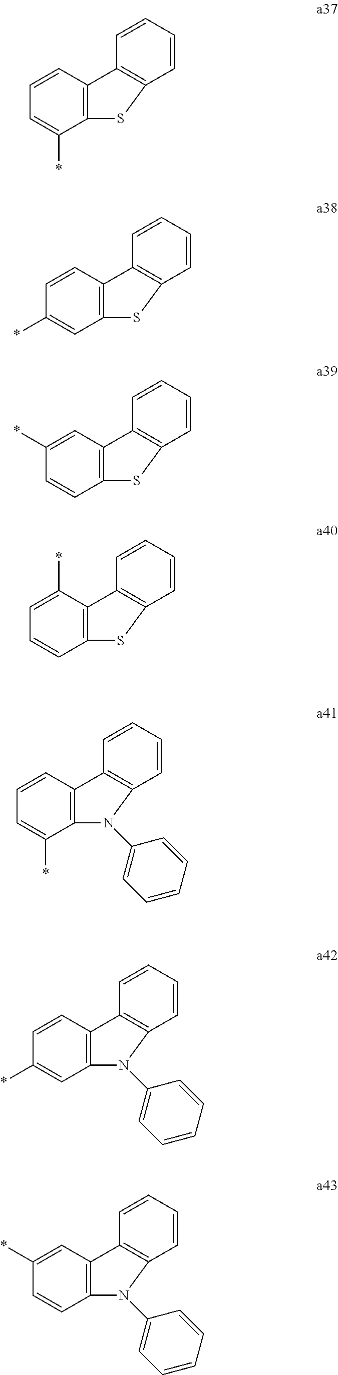

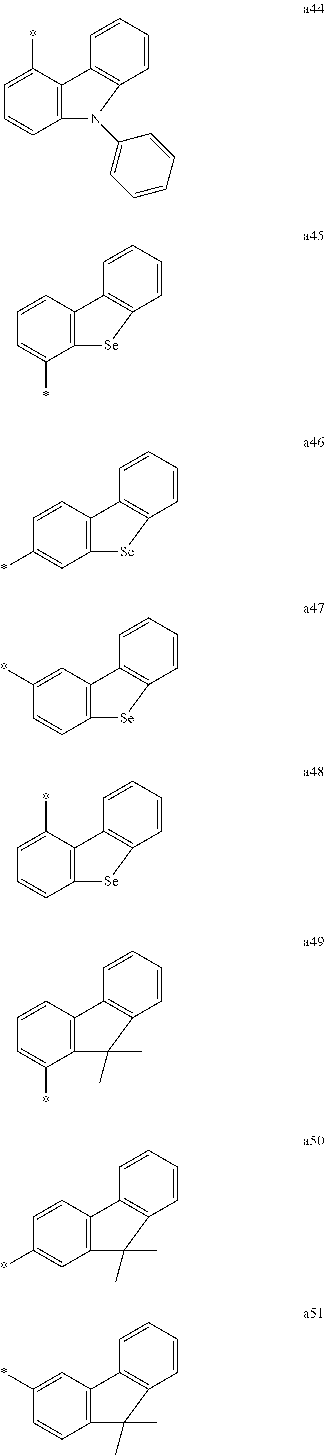

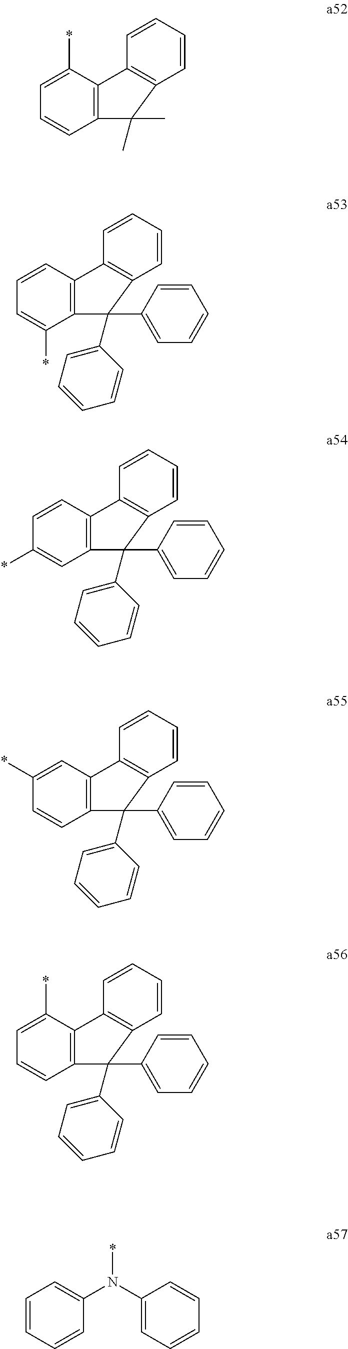 [SMILES: *c1cccc2c1-c1ccccc1C2(C)C ; *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1 ; *N(c1ccccc1)c1ccccc1]

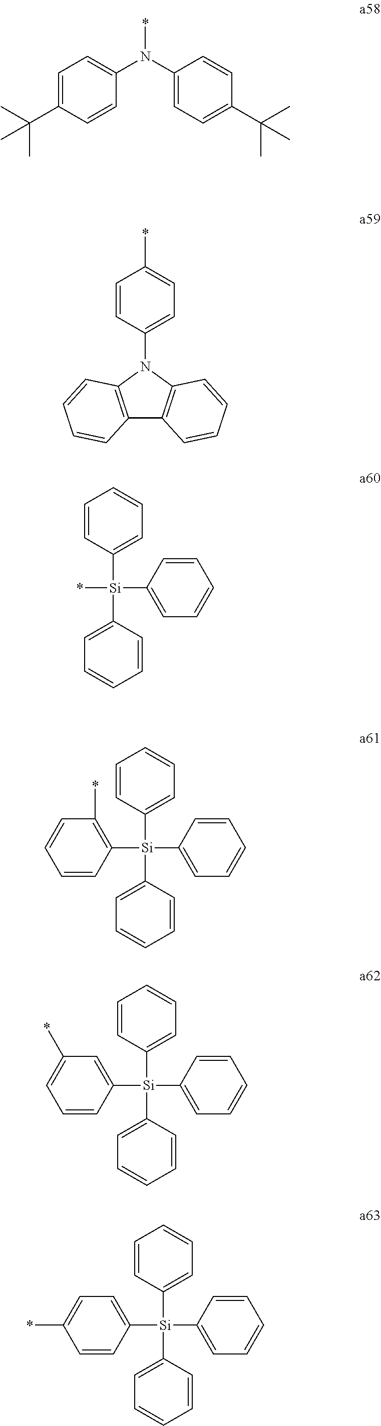

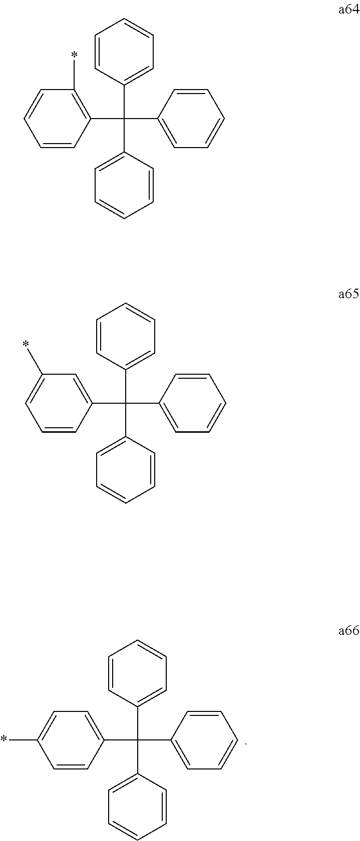 [SMILES: *c1ccccc1C(c1ccccc1)(c1ccccc1)c1ccccc1 ; *c1cccc(C(c2ccccc2)(c2ccccc2)c2ccccc2)c1 ; *c1ccc(C(c2ccccc2)(c2ccccc2)c2ccccc2)cc1]

In an embodiment, the first compound may be represented by Formula 6-1 or Formula 6-2.

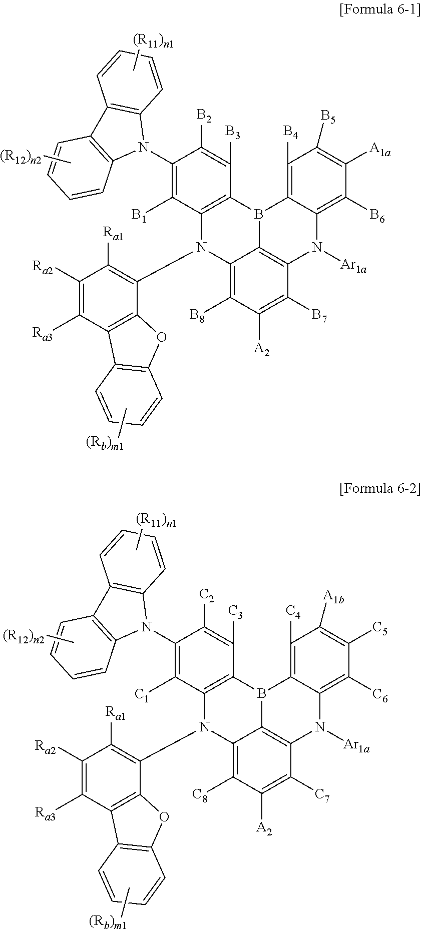

In Formula 6-1 and Formula 6-2, A₁ₐ and A_{1b} may each independently be a cyano group, a substituted or unsubstituted amine group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms; A₂ may be a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms; B₁ to B₈ and C₁ to C₈ may each independently be a hydrogen atom or a deuterium atom; and Ar₁ₐ may be a group represented by Formula B-1 or Formula B-2.

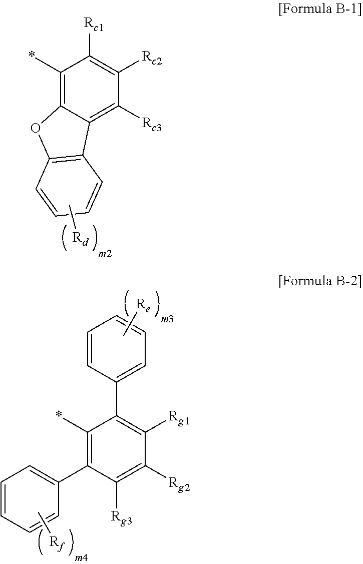

In Formula B-1 and Formula B-2, R_{c1} to R_{c3}, R_{d}, Rₑ, R_{f}, and R_{g1} to R_{g3} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m2 may be an integer from 0 to 4; and m3 and m4 may each independently be an integer from 0 to 5,
wherein in Formula B-1, at least one of R_{c1} to R_{c3} may each independently be a substituted or unsubstituted aryl group of 6 to 30 ring-forming carbon atoms or a substituted or unsubstituted heteroaryl group of 2 to 30 ring-forming carbon atoms.

In Formula 6-1 and Formula 6-2, R₁₁, R₁₂, Rₐ₁ to Rₐ₃, R_{b}, m1, n1, and n2 may be the same as defined in Formula 1.

In an embodiment, the first compound may be represented by Formula 7-1 or Formula 7-2.

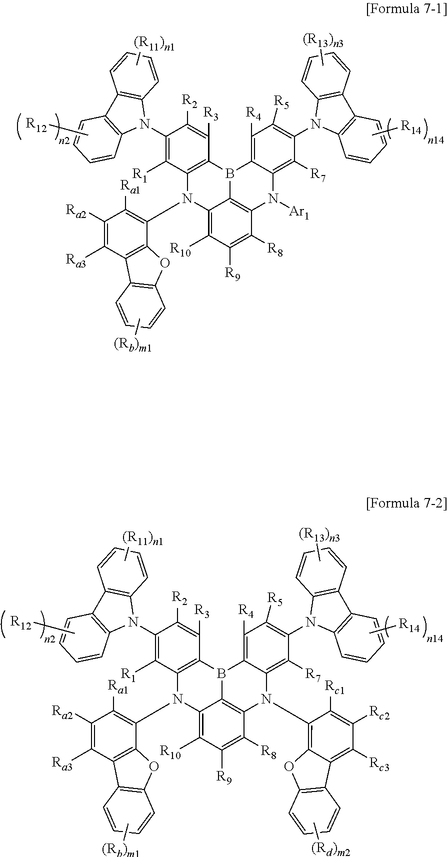

In Formula 7-1 and Formula 7-2, R₁₃, R₁₄, R_{c1} to R_{c3}, and R_{d} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; and n13, n14 and m2 may each independently be an integer from 0 to 4.

In Formula 7-1 and Formula 7-2, Ar₁, R₁ to R₅, R₇ to R₁₂, Rₐ₁ to Rₐ₃, R_{b}, m1, n1, and n2 may be the same as defined in Formula 1.

In an embodiment, the emission layer may further include at least one of a second compound represented by Formula HT-1, a third compound represented by Formula ET-1, and a fourth compound represented by Formula D-1.

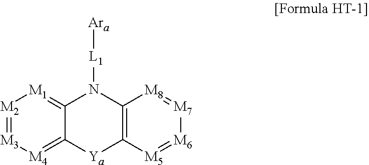

In Formula HT-1, M₁ to M₈ may each independently be N or C(R₅₁); L₁ may be a direct linkage, a substituted or unsubstituted arylene group of 6 to 30 ring-forming carbon atoms, or a substituted or unsubstituted heteroarylene group of 2 to 30 ring-forming carbon atoms; Yₐ may be a direct linkage, C(R₅₂)(R₅₃), or Si(R₅₄)(R₅₅); Arₐ may be a substituted or unsubstituted aryl group of 6 to 30 ring-forming carbon atoms, or a substituted or unsubstituted heteroaryl group of 2 to 30 ring-forming carbon atoms, and

R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring.

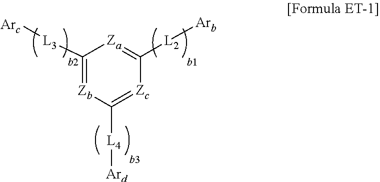

In Formula ET-1, at least one of Zₐ to Zₑ may each be N; the remainder of Zₐ to Zₑ may each independently be C(R₅₆); R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; b1 to b3 may each independently be an integer from 0 to 10,

Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; and L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms.

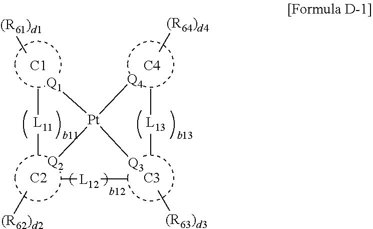

In Formula D-1, Q₁ to Q₄ may each independently be C or N; C1 to C4 may each independently be a substituted or unsubstituted hydrocarbon ring of 5 to 30 ring-forming carbon atoms or a substituted or unsubstituted heterocycle of 2 to 30 ring-forming carbon atoms; L₁₁ to L₁₃ may each independently be a direct linkage,

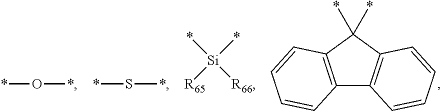

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms; b11 to b13 may each independently be 0 or 1; R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms; and d1 to d4 are each independently an integer from 0 to 4.

Embodiments provide a display device which may include a circuit layer disposed on a base layer, and a display device layer disposed on the circuit layer and including a light emitting element, wherein the light emitting element may include a first electrode, a second electrode disposed on the first electrode, and an emission layer disposed between the first electrode and the second electrode and including a first compound represented by Formula 1.

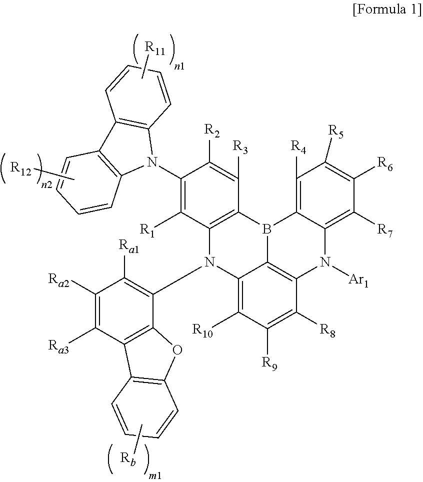

In Formula 1, R₁ to R₁₀ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
Rₐ₁ to Rₐ₃ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
except that at least one of Rₐ₁ to Rₐ₃ may each independently be a substituted or unsubstituted aryl group of 6 to 30 ring-forming carbon atoms or a substituted or unsubstituted heteroaryl group of 2 to 30 ring-forming carbon atoms,
R_{b}, R₁₁, and R₁₂ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
Ar₁ may be a substituted or unsubstituted aryl group of 6 to 30 ring-forming carbon atoms or a substituted or unsubstituted heteroaryl group of 2 to 30 ring-forming carbon atoms; and m1, n1, and n2 may each independently be an integer from 0 to 4.

In an embodiment, the light emitting element may further include a capping layer disposed on the second electrode; and a refractive index of the capping layer may be greater than or equal to about 1.6, with respect to light in a wavelength range of about 550 nm to about 660 nm.

In an embodiment, the display device may further include a light controlling layer disposed on the display device layer and including a quantum dot; the light emitting element may emit first color light; and the light controlling layer may include a first light controlling part including a first quantum dot that converts the first color light into second color light in a wavelength region that is greater than the first color light, a second light controlling part including a second quantum dot that converts the first color light into third color light in a wavelength region that is greater than the first color light and the second color light, and a third light controlling part that transmits the first color light.

In an embodiment, the display device may further include a color filter layer disposed on the light controlling layer; and the color filter layer may include a first filter transmitting the second color light, a second filter transmitting the third color light, and a third filter transmitting the first color light.

Embodiments provide a fused polycyclic compound which may be represented by Formula 1, which is explained herein.

In an embodiment, the fused polycyclic compound may be represented by Formula 4-1 or Formula 4-2, which are explained herein.

In an embodiment, the fused polycyclic compound may be represented by Formula 5, which is explained herein.

In an embodiment, the fused polycyclic compound may be represented by Formula 6-1 or Formula 6-2, which are explained herein.

In an embodiment, the fused polycyclic compound may be represented by Formula 7-1 or 7-2, which are explained herein.

In an embodiment, at least one of R₁ to R₁₀ may each independently be a group selected from Substituent Group 1, which is explained herein.

In an embodiment, the fused polycyclic compound may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments and are incorporated in and constitute a part of this specification. The drawings illustrate embodiments of the disclosure and principles thereof. The above and other aspects and features of the disclosure will become more apparent by describing in detail embodiments thereof with reference to the accompanying drawings in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 and FIG. 8 are each schematic cross-sectional views of display devices according to embodiments;

FIG. 9 is a schematic cross-sectional view of a display device according to an embodiment;

FIG. 10 is a schematic cross-sectional view of a display device according to an embodiment; and

FIG. 11 is a schematic perspective view of an automobile in which a display devices are disposed according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the specification, the phrase “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbons in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. The alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. The alkynyl group may be linear or branched. Although the number of carbon atoms is not specifically limited, it may be 2 to 30, 2 to 20, or 2 to 10. Examples of an alkynyl group may include an ethynyl group, a propynyl group, etc., but are not limited thereto.

In the specification, the hydrocarbon ring group may be any functional group or substituent derived from an aliphatic hydrocarbon ring. The hydrocarbon ring group may be a saturated hydrocarbon ring group having 5 to 20 ring-forming carbon atoms.

In the specification, an aryl group may be any functional group or substituent derived from an aromatic hydrocarbon ring. The aryl group may be monocyclic or polycyclic. The number of ring-forming carbon atoms in the aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group are as follows, but embodiments are not limited thereto.

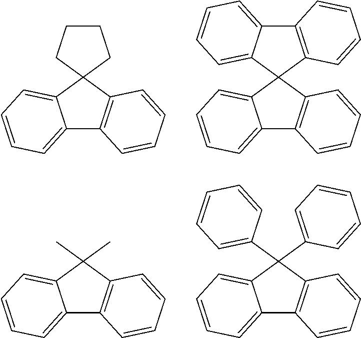

In the specification, a heterocyclic group herein may be any functional group or substituent derived from a ring containing at least one of B, O, N, P, Si, or Se as a heteroatom. The heterocyclic group may be aliphatic or aromatic. An aromatic heterocyclic group may be a heteroaryl group. The aliphatic heterocycle and the aromatic heterocycle may each independently be monocyclic or polycyclic.

In the specification, a heterocyclic group may contain at least one of B, O, N, P, Si or S as a heteroatom. If the heterocyclic group contains two or more heteroatoms, the two or more heteroatoms may be the same as or different from each other. The heterocyclic group may be monocyclic or polycyclic, and a heterocyclic group may be a heteroaryl group. The number of ring-forming carbon atoms in a heterocyclic group may be 2 to 60, 2 to 50, 2 to 40, 2 to 30, 2 to 20, or 2 to 10.

In the specification, an aliphatic heterocyclic group may include at least one of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may contain at least one of B, O, N, P, Si, or S as a heteroatom. If a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 50, 2 to 40, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group except that an arylene group may be a divalent group. The above description of a heteroaryl group may be applied to a heteroarylene group except that a heteroarylene group may be a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not specifically limited, but may be 1 to 40, 1 to 30, or 1 to 20. For example, a carbonyl group may have one of the following structures, but embodiments are not limited thereto.

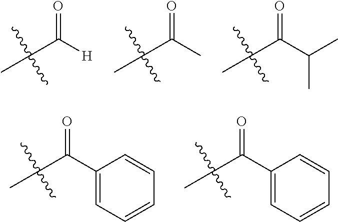

In the specification, the number of carbon atoms in a sulfinyl group and a sulfonyl group is not particularly limited, but may be 1 to 30. A sulfinyl group may include an alkyl sulfinyl group or an aryl sulfinyl group. A sulfonyl group may include an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. The alkoxy group may be linear, branched, or cyclic. The number of carbon atoms in an alkoxy group is not specifically limited, but may be, for example, 1 to 20 or 1 to 10.

Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not specifically limited, but may be 1 to 30. An amine group may include an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

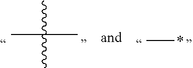

each represent a bonding site to a neighboring atom.

Hereinafter, embodiments will be described with reference to the accompanying drawings.

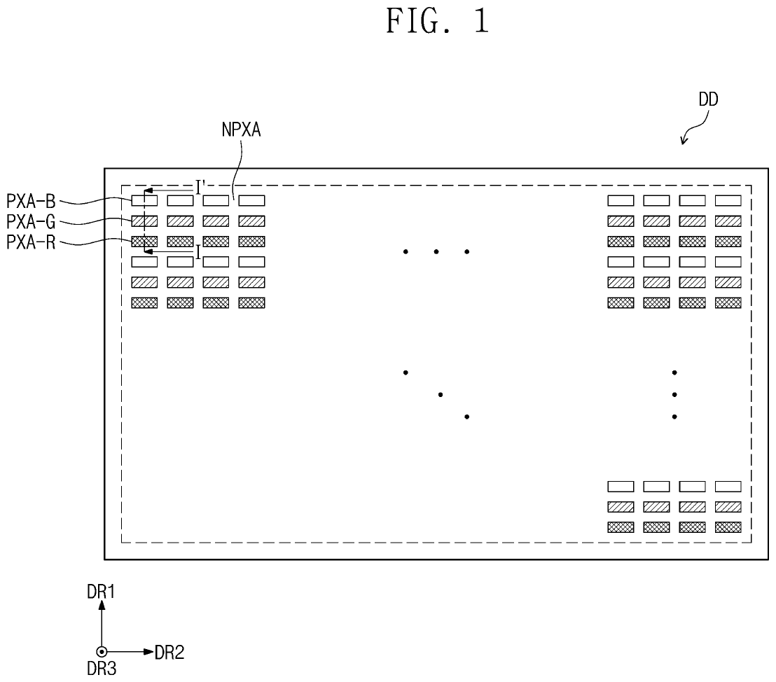

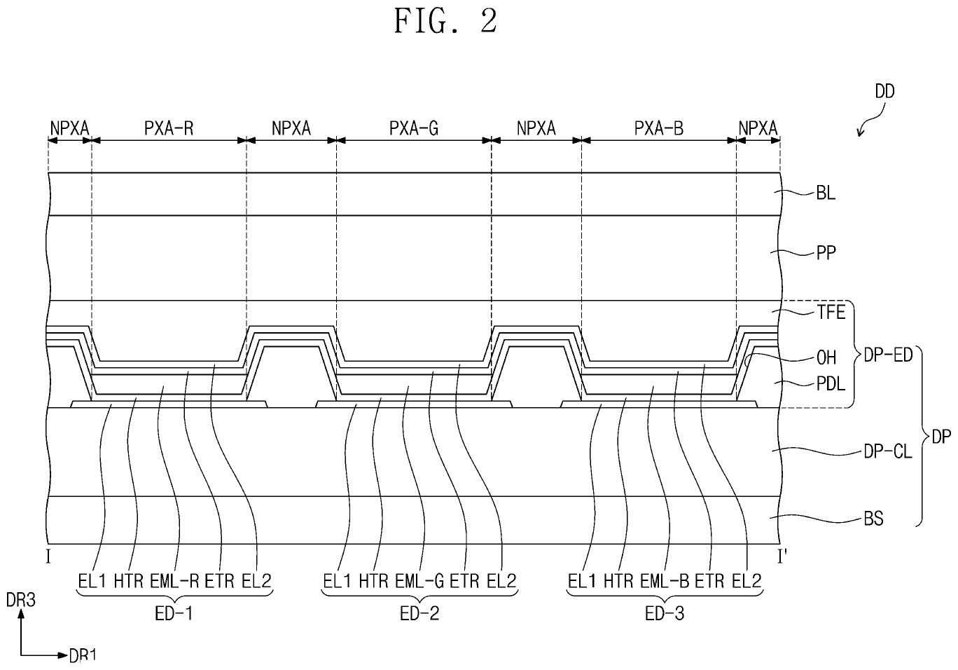

FIG. 1 is a schematic plan view illustrating an embodiment of a display device DD. FIG. 2 is a schematic cross-sectional view of the display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer.

The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may be an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting elements ED-1, ED-2, and ED-3 of the display device layer DP-ED.

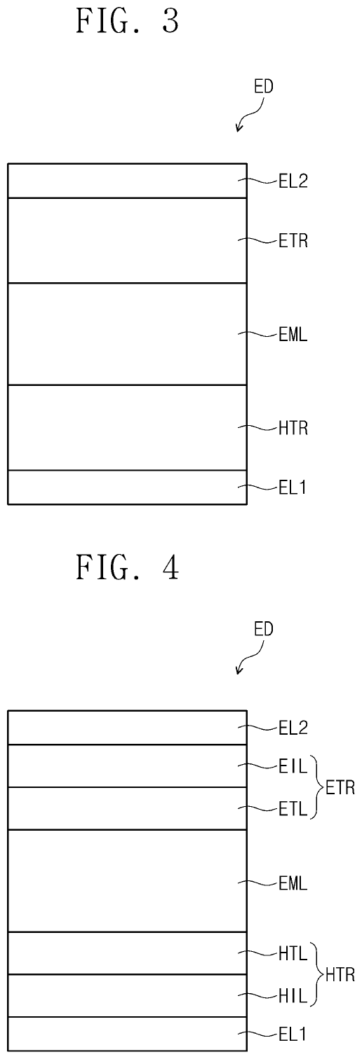

The light emitting elements ED-1, ED-2, and ED-3 may each have a structure of each light emitting element ED of an embodiment according to FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3t may each be provided by being patterned by an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed by laminating a single layer or multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but embodiments are not particularly limited thereto. The encapsulation-organic film may include an acrylic-based compound, an epoxy-based compound, or the like. The encapsulation-organic film may include a photopolymerizable organic material, but embodiments are not particularly limited thereto.

The encapsulation layer TFE may be disposed on the second electrode EL2 and may be disposed to fill the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may each be a region that emits light generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting areas NPXA may be areas between the adjacent light emitting areas PXA-R, PXA-G, and PXA-B, which correspond to the pixel defining film PDL. In an embodiment, the light emitting regions PXA-R, PXA-G, and PXA-B may correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include the red light emitting region PXA-R, the green light emitting region PXA-G, and the blue light emitting region PXA-B that are separated from each other.

In the display device DD according to an embodiment, the light emitting elements ED-1, ED-2 and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit light in a wavelength range different from the other light emitting elements. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B have a similar area to each other, but embodiments are not limited thereto. Thus, the light emitting regions PXA-R, PXA-G, and PXA-B may be different in size of shape from each other according to a wavelength range of the emitted light. The areas of the light emitting regions PXA-R, PXA-G, and PXA-B may be areas in a plan view defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required in the display device DD. For example, the light emitting regions PXA-R, PXA-G, and PXA-B may be arranged in a pentile configuration (such as PENTILE®) or in a diamond configuration (such as Diamond Pixel®).

The areas of the light emitting regions PXA-R, PXA-G, and PXA-B may be different in size from each other. For example, in an embodiment, an area of the green light emitting region PXA-G may be smaller than an area of the blue light emitting region PXA-B, but embodiments are not limited thereto.

Hereinafter, FIG. 3 to FIG. 6 is each a schematic cross-sectional view of a light emitting element according to an embodiment. The light emitting element ED according to an embodiment may include a first electrode EL1, a second electrode EL2 oppositely disposed to the first electrode EL1, and at least one functional layer disposed between the first electrode EL1 and the second electrode EL2. The light emitting element ED according to an embodiment may include a fused polycyclic compound, which will be explained later, in the at least one functional layer.

The light emitting element ED may include a hole transport region HTR, an emission layer EML, an electron transport region ETR, or the like, stacked in that order, as the at least one functional layer. Referring to FIG. 3, the light emitting element ED of an embodiment may include a first electrode EL1, a hole transport region HTR, an emission layer EML, an electron transport region ETR, and a second electrode EL2, stacked in that order.

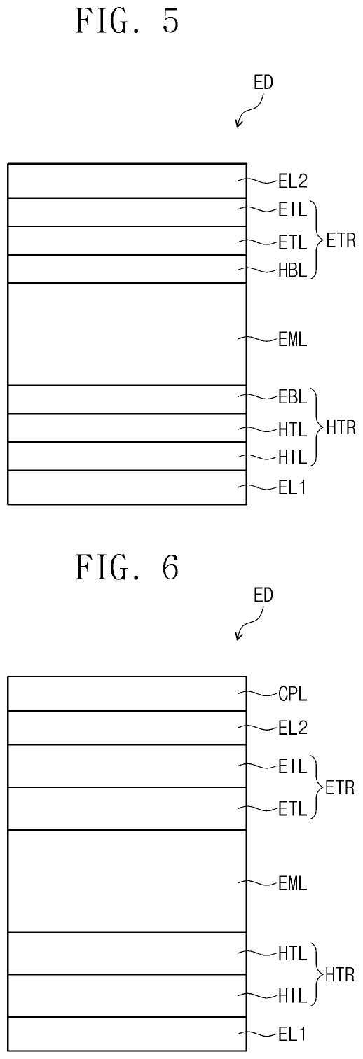

In comparison to FIG. 3, FIG. 4 illustrates a schematic cross-sectional view of a light emitting element ED, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting element ED, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting element ED that includes a capping layer CPL disposed on a second electrode EL2.

The light emitting element ED according to an embodiment may include a fused polycyclic compound, which will be explained later, in the at least one functional layer. In the light emitting element ED according to an embodiment, at least one among the hole transport region HTR, the emission layer EML, and the electron transport region ETR may include the fused polycyclic compound of an embodiment. For example, in the light emitting element ED, the emission layer EML may include the fused polycyclic compound.

The first electrode EL1 may have conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, and Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In an embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

For example, the hole transport region HTR may have a single layer structure of a hole injection layer HIL or a hole transport layer HTL, or may have a single layer structure formed of a hole injection material and a hole transport material. In other embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

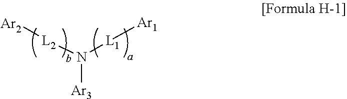

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer from 0 to 10. When a or b is 2 or greater, multiple L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

In an embodiment, the compound represented by Formula H-1 may be a monoamine compound. In another embodiment, the compound represented by Formula H-2 may be a diamine compound in which at least one of Ar₁ to Ar₃ includes an amine group as a substituent.

In still other embodiments, the compound represented by Formula H-1 may be a carbazole-based compound in which at least one of Ar₁ and Ar₂ includes a substituted or unsubstituted carbazole group, or a fluorene-based compound in which at least one of Ar₁ or Ar₂ includes a substituted or unsubstituted fluorene group.

The compound represented by Formula H-1 may be any compound selected from Compound Group H. However, the compounds listed in Compound Group H are only examples, and the compounds represented by Formula H-1 are not limited to those represented by Compound Group H:

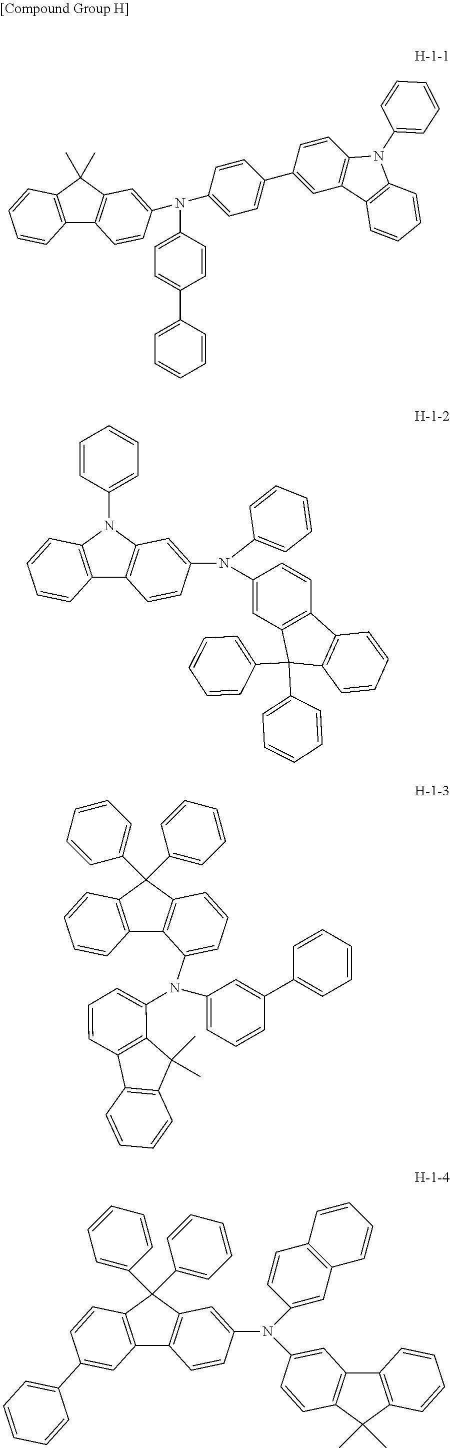 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

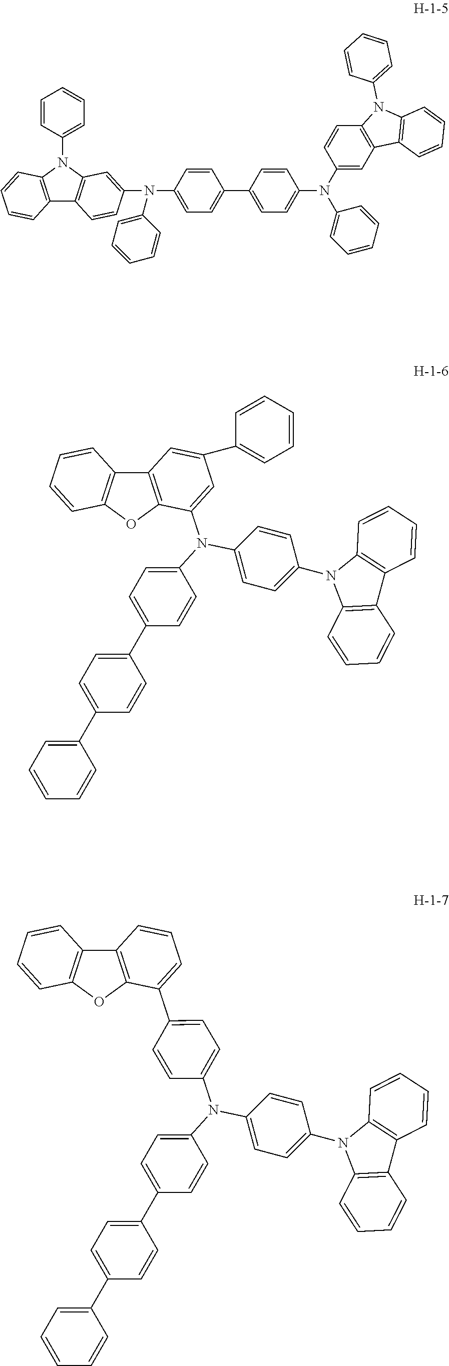 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

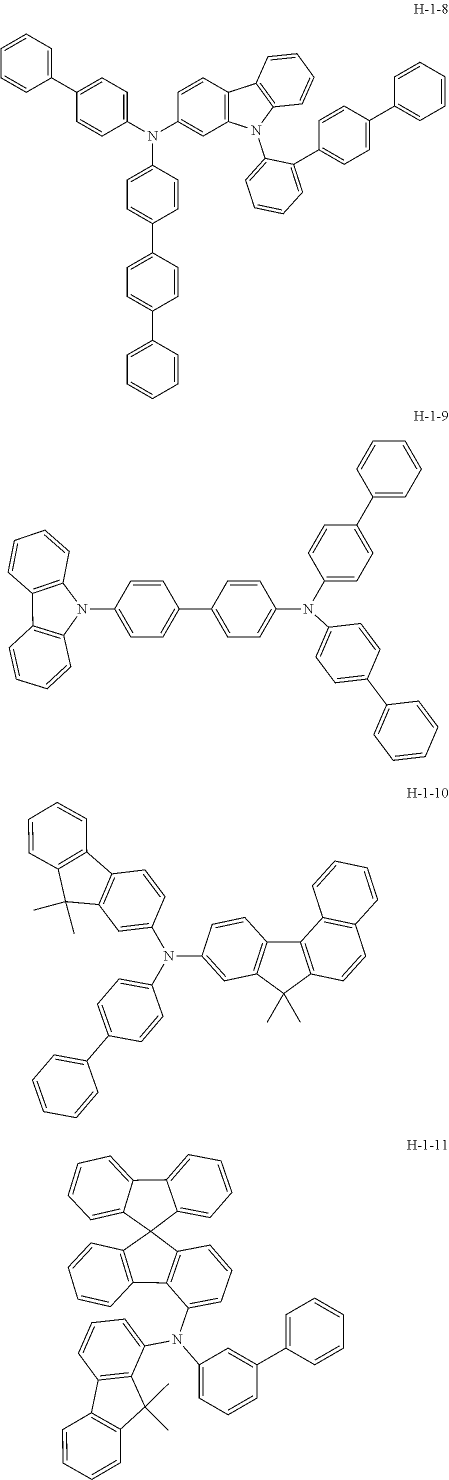 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

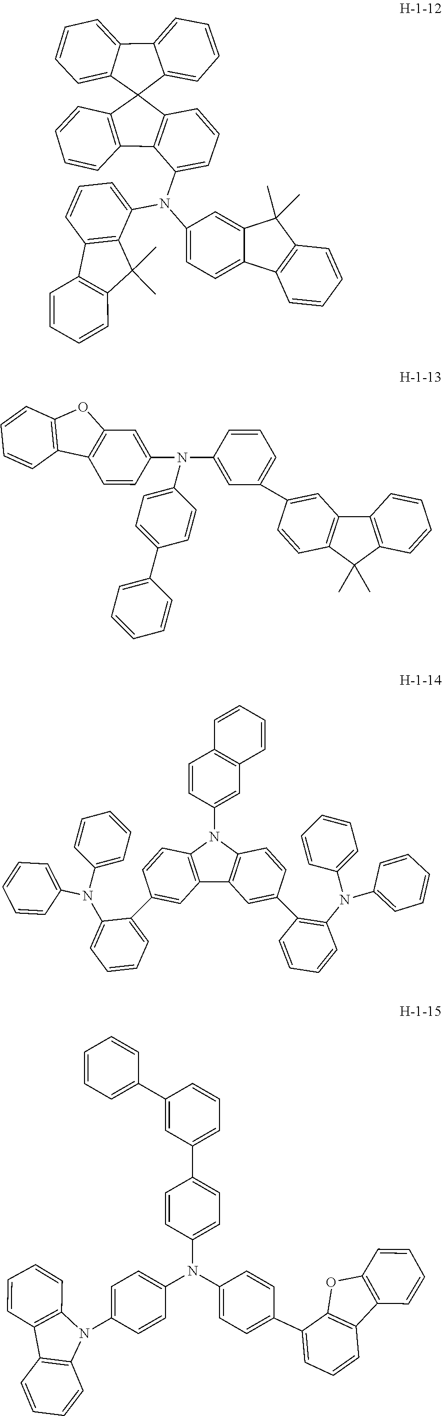 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

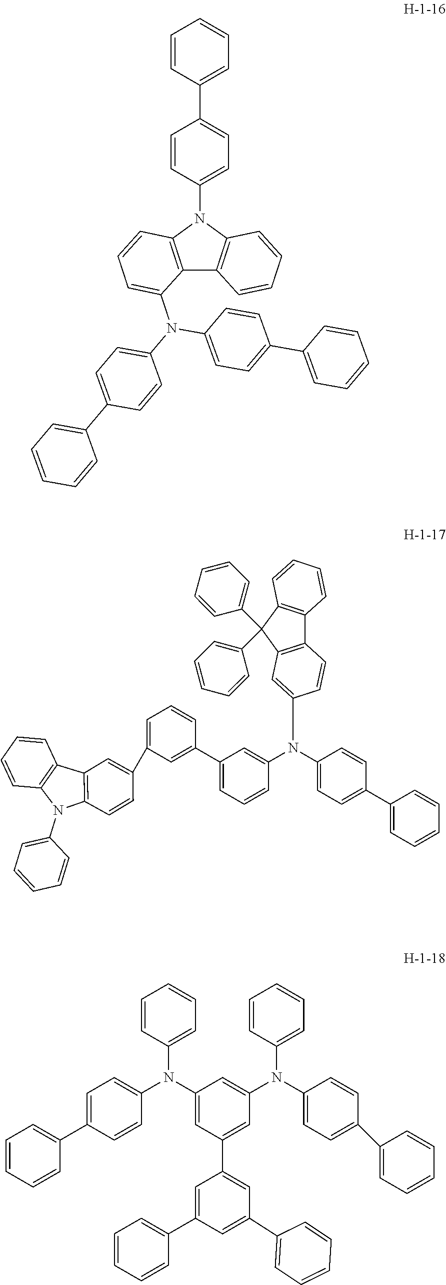 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

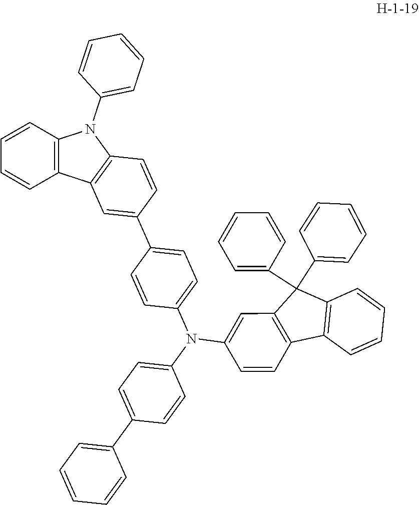 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrene sulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes the hole injection layer HIL, the hole injection layer HIL may have, for example, a thickness in a range of about 30 Å to about 1,000 Å. When the hole transport region HTR includes the hole transport layer HTL, the hole transport layer HTL may have a thickness in a range of about 250 Å to about 1,000 Å. For example, when the hole transport region HTR includes the electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of the buffer layer (not shown) or the electron blocking layer EBL in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be included in the buffer layer (not shown). The electron blocking layer EBL is a layer that may prevent the electron injection from the electron transport region ETR to the hole transport region HTR.

The emission layer EML may be provided on the hole transport region HTR. The emission layer EML may have a thickness of, for example, about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The light emitting element ED according to an embodiment may include the fused polycyclic compound represented by Formula 1 in at least one functional layer disposed between the first electrode EL1 and the second electrode EL2. In the light emitting element ED according to an embodiment, the emission layer EML may include the fused polycyclic compound. In an embodiment, the emission layer EML may include the fused polycyclic compound as a dopant. The fused polycyclic compound according to an embodiment may be a dopant material of the emission layer EML. In the specification, the fused polycyclic compound according to an embodiment may be referred to as a first compound.

The fused polycyclic compound according to an embodiment may include a fused structure of multiple aromatic rings via a boron atom and a nitrogen atom. The fused polycyclic compound according to an embodiment may include a fused structure of multiple aromatic rings via a boron atom and two nitrogen atoms. The fused polycyclic compound according to an embodiment may include a fused structure of multiple aromatic rings via a first boron atom, a first nitrogen atom and a second nitrogen atom. For example, the fused polycyclic compound according to an embodiment may include a fused ring formed by fusing multiple aromatic rings via a boron atom, a first nitrogen atom and a second nitrogen atom.

The fused polycyclic compound according to an embodiment may have a structure including first to third aromatic rings that are fused together via a first boron atom, a first nitrogen atom, and a second nitrogen atom. The first to third aromatic rings may be connected to the first boron atom, the first aromatic ring and the third aromatic ring may be connected to each other via the first nitrogen atom, and the second aromatic ring and the third aromatic ring may be connected to each other via the second nitrogen atom. In the specification, the first boron atom, the first nitrogen atom, the second nitrogen atom, and the fused structure formed through fusing the first to first to third aromatic rings via the first boron atom, the first nitrogen atom and the second nitrogen atom, may be referred to as a “fused ring core”.

In an embodiment, the first to third aromatic rings may be each independently a substituted or unsubstituted monocyclic aromatic hydrocarbon ring of 6 to 30 ring-forming carbon atoms. The first to third aromatic rings may each independently be a six-member aromatic hydrocarbon ring. For example, the first to third aromatic rings may each be a benzene ring.

The fused polycyclic compound according to an embodiment may include a first substituent connected with the fused ring core. The first substituent may be connected with the first nitrogen atom of the fused ring core. The first substituent may include a first dibenzofuran moiety and a first sub-substituent connected with the first dibenzofuran moiety. The first sub-substituent may be a substituted or unsubstituted aryl group of 6 to 30 ring-forming carbon atoms, or a substituted or unsubstituted heteroaryl group of 2 to 30 ring-forming carbon atoms.

The first substituent may be connected with the first nitrogen atom of the fused ring core via a carbon atom at position 4 of the first dibenzofuran moiety. The first sub-substituent may be connected with a benzene ring connected with the first nitrogen atom among two benzene rings constituting the first dibenzofuran moiety. The carbon atom at position 4 of the first dibenzofuran moiety may be connected with the first nitrogen atom, and the first sub-substituent may be connected with at least one of the remaining carbon at positions 1 to 3. For example, the first nitrogen atom may be connected with the carbon atom at position 4 of the first dibenzofuran moiety, and the first sub-substituent may be connected with any one of the remaining carbon atoms at positions 1 to 3. In another embodiment, the first nitrogen atom may be connected with a carbon atom at position 4 of the first dibenzofuran moiety, and the first sub-substituent may be connected with two of the remaining carbon atoms at positions 1 to 3. In another embodiment, the first nitrogen atom may be connected with a carbon atom at position 4 of the first dibenzofuran moiety, and the first sub-substituent may be connected with each of the carbon atoms at positions 1 to 3. The first dibenzofuran moiety may be directly connected with the first nitrogen atom. For example, the first dibenzofuran moiety may be directly connected with the first nitrogen atom without a separate linking moiety. In the specification, the first sub-substituent may be referred to as an “aromatic substituent”.

The carbon numbers of the first dibenzofuran moiety are shown in Formula D.

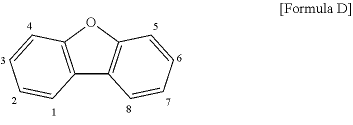 [SMILES: c1ccc2c(c1)oc1ccccc12]

For the carbon numbering of the first dibenzofuran moiety, the first dibenzofuran moiety may be disposed so that an oxygen atom (O) is positioned at the top as in Formula D, numbering starts from the carbon atom at a meta position with respect to the oxygen atom among the carbon atoms constituting the left benzene ring in a clockwise order, and the carbon atoms at fused positions are excluded from numbering.

For example, the fused polycyclic compound according to an embodiment may include a second substituent connected with an aromatic ring among the aromatic rings constituting the fused ring core. The second substituent is an electron donor substituent and may include a carbazole moiety. The second substituent may be connected with the first aromatic ring. The second substituent may be connected with the first aromatic ring at a para position with respect to the boron atom.

The fused polycyclic compound according to an embodiment may be represented by Formula 1.

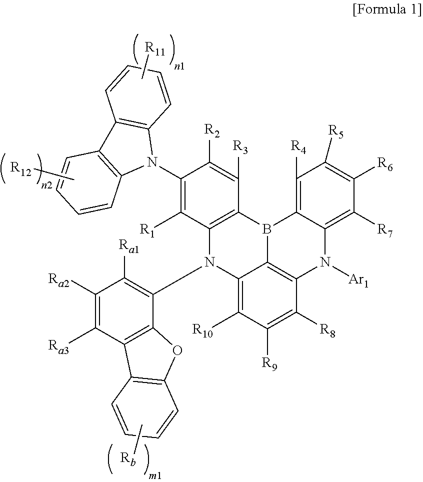

The fused polycyclic compound according to an embodiment, represented by Formula 1 may include a fused structure of three aromatic rings via a boron atom, a first nitrogen atom and a second nitrogen atom. In the specification, in Formula 1, a benzene ring at which substituents represented by R₁ to R₃ are substituted may correspond to the above-described first aromatic ring, a benzene ring at which substituents represented by R₄ to R₇ are substituted may correspond to the above-described second aromatic ring, and a benzene ring at which substituents represented by R₈ to R₁₀ are substituted may correspond to the above-described third aromatic ring. In Formula 1, a heterocycle at which substituents represented by Rₐ₁ to Rₐ₃, and Rₑ are substituted may correspond to the above-described first substituent. In Formula 1, a heterocycle at which substituents represented by R₁₁ and R₁₂ are substituted may correspond to the above-described second substituent.

In Formula 1, R₁ to R₁₀ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₁ to R₁₀ may each independently be a hydrogen atom, a deuterium atom, a cyano group, a substituted or unsubstituted methyl group, a substituted or unsubstituted n-propyl group, a substituted or unsubstituted isopropyl group, a substituted or unsubstituted diphenylamine group, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, a substituted or unsubstituted dibenzothiophene group, a substituted or unsubstituted dibenzoselenophene group, a substituted or unsubstituted fluorenyl group, or a substituted or unsubstituted triphenylsilyl group.

In an embodiment, in Formula 1, at least one of R₁ to R₁₀ may each independently be a group selected from Substituent Group 1, which will be explained later.

In Formula 1, Rₐ₁ to Rₐ₃ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, except that at least one of Rₐ₁ to Rₐ₃ may each independently be a substituted or unsubstituted aryl group of 6 to 30 ring-forming carbon atoms or a substituted or unsubstituted heteroaryl group of 2 to 30 ring-forming carbon atoms. For example, Rₐ₁ to Rₐ₃ may each independently be a hydrogen atom, a deuterium atom, a substituted or unsubstituted t-butyl group, a substituted or unsubstituted phenyl group, a substituted or unsubstituted biphenyl group, a substituted or unsubstituted naphthyl group, or a substituted or unsubstituted carbazole group.

In an embodiment, in Formula 1, at least one of Rₐ₁ to Rₐ₃ may be a substituted or unsubstituted aryl group of 6 to 30 ring-forming carbon atoms. For example, at least one of Rₐ₁ to Ran may be a substituted or unsubstituted phenyl group, a substituted or unsubstituted biphenyl group, or a substituted or unsubstituted naphthyl group.

In Formula 1, R_{b}, R₁₁, and R₁₂ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R_{b} may be a hydrogen atom, a deuterium atom, a substituted or unsubstituted t-butyl group, a substituted or unsubstituted phenyl group, or a substituted or unsubstituted carbazole group; and R₁₁, and R₁₂ may each independently be a hydrogen atom, a deuterium atom, a cyano group, a substituted or unsubstituted t-butyl group, a substituted or unsubstituted phenyl group, or a substituted or unsubstituted dibenzofuran group.

In Formula 1, Ar₁ may be a substituted or unsubstituted aryl group of 6 to 30 ring-forming carbon atoms or a substituted or unsubstituted heteroaryl group of 2 to 30 ring-forming carbon atoms. For example, Ar₁ may be a substituted or unsubstituted phenyl group, a substituted or unsubstituted biphenyl group, a substituted or unsubstituted terphenyl group or a substituted or unsubstituted dibenzofuran group.

In Formula 1, m1, n1, and n2 may each independently be an integer from 0 to 4. In Formula 1, if m1, n1 and n2 are 0, the fused polycyclic compound of an embodiment may be unsubstituted with R_{b}, R₁₁ and R₁₂, respectively. Cases where m1, n1 and n2 are 4, and all of R_{b}, R₁₁ and R₁₂ each are hydrogen atoms, may be the same as cases where m1, n1 and n2 are 0, respectively. If m1, n1 and n2 are integers of 2 or more, each of multiple R_{b}, R₁₁ and R₁₂ may be all the same, or at least one among each of multiple R_{b}, R₁₁ and R₁₂ may be different.

In an embodiment, in Formula 1, An may be a group represented by one of Formula X-1 to Formula X-5.

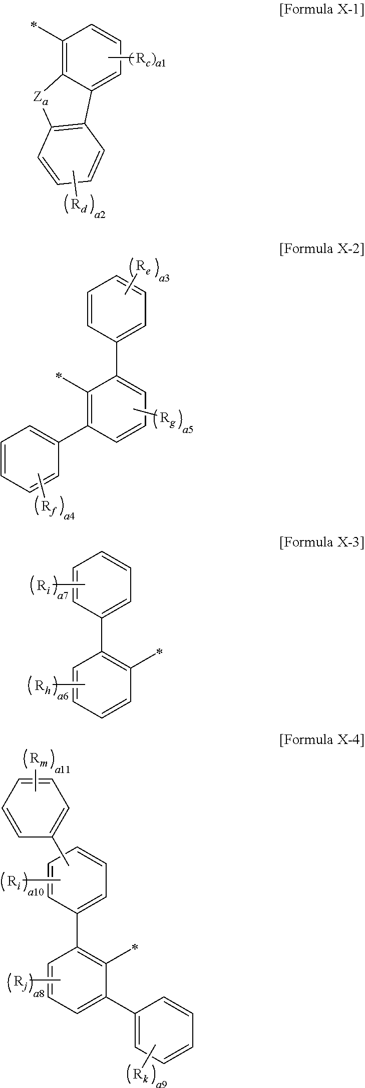

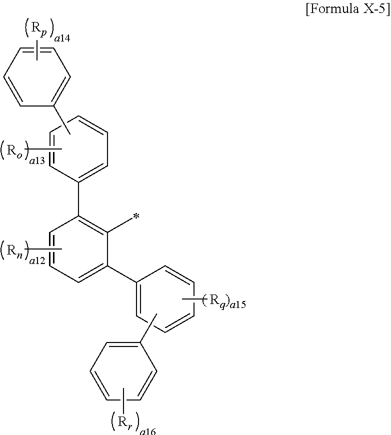

In Formula X-1, Zₐ may be O or S. For example, Zₐ may be O.

In Formula X-1 to Formula X-5, R_{c} to Rᵣ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula X-1 to Formula X-5, a1, a5, a8, and a12 may each independently be an integer from 0 to 3; a2, a6, a10, a13 and a15 may each independently be an integer from 0 to 4; and a3, a4, a7, a9, all, a14 and a16 may each independently be an integer from 0 to 5.

In Formula X-1 to Formula X-5, if a1 to a16 are 0, the fused polycyclic compound of an embodiment may be unsubstituted with R_{c} to Rᵣ, respectively. Cases where a1, a5, a8 and a12 are 3, and all R_{c}, R_{g}, Rⱼ and R₁ each are hydrogen atoms, may be the same as cases where a1, a5, a8 and a12 are 0, respectively. Cases where a2, a6, a10, a13, and a15 are 4, and all R_{d}, Rₕ, R₁, Rₒ, and R_{q} each are hydrogen atoms, may be the same as cases where a2, a6, a10, a13, and a15 are 0, respectively. Cases where a3, a4, a7, a9, all, a14, and a16 are 5, and all Rₑ, R_{f}, Rᵢ, Rₖ, Rₘ, Rₚ, and Rᵣ each are hydrogen atoms, may be the same as cases where a3, a4, a7, a9, all, a14, and a16 are 0, respectively. If a1 to a16 are integers of 2 or more, each of multiple R_{c} to Rᵣ may be all the same, or at least one among each of multiple R_{c} to Rᵣ may be different.

In an embodiment, the first compound represented may be represented by one of Formula 2-1 to Formula 2-3.

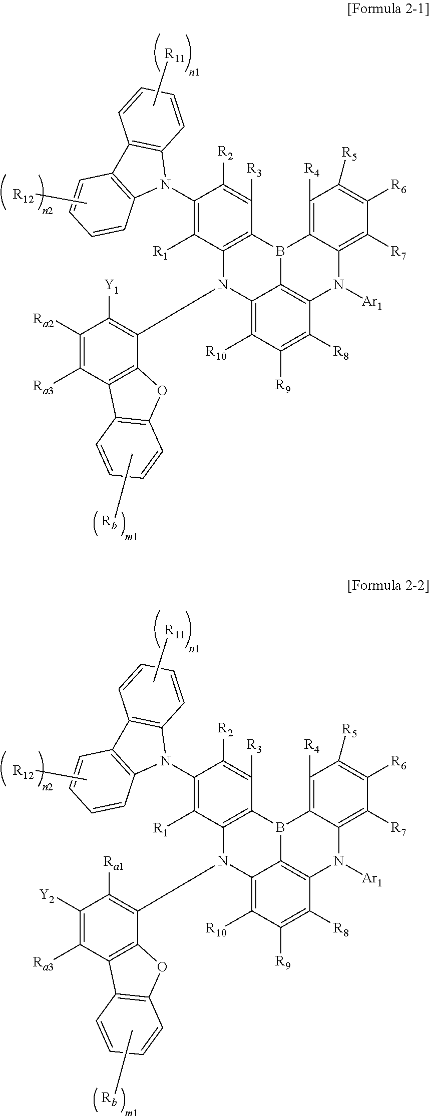

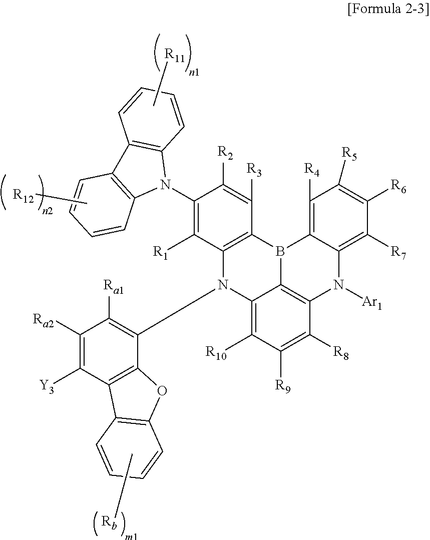

Formula 2-1 to Formula 2-3 represent embodiments in which Rₐ₁ to Rₐ₃ are further defined. Formula 2-1 represents Formula 1 in which Rₐ₁ may be an aryl group or a heteroaryl group. Formula 2-2 represents Formula 1 in which Rₐ₂ may be an aryl group or a heteroaryl group. Formula 2-3 represents Formula 1 in which Rₐ₃ may be an aryl group or a heteroaryl group.

In Formula 2-1 to Formula 2-3, Y₁ to Y₃ may each independently be a substituted or unsubstituted aryl group of 6 to 30 ring-forming carbon atoms or a substituted or unsubstituted heteroaryl group of 2 to 30 ring-forming carbon atoms. In an embodiment, Y₁ to Y₃ may each independently be a substituted or unsubstituted aryl group of 6 to 30 ring-forming carbon atoms. For example, Y₁ to Y₃ may each independently be a substituted or unsubstituted phenyl group, a substituted or unsubstituted biphenyl group, or a substituted or unsubstituted naphthyl group.

In Formula 2-1 to Formula 2-3, Ar₁, R₁ to R₁₂, Rₐ₁ to Rₐ₃, R_{b}, m1, n1, and n2 may be the same as described in Formula 1.

In an embodiment, the first compound may be represented by Formula 3.

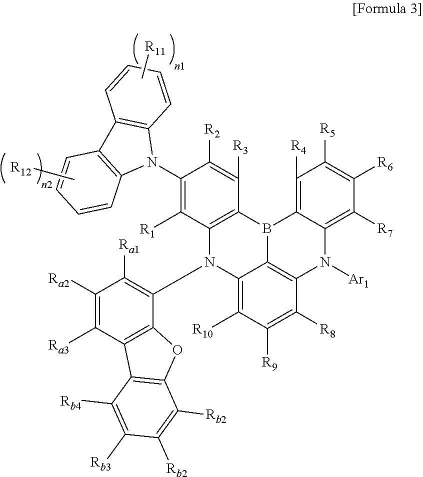

In Formula 3, R_{b1} to R_{b4} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted cycloalkyl group of 3 to 20 ring-forming carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, except that at least one of R_{b1} to R_{b4} may each independently be a substituted or unsubstituted aryl group of 6 to 30 ring-forming carbon atoms or a substituted or unsubstituted heteroaryl group of 2 to 30 ring-forming carbon atoms. For example, R_{b1} to R_{b4} may each independently be a hydrogen atom, a deuterium atom, a substituted or unsubstituted t-butyl group, a substituted or unsubstituted phenyl group or a substituted or unsubstituted carbazole group.

In an embodiment, in Formula 3, at least one of R_{b1} to R_{b4} may each independently be a substituted or unsubstituted phenyl group or a substituted or unsubstituted carbazole group.

In Formula 3, Ar₁, R₁ to R₁₂, Rₐ₁ to Rₐ₃, n1, and n2 may be the same as described in Formula 1.

In an embodiment, the first compound may be represented by Formula 4-1 or Formula 4-2.

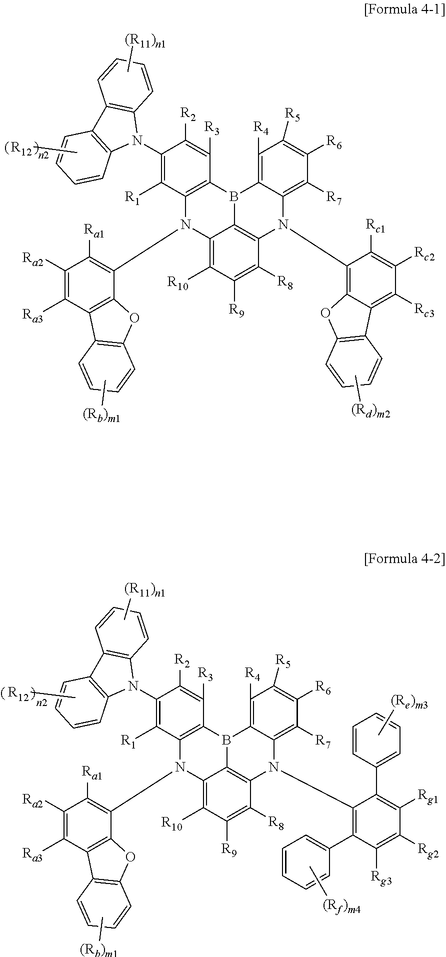

Formula 4-1 and Formula 4-2 represent embodiments in which a third substituent may be connected with the second nitrogen atom of the fused ring core of Formula 1. The fused polycyclic compound according to an embodiment may further include a third substituent connected with the fused ring core. The third substituent may include a dibenzofuran moiety or a terphenyl moiety. Formula 4-1 represents a case of including a dibenzofuran moiety as the third substituent. Formula 4-2 represents a case of including a terphenyl moiety as the third substituent.

In an embodiment, the third substituent may include a dibenzofuran moiety. For example, the third substituent may include a second dibenzofuran moiety and a second sub-substituent connected with the second dibenzofuran moiety. The second sub-substituent may be a substituted or unsubstituted aryl group of 6 to 30 ring-forming carbon atoms or a substituted or unsubstituted heteroaryl group of 2 to 30 ring-forming carbon atoms. The second substituent may be connected with the second nitrogen atom of the fused ring core via the carbon at position 4 of the second dibenzofuran moiety. The second sub-substituent may be connected with a benzene ring connected with the second nitrogen atom among two benzene rings constituting the second dibenzofuran moiety. For example, the carbon at position 4 of the second dibenzofuran moiety may be connected with the second nitrogen atom, and the second sub-substituent may be connected with at least one among the remaining carbon at positions 1 to 3. The carbon numbering of the first substituent may be the same as the carbon numbering of the second dibenzofuran moiety.

In another embodiment, the second substituent may include a terphenyl moiety. For example, the third substituent may include a connected structure of three benzene moieties. For example, the third substituent may include a first benzene moiety connected with the second nitrogen atom of the fused ring core, and second and third benzene moieties substituted at specific positions of the first benzene moiety. For example, the third substituent may include a first benzene moiety connected with the second nitrogen atom of the fused ring core, and second and third benzene moieties connected with carbon atoms at ortho positions with respect to the second nitrogen atom among carbon atoms constituting the first benzene moiety.

In Formula 4-1 and Formula 4-2, R_{c1} to R_{c3}, R_{d}, Rₑ, R_{f}, and R_{g1} to R_{g3} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R_{c1} to R_{c3} may each independently be a hydrogen atom, a deuterium atom, a substituted or unsubstituted t-butyl group, a substituted or unsubstituted phenyl group, a substituted or unsubstituted biphenyl group, or a substituted or unsubstituted naphthyl group. For example, R_{d} may be a hydrogen atom, a deuterium atom, a cyano group, a substituted or unsubstituted t-butyl group, a substituted or unsubstituted phenyl group, or a substituted or unsubstituted carbazole group. For example, Rₑ and R_{f} may each independently be a hydrogen atom, a deuterium atom, a substituted or unsubstituted t-butyl group, or a substituted or unsubstituted phenyl group. For example, R_{g1} to R_{g3} may each independently be a hydrogen atom, a deuterium atom, or a substituted or unsubstituted t-butyl group.

In Formula 4-1, m2 may be an integer from 0 to 4. In Formula 4-1, if m2 is 0, the fused polycyclic compound of an embodiment may be unsubstituted with R_{d}. In Formula 4-1, a case where m2 is 4, and all R_{d} are hydrogen atoms, may be the same as a case of Formula 4-1 where m2 is 0. If m2 is an integer of 2 or more, multiple R_{d} may be all the same, or at least one among multiple R_{d} may be different.

In Formula 4-2, m3 and m4 may each independently be an integer from 0 to 5. In Formula 4-2, if m3 and m4 are 0, the fused polycyclic compound of an embodiment may be unsubstituted with Rₑ and R_{f}, respectively. Cases where m3 and m4 are 5, and all Rₑ and R_{f} each are hydrogen atoms, may be the same as cases where m3 and m4 are 0, respectively. If m3 and m4 are integers of 2 or more, each of multiple Rₑ and R_{f} may be all the same, or at least one among each of multiple Rₑ and R_{f} may be different.

In Formula 4-1, at least one of R_{c1} to R_{c3} may each independently be a substituted or unsubstituted aryl group of 6 to 30 ring-forming carbon atoms or a substituted or unsubstituted heteroaryl group of 2 to 30 ring-forming carbon atoms. For example, at least one of R_{c1} to R_{c3} may each independently be a substituted or unsubstituted phenyl group, a substituted or unsubstituted biphenyl group, or a substituted or unsubstituted naphthyl group.

In Formula 4-1 and Formula 4-2, R₁ to R₁₂, Rₐ₁ to Rₐ₃, R_{b}, m1, n1, and n2 may be the same as described in Formula 1.

In an embodiment, the first compound may be represented by Formula 5.

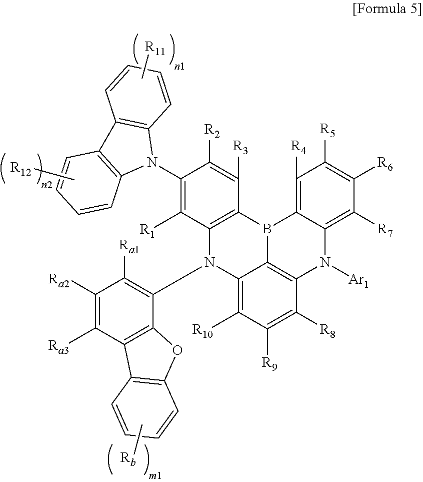

In Formula 5, Z₁ to Z₅ may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, except that at least one of Z₁ to Z₅ may each independently be a substituted or unsubstituted alkyl group of 1 to 10 carbon atoms, or a group represented by one of Formula A-1 to Formula A-5. For example, Z₁ to Z₅ may each independently be a hydrogen atom, a deuterium atom, a cyano group, a substituted or unsubstituted methyl group, a substituted or unsubstituted n-propyl group, a substituted or unsubstituted isopropyl group, a substituted or unsubstituted t-butyl group, a substituted or unsubstituted diphenylamine group, a substituted or unsubstituted phenyl group, a substituted or unsubstituted biphenyl group, a substituted or unsubstituted carbazole group, a substituted or unsubstituted dibenzofuran group, a substituted or unsubstituted dibenzothiophene group, a substituted or unsubstituted dibenzoselenophene group, a substituted or unsubstituted fluorene group, or a substituted or unsubstituted triphenylsilyl group.

In an embodiment, in Formula 5, at least one of Z₂ and Z₃ may each independently be a group represented by one of Formula A-1 to Formula A-5. For example, in Formula 5, Z₂ may be a group represented by one of Formula A-1 to Formula A-5. As another example, in Formula 5, Z₃ may be a group represented by one of Formula A-1 to Formula A-5.

In an embodiment, in Formula 5, at least one of Z₂, Z₃ and Z₅ may each independently be a substituted or unsubstituted alkyl group of 1 to 10 carbon atoms, or a group represented by one among Formula A-1 to Formula A-5. For example, in Formula 5, Z₂ and Z₅ may each independently be a substituted or unsubstituted methyl group, a substituted or unsubstituted n-propyl group, a substituted or unsubstituted isopropyl group, or a substituted or unsubstituted t-butyl group, or a group represented by one of Formula A-1 to Formula A-5. In another embodiment, in Formula 5, Z₃ and Z₅ may each independently be a substituted or unsubstituted methyl group, a substituted or unsubstituted n-propyl group, a substituted or unsubstituted isopropyl group, or a substituted or unsubstituted t-butyl group, or a group represented by one of Formula A-1 to Formula A-5.

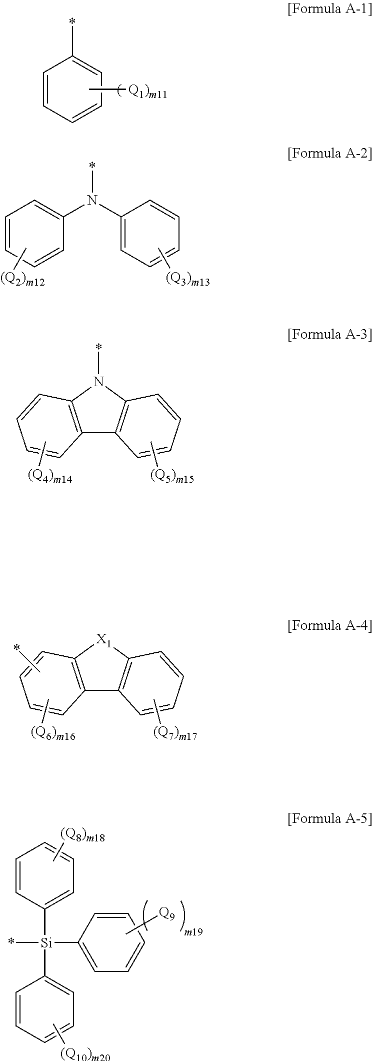

In Formula A-1 to Formula A-5, X₁ may be O, S, Se, N(Q₁₁), or C(Q₁₂)(Q₁₃).

In Formula A-1 to Formula A-5, Q₁ to Q₁₃ may each independently be a hydrogen atom, a deuterium atom, a halogen atom, a cyano group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Q₁ to Q₁₃ may each independently be a hydrogen atom, a deuterium atom, a cyano group, a substituted or unsubstituted methyl group, a substituted or unsubstituted t-butyl group, a substituted or unsubstituted triphenylsilyl group, or a substituted or unsubstituted phenyl group.

In Formula A-1 to Formula A-5, m11 to m13 and m18 to m20 may each independently be an integer from 0 to 5; m14, m15, and m17 may each independently be an integer from 0 to 4; and m16 may be an integer from 0 to 3.

In Formula A-1 to Formula A-5, if m11 to m20 are 0, the fused polycyclic compound of an embodiment may be unsubstituted with Q₁ to Q₁₀, respectively. Cases where m11 to m13, and m18 to m20 are 5, and all Q₁ to Q₃, and Q₈ to Q₁₀ each are hydrogen atoms, may be the same as cases where m11 to m13, and m18 to m20 are 0, respectively. Cases where m14, m15, and m17 are 4, and all Q₄, Q₅ and Q₇ each all hydrogen atoms, may be the same as cases where m14, m15, and m17 are 0, respectively. A case where m16 is 3, and all Q₆ are hydrogen atoms, may be the same as a case where m16 is 0. If m11 to m20 are 2 or more, multiple groups of Q₁ to Q₁₀ may be all the same, or at least one of Q₁ to Q₁₀ may be different.

In Formula 5, Ar₁, R₁ to R₃, R₈, R₁₀ to R₁₂, Rₐ₁ to Rₐ₃, R_{b}, m1, n1, and n2 may be the same as described in Formula 1.

In an embodiment, at least one of Z₁ to Z₅ may each independently be a group selected from Substituent Group 1.

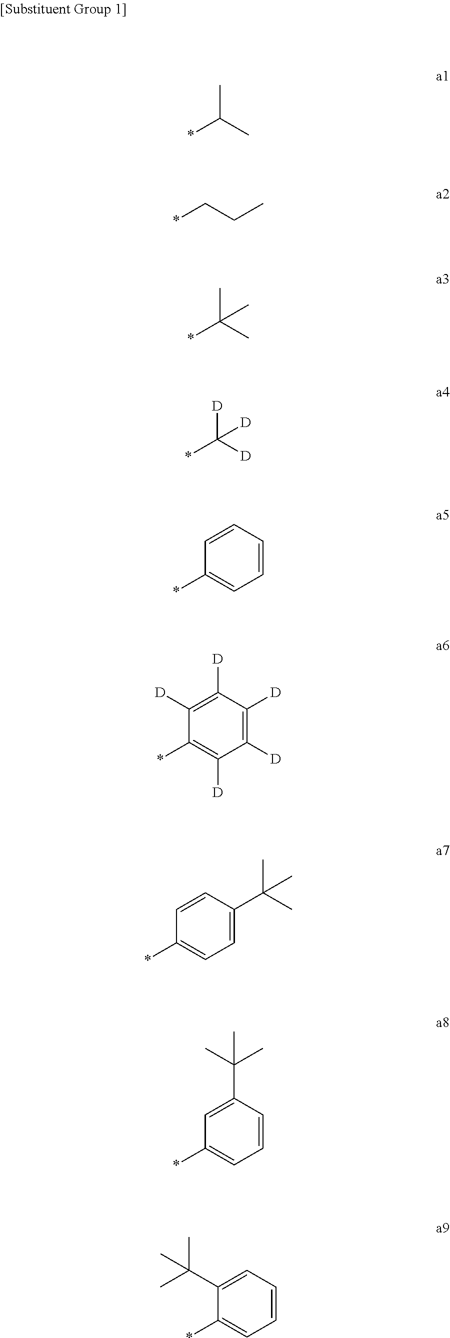

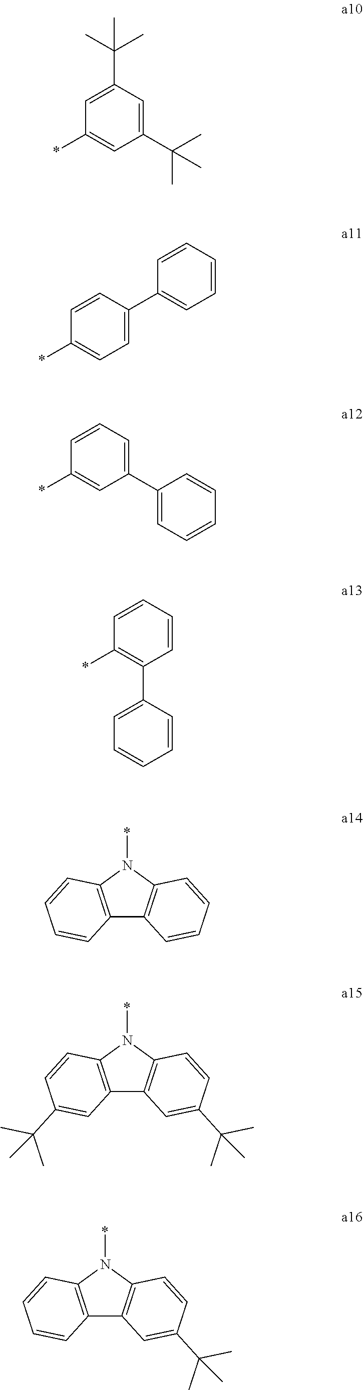

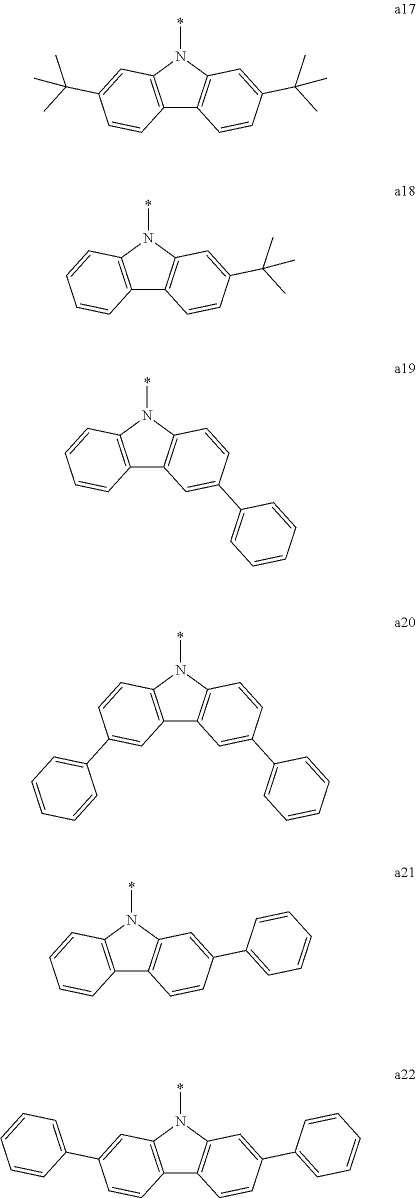 [SMILES: *n1c2cc(C(C)(C)C)ccc2c2ccc(C(C)(C)C)cc21 ; *n1c2ccccc2c2ccc(C(C)(C)C)cc21 ; *n1c2ccccc2c2cc(-c3ccccc3)ccc21 ; *n1c2ccc(-c3ccccc3)cc2c2cc(-c3ccccc3)ccc21 ; *n1c2ccccc2c2ccc(-c3ccccc3)cc21 ; *n1c2cc(-c3ccccc3)ccc2c2ccc(-c3ccccc3)cc21]

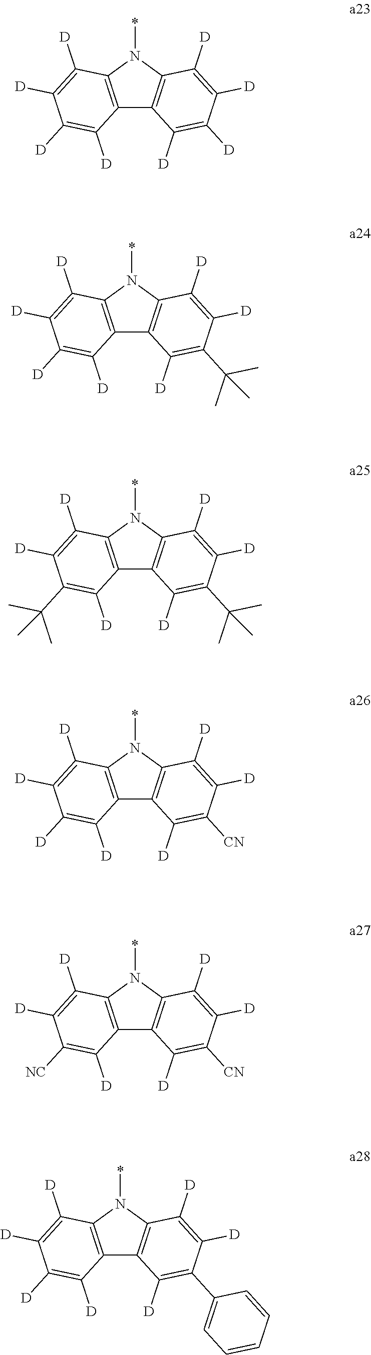

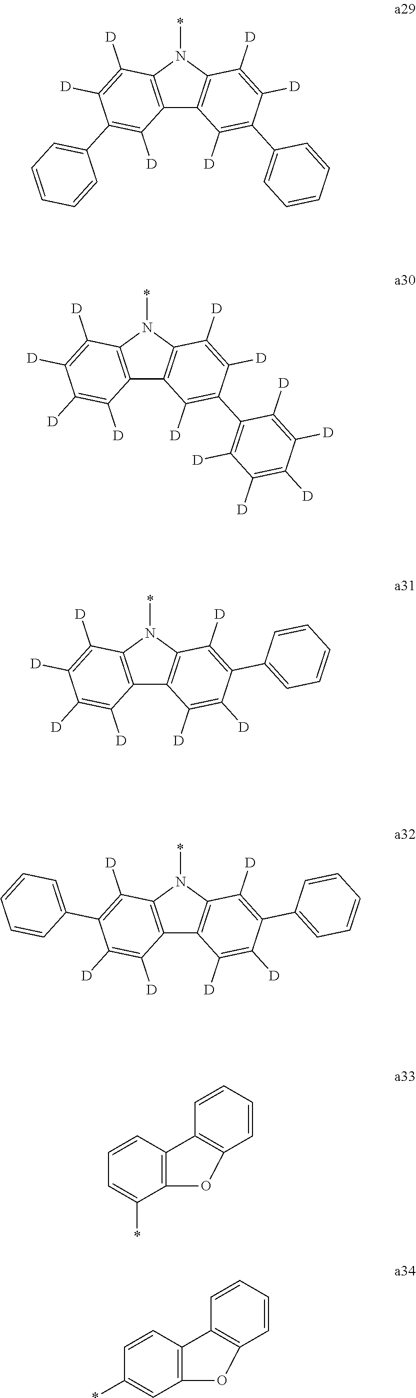 [SMILES: *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *n1c2c([2H])c([2H])c([2H])c([2H])c2c2c([2H])c([2H])c(-c3ccccc3)c([2H])c21 ; *n1c2c([2H])c(-c3ccccc3)c([2H])c([2H])c2c2c([2H])c([2H])c(-c3ccccc3)c([2H])c21 ; *c1cccc2c1oc1ccccc12 ; *c1ccc2c(c1)oc1ccccc12]

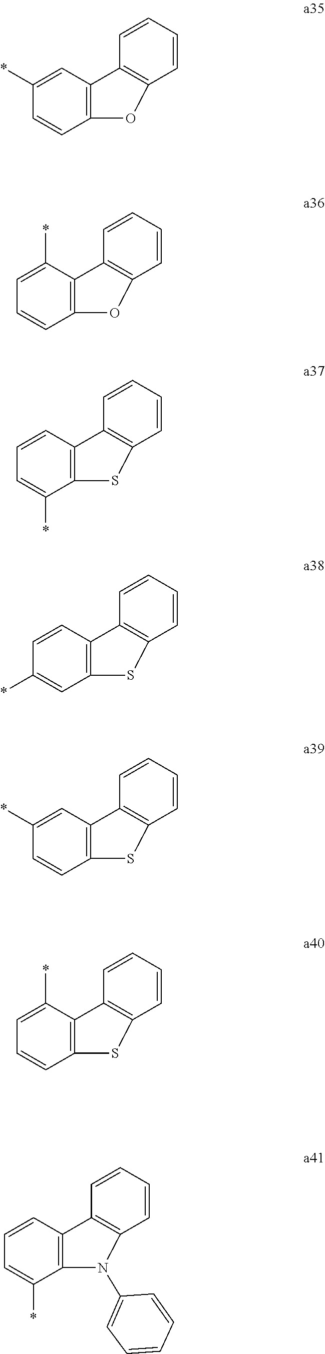

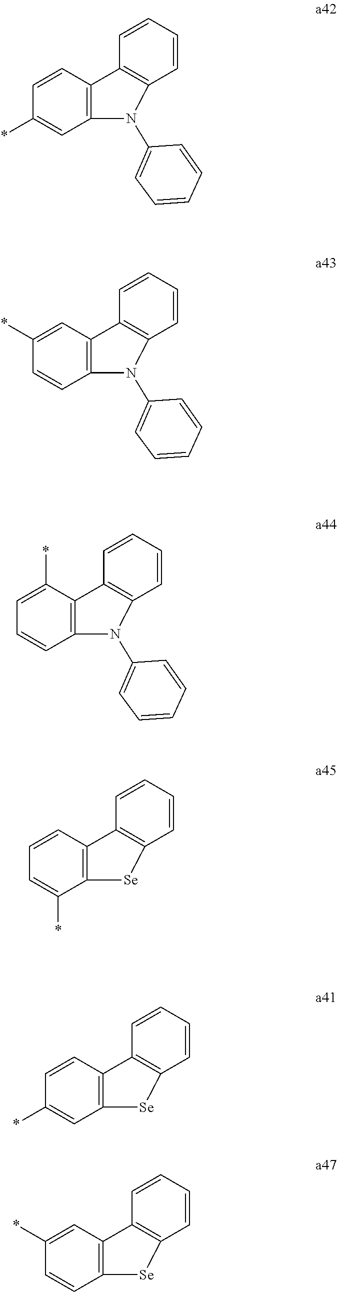 [SMILES: *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1 ; *c1cccc2c1[se]c1ccccc12 ; *c1ccc2c(c1)[se]c1ccccc12 ; *c1ccc2[se]c3ccccc3c2c1]

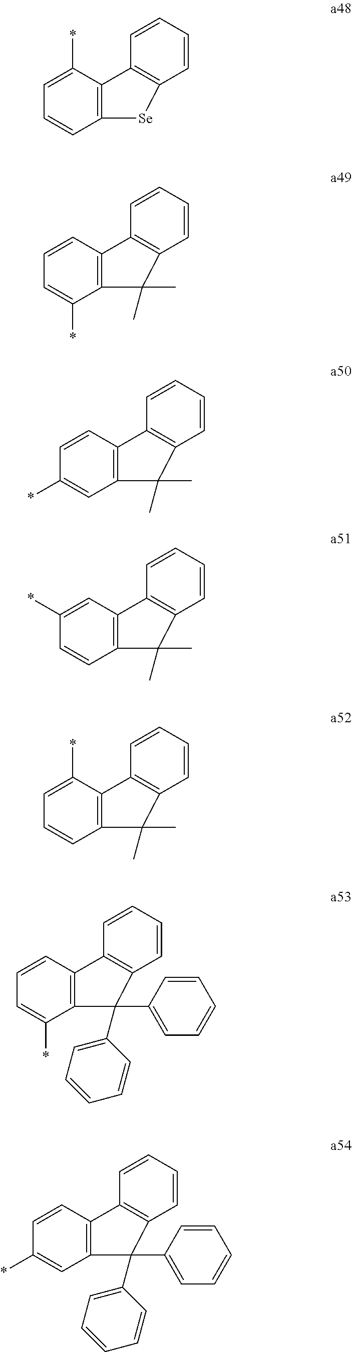

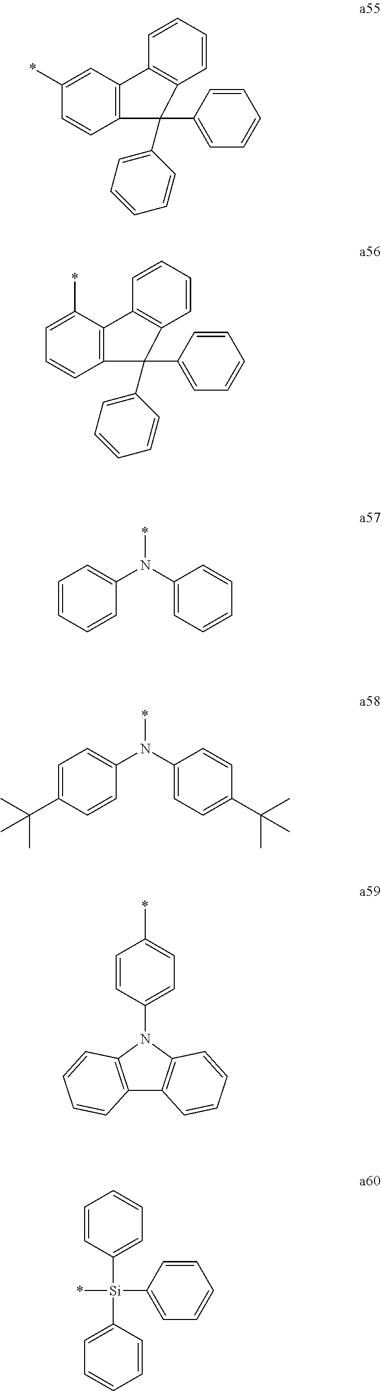 [SMILES: *c1ccc2c(c1)-c1ccccc1C2(c1ccccc1)c1ccccc1 ; *c1cccc2c1-c1ccccc1C2(c1ccccc1)c1ccccc1 ; *N(c1ccccc1)c1ccccc1 ; *N(c1ccc(C(C)(C)C)cc1)c1ccc(C(C)(C)C)cc1 ; *c1ccc(-n2c3ccccc3c3ccccc32)cc1 ; *[Si](c1ccccc1)(c1ccccc1)c1ccccc1]

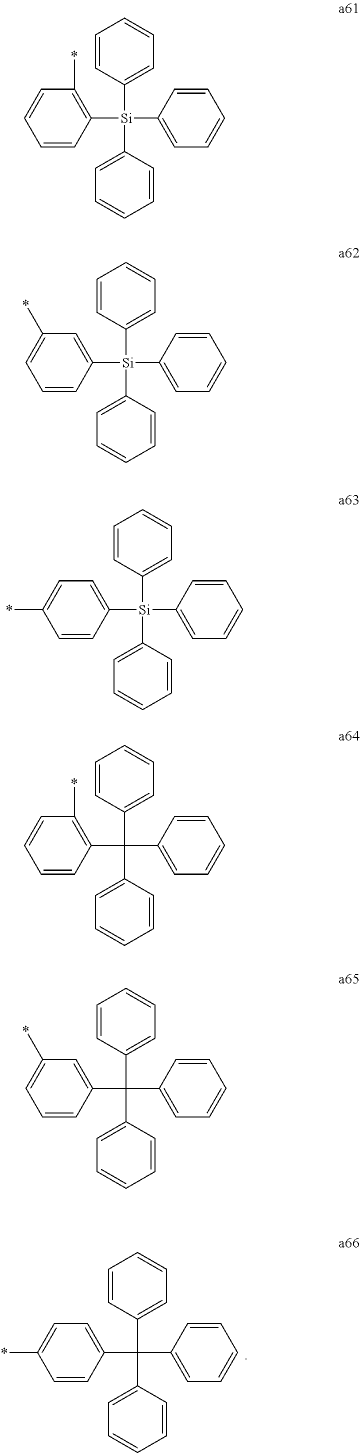

In an embodiment, the first compound may be represented by Formula 6-1 or Formula 6-2.

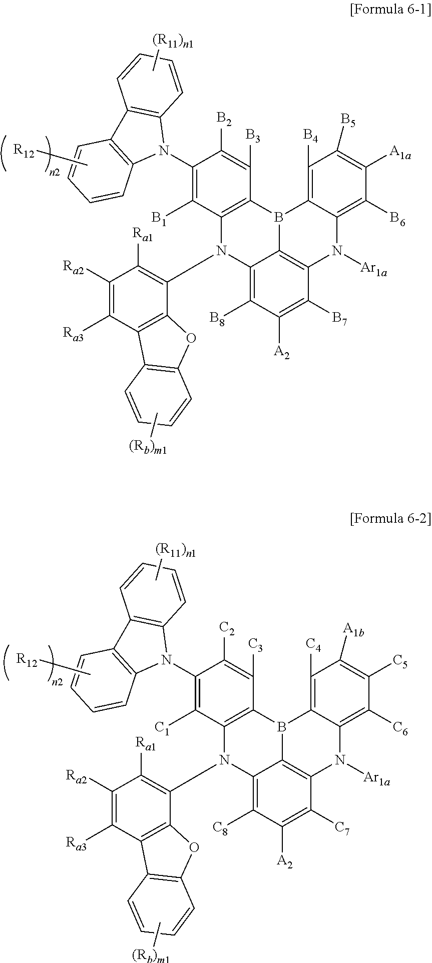

In Formula 6-1 and Formula 6-2, A₁ₐ and A_{1b} may each independently be a cyano group, a substituted or unsubstituted amine group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms. For example, A₁ₐ and A_{1b} may each independently be a cyano group, a substituted or unsubstituted t-butyl group, a substituted or unsubstituted phenyl group, a substituted or unsubstituted biphenyl group, a substituted or unsubstituted carbazole group, or a substituted or unsubstituted triphenylsilyl group. In an embodiment, in Formula 6-1 and Formula 6-2, A₁ₐ and A_{1b} may each independently be a group selected from Substituent Group 1.

In Formula 6-1 and Formula 6-2, A₂ may be a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms. For example, A₂ may be a substituted or unsubstituted methyl group, a substituted or unsubstituted n-propyl group, a substituted or unsubstituted isopropyl group, a substituted or unsubstituted t-butyl group, a substituted or unsubstituted phenyl group, a substituted or unsubstituted biphenyl group, a substituted or unsubstituted dibenzofuran group, a substituted or unsubstituted dibenzothiophene group, a substituted or unsubstituted dibenzoselenophene group, a substituted or unsubstituted carbazole group, or a substituted or unsubstituted fluorene group. In an embodiment, in Formula 6-1 and Formula 6-2, A₂ may be a group selected from Substituent Group 1.

In Formula 6-1 and Formula 6-2, B₁ to B₈ and C₁ to C₈ may each independently be a hydrogen atom or a deuterium atom.

In Formula 6-1 and Formula 6-2, Ar₁ₐ may be a group represented by Formula B-1 or Formula B-2.

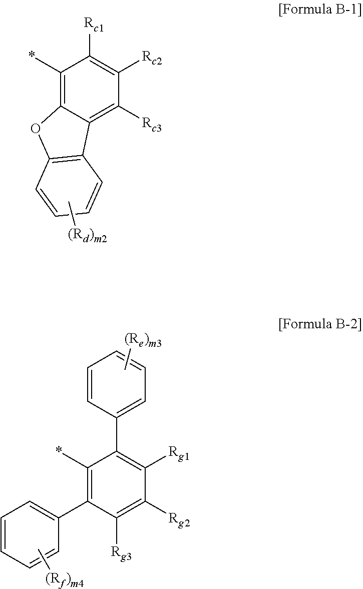

In Formula B-1 and Formula B-2, R_{c1} to R_{c3}, R_{d}, Rₑ, R_{f}, and R_{g1} to R_{g3} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R_{c1} to R_{c3} may each independently be a hydrogen atom, a deuterium atom, a substituted or unsubstituted t-butyl group, a substituted or unsubstituted phenyl group, a substituted or unsubstituted biphenyl group, or a substituted or unsubstituted naphthyl group. For example, R_{d} may be a hydrogen atom, a deuterium atom, a cyano group, a substituted or unsubstituted t-butyl group, a substituted or unsubstituted phenyl group, or a substituted or unsubstituted carbazole group. For example, Rₑ and R_{f} may each independently be a hydrogen atom, a deuterium atom, a substituted or unsubstituted t-butyl group, or a substituted or unsubstituted phenyl group. For example, R_{g1} to R_{g3} may each independently be a hydrogen atom, a deuterium atom, or a substituted or unsubstituted t-butyl group.

In Formula B-1, m2 may be an integer from 0 to 4. In Formula B-1, if m2 is 0, the fused polycyclic compound of an embodiment may be unsubstituted with R_{d}. In Formula B-1, a case where m2 is 4, and all R_{d} are hydrogen atoms, may be the same as a case where m2 is 0. If m2 is an integer of 2 or more, multiple R_{d} may be all the same, or at least one among multiple R_{d} may be different.

In Formula B-2, m3 and m4 may each independently be an integer from 0 to 5. In Formula B-2, if m3 and m4 are 0, the fused polycyclic compound of an embodiment may be unsubstituted with Rₑ and R_{f}, respectively. Cases where m3 and m4 are 5, and all Rₑ and R_{f} each are hydrogen atoms, may be the same as cases where m3 and m4 are 0, respectively. If m3 and m4 are integers of 2 or more, each of multiple Rₑ and R_{f} may be all the same, or at least one among each of multiple Rₑ and R_{f} may be different.

In Formula B-1, at least one of R_{c1} to R_{c3} may each independently be a substituted or unsubstituted aryl group of 6 to 30 ring-forming carbon atoms or a substituted or unsubstituted heteroaryl group of 2 to 30 ring-forming carbon atoms. For example, at least one of R_{c1} to R_{c3} may each independently be a substituted or unsubstituted phenyl group, a substituted or unsubstituted biphenyl group, or a substituted or unsubstituted naphthyl group.

In Formula 6-1 and Formula 6-2, R₁₁, R₁₂, Rₐ₁ to Rₐ₃, R_{b}, m1, n1, and n2 may be the same as described in Formula 1.

In an embodiment, the first compound may be represented by Formula 7-1 or Formula 7-2.

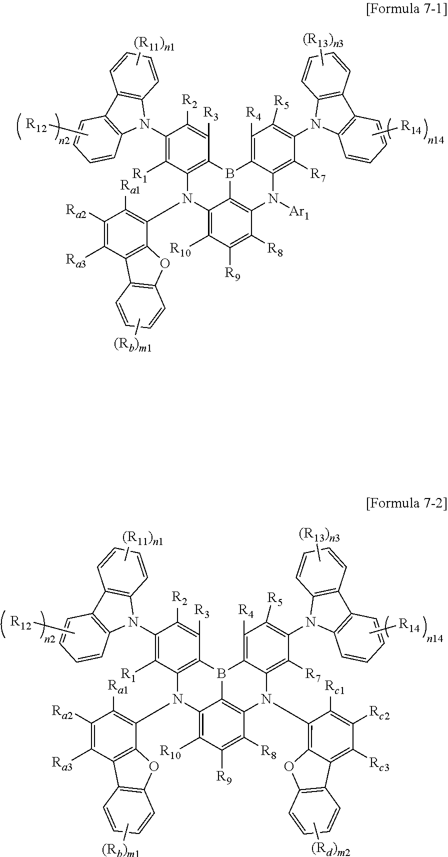

The fused polycyclic compound according to an embodiment may further include a fourth substituent which may be connected with an aromatic ring of the fused ring core. The fourth substituent may be an electron donor substituent and may include a carbazole moiety. The fourth substituent may be connected with the second aromatic ring of the fused ring core. The fourth substituent may be connected with the second aromatic ring at a para position with respect to the boron atom. In Formula 7-1 and Formula 7-2, the heterocycle that includes R₁₃ and R₁₄ may correspond to the fourth substituent.

In Formula 7-1 and Formula 7-2, R₁₃, R₁₄, R_{c1} to R_{c3}, and R_{d} may each independently be a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R₁₃ and R₁₄ may each independently be a hydrogen atom, a deuterium atom, a cyano group, a substituted or unsubstituted t-butyl group, or a substituted or unsubstituted phenyl group.

In Formula 7-1 and Formula 7-2, n13, n14, and m2 may each independently be an integer from 0 to 4. In Formula 7-1 and Formula 7-2, if n13, n14 and m2 are 0, the fused polycyclic compound of an embodiment may be unsubstituted with R₁₃, R₁₄, and R_{d}, respectively. Cases where n13, n14 and m2 are 4, and all R₁₃, R₁₄, and R_{d} each are hydrogen atoms, may be the same as cases where n13, n14 and m2 are 0. If n13, n14 and m2 are integers of 2 or more, each of multiple R₁₃, R₁₄, and R_{d} may be all the same, or at least one among each of multiple R₁₃, R₁₄, and R_{d} may be different.

In Formula 7-1 and Formula 7-2, Ar₁, R₁ to R₈, R₇ to R₁₂, Rₐ₁ to R₃, R_{b}, m1, n1, and n2 may be the same as described in Formula 1.

In an embodiment, the fused polycyclic compound, represented by Formula 1 may include at least one deuterium atom as a substituent. In an embodiment, in the fused polycyclic compound represented by Formula 1, at least one hydrogen atom may be optionally substituted with a deuterium atom.

In an embodiment, the fused polycyclic compound may be any compound selected from Compound Group 1. At least one functional layer included in the light emitting element ED according to an embodiment may each independently include at least one fused polycyclic compound selected from Compound Group 1. In an embodiment, in light emitting element ED, the at least one functional layer (for example, an emission layer EML) may include at least one fused polycyclic compound selected from Compound Group 1.

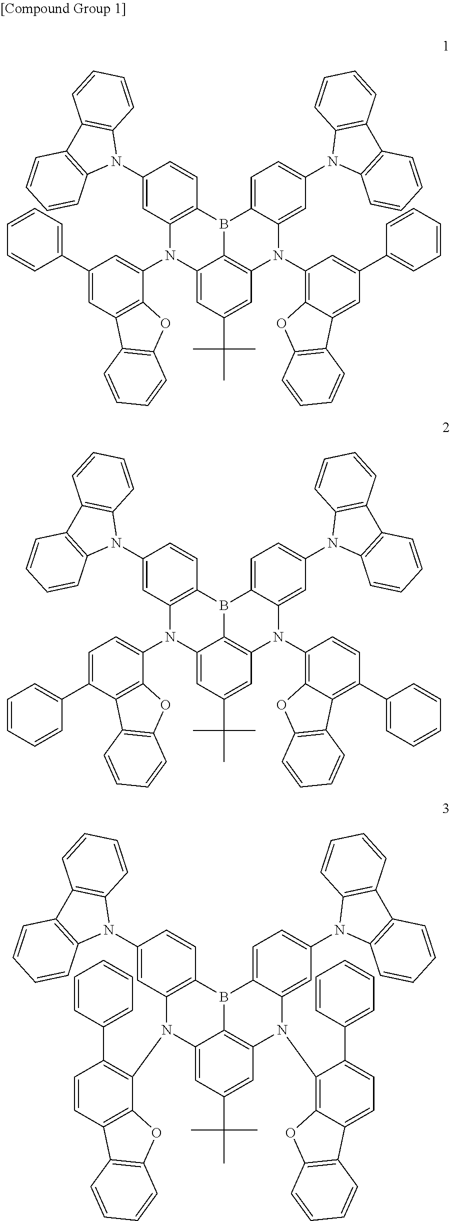 [SMILES: CC(C)(C)c1cc2c3c(c1)N(c1cc(-c4ccccc4)cc4c1oc1ccccc14)c1cc(-n4c5ccccc5c5ccccc54)ccc1B3c1ccc(-n3c4ccccc4c4ccccc43)cc1N2c1cc(-c2ccccc2)cc2c1oc1ccccc12 ; CC(C)(C)c1cc2c3c(c1)N(c1ccc(-c4ccccc4)c4c1oc1ccccc14)c1cc(-n4c5ccccc5c5ccccc54)ccc1B3c1ccc(-n3c4ccccc4c4ccccc43)cc1N2c1ccc(-c2ccccc2)c2c1oc1ccccc12 ; CC(C)(C)c1cc2c3c(c1)N(c1c(-c4ccccc4)ccc4c1oc1ccccc14)c1cc(-n4c5ccccc5c5ccccc54)ccc1B3c1ccc(-n3c4ccccc4c4ccccc43)cc1N2c1c(-c2ccccc2)ccc2c1oc1ccccc12]

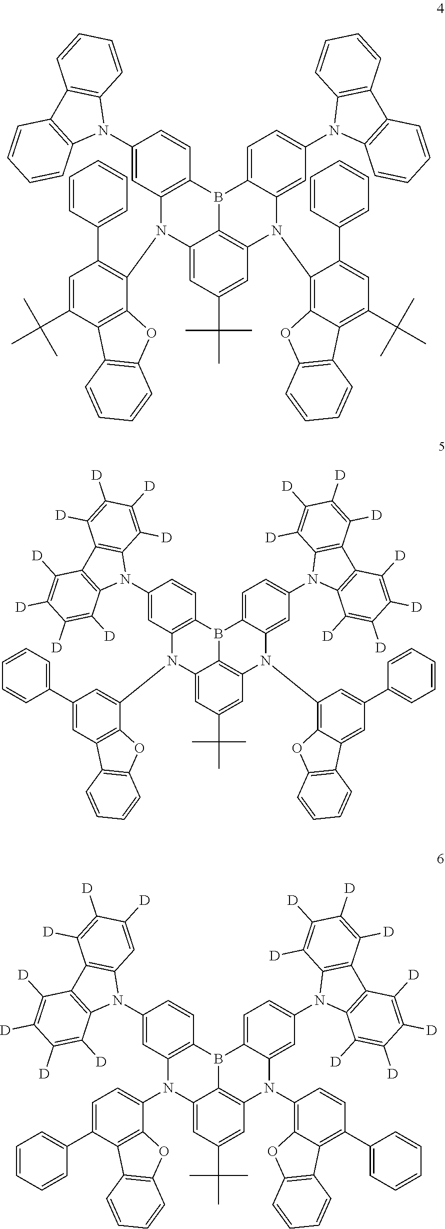

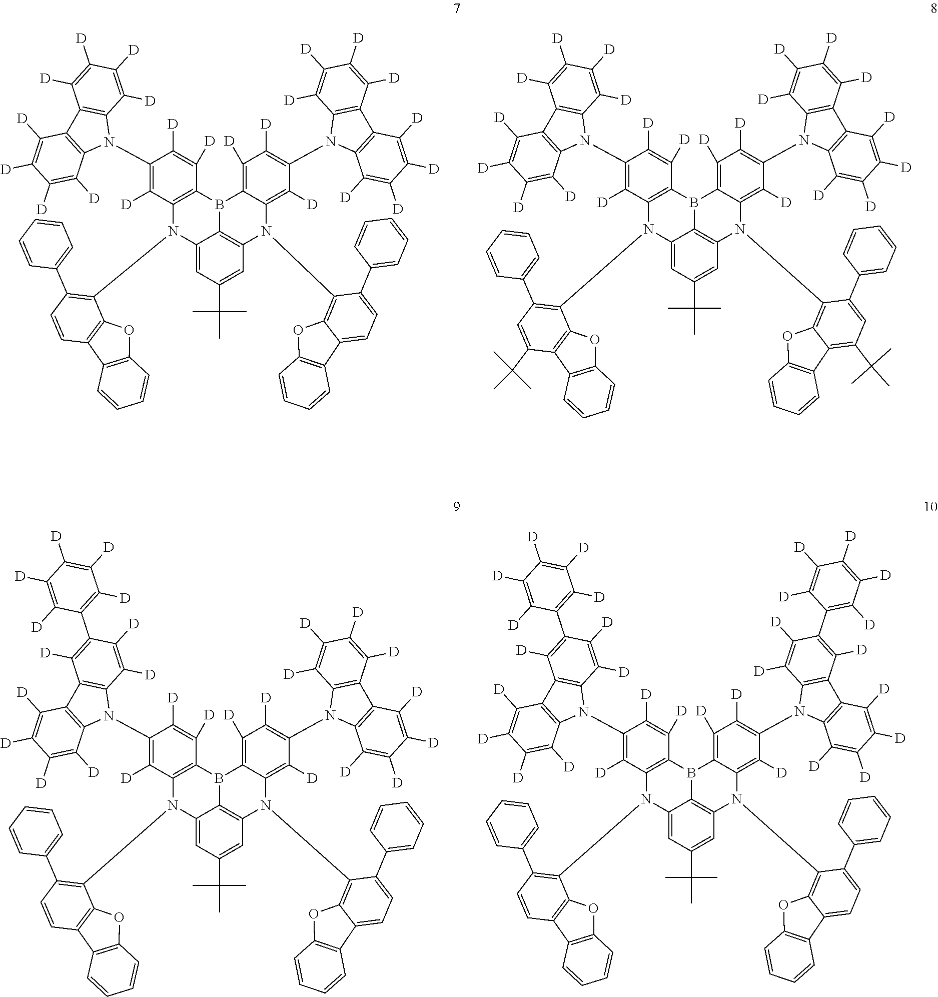

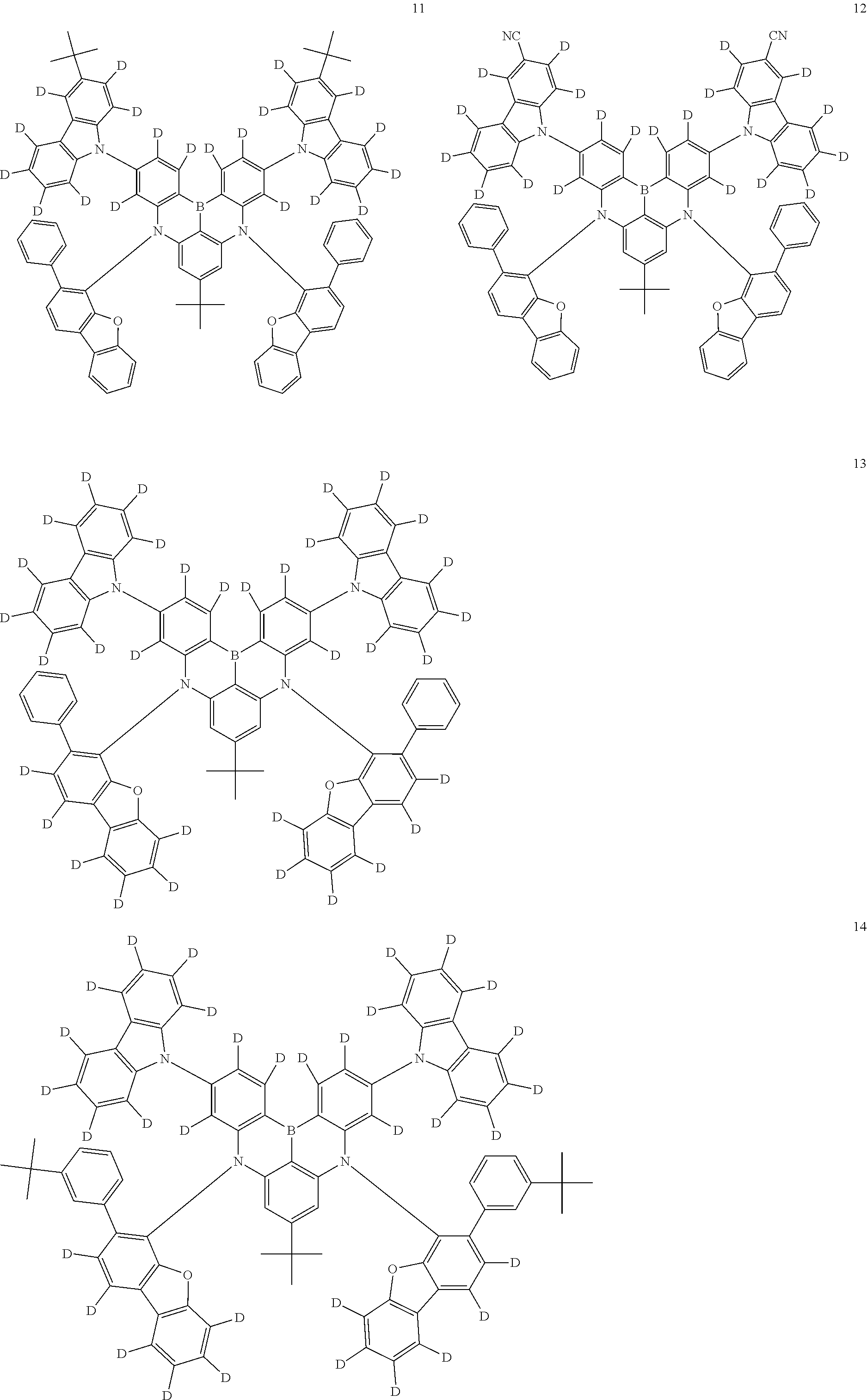

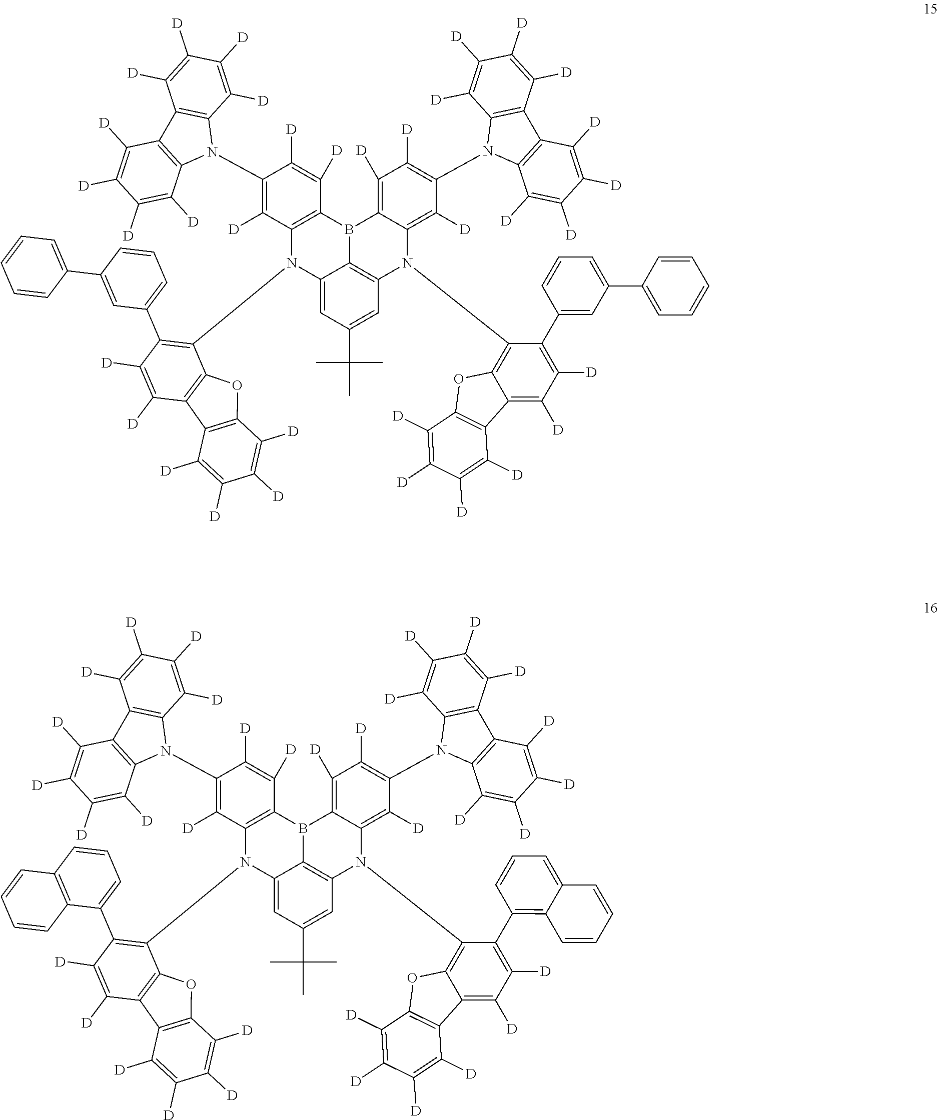

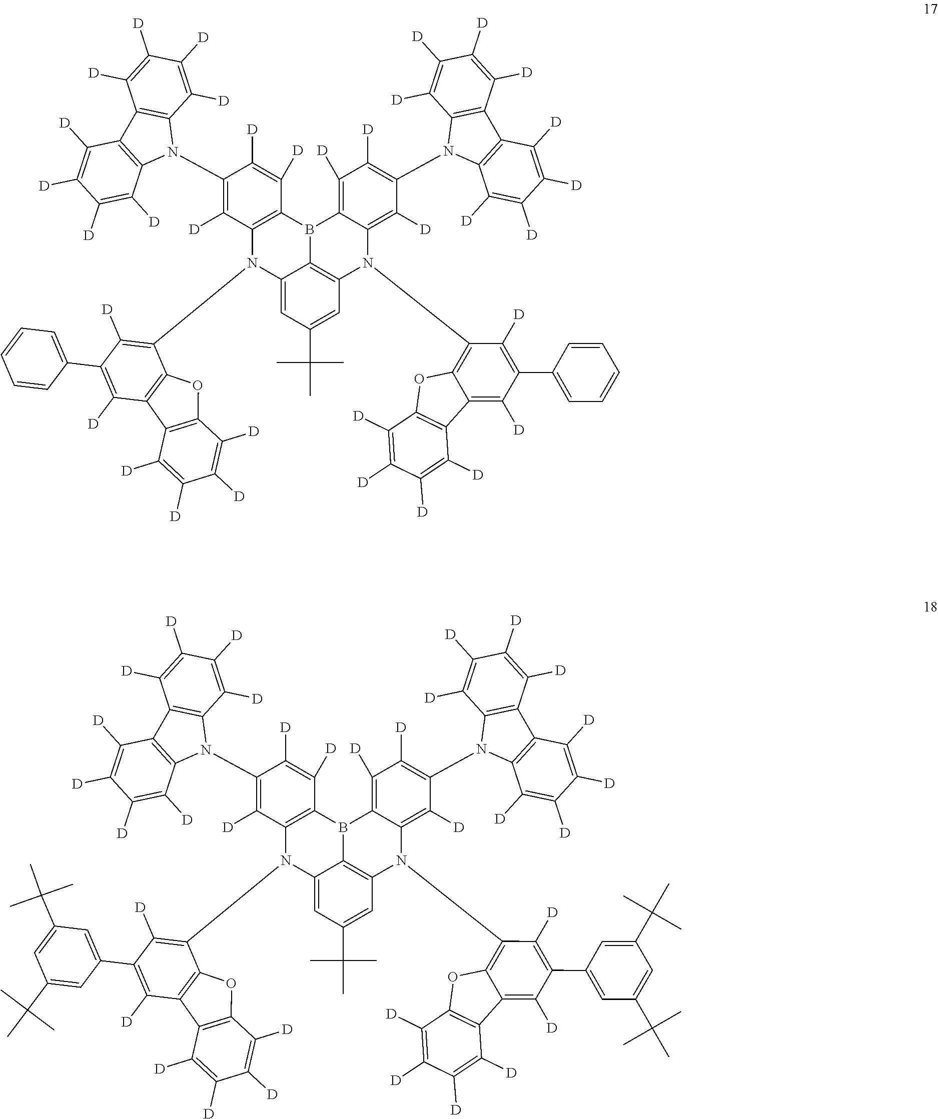

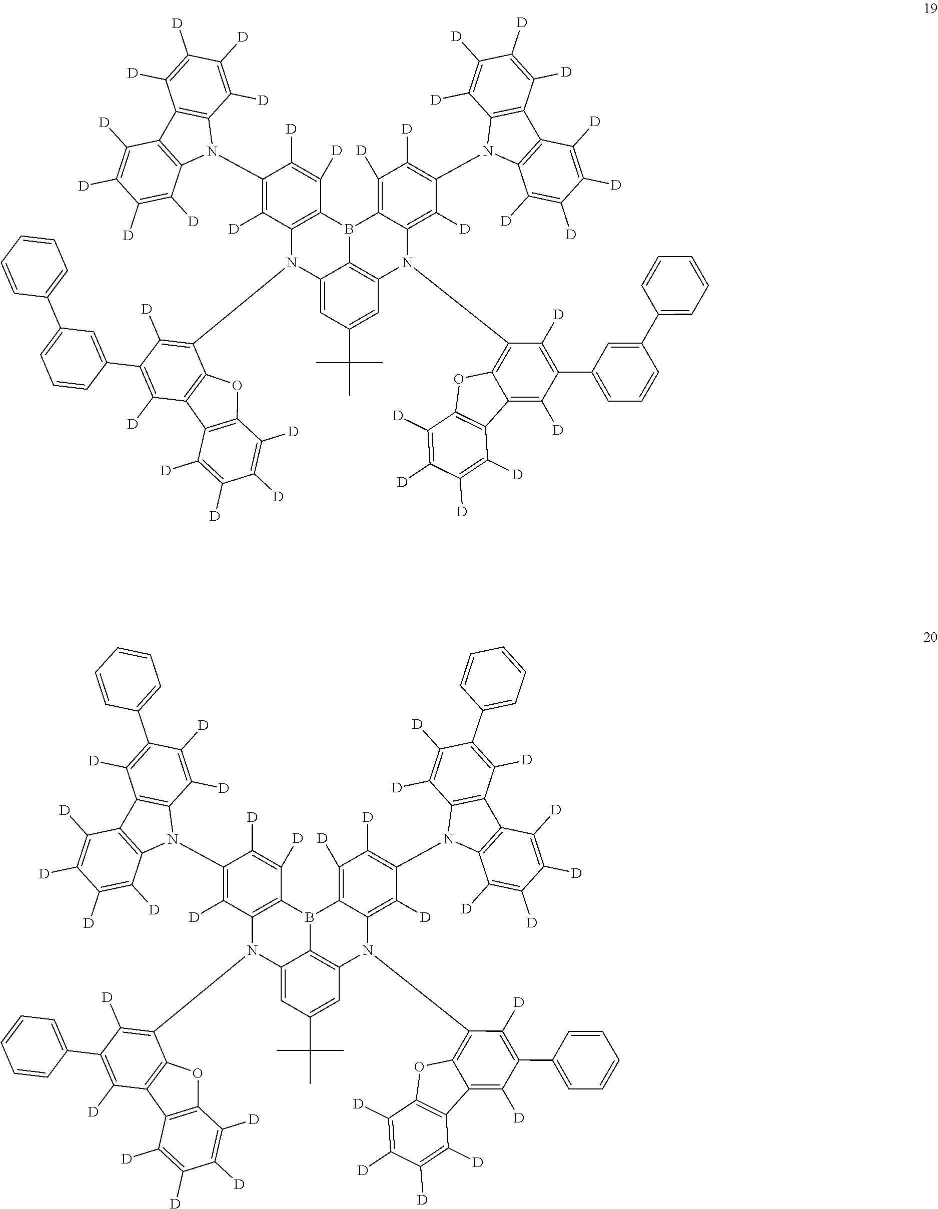

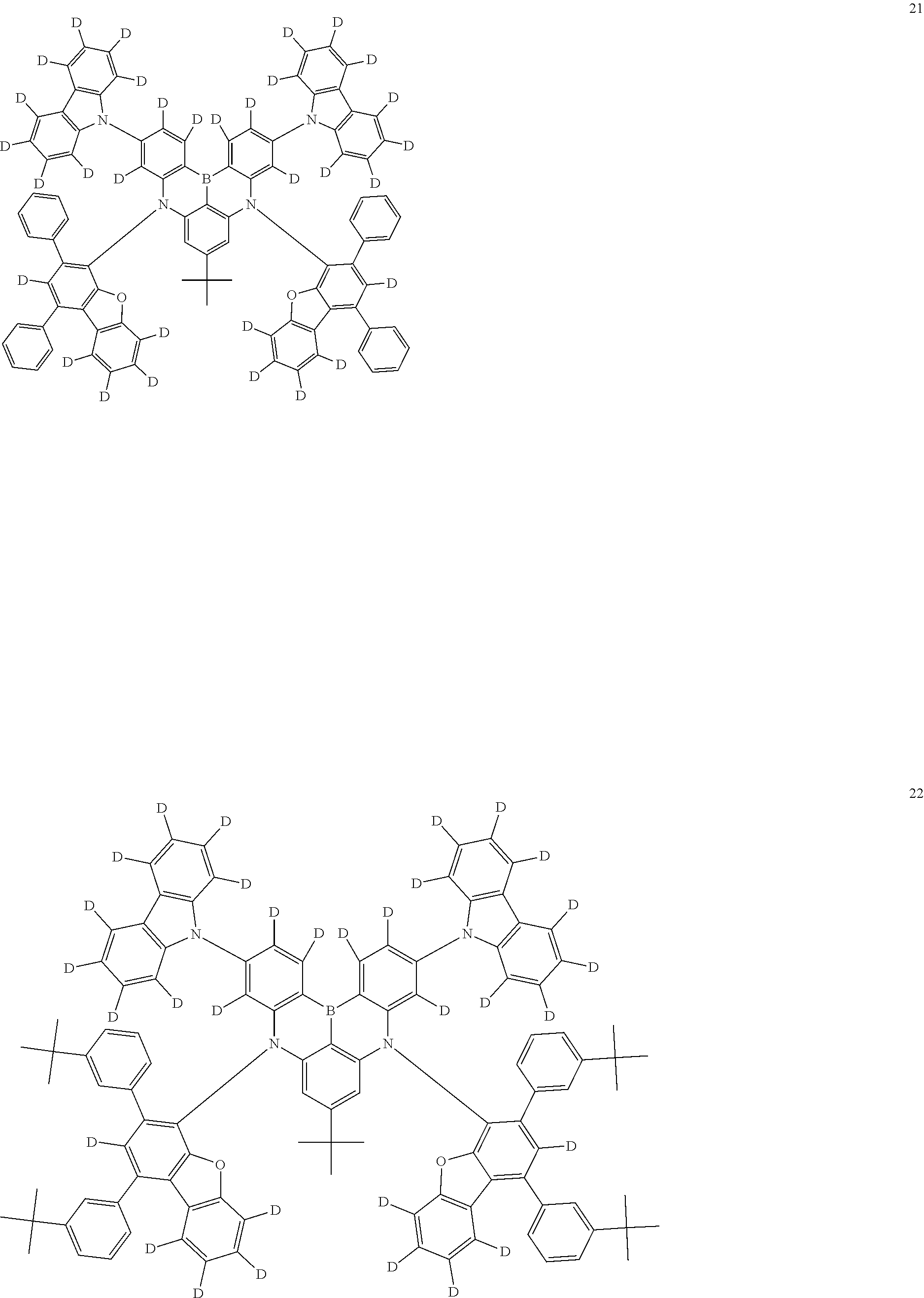

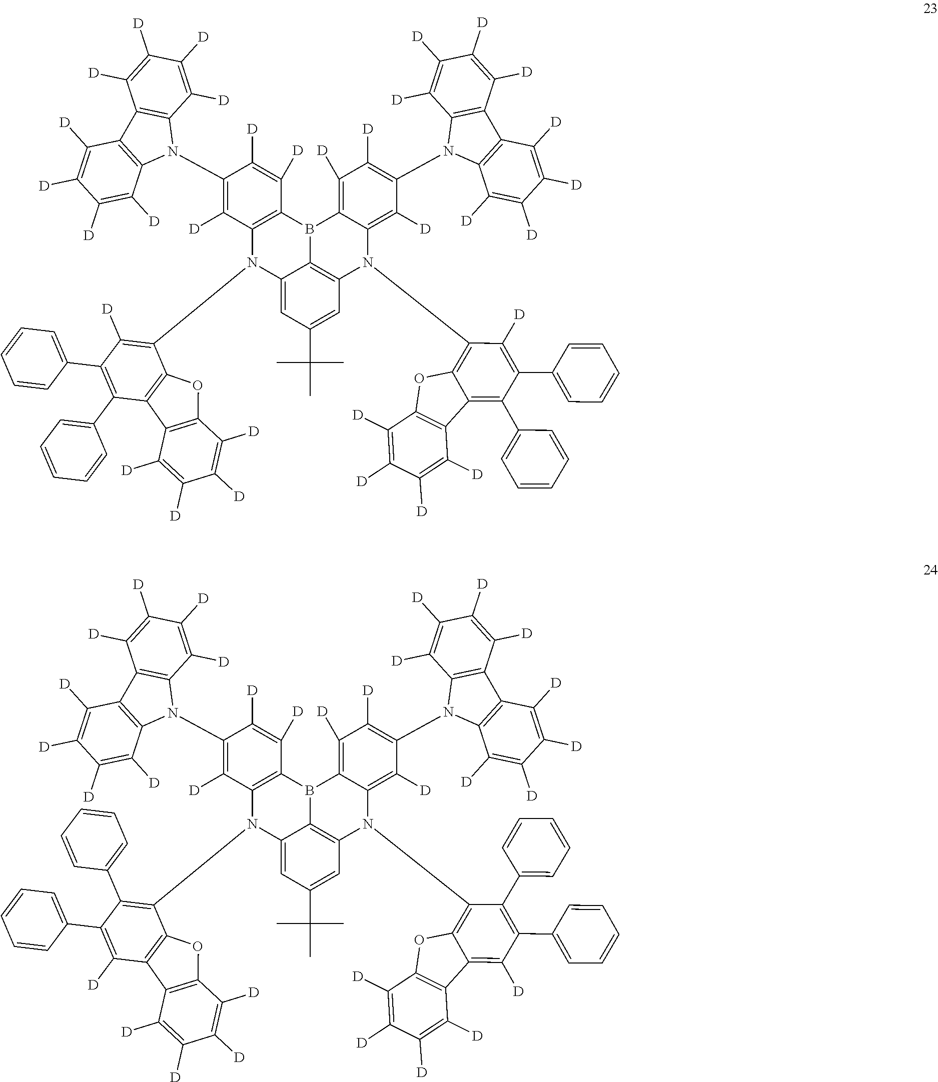

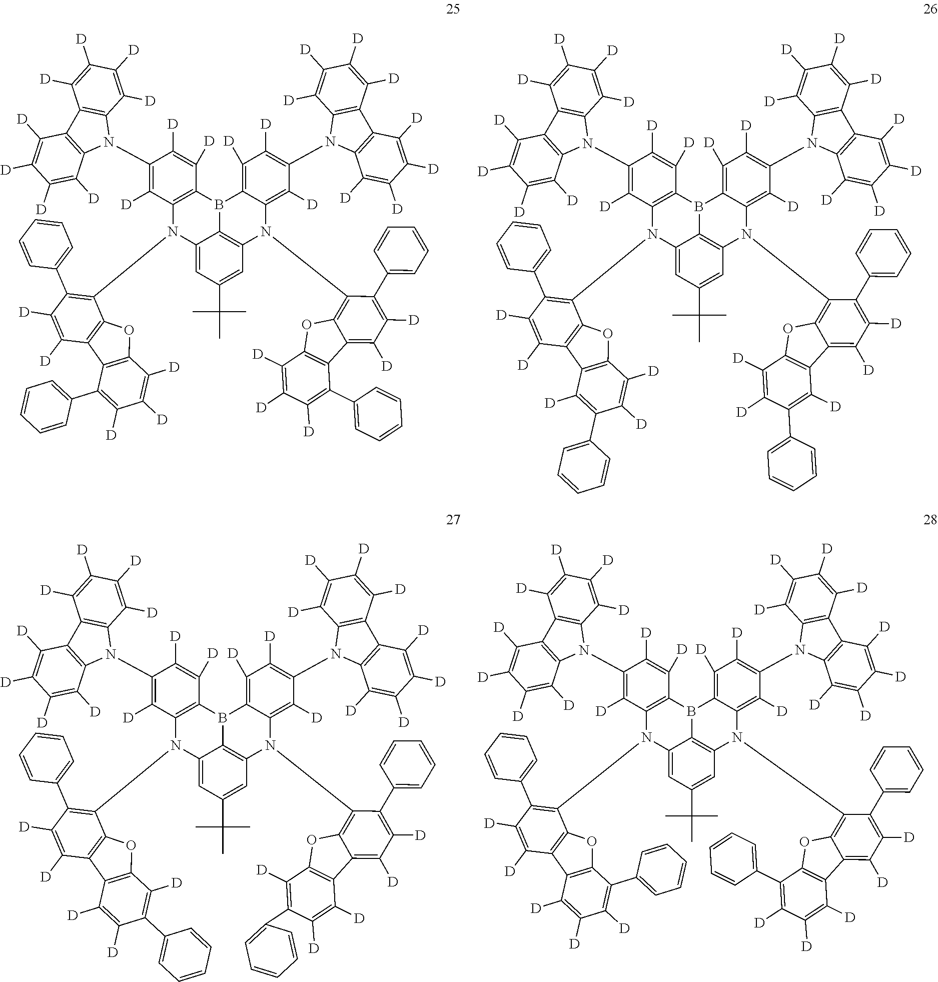

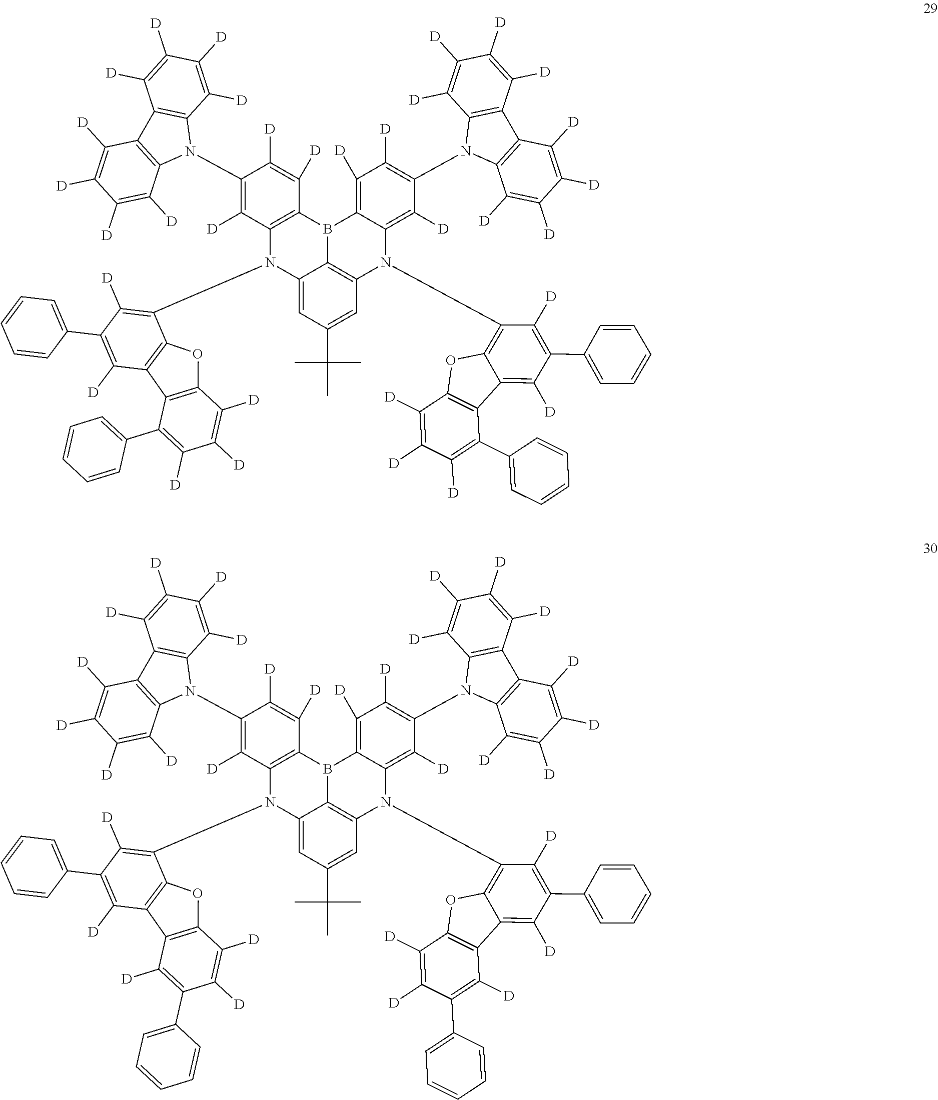

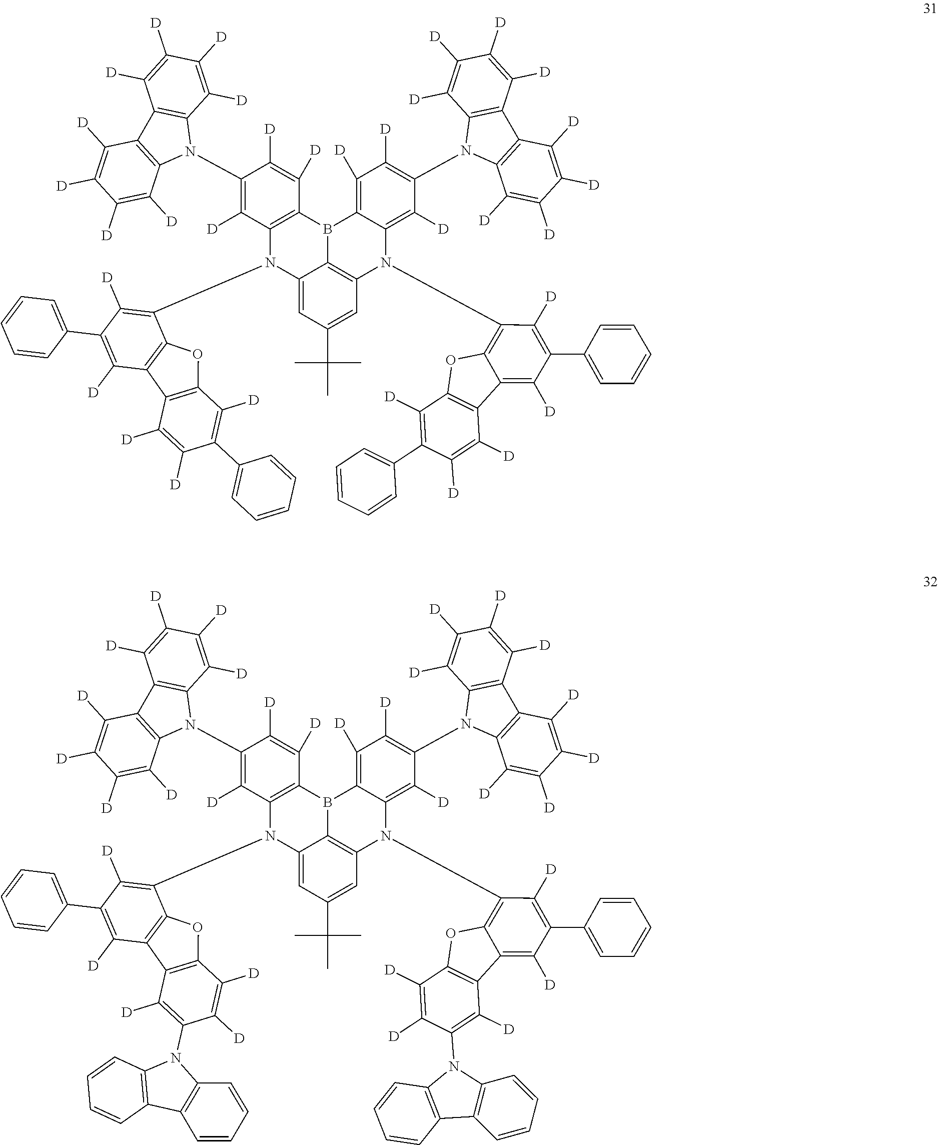

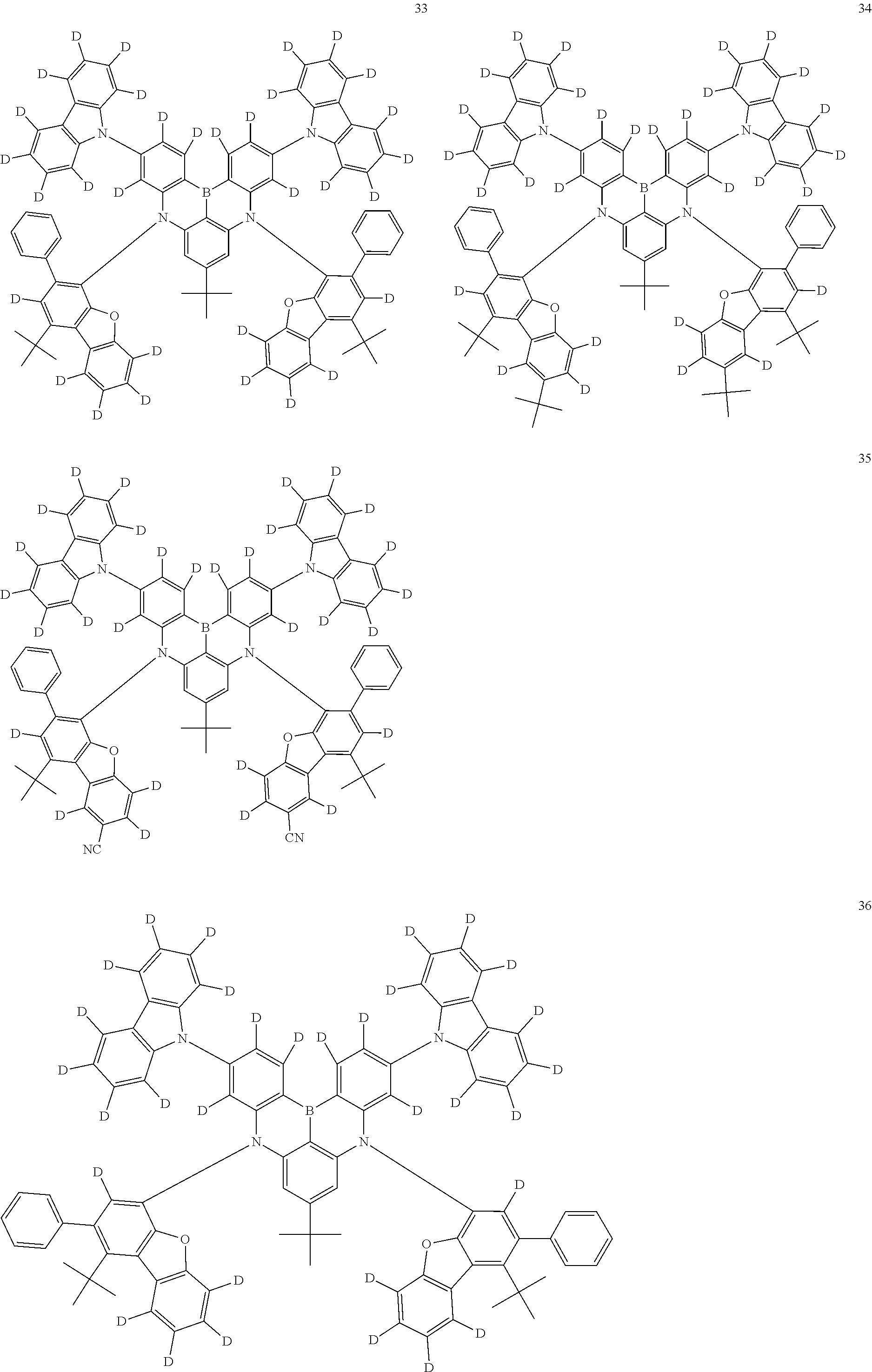

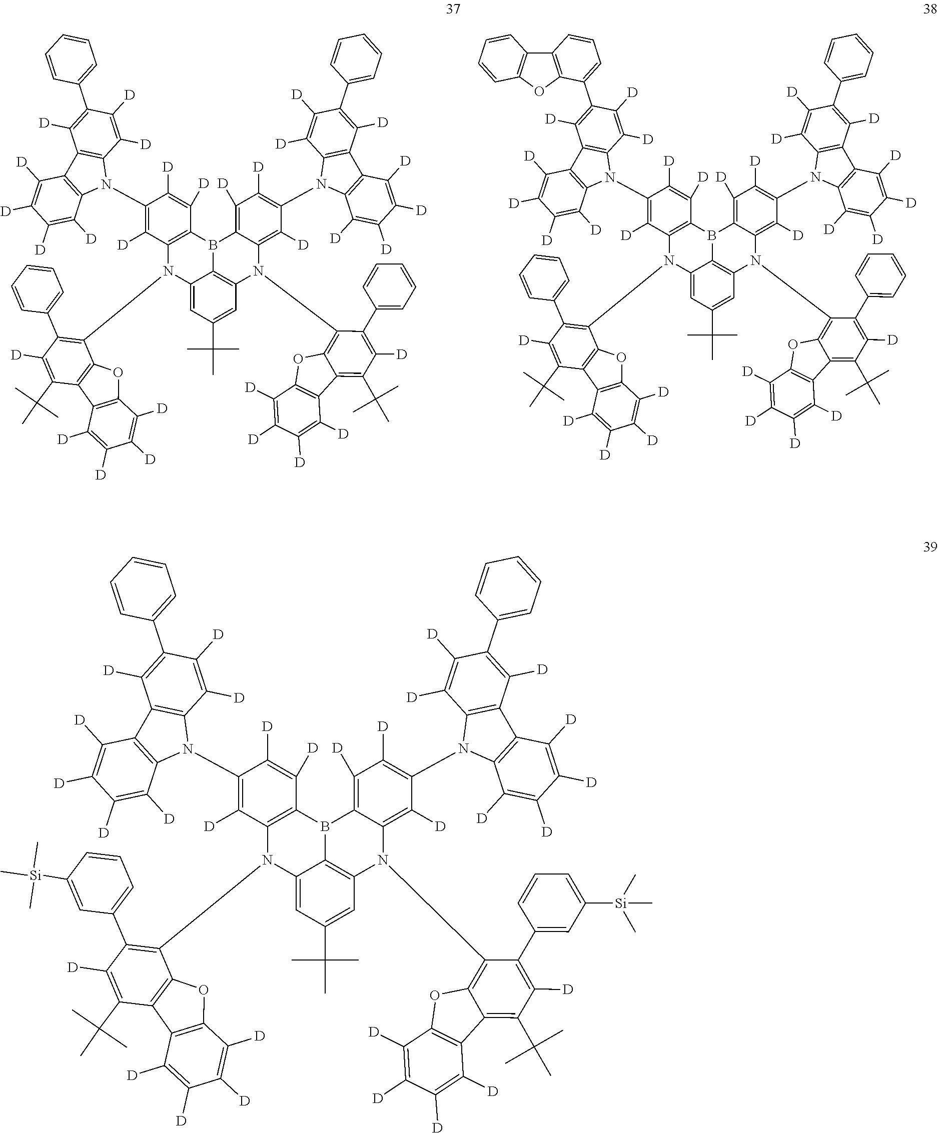

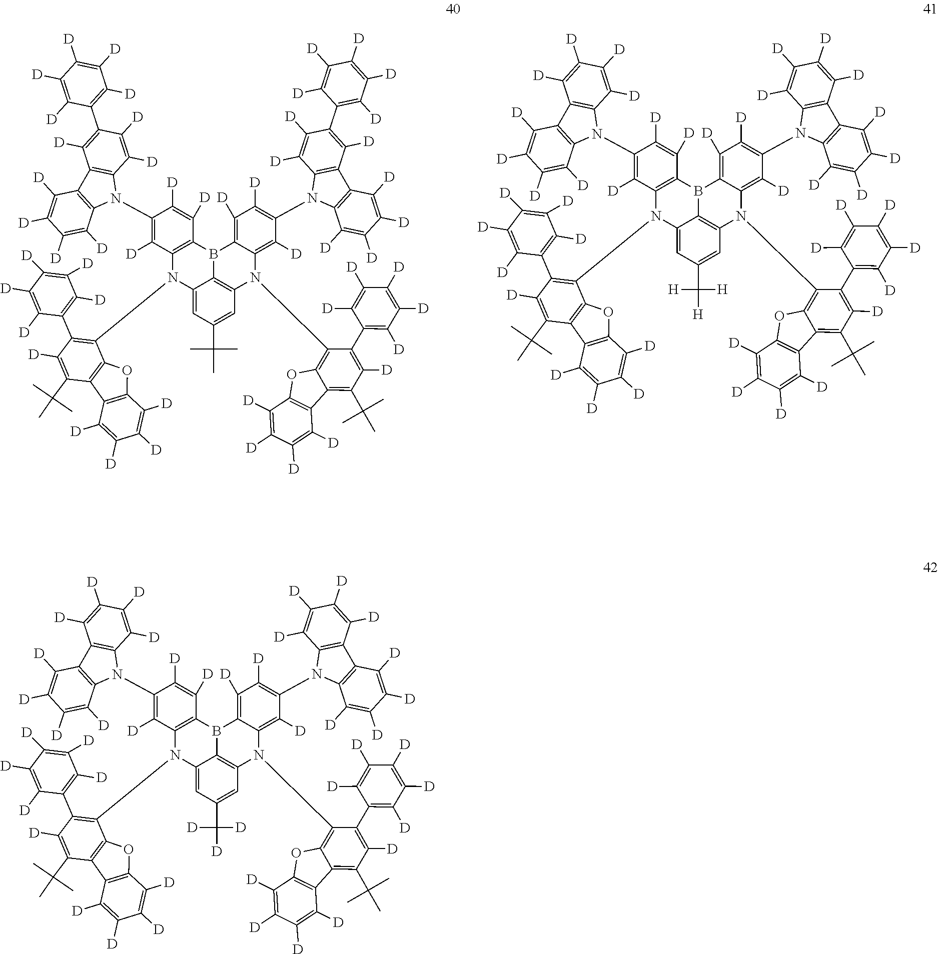

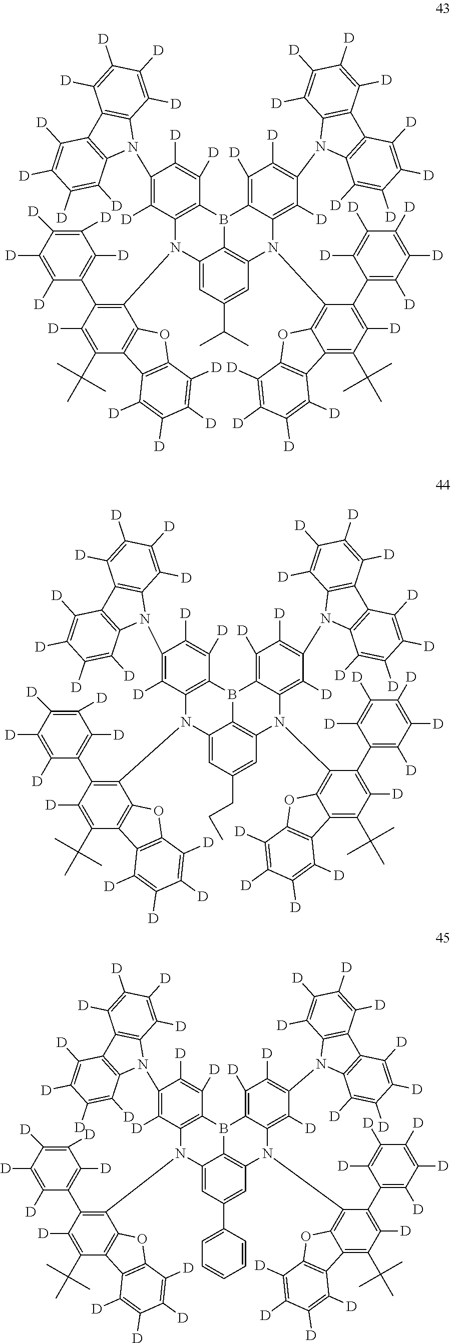

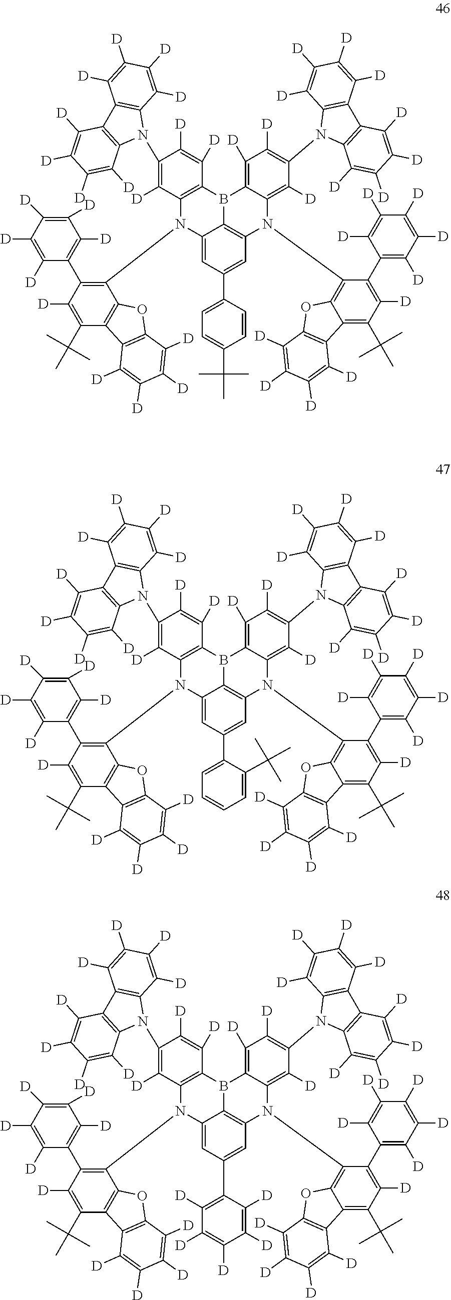

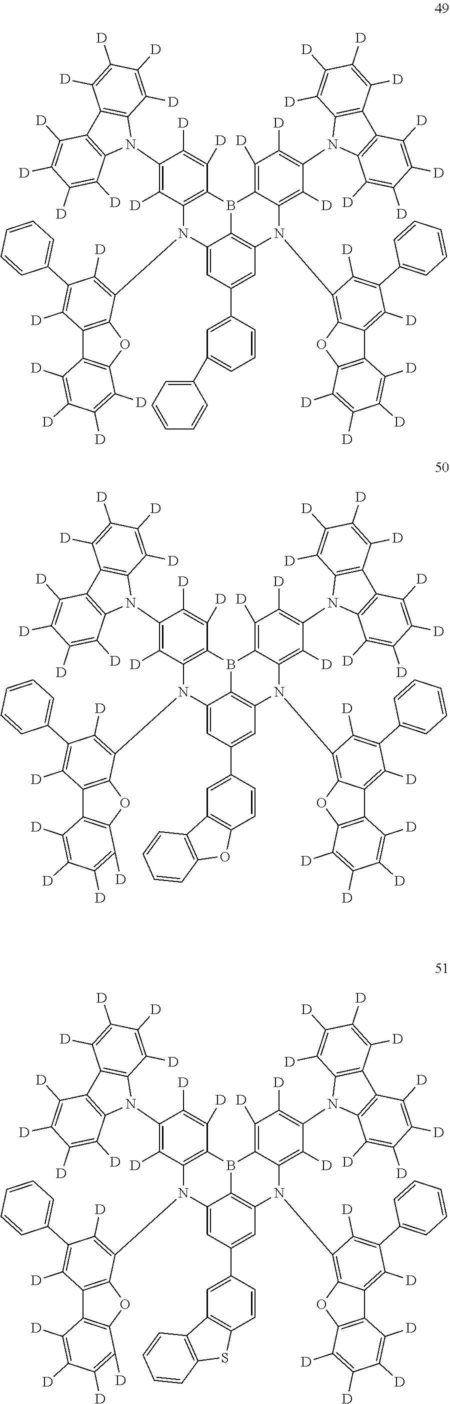

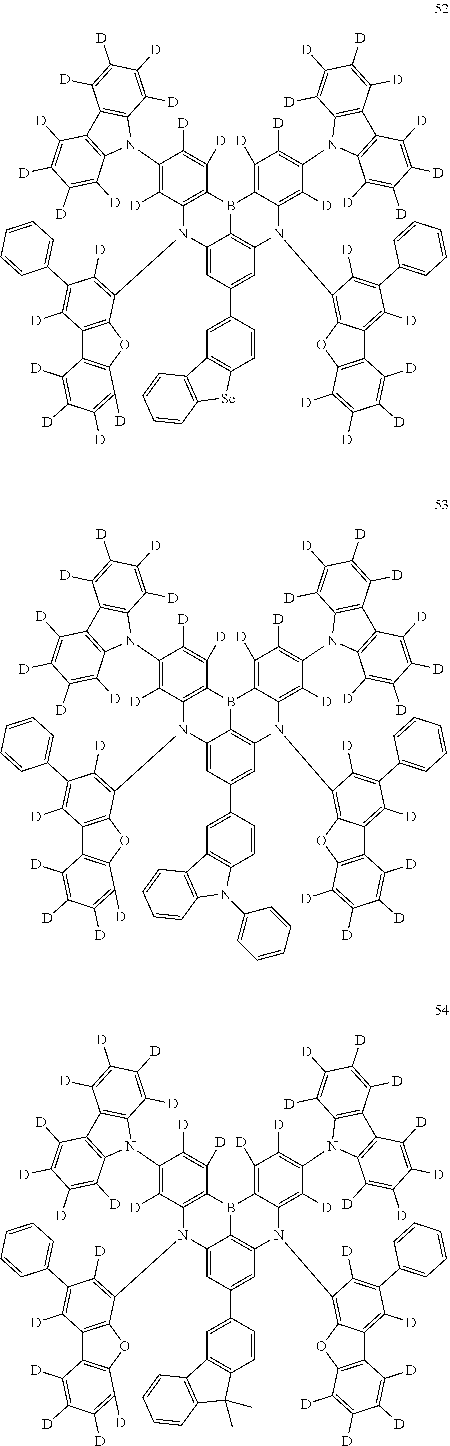

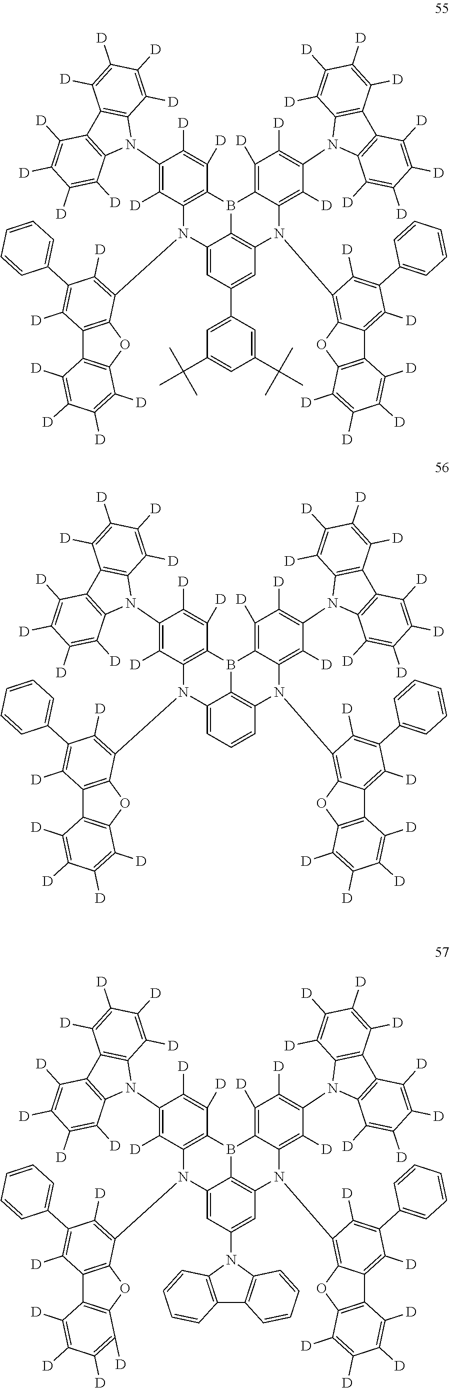

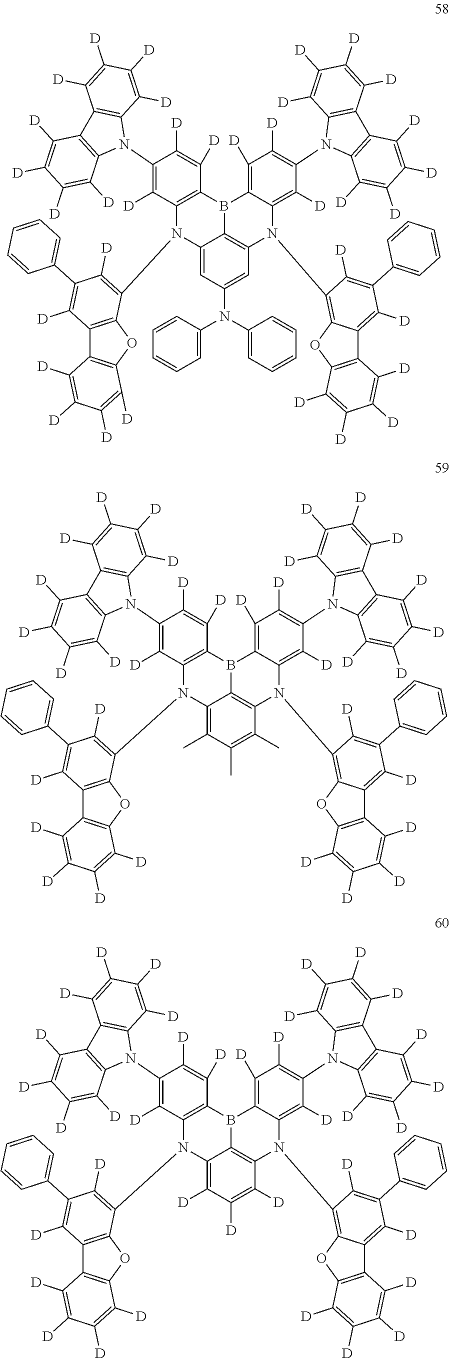

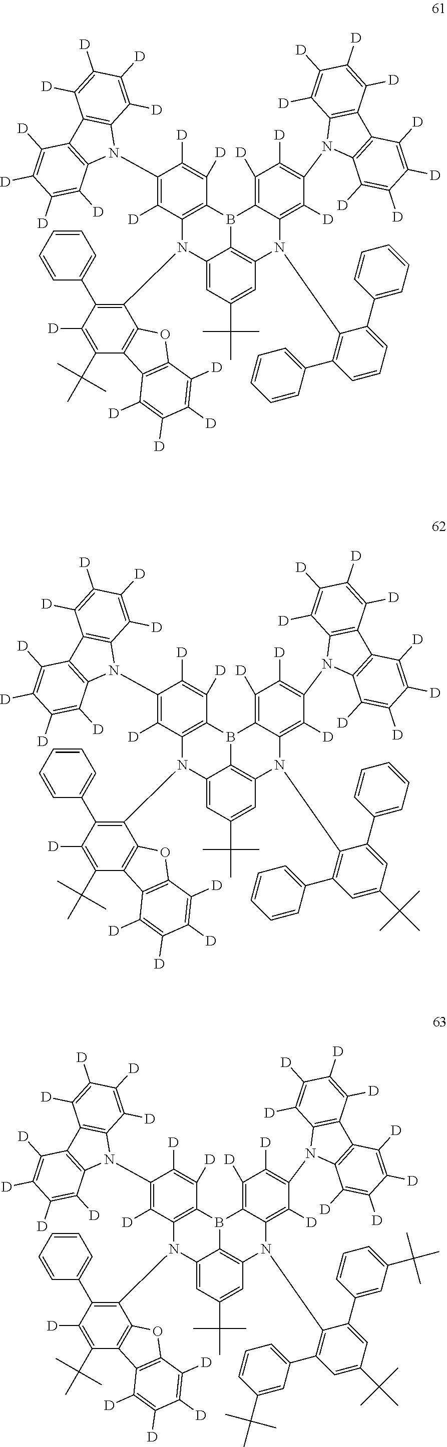

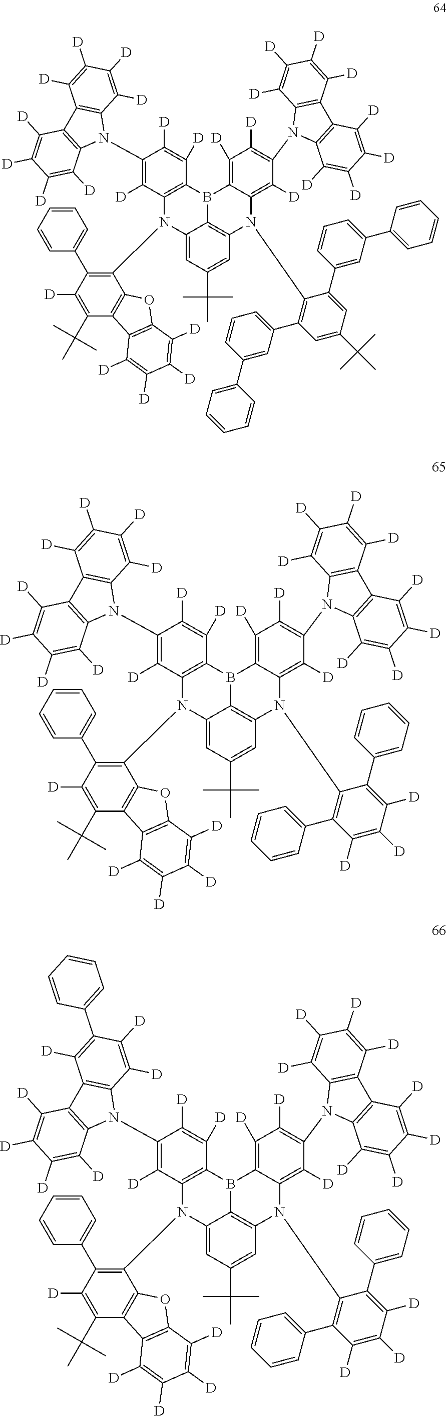

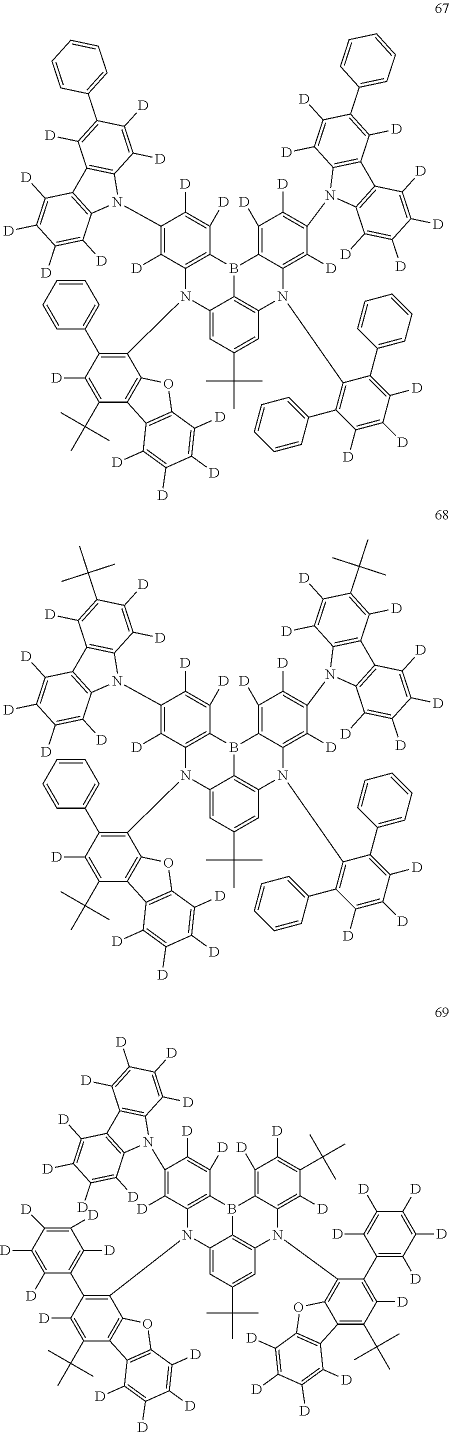

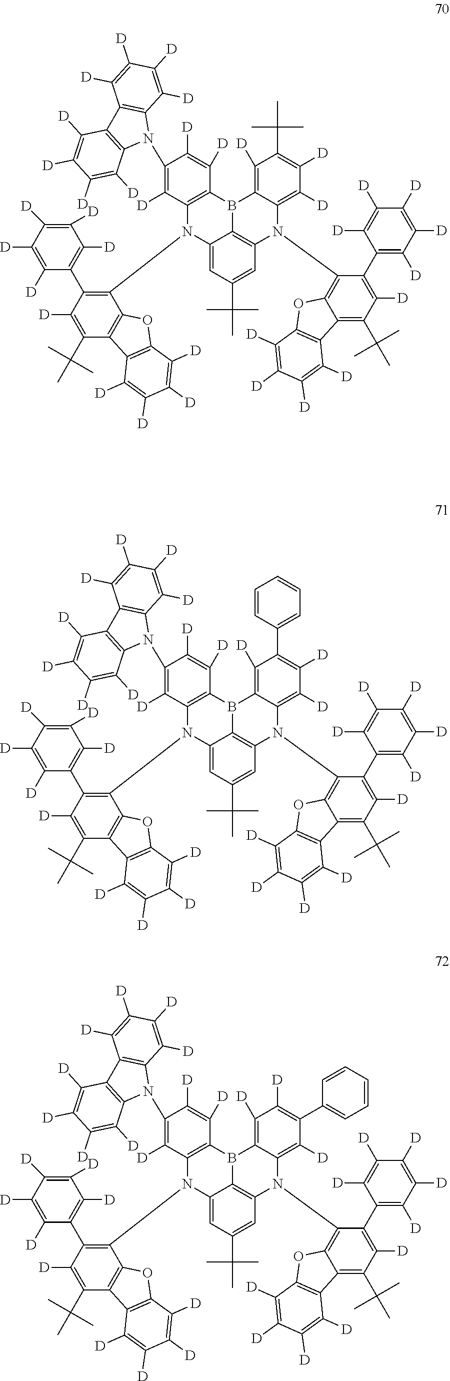

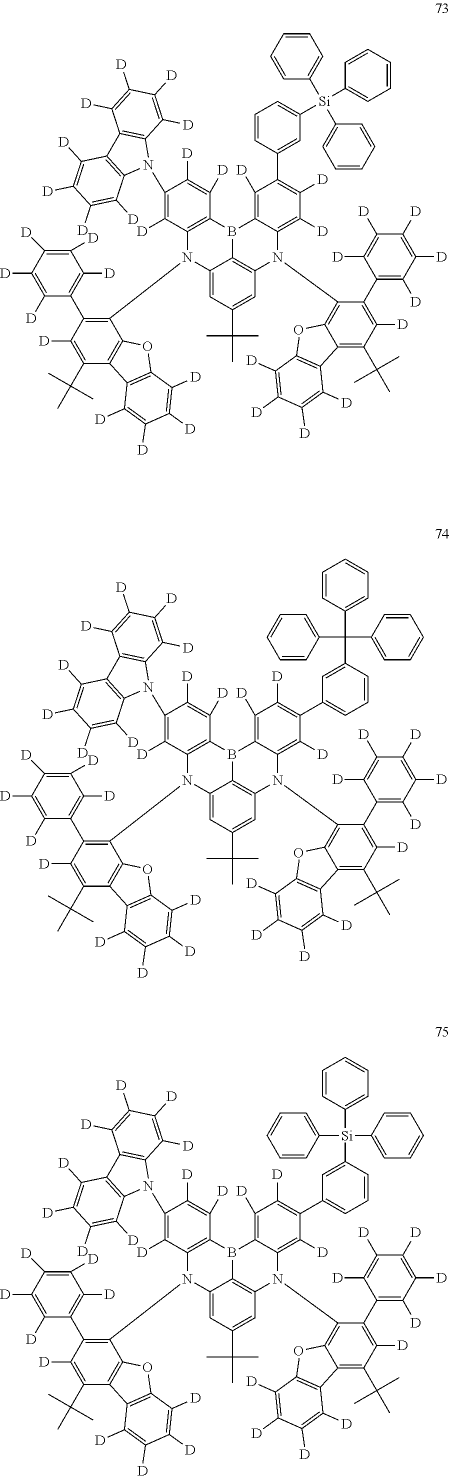

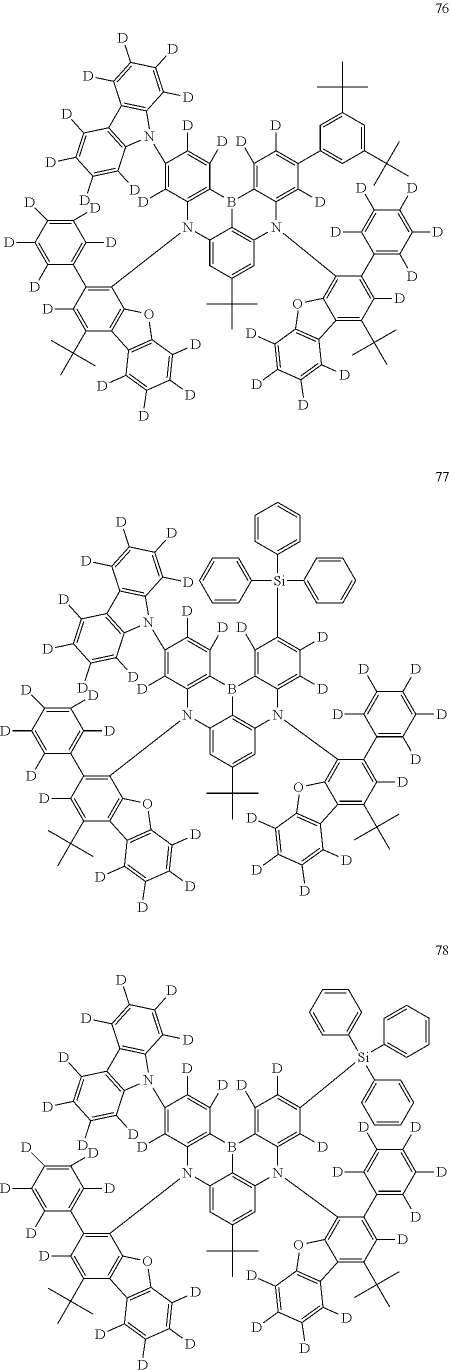

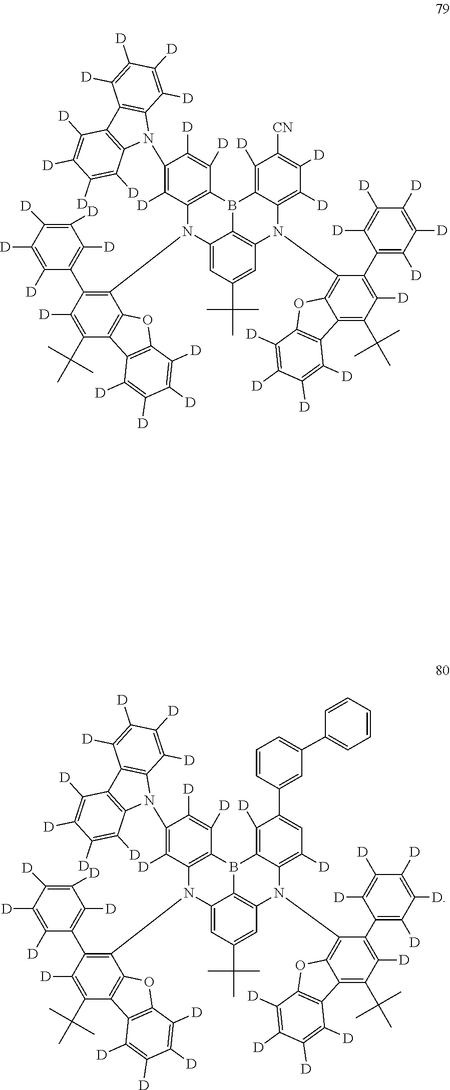

In the particular compounds suggested in Compound Group 1, D is a deuterium atom.

The fused polycyclic compound according to an embodiment represented by Formula 1 has a structure in which a first substituent is connected with a fused ring core, and high efficiency and long lifetime may be achieved, and there may be advantages in that emission wavelength may be blue shifted, and emission wavelength may be finely controlled at the same time.

The fused polycyclic compound according to an embodiment may include a “fused ring core” of five rings formed by fusing first to third aromatic rings via a boron atom, a first nitrogen atom and a second nitrogen atom. In an embodiment, the fused polycyclic compound may include a first substituent which is connected with the first nitrogen atom of the fused ring core, and a second substituent which is connected with the first aromatic ring of the fused ring core. The fused polycyclic compound represented by Formula 1 according to an embodiment may include the first substituent and the second substituent, and may accomplish high emission efficiency and increased lifetime.

The first substituent may include a first dibenzofuran moiety connected with an aromatic substituent. A carbon atom at position 4 of the first dibenzofuran moiety may be connected with the first nitrogen atom of the fused ring core, and at least one of the remaining carbon atoms at positions 1 to 3 may be connected with the aromatic substituent. The fused polycyclic compound according to an embodiment may show high steric bulkiness due to the specific connection structure of the first substituent, and the trigonal planar structure of the boron atom in the fused ring core may be effectively protected, and accordingly, the stability of a material may be improved during the operation of an element. A boron atom has electron-deficient properties due to a vacant p-orbital and may form a bond with another nucleophile to be transformed into a tetrahedral structure. Such a change to a tetrahedral configuration may contribute to deterioration of the element. According to an embodiment, in the fused polycyclic compound, since the first substituent is introduced to the fused ring core, the vacant p-orbital of the boron atom may be effectively protected, and deterioration of the element due to structural deformation of the boron atom may be prevented.

In an embodiment, in the fused polycyclic compound, intermolecular interaction may be restrained through steric hindrance effects by the first substituent, such that the formation of aggregates, excimers, or exciplexes may be controlled, and emission efficiency may be increased. Since the fused polycyclic compound according to an embodiment, represented by Formula 1 has a bulky structure, intermolecular distance may increase, and dexter energy transfer may be reduced. The dexter energy transfer is a phenomenon of transferring intermolecular triplet excitons, and is increased if the distance between molecules is short, and may become a factor increasing quenching phenomenon according to the increase of triplet concentration. According to an embodiment, in the fused polycyclic compound, an intermolecular distance between adjacent molecules increases due to large steric hindrance, dexter energy transfer may be suppressed, and lifetime deterioration because of the increase of the triplet concentration may be suppressed. Accordingly, if the fused polycyclic compound according to an embodiment is applied to an emission layer EML, emission efficiency may be increased, and element lifetime may be improved.

In an embodiment, the fused polycyclic compound may have a structure in which a dibenzofuran moiety having large electronegativity is connected with the fused ring core at a specific position, and emission wavelength is blue shifted to accomplish high color purity. Accordingly, in the fused polycyclic compound according to an embodiment, by including the first substituent, and changing the type of the substituent connected with the fused ring core and/or the first substituent, emission wavelength may be blue shifted, while finely controlling the emission wavelength at the same time. For example, the fused polycyclic compound according to an embodiment may control a target emission wavelength in a wavelength region in a range of about 430 nm to about 490 nm without changing optical and physical properties significantly.

The fused polycyclic compound according to an embodiment, if applied to a light emitting element, may accomplish high efficiency and long lifetime due to synergistic effects according to the connection position of the dibenzofuran and the first nitrogen atom, and the introduction of the specific substituent of the dibenzofuran moiety.

In an embodiment, the fused polycyclic compound may have a structure in which a second substituent is connected in the fused ring including a boron atom and a nitrogen atom. The second substituent may include a carbazole moiety and may be directly connected with the first aromatic ring forming the fused ring. Accordingly, the fused polycyclic compound according to an embodiment may show multiple resonance at a broad plate-type skeleton, and allow for highest occupied molecular orbital (HOMO) and lowest unoccupied molecular orbital (LUMO) states in a molecule to readily separate, and thus, may be used as a delayed fluorescence emitting material. The fused polycyclic compound according to an embodiment may have a reduced difference (ΔE_{ST}) between a lowest triplet excitation energy level (T1 level) and a lowest singlet excitation energy level (Si level) due to the structure, and accordingly, if used as a delayed fluorescence emitting material, the emission efficiency of a light emitting element may be improved even further.

In an embodiment, the fused polycyclic compound may include the first substituent, and the synthesis thereof may be readily performed, and process efficiency may be improved. As a method for sterically protecting boron, an ortho-terphenyl (o-terphenyl) moiety represented by Formula T below may be introduced. However, in the case of o-terphenyl, such a moiety may not be readily synthesized because of its steric structure. As a method for synthesizing a fused polycyclic compound with boron in the center, a coupling reaction such as borylation and Ullmann reaction may be used. The borylation may include a transmetalation reaction for modifying the C—H bond of an aromatic ring into C—B, and a subsequent annulations reaction for forming a fused ring. The Ullmann reaction is a coupling reaction between aryl halide and aryl amine, and may be used as a reaction for substituting a corresponding substituent at the fused ring core. For the borylation of the polycyclic compound in which an o-terphenyl group is introduced, borylation using a nucleophile such as BuLi is difficult due to its steric structure, and there may be disadvantages of using a reagent such as expensive BI₃. During the Ullmann reaction, a large amount of a reagent is required due to the steric structure of the o-terphenyl, and there may be disadvantages associated with an increase in the cost.

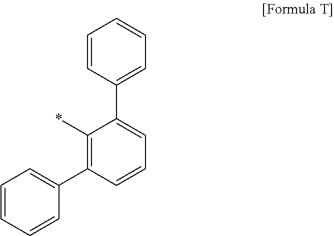 [SMILES: *c1c(-c2ccccc2)cccc1-c1ccccc1]

In the specification, in the fused ring core having a boron atom and two nitrogen atoms in the center, a structure in which a first substituent may be connected with at least one of the nitrogen atoms at both sides, excellent boron protection effects may be shown, and the structure thereof may be readily synthesized. The first substituent may be connected with at least one of two nitrogen atoms constituting the fused ring core. In the fused polycyclic compound according to an embodiment, since the first substituent may be connected with the fused ring core at a specific position, a similar degree of steric bulkiness as a polycyclic compound in which o-terphenyl groups are substituted at the nitrogen atoms at both sides, may be shown, and improved synthesis may be accomplished. When compared to a polycyclic compound of the related art in which an o-terphenyl group is introduced, the borylation of the polycyclic compound in which the first substituent is introduced may allow borylation using a nucleophile such as BuLi, and may reduce the amount of reactants during an Ullmann reaction, thereby reducing the manufacturing cost and improving process efficiency.

In an embodiment, an emission spectrum of the fused polycyclic compound, represented by Formula 1 may have a full width at half maximum (FWHM) in a range of about 10 nm to 50 nm. For example, the emission spectrum of the fused polycyclic compound may have a FWHM in a range of about 20 nm to 40 nm. Since the emission spectrum of the first dopant according to an embodiment, represented by Formula 1 has the above-described range of the full width at half maximum, if applied to an element, emission efficiency may be improved. If used as a material as a blue light emitting element, element lifetime may be improved.

In an embodiment, the fused polycyclic compound, represented by Formula 1 may be a material for emitting thermally activated delayed fluorescence. In an embodiment, the fused polycyclic compound, represented by Formula 1 may be a thermally activated delayed fluorescence dopant having a difference (ΔE_{ST}) between the lowest triplet excitation energy level (T1 level) and the lowest singlet excitation energy level (Si level) of less than or equal to about 0.6 eV. The fused polycyclic compound according to an embodiment, represented by Formula 1 may be a thermally activated delayed fluorescence dopant having a difference (ΔE_{ST}) between a lowest triplet excitation energy level (T1 level) and a lowest singlet excitation energy level (Si level) of less than or equal to about 0.2 eV. However, embodiments are not limited thereto.

In an embodiment, the fused polycyclic compound, represented by Formula 1 may include a first substituent and a second substituent in a compound. The singlet energy level and the triplet energy level of a whole compound may be appropriately controlled by controlling the substitution numbers and substitution positions of the first substituent and the second substitution. Through this, the fused polycyclic compound may show improved thermally activated delayed fluorescence properties.

The fused polycyclic compound according to an embodiment, represented by Formula 1 may be a light emitting material having a central wavelength in a range of about 430 nm to about 490 nm. For example, the fused polycyclic compound according to an embodiment, represented by Formula 1 may be a blue thermally activated delayed fluorescence (TADF) dopant. However, embodiments are not limited thereto, and if the fused polycyclic compound is used as a light emitting material, the first dopant may be used as a dopant material emitting light in various wavelength regions such as a red emitting dopant, or a green emitting dopant.

In an embodiment, in the light emitting element ED, an emission layer EML may emit delayed fluorescence. For example, the emission layer EML may emit thermally activated delayed fluorescence (TADF).

In an embodiment, the emission layer EML of the light emitting element ED may emit blue light. For example, the emission layer EML of a light emitting element ED may emit blue light having a wavelength less than or equal to about 490 nm. However, embodiments are not limited thereto, and the emission layer EML may emit green light or red light.

The fused polycyclic compound according to an embodiment may be included in an emission layer EML. The fused polycyclic compound according to an embodiment may be included in an emission layer EML as a dopant material. The fused polycyclic compound according to an embodiment may be a thermally activated delayed fluorescence emitting material. The fused polycyclic compound according to an embodiment may be used as a thermally activated delayed fluorescence dopant. For example, in the light emitting element ED, the emission layer EML may include at least one fused polycyclic compound selected from Compound Group 1 as a thermally activated delayed fluorescence dopant. However, the use of the fused polycyclic compound according to an embodiment is not limited thereto.

In an embodiment, the emission layer EML may include multiple compounds. The emission layer EML according to an embodiment may include the fused polycyclic compound represented by Formula 1 as a first compound, and at least one of a second compound represented by Formula HT-1, a third compound represented by Formula ET-1, and a fourth compound represented by Formula D-1.

In an embodiment, the emission layer EML may include the first compound represented by Formula 1 and may further include at least one of a second compound represented by Formula HT-1 and a third compound represented by Formula ET-1.

In an embodiment, the emission layer EML may further include a second compound represented by Formula HT-1. In an embodiment, the second compound may be used as a hole transport host material in an emission layer EML.

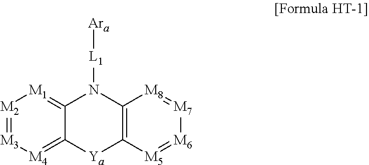

In Formula HT-1, M₁ to M₈ may each independently be N or C(R₅₁). For example, M₁ to M₈ may each independently be C(R₅₁). As another example, one of M₁ to M₈ may be N, and the remainder of M₁ to M₈ may each independently be C(R₅₁).

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene aromatic rings that are bonded to the nitrogen atom in Formula HT-1 may directly be connected to each other via a direct linkage,

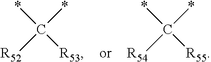

In Formula HT-1, if Yₐ is a direct linkage, the substituent represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

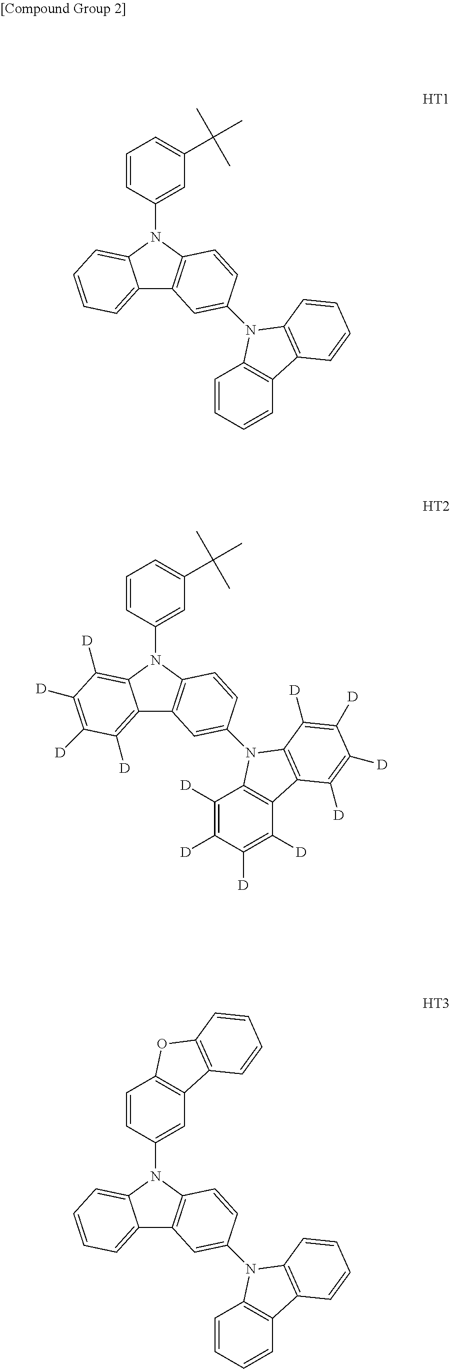 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

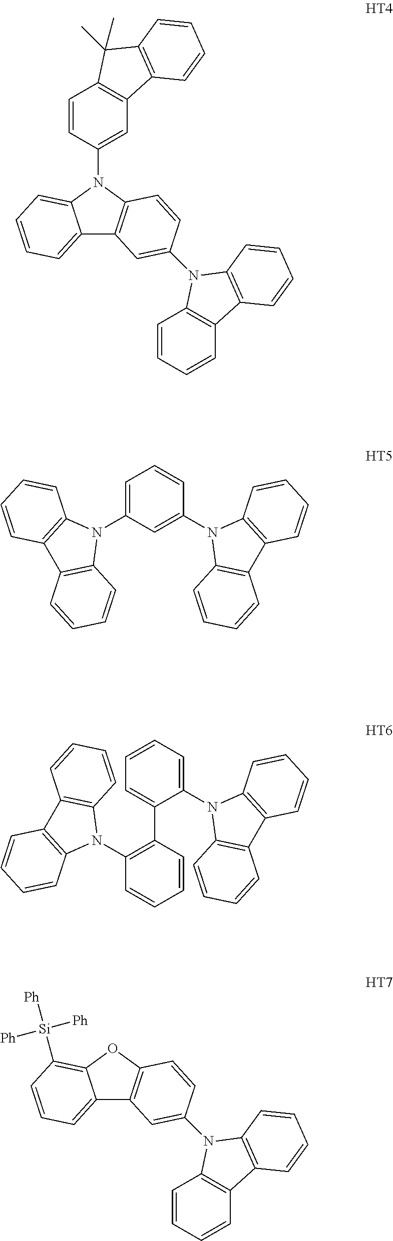 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

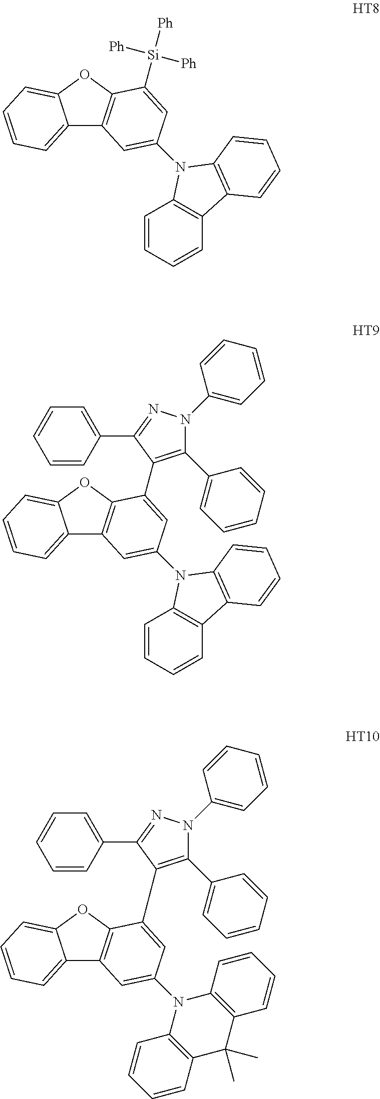 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

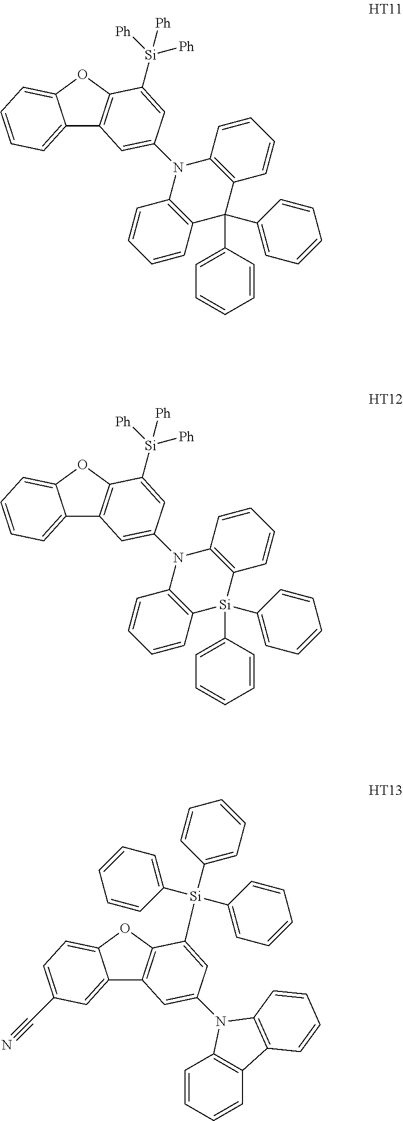 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

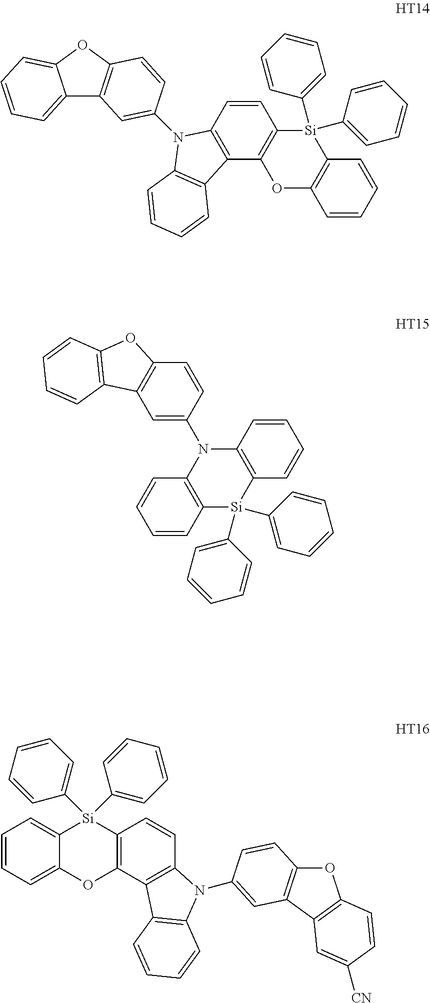 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

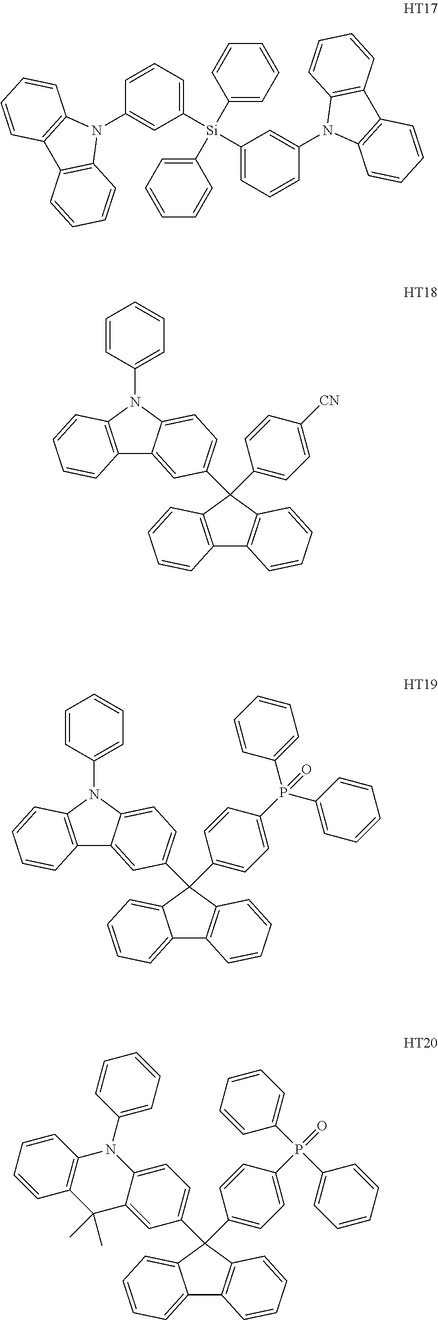 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

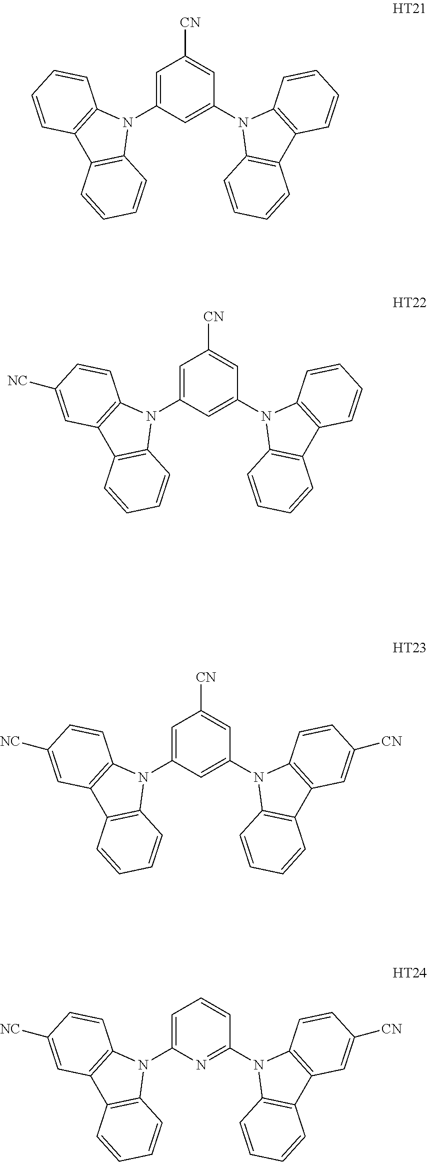 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

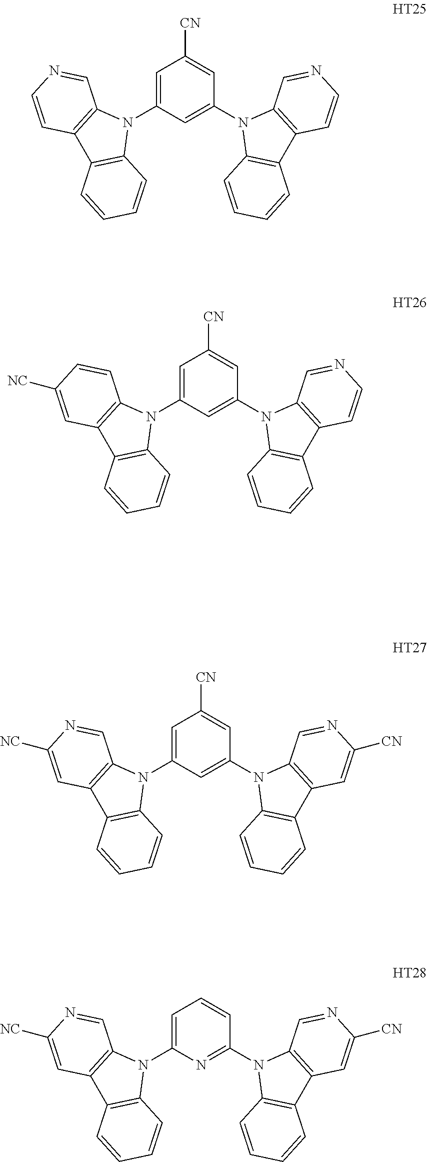 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

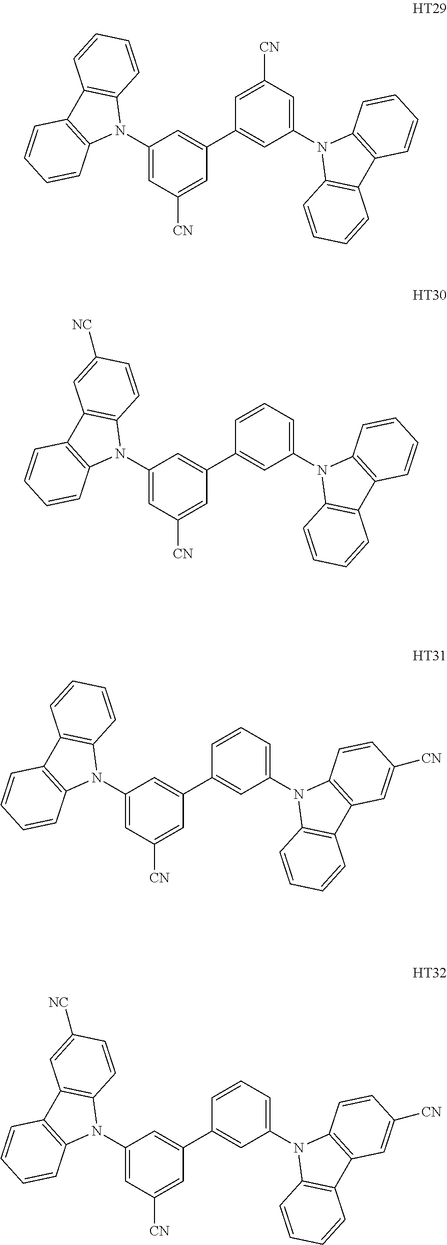 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

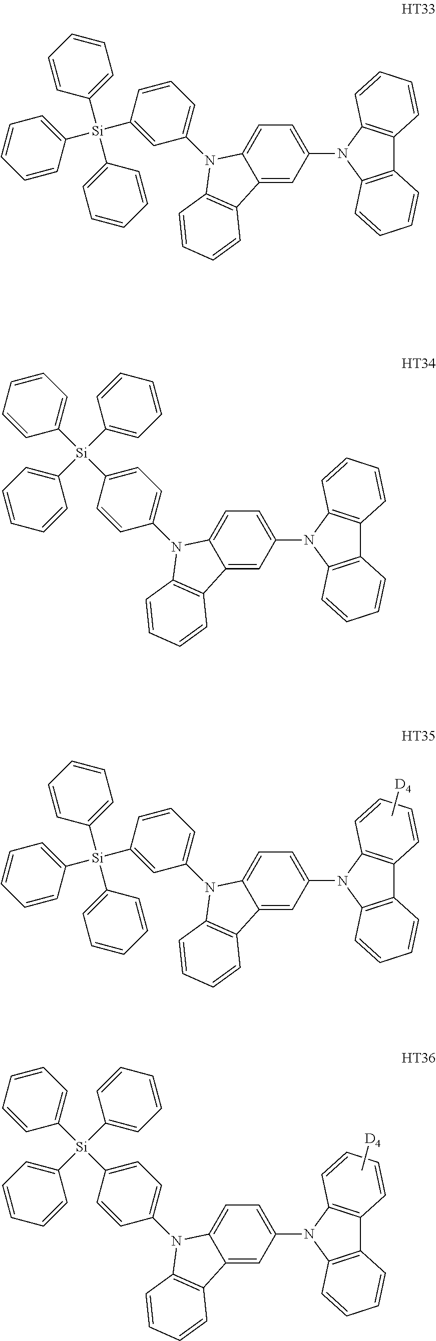

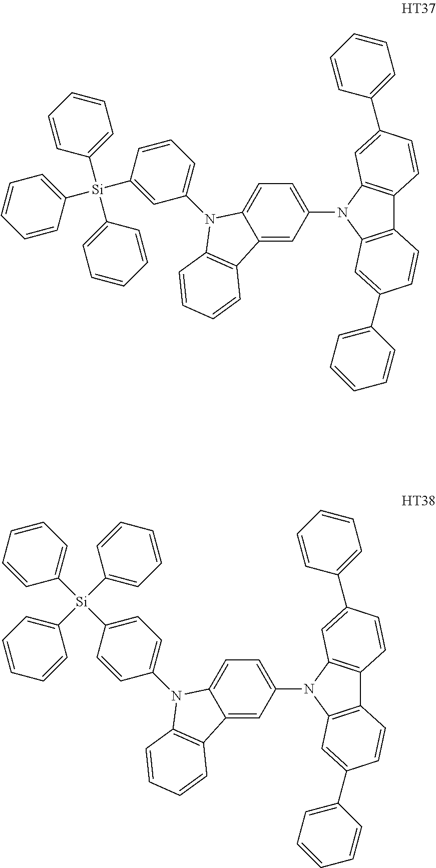 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

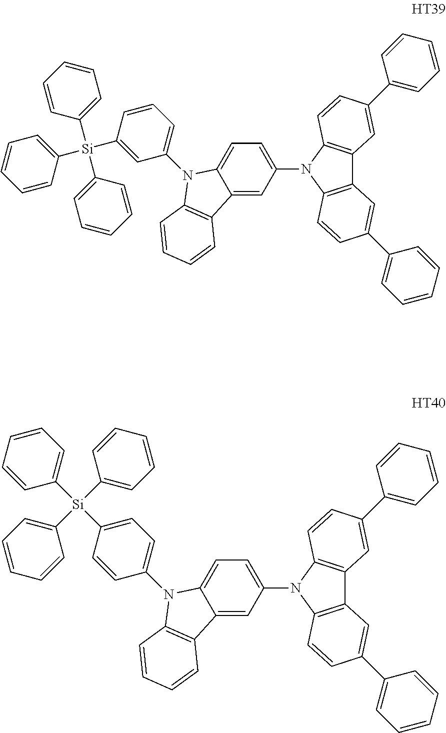 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

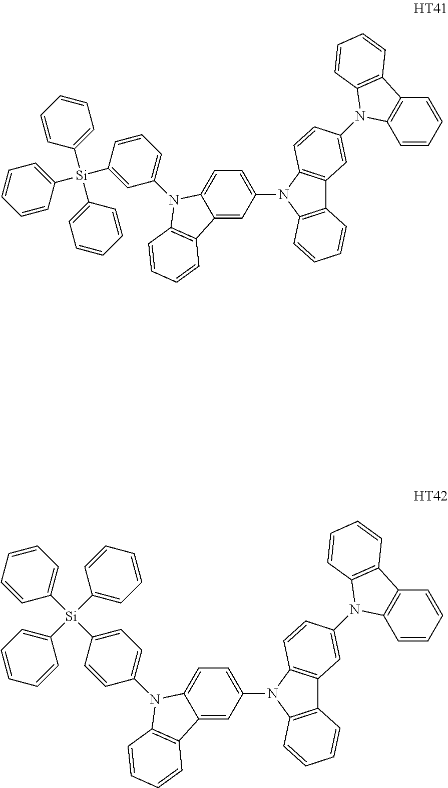 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

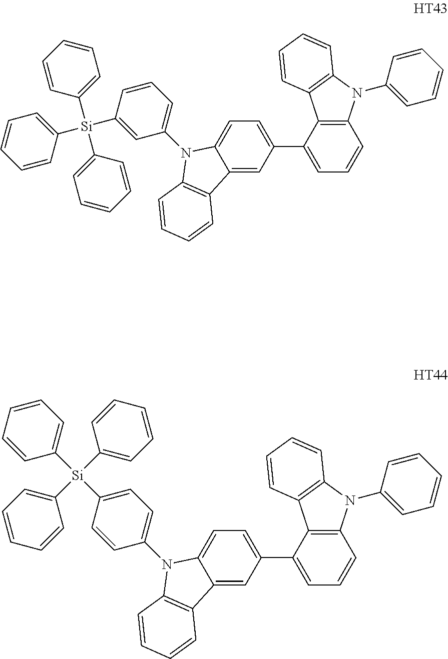 [SMILES: c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

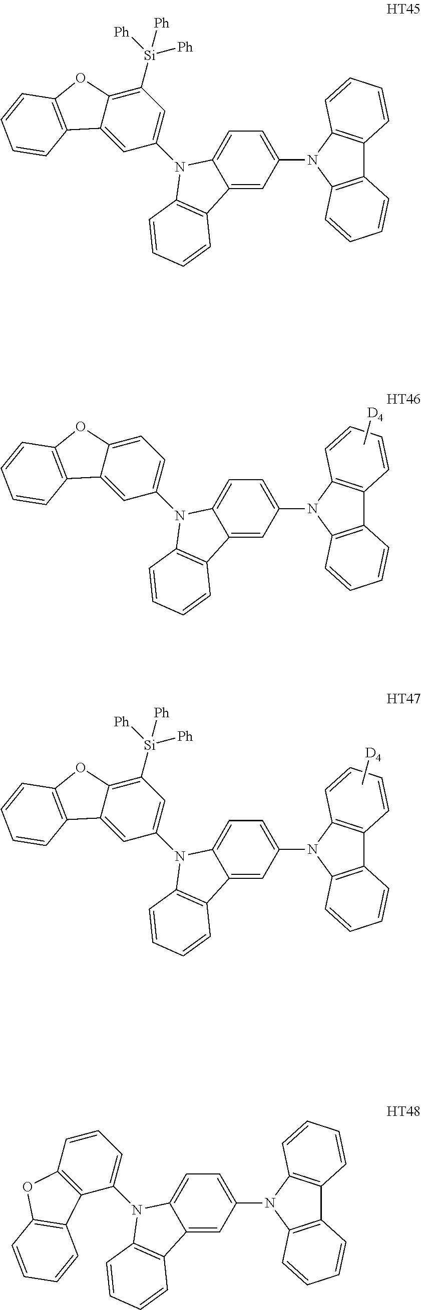

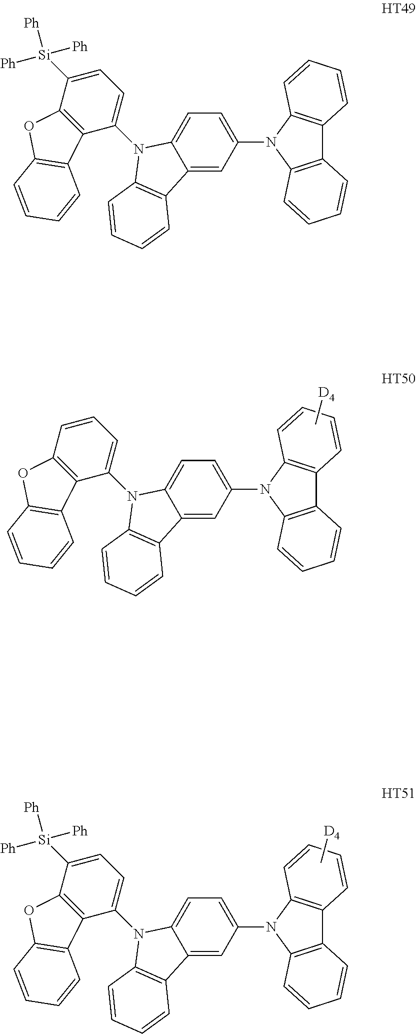

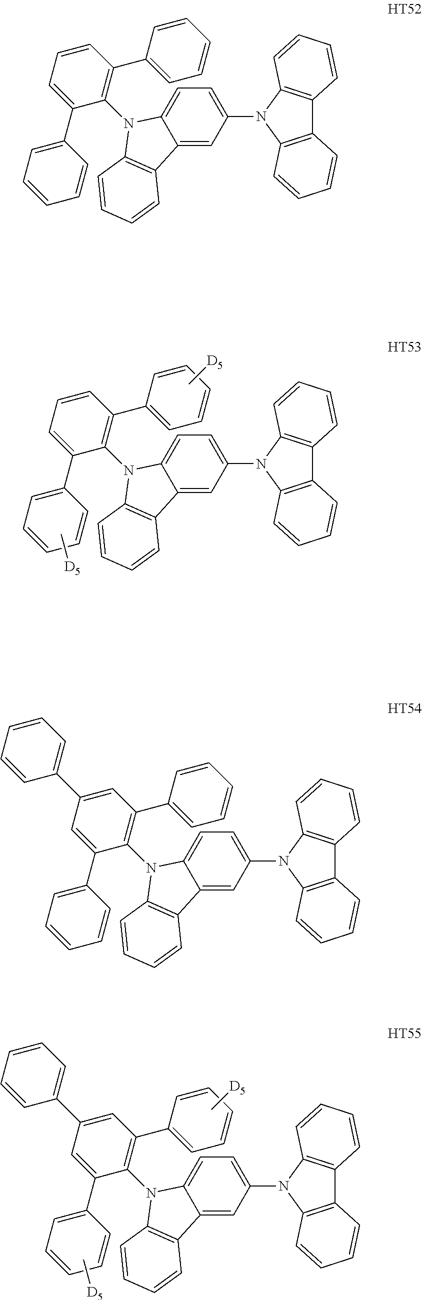

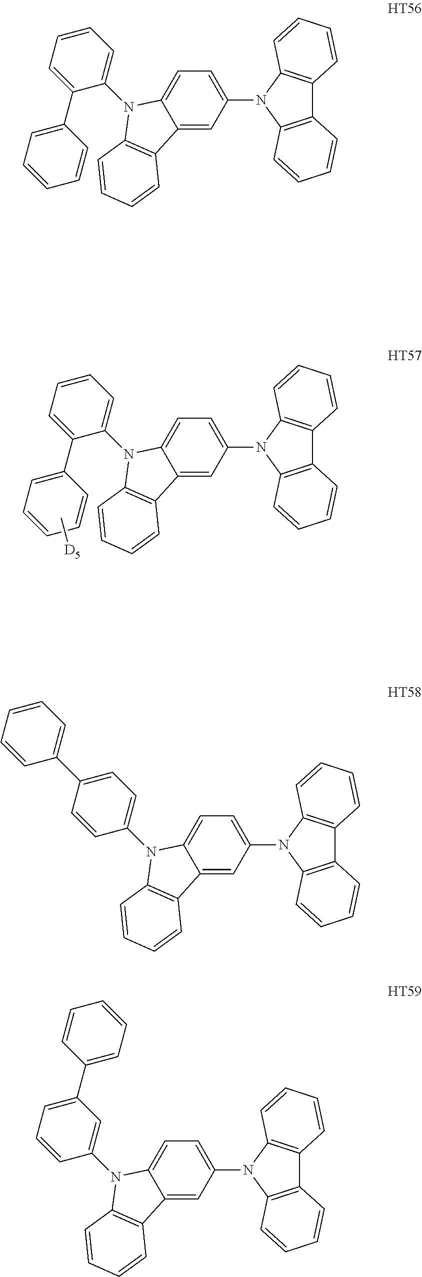

In Compound Group 2, D may be a deuterium atom, and Ph may be a substituted or unsubstituted phenyl group. For example, in Compound Group 2, Ph may be an unsubstituted phenyl group.

In an embodiment, the emission layer EML may further include a third compound represented by Formula ET-1. In an embodiment, the third compound may be used as an electron transport host material in the emission layer EML.

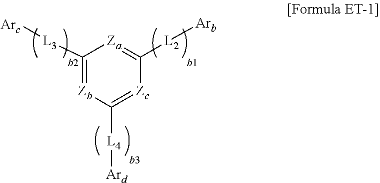

In Formula ET-1, at least one of Zₐ to Zₑ may each be N, and the remainder of Zₐ to Zₑ may each independently be C(R₅₆). For example, at least one of Zₐ to Zₑ may each be N, and the remainder of Zₐ to Zₑ may each independently be C(R₅₆). Thus, the third compound represented by Formula ET-1 may include a pyridine moiety. As another example, at least two of Zₐ to Zₑ may each be N, and the remainder of Zₐ to Zₑ may be C(R₅₆). Thus, the third compound represented by Formula ET-1 may include a pyrimidine moiety. As yet another example, Zₐ to Zₑ may each be N. Thus, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar_{b} to Ar_{d} may each independently be a substituted or unsubstituted phenyl group or a substituted or unsubstituted carbazole group.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, L₂ to L₄ may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3.

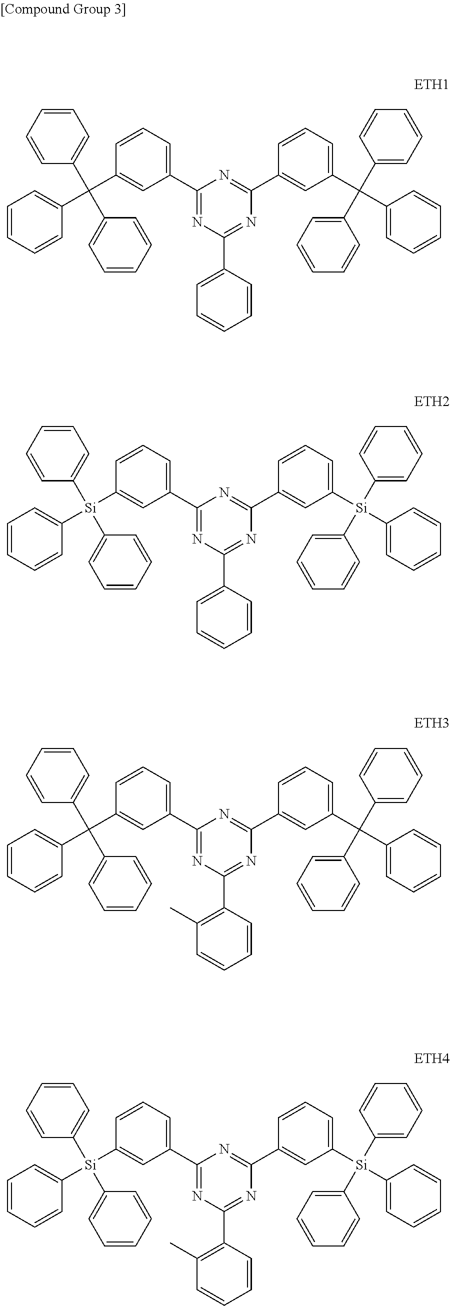 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

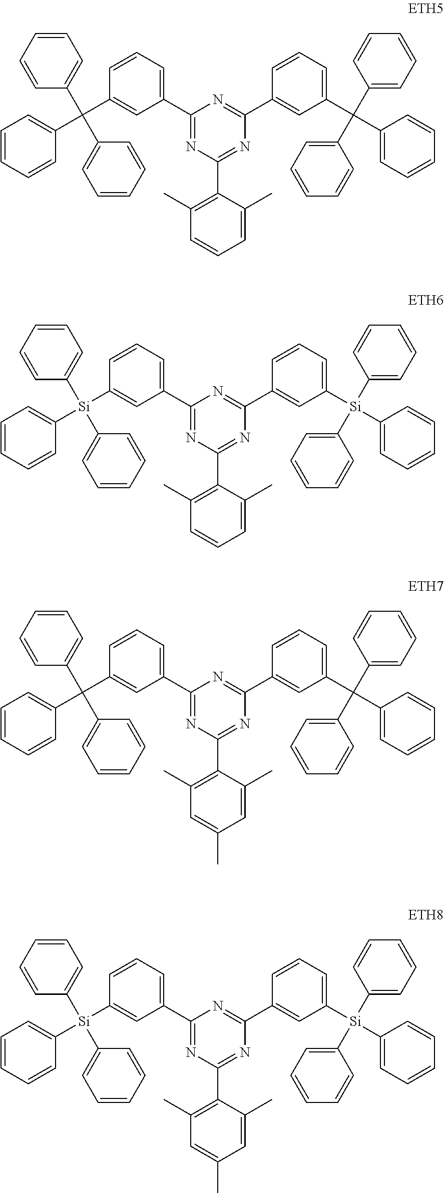 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

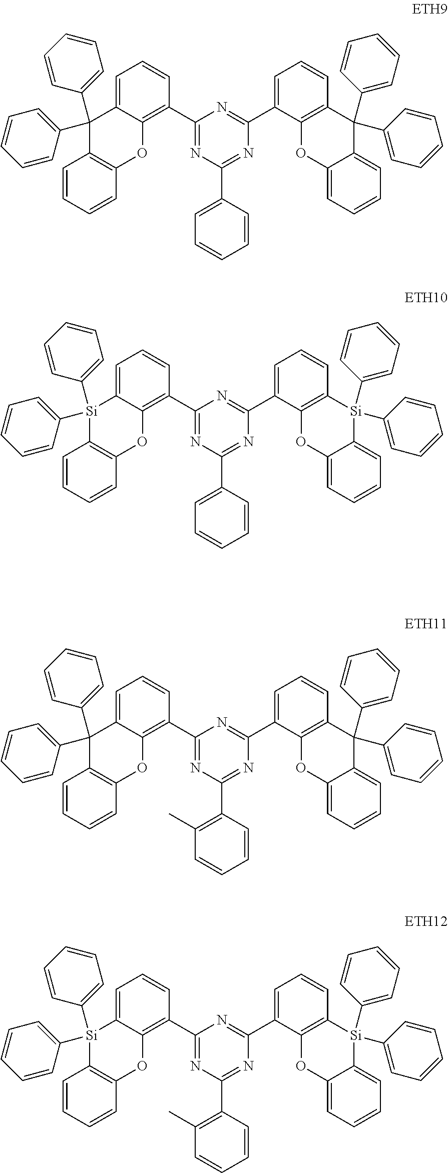 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

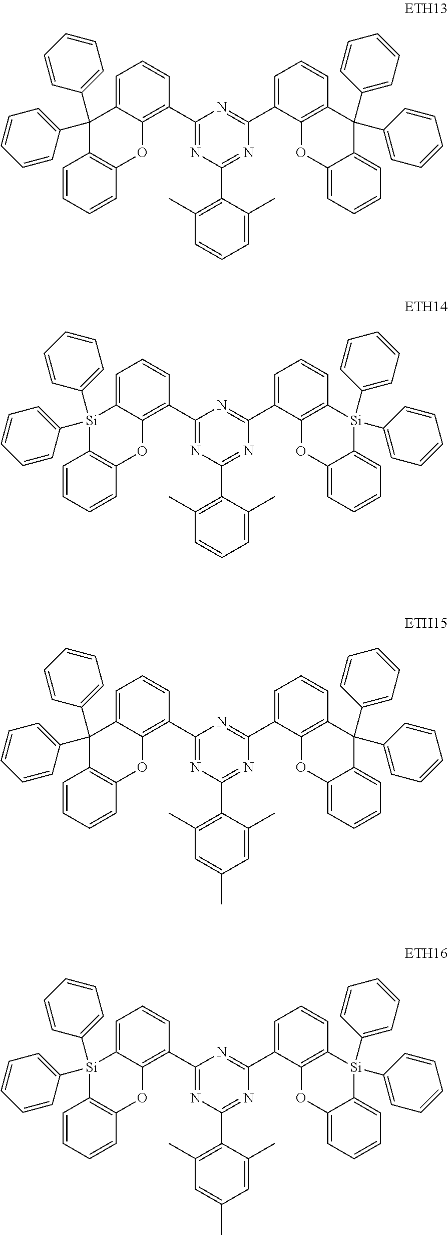 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

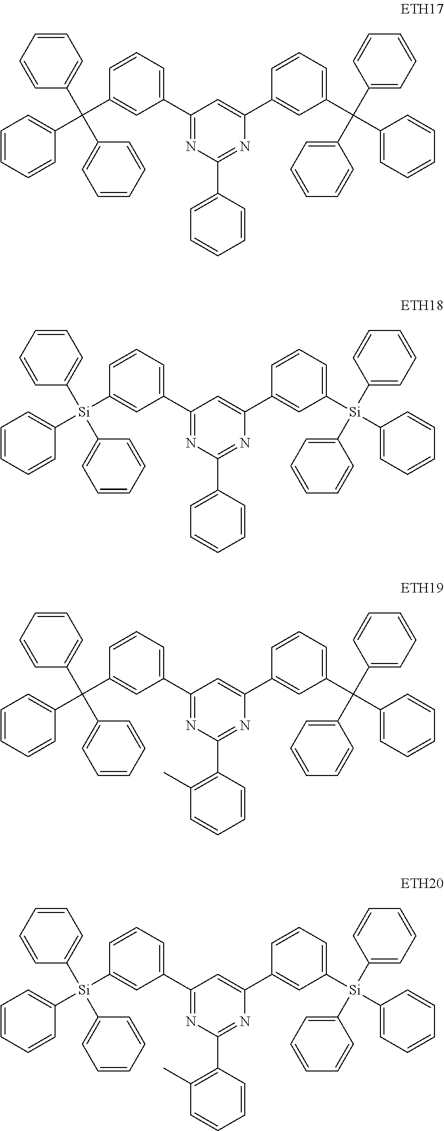 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

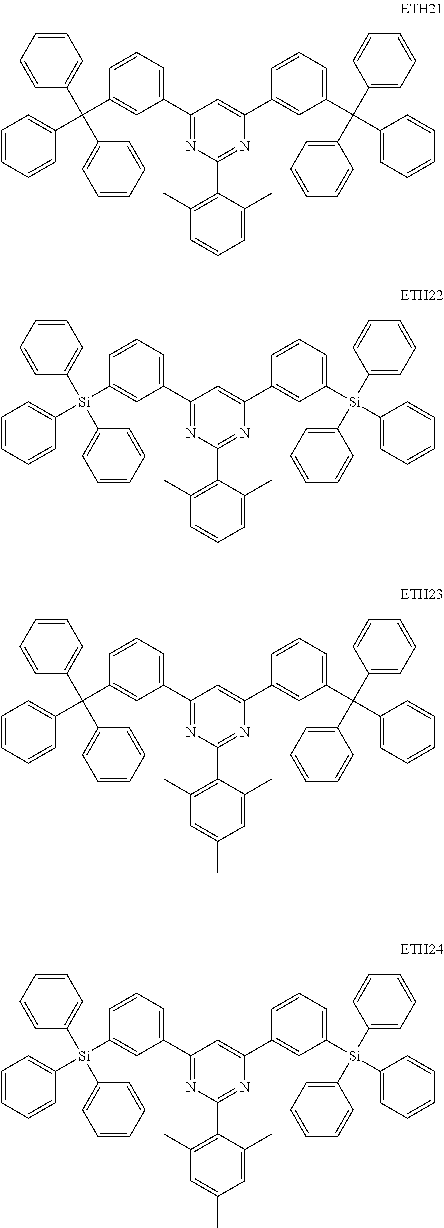 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

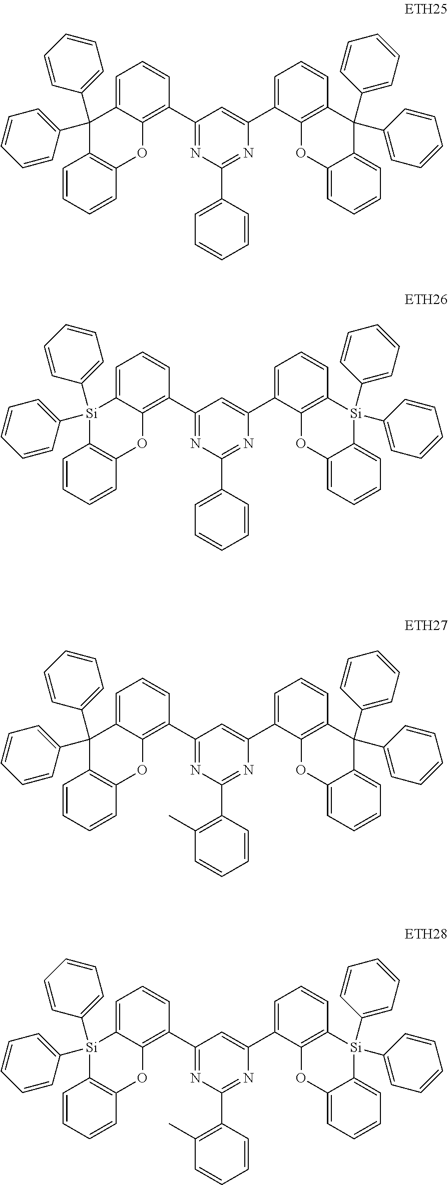 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

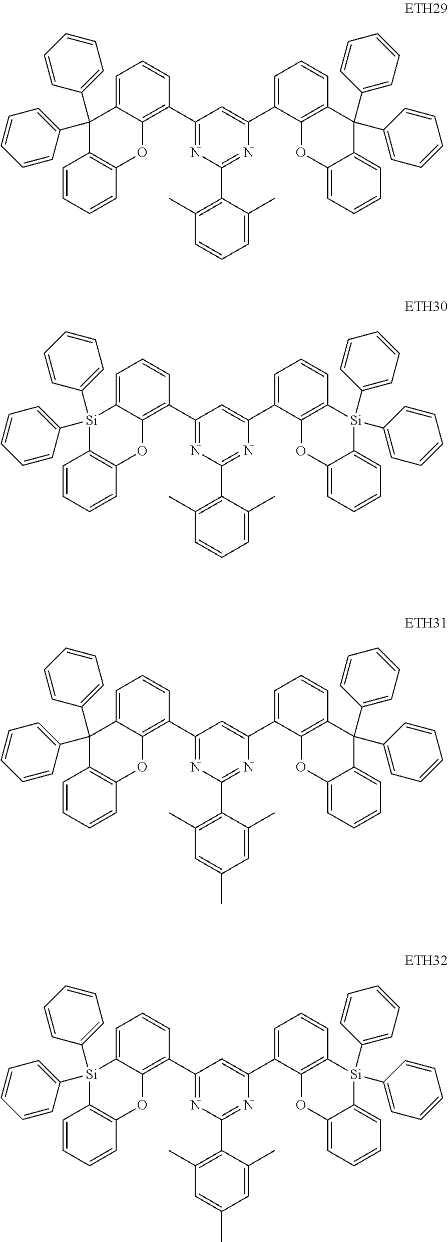 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

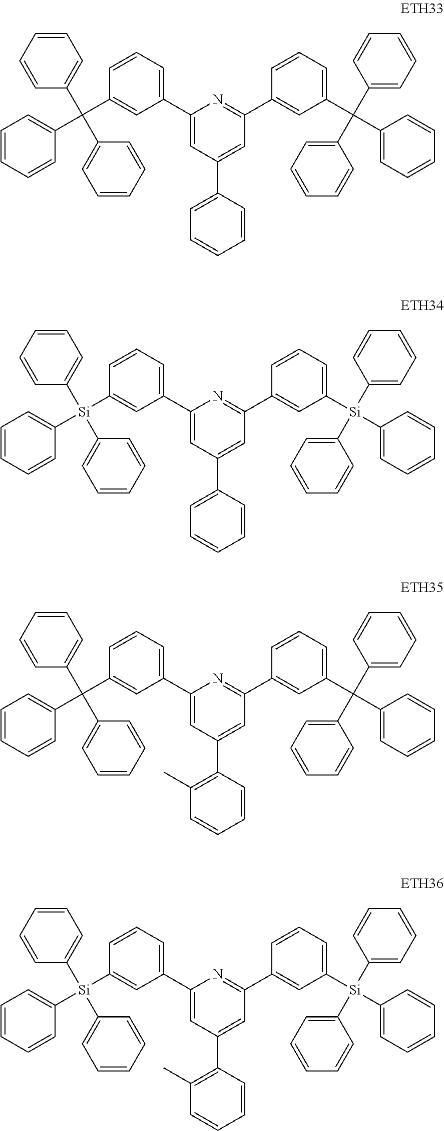 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

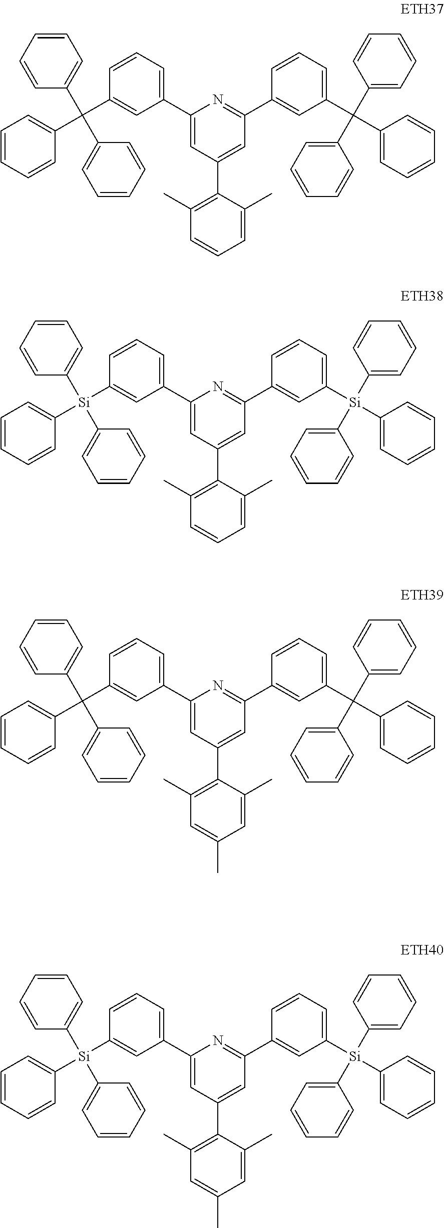 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

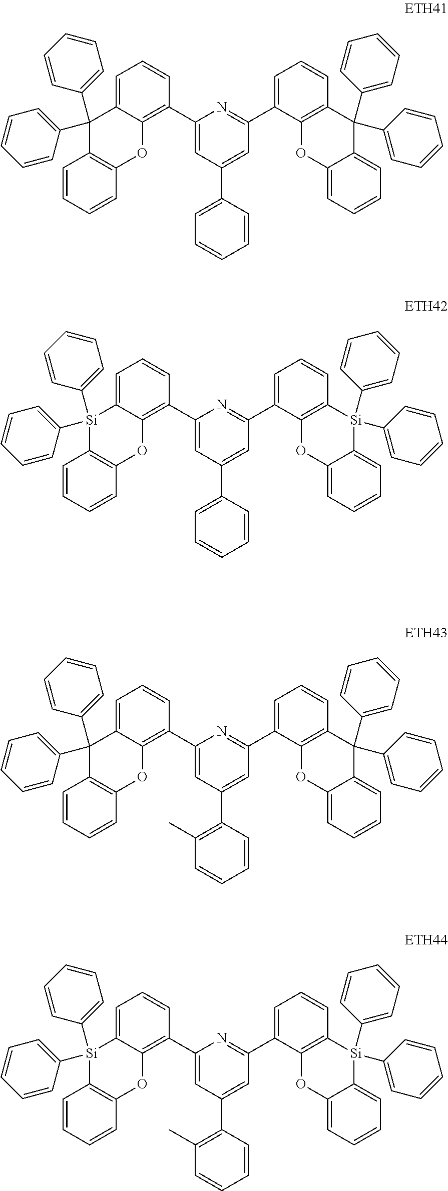 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

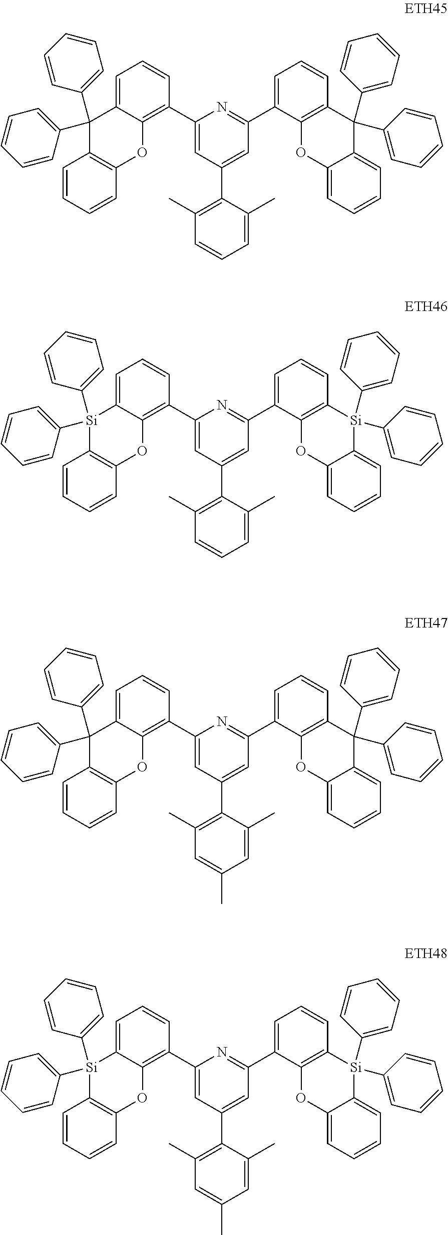 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

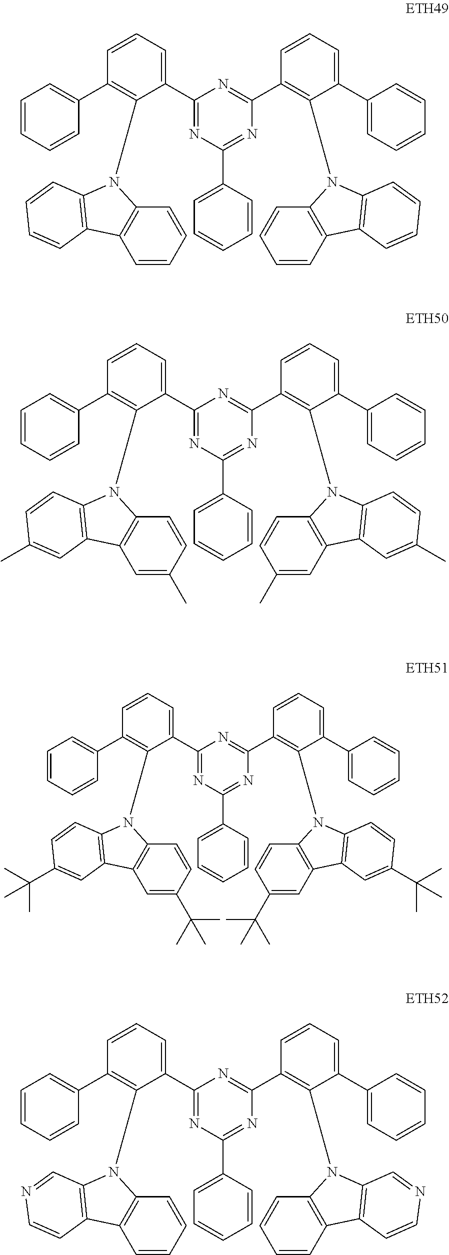

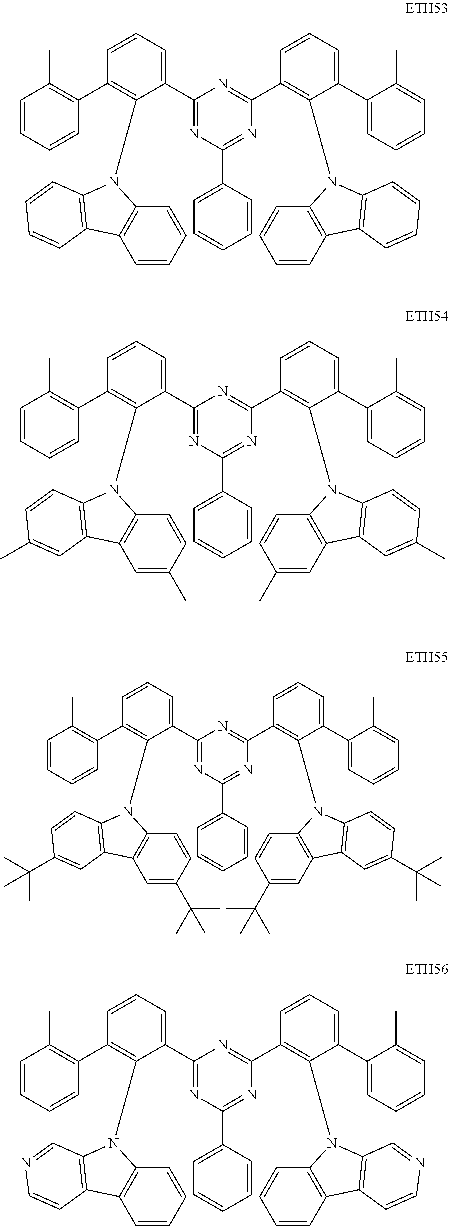

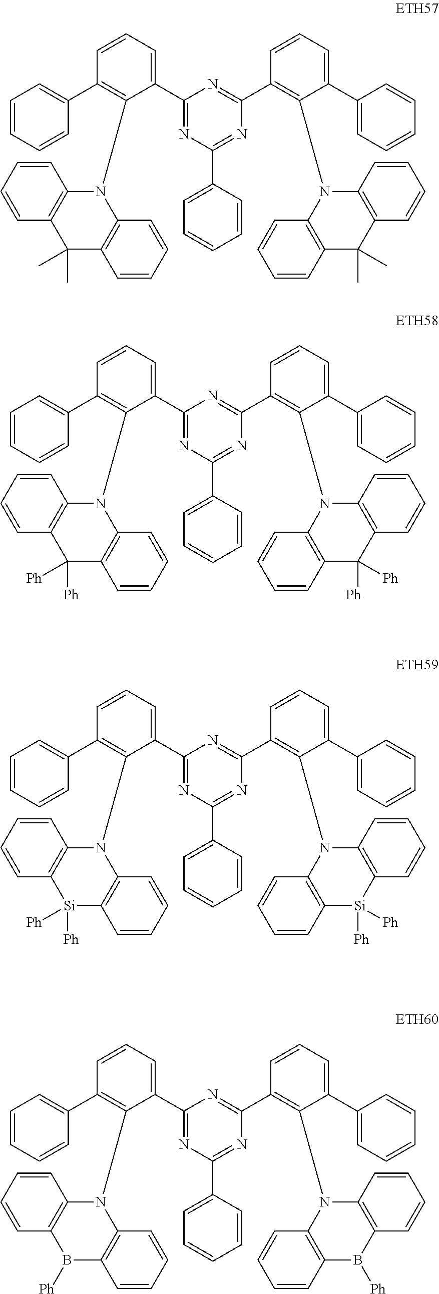

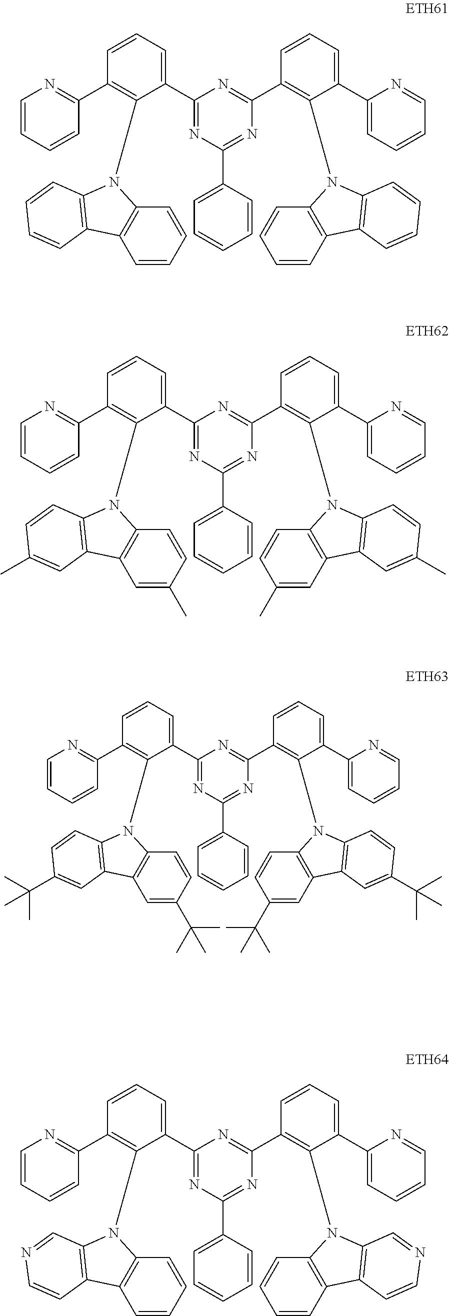

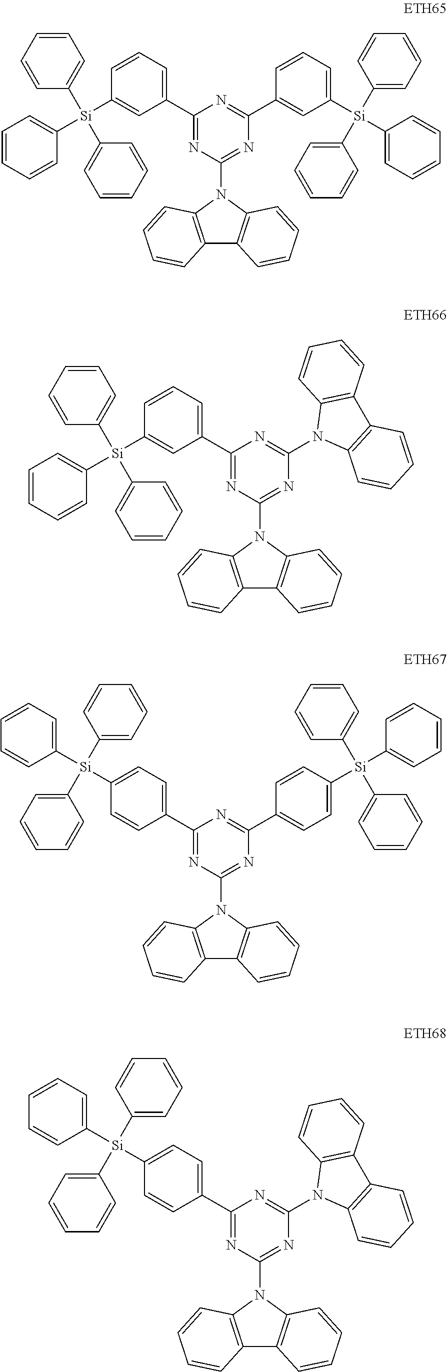 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

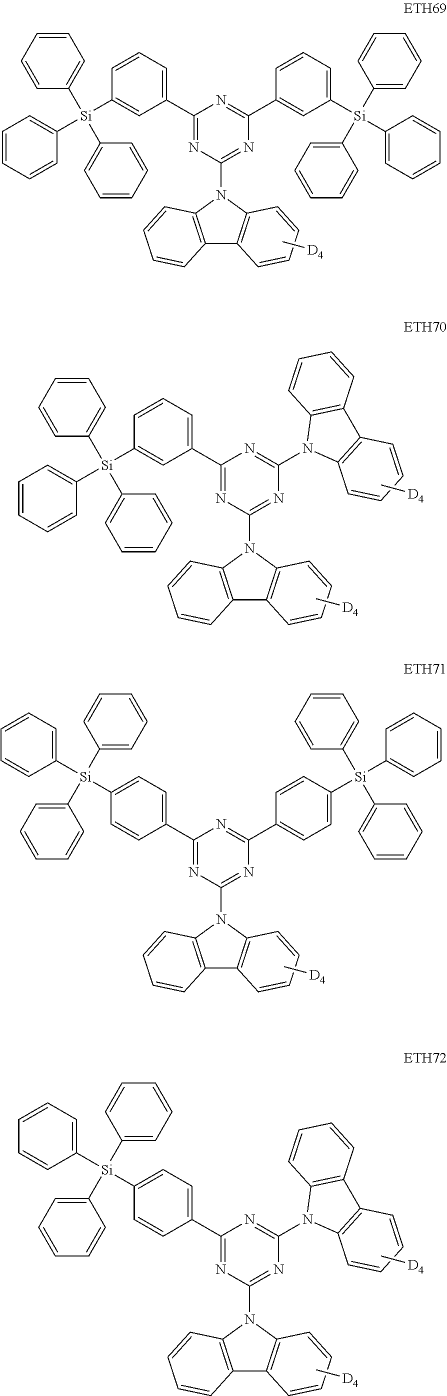

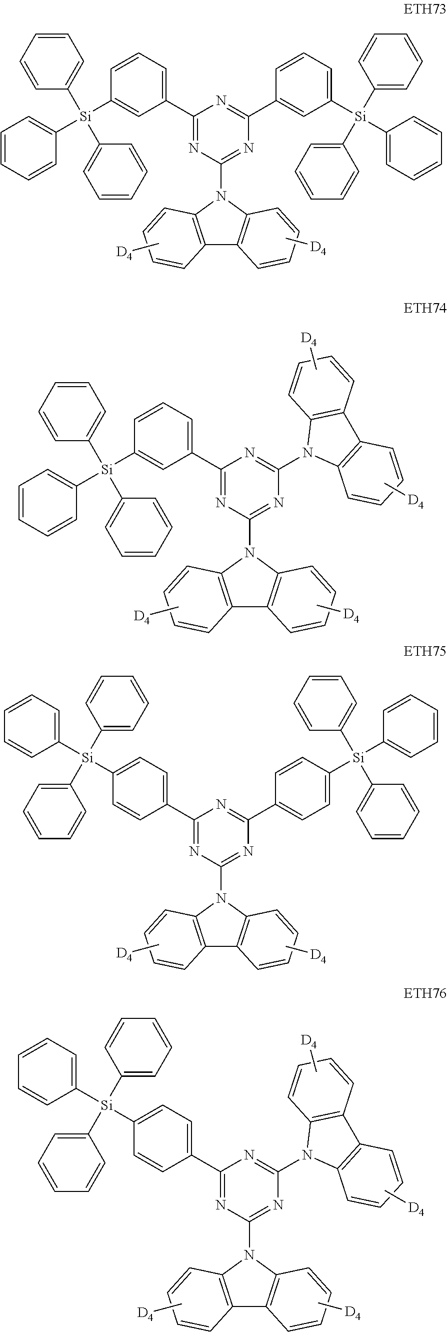

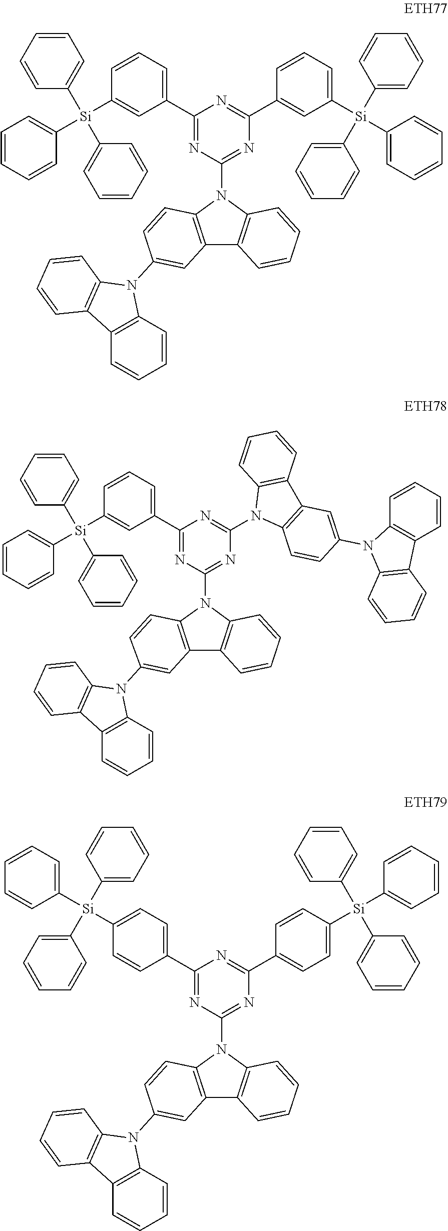 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

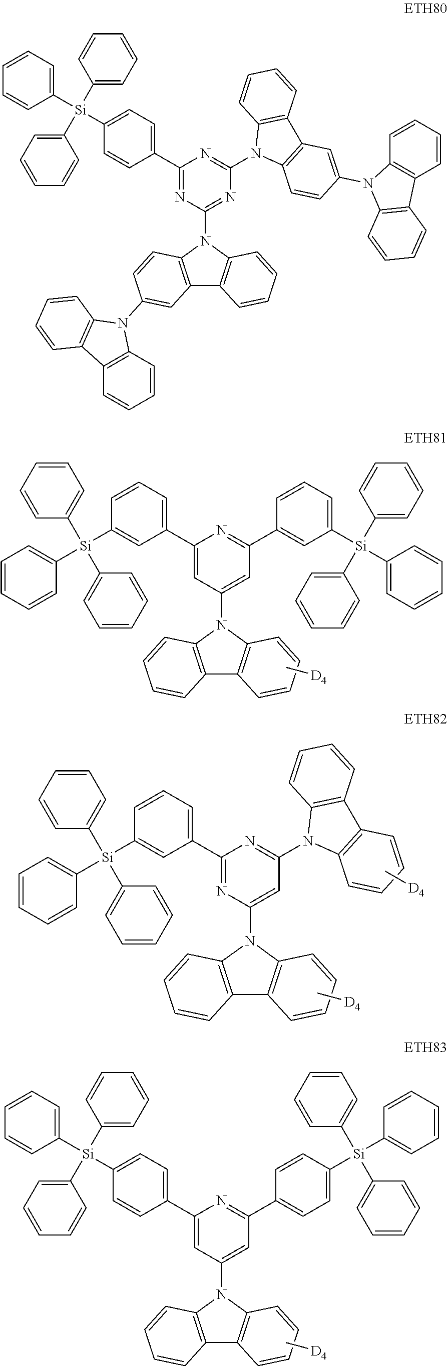

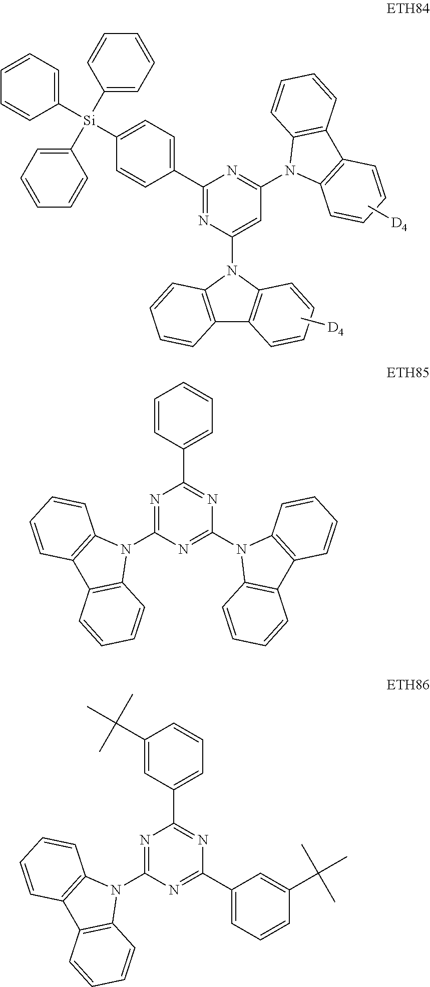

In Compound Group 3, D may be a deuterium atom, and Ph may be an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (Ti) of the exciplex formed by the hole transport host and the electron transport host may be in a range of about 2.4 eV to about 3.0 eV. The triplet energy level of the exciplex may have a value that is smaller than an energy gap of each host material. The exciplex may have a triplet energy level equal to or less than about 3.0 eV, which is the energy gap between the hole transport host and the electron transport host.

In an embodiment, the emission layer EML may include a fourth compound in addition to the first compound, the second compound, and the third compound. The fourth compound may be used as a phosphorescence sensitizer in an emission layer EML. Since energy may transfer from the fourth compound to the first compound, light emission may occur.

The emission layer EML may include, as a fourth compound, an organometallic complex that includes platinum (Pt) as a central metal atom and ligands bonded to the central metal atom. In an embodiment, the emission layer EML may further include a compound represented by Formula D-1 as the fourth compound.

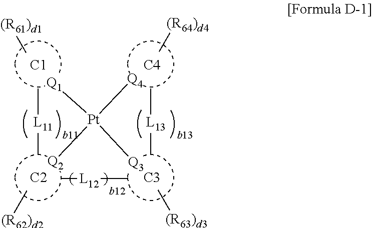

In Formula D-1, Q₁ to Q₄ may each independently be C or N.

In Formula D-1, C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, L₁₁ to L₁₃ may each independently be a direct linkage,

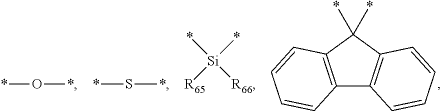

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “ [symbol] ” represents a bond to one of C1 to C4.

In Formula D-1, b11 to b13 may each independently be 0 or 1. If b11 is 0, C1 and C2 may not be directly connected to each other. If b12 is 0, C2 and C3 may not be directly connected to each other. If b3 is 0, C3 and C4 may not be directly connected to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may be unsubstituted with R₆₁ to R₆₄, respectively. A case where d1 to d4 are 4, and R₆₁ to R₆₄ are hydrogen atoms, may be the same as a case where d1 to d4 are 0. If d1 to d4 are integers of 2 or more, each of multiple R₆₁ to R₆₄ may be all the same, or at least one among multiple R₆₁ to R₆₄ may be different.

In an embodiment, in Formula D-1, C1 to C4 may each independently be a substituted or unsubstituted hydrocarbon ring or a substituted or unsubstituted heterocycle that is represented by any one of Formula C-1 to Formula C-4.

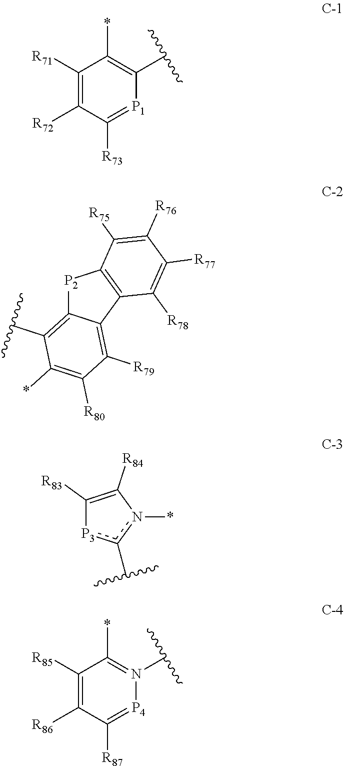

In Formula C-1 to Formula C-4, P₁ may be [symbol] or C(R₇₄), P₂ may be [symbol] or N(R₈₁), P₃ may be [symbol] or N(R₈₂), and P₄ may be [symbol] or C(R₈₈).

In Formula C-1 to Formula C-4, R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula C-1 to Formula C-4, [symbol] represents a bond to Pt, and [symbol] represents a bond to an adjacent ring group (C1 to C4) or to a linker (L₁₁ to L₁₃).

In an embodiment, the emission layer EML may include the first compound represented by Formula 1, and may further include at least one of the second compound, the third compound, and the fourth compound. In an embodiment, the emission layer EML may include the first compound, the second compound, and the third compound. In the emission layer EML, the second compound and the third compound may form an exciplex, and in the exciplex, energy transfer to the first compound may occur, and light emission may occur.

In another embodiment, the emission layer EML may include the first compound, the second compound, the third compound, and the fourth compound. In the emission layer EML, the second compound and the third compound may form an exciplex, and in the exciplex, energy may be transferred from the exciplex to the fourth compound and the first compound, and light emission may occur. In an embodiment, the fourth compound may be a sensitizer. In the light emitting element ED, the fourth compound included in the emission layer EML may serve as a sensitizer and may transfer energy from a host to the first compound which is a light-emitting dopant. For example, the fourth compound which serves as an auxiliary dopant, may accelerate energy transfer to the first compound which is a light emitting dopant, thereby increasing an emission ratio of the first compound. Accordingly, efficiency of the emission layer EML may be improved. If the energy transfer to the first compound increases, excitons formed in the emission layer EML may not accumulate, but may rapidly emit light, so that deterioration of a device may be reduced. Accordingly, the lifetime of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may exhibit excellent emission efficiency properties.

In an embodiment, the fourth compound represented by Formula D-1 may be selected from Compound Group 4. In an embodiment, in the light emitting element ED, the fourth compound may include at least one compound selected from Compound Group 4.

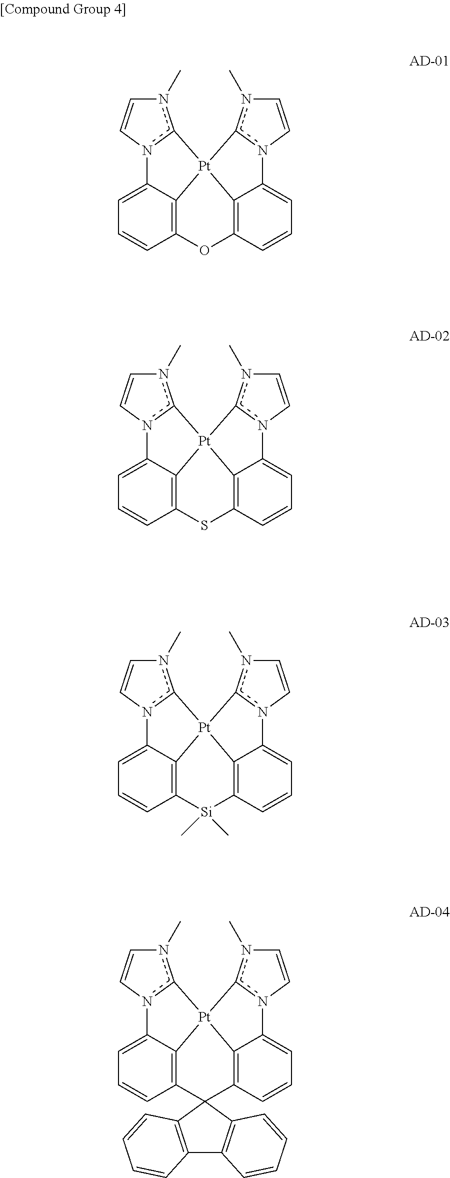

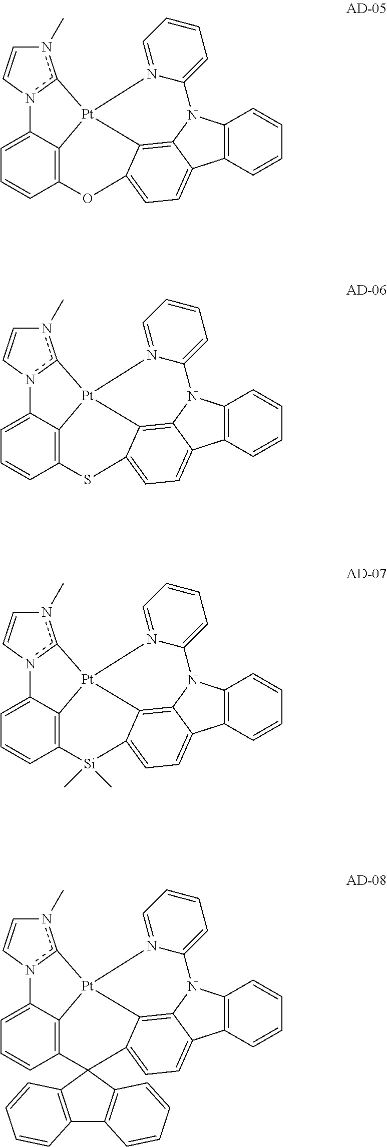

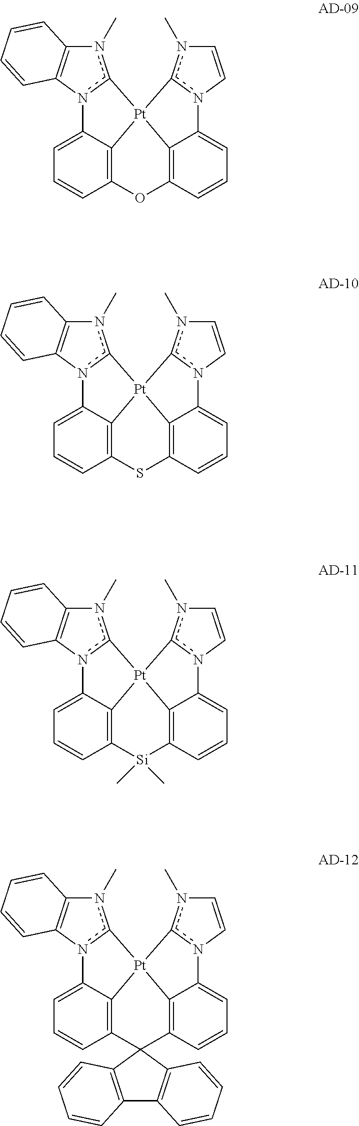

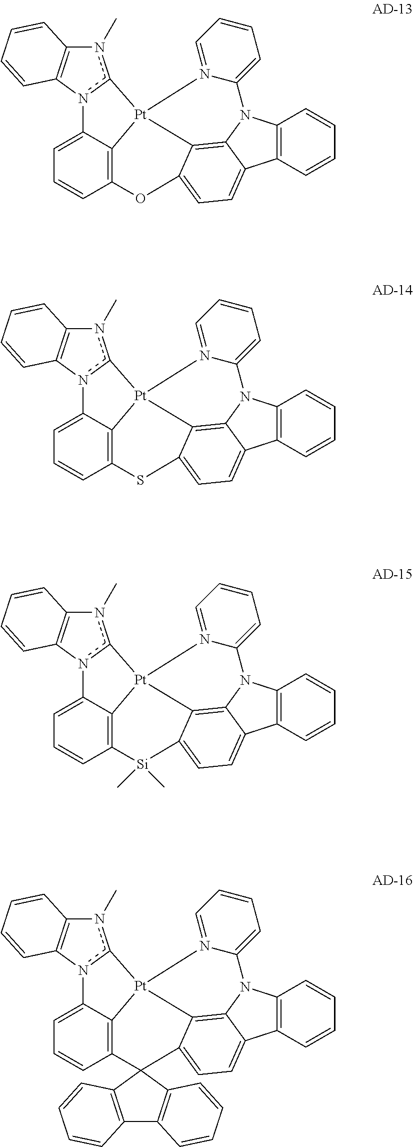

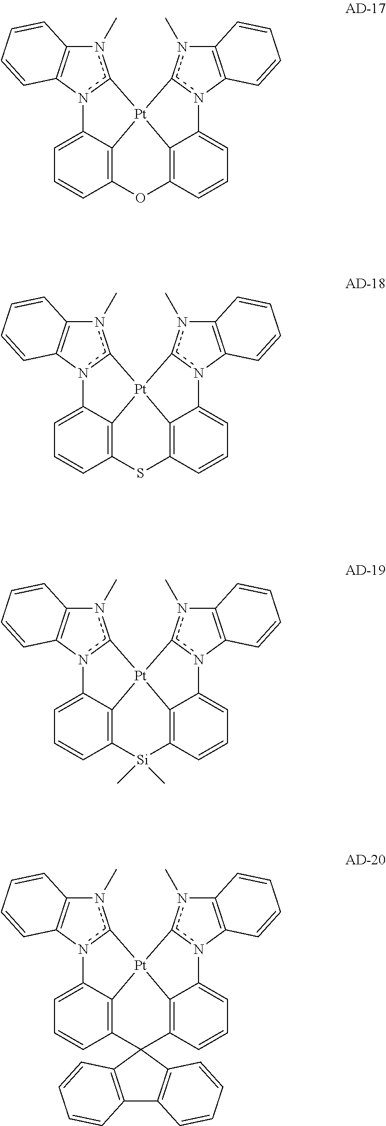

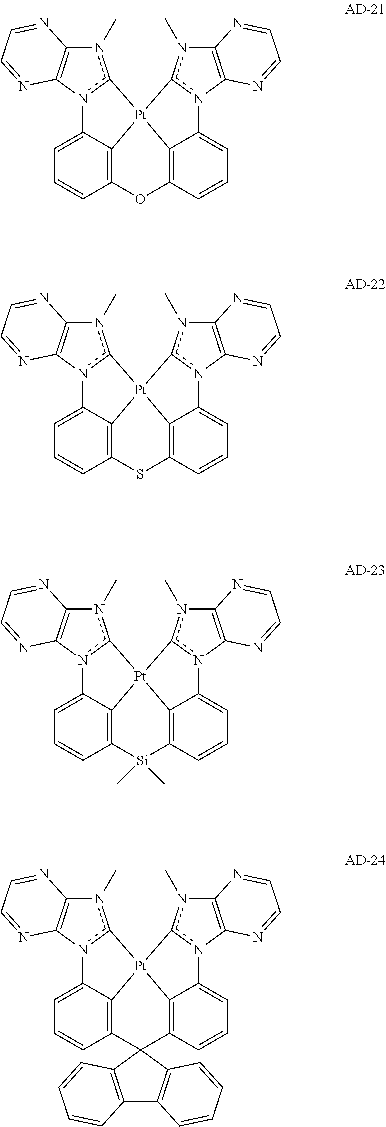

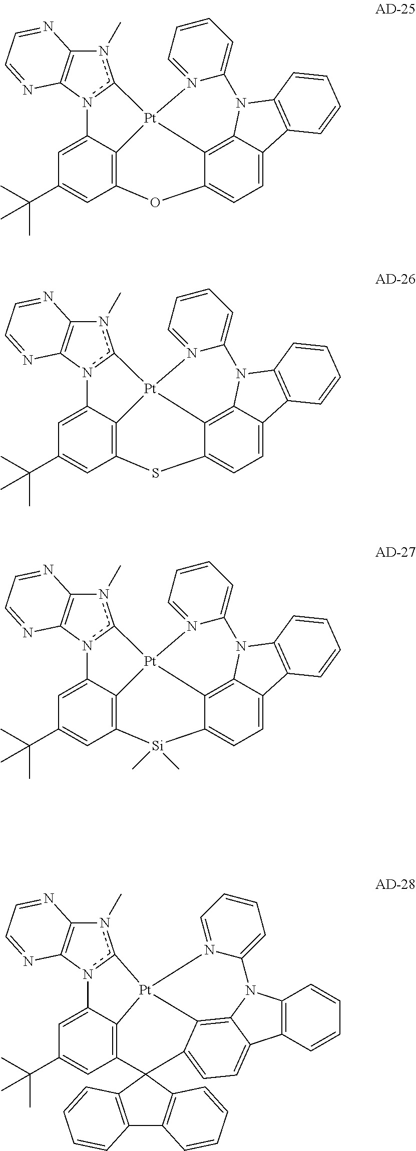

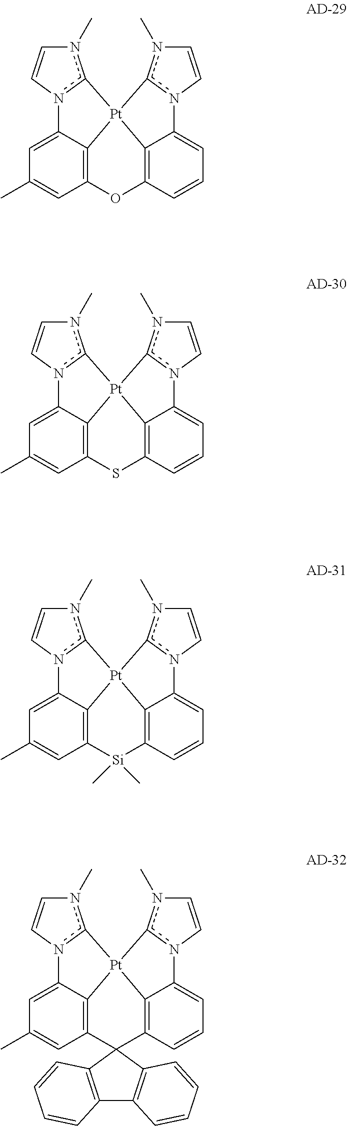

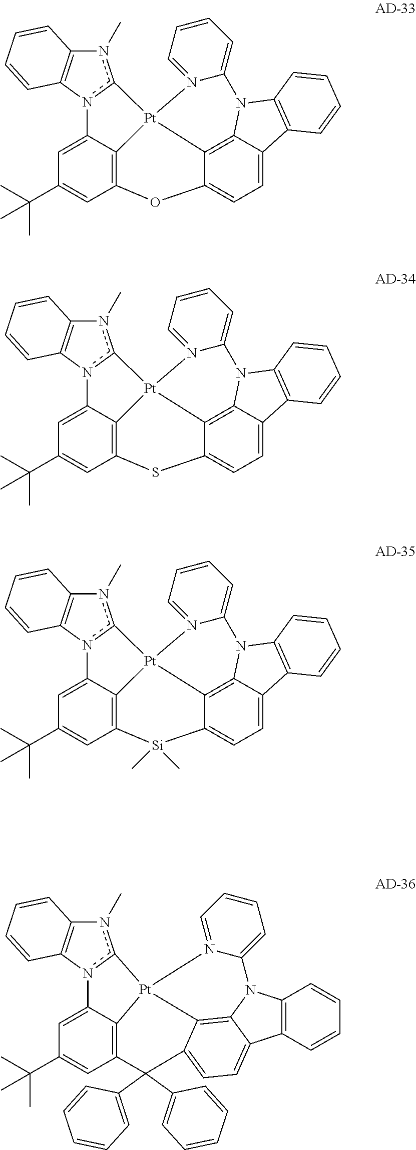

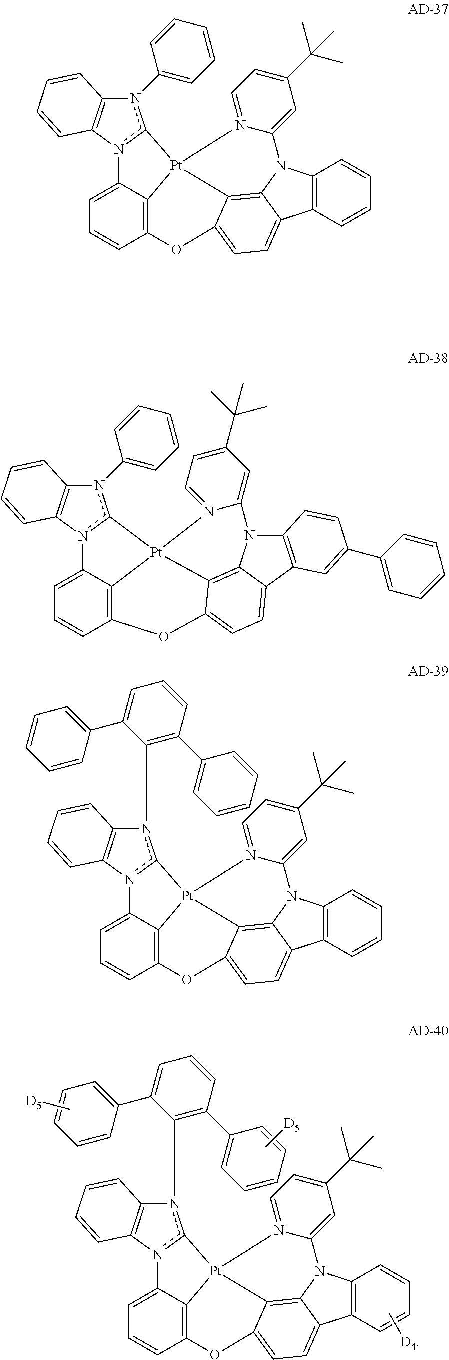

In Compound Group 4, D may be a deuterium atom.

In an embodiment, the light emitting element ED may include multiple emission layers. Multiple emission layers may be provided as a stack, so that a light emitting element ED including multiple emission layers may emit white light. The light emitting element ED including multiple emission layers may be a light emitting device having a tandem structure. If the light emitting element ED includes multiple emission layers, at least one emission layer EML may include the first compound represented by Formula 1. For example, if the light emitting element ED includes multiple emission layers, at least one emission layer EML may include the first compound, the second compound, the third compound, and the fourth compound.

In the light emitting element ED according to an embodiment, if the emission layer EML includes the first compound, the second compound, the third compound, and the fourth compound, an amount of the first compound may be in a range of about 0.1 wt % to about 5 wt %, based on a total weight of the first compound, the second compound, the third compound, and the fourth compound. However, embodiments are not limited thereto. If an amount of the first compound satisfies the above-described range, energy transfer from the second compound and the third compound to the first compound may increase, and accordingly, emission efficiency and device lifetime may increase.

In the emission layer EML, a total amount of the second compound and the third compound may be the remainder of the total weight of the first compound, the second compound, and the third compound, excluding the amount of the first compound and the fourth compound. For example, the total amount of the second compound and the third compound may be in a range of about 65 wt % to about 95 wt %, based on a total weight of the first compound, the second compound, the third compound, and the fourth compound.

Within the combined amount of the second compound and the third compound in the emission layer EML, a weight ratio of the second compound to the third compound may be in a range of about 3:7 to about 7:3.

If the total amount of the second compound and the third compound satisfies the above-described ranges and ratios, charge balance properties in the emission layer EML may be improved, and emission efficiency and device lifetime may be improved. If the total amount of the second compound and the third compound deviates from the above-described ranges and ratios, charge balance in the emission layer EML may not be achieved, so that emission efficiency may be reduced, and the device may more readily deteriorate.

If the emission layer EML includes the fourth compound, an amount of the fourth compound may be in a range of about 4 wt % to 30 wt %, based on a total weight of the first compound, the second compound, the third compound, and the fourth compound in the emission layer EML. However, embodiments are not limited thereto. If an amount of the fourth compound satisfies the above-described range, energy transfer from a host to the first compound, which is a light emitting dopant may increase, and an emission ratio may be improved. Accordingly, the emission efficiency of the emission layer EML may be improved.

If the amounts of the first compound, the second compound, the third compound and the fourth compound, included in the emission layer EML satisfies the above-described ranges and ratios, excellent emission efficiency and long lifetime may be achieved.

In the light emitting element ED, the emission layer EML may further include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting elements ED according to embodiments, as shown in FIG. 3 to FIG. 6, the emission layer EML may further include hosts and dopants of the related art in addition to the above-described host and dopant.

In an embodiment, the emission layer EML may include a compound represented by Formula E-1. The compound represented by Formula E-1 may be used as a fluorescence host material.

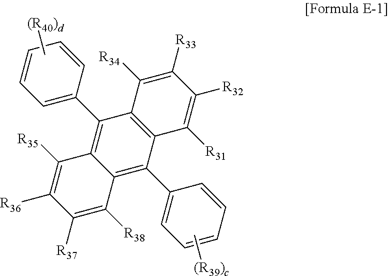

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. In an embodiment, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19.

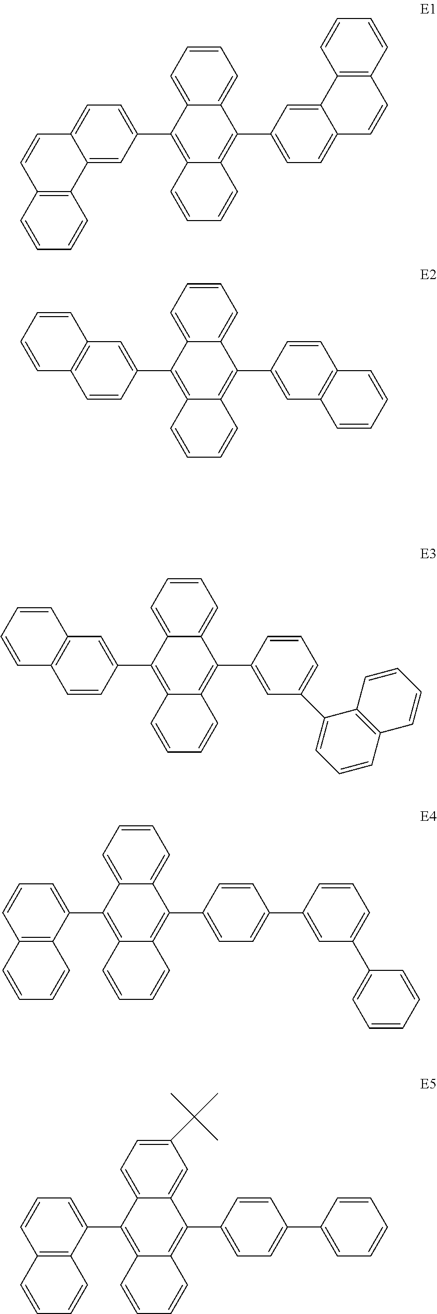

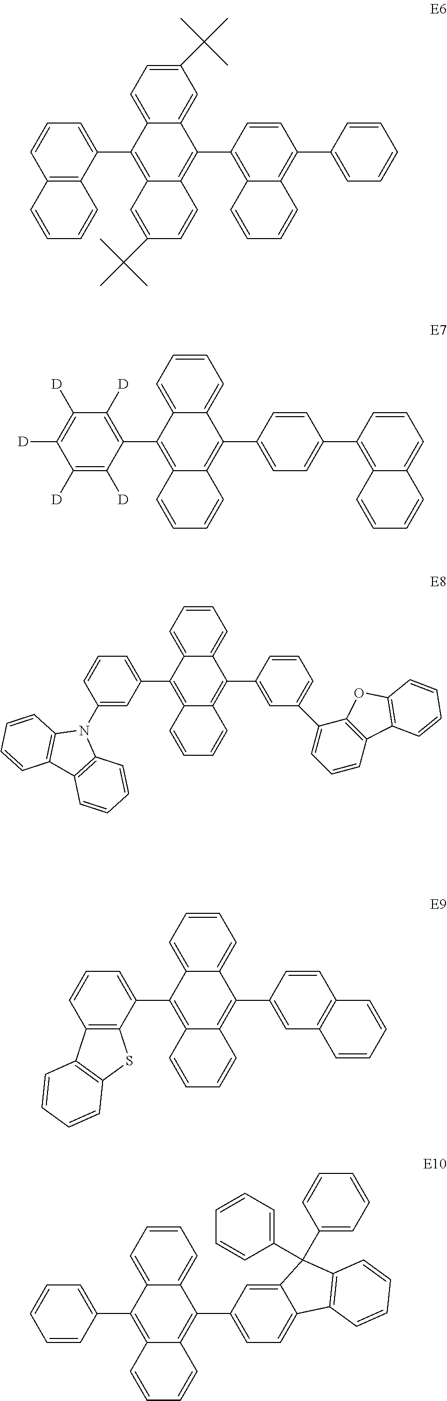

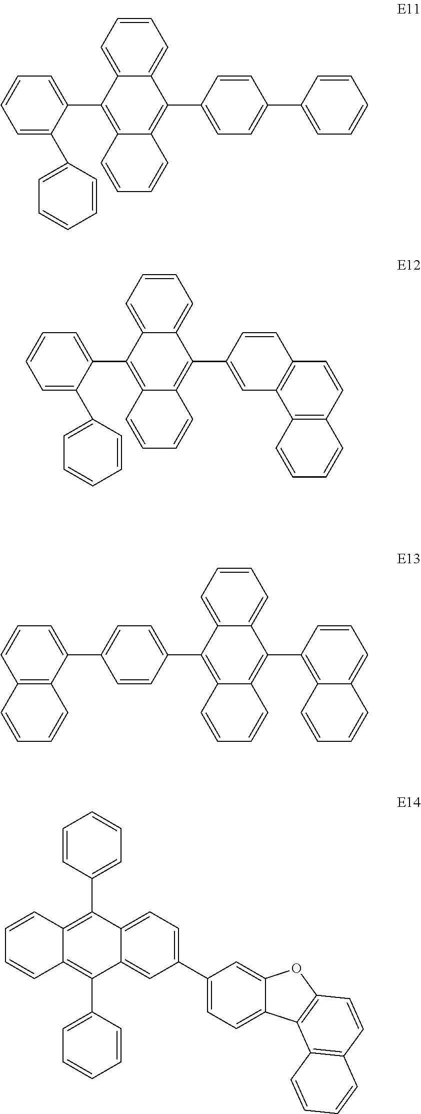

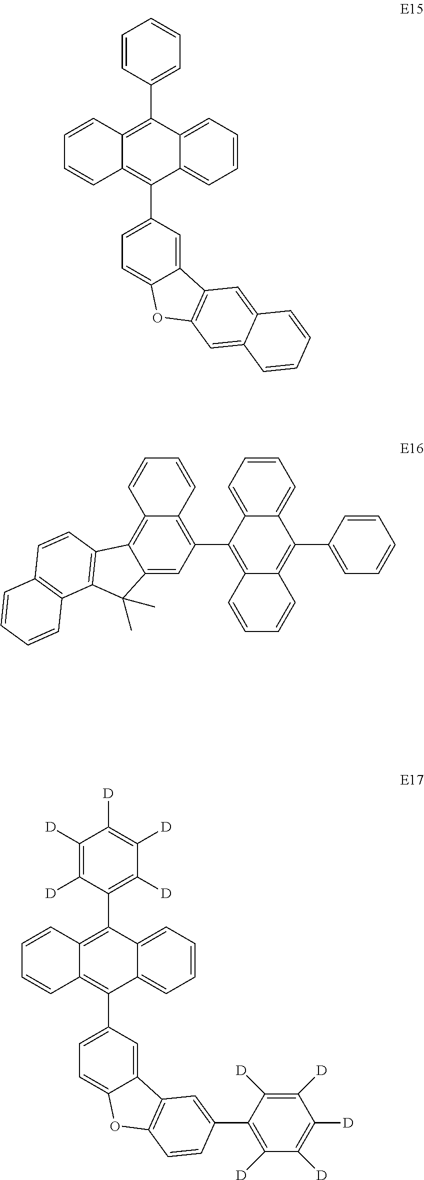

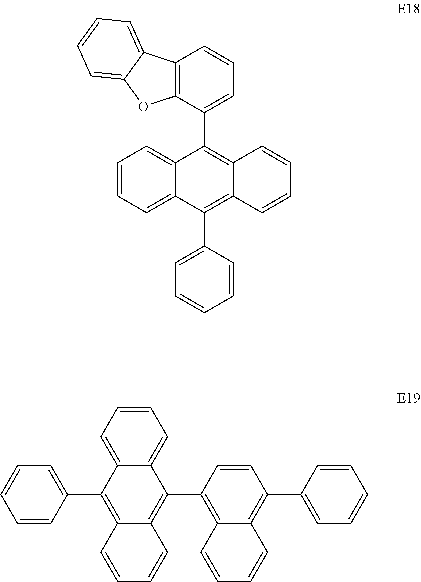

In an embodiment, the emission layer EML may include a compound represented by Formula E-2a or Formula E-2b. The compound represented by Formula E-2a or Formula E-2b may be used as a phosphorescence host material.

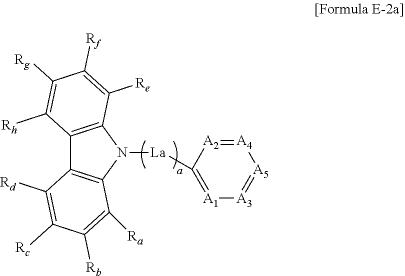

In Formula E-2a, a may be an integer from 0 to 10; La may be a direct linkage, a substituted or unsubstituted arylene group of 6 to 30 ring-forming carbon atoms, or a substituted or unsubstituted heteroarylene group of 2 to 30 ring-forming carbon atoms. Meanwhile, if “a” is an integer of 2 or more, multiple La may be each independently a substituted or unsubstituted arylene group of 6 to 30 ring-forming carbon atoms, or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

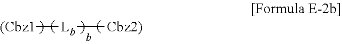

In Formula E-2b, Cbz1 and Cbz2 may each independently be an unsubstituted carbazole group, or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b″ is 2 or more, multiple L_{b} groups may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be any one compound selected from Compound Group E-2. However, the compounds shown in Compound Group E-2 are only examples, and the compound represented by Formula E-2a or Formula E-2b is not limited to Compound Group E-2.

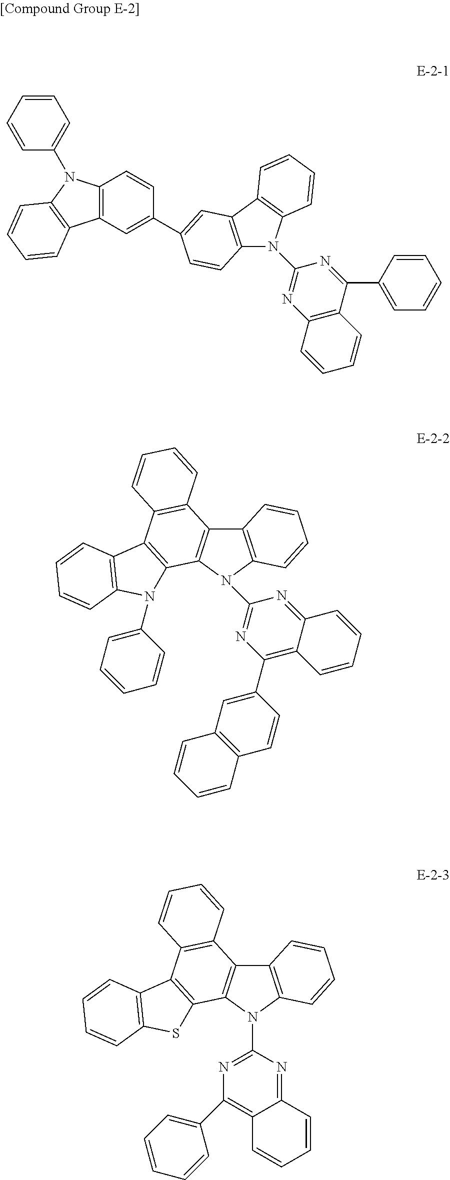 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

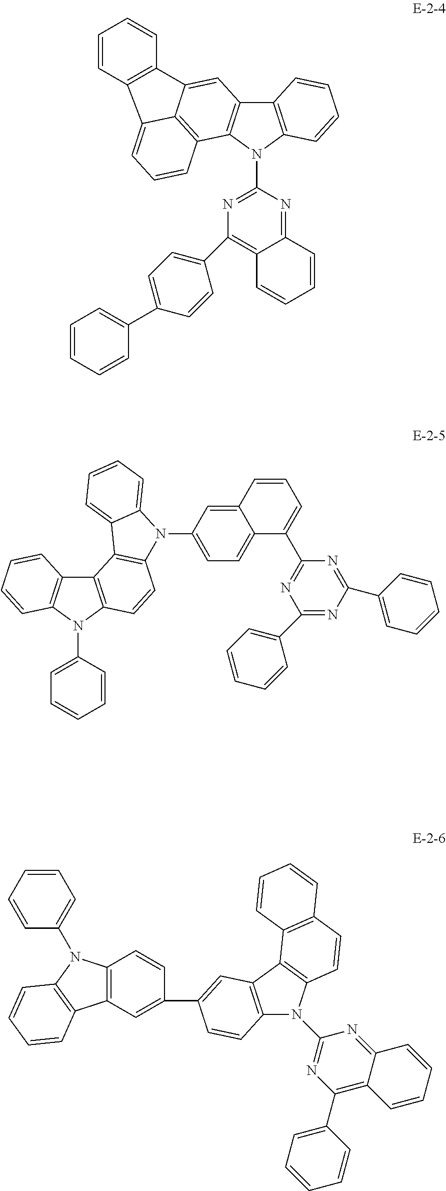 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

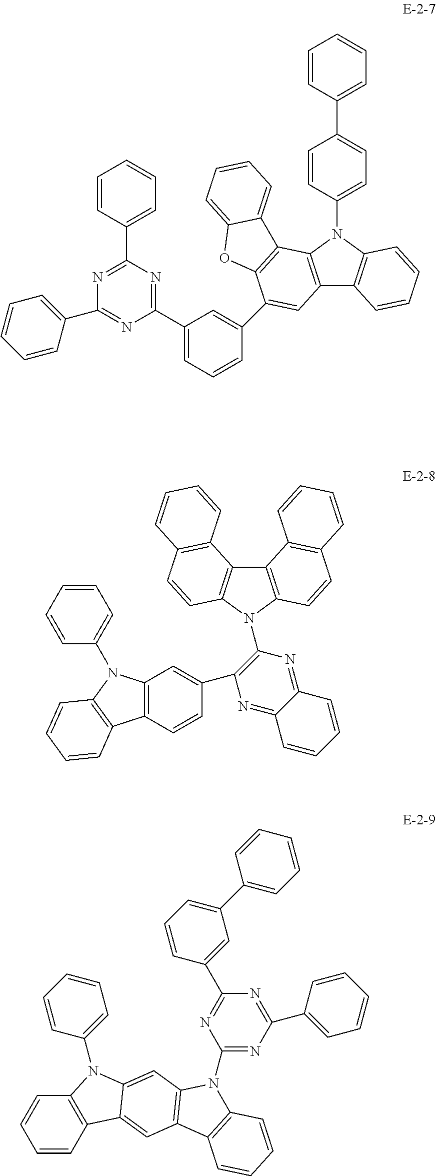 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

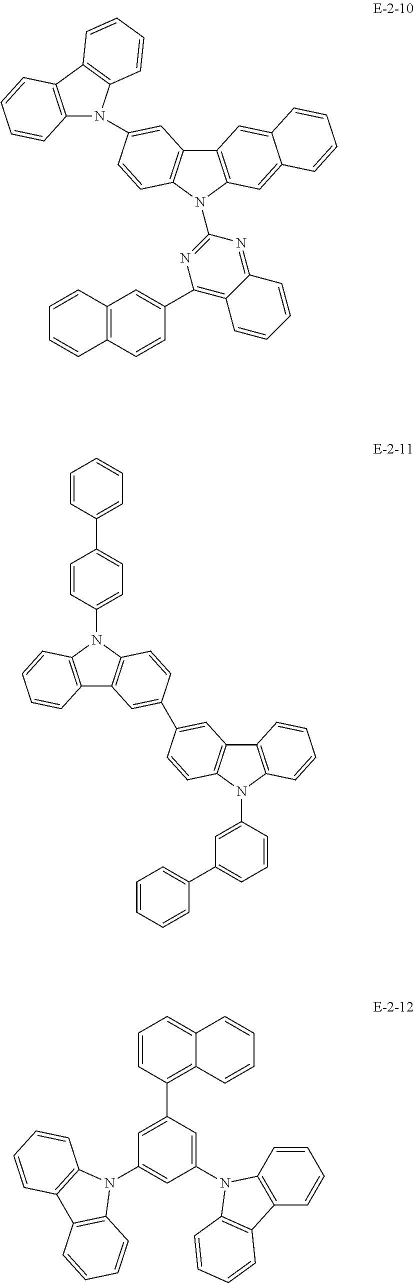 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

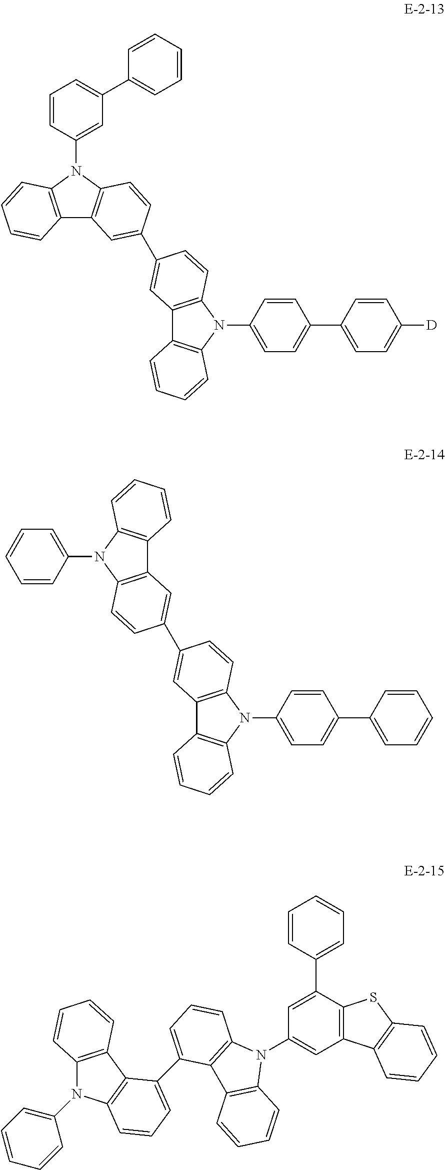 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

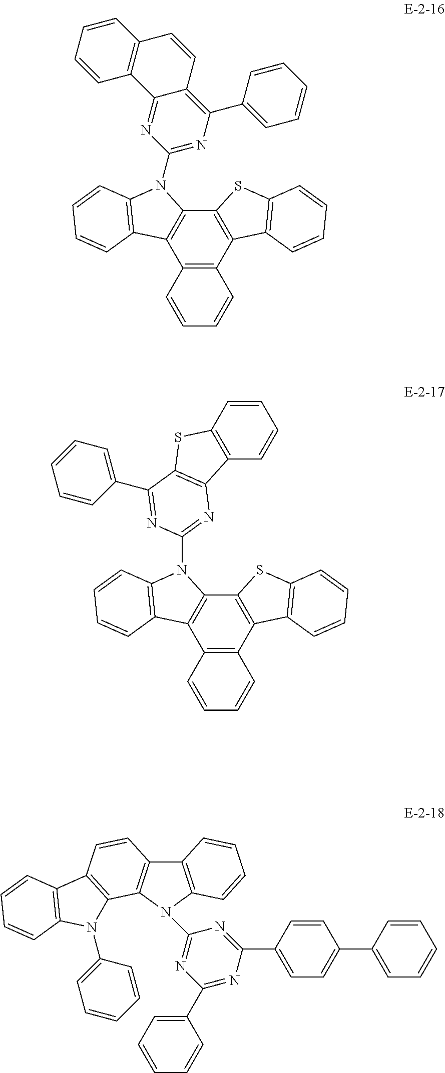 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

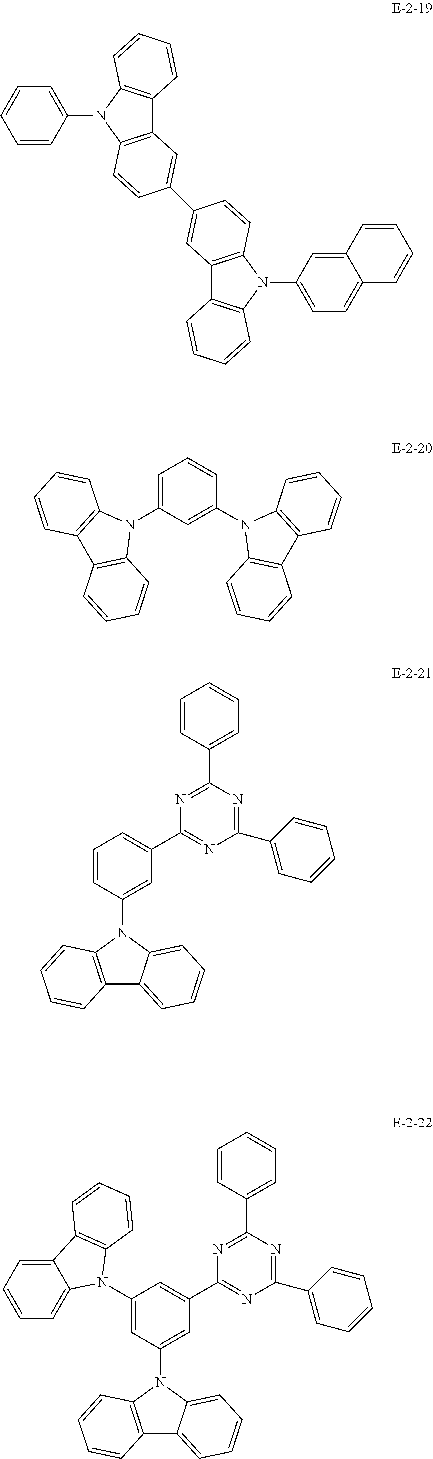 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

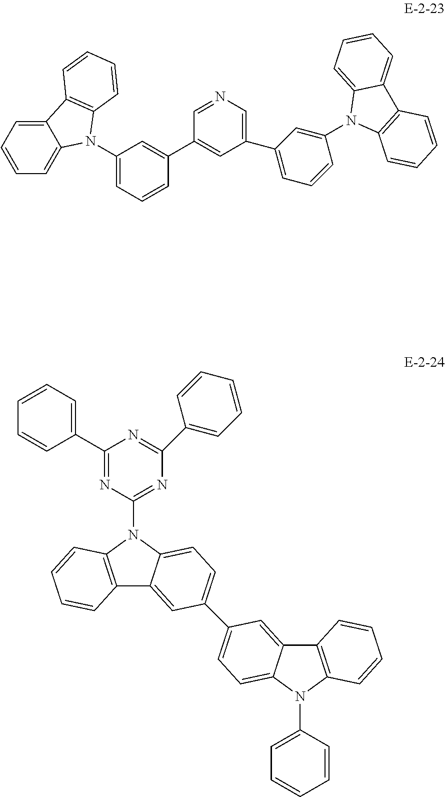 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material of the related art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

In an embodiment, the emission layer EML may include a compound represented by Formula M-a. The compound represented by Formula M-a may be used as a phosphorescence dopant material.

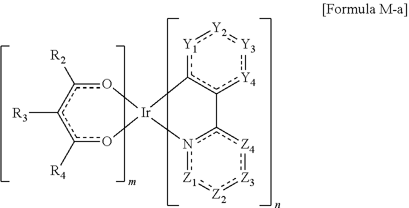

In Formula M-a, Y₁ to Y₄, and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, m may be 0 or 1, and n may be 2 or 3. In Formula M-a, if m is 0, n may be 3, and if m is 1, n may be 2.

The compound represented by Formula M-a may be any compound selected from Compounds M-a1 to M-a25. However, Compounds M-a1 to M-a25 are only examples, and the compound represented by Formula M-a is not limited to the compounds represented by Compounds M-a1 to M-a25.

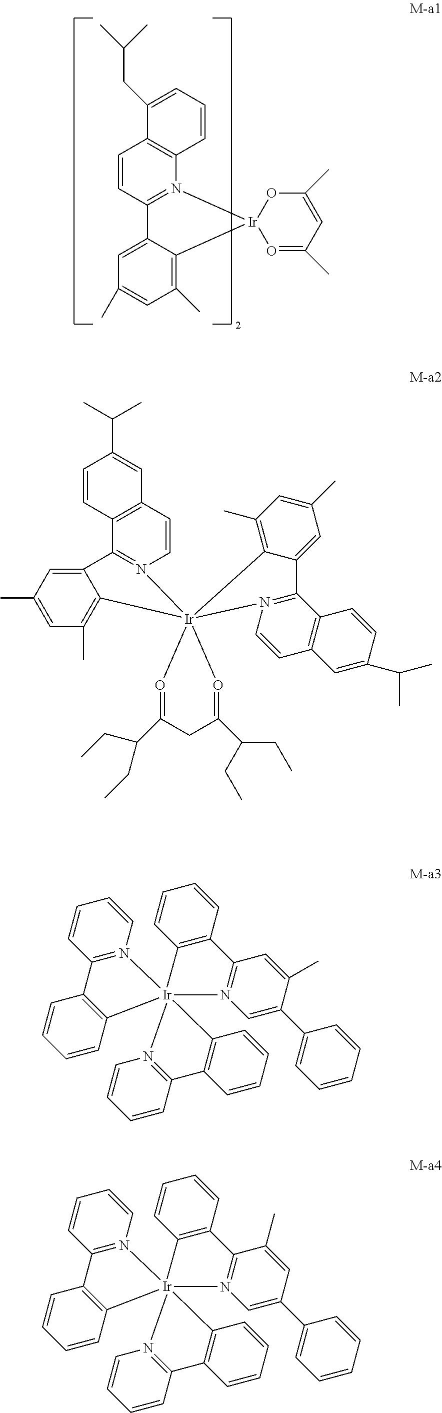

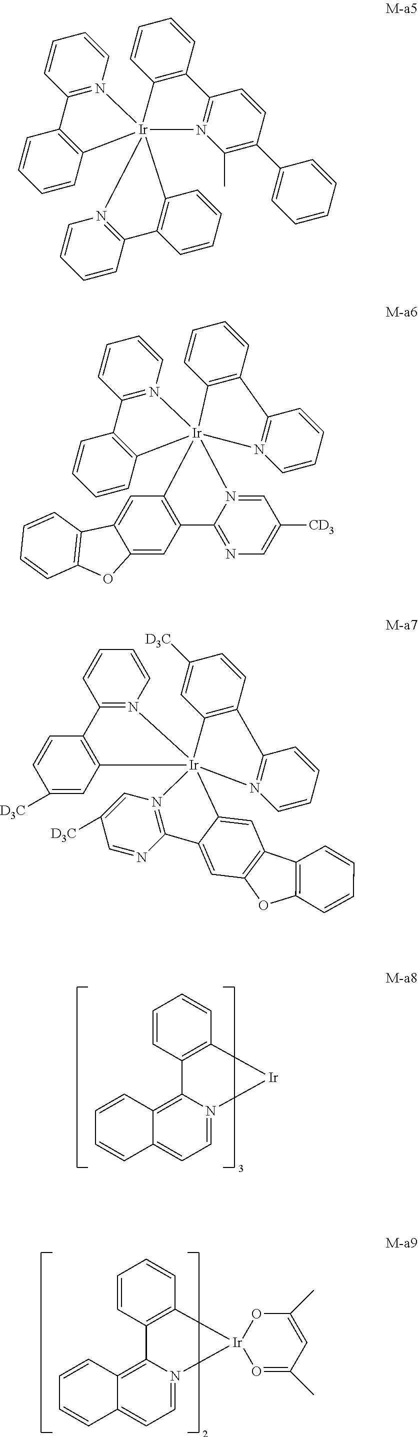

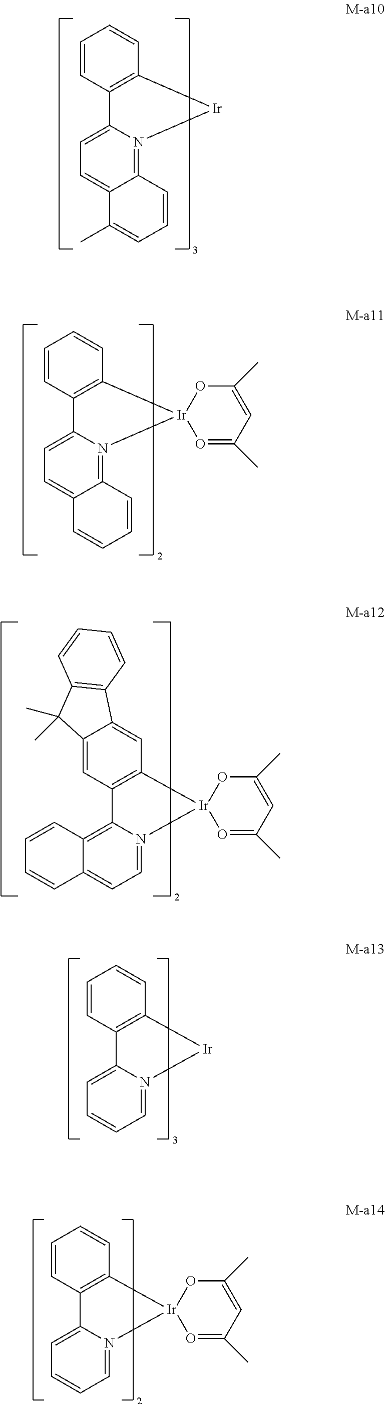

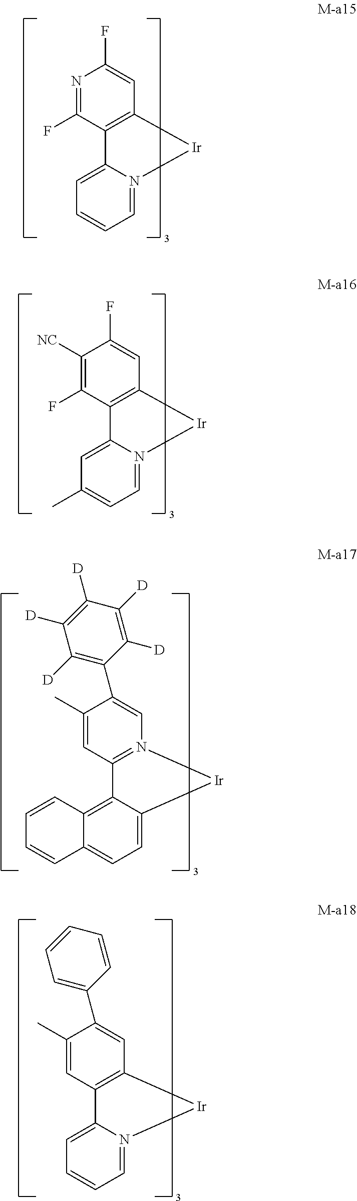

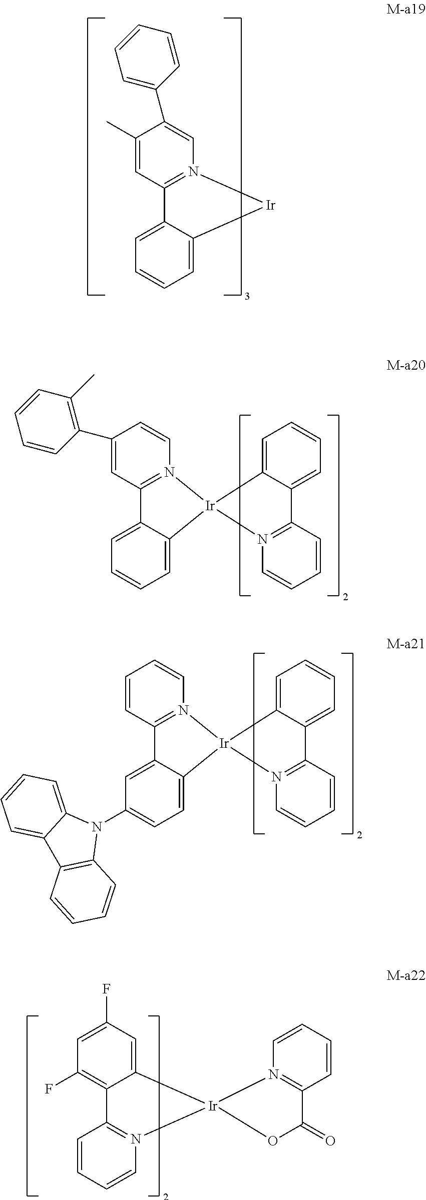

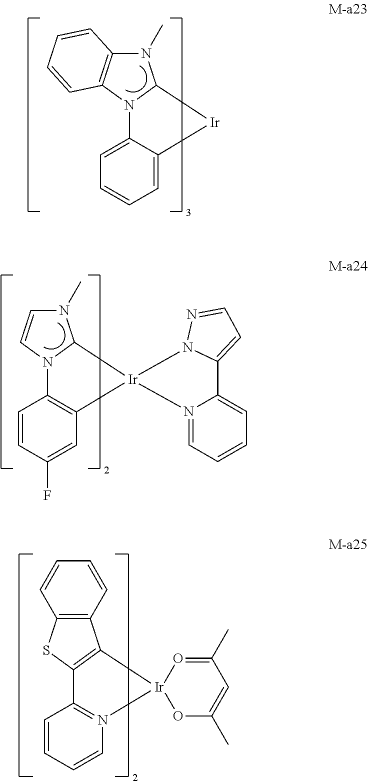

In an embodiment, the emission layer EML may further include a compound represented by any one of Formula F-a to Formula F-c. The compounds represented by one of Formula F-a to Formula F-c may be used as fluorescence dopant materials.

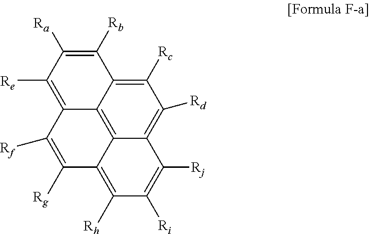

In Formula F-a, two of Rₐ to Rⱼ may each independently be substituted with a group represented by [symbol] . The remainder of Rₐ to Rⱼ not substituted with a group represented by [symbol] may each be independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In the group represented by [symbol] Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one of Ar₁ and Ar₂ may be a heteroaryl group including O or S as a ring-forming atom.

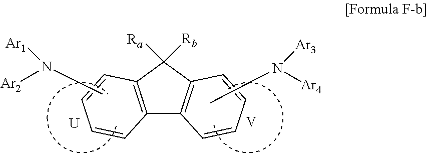

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula F-b, Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. If the number of U or V is 1, a fused ring may be present at the portion indicated by U or V, and if the number of U or V is 0, a fused ring may not be present at the portion indicated by U or V. If the number of U is 0 and the number of V is 1, or if the number of U is 1 and the number of V is 0, a fused ring having the fluorene core of Formula F-b may be a cyclic compound with four rings. If the number of both U and V is 0, a fused ring having the fluorene core of Formula F-b may be a cyclic compound with three rings. If the number of both U and V is 1, a fused ring having the fluorene core of Formula F-b may be a cyclic compound with five rings.

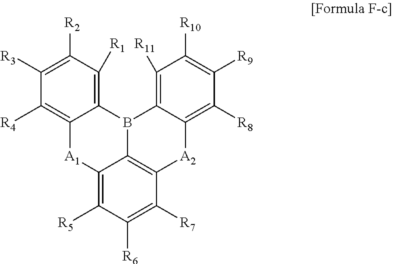

In Formula F-c, A₁ and A₂ may each independently be O, S, Se, or N(Rₘ), and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may each independently be combined with a substituent of an adjacent ring to form a fused ring. For example, if A₁ and A₂ are each independently N(Rₘ), A₁ may be combined with R₄ or R₅ to form a ring. For example, A₂ may be combined with R₇ or R₈ to form a ring.

In an embodiment, the emission layer EML may include, as a dopant material of the related art, styryl derivatives (for example, 1,4-bis [2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, embodiments are not limited thereto.

The emission layer may include a quantum dot.

In the description, the quantum dot may be crystal of a semiconductor compound. The quantum dot may emit light in various emission wavelengths according to the size of the crystal. The quantum dot may emit light in various emission wavelengths by controlling the element ratio in the quantum dot compound.

The diameter of the quantum dot may be, for example, about 1 nm to about 10 nm.

The quantum dot may be synthesized by a chemical bath deposition, a metal organic chemical vapor deposition, a molecular beam epitaxy or a similar process therewith.

The chemical bath deposition is a method of mixing an organic solvent and a precursor material and growing a quantum dot particle crystal. During crystal growth, the organic solvent may serve as a dispersant which is coordinated on the surface of the quantum dot crystal and may control the growth of the crystal. Accordingly, the chemical bath deposition may be more advantageous when compared to a vapor deposition method including a metal organic chemical vapor deposition (MOCVD) and molecular beam epitaxy (MBE), and the growth of the quantum dot particle may be controlled through a low-cost process.

In an embodiment, the emission layer EML may include a quantum dot material. The quantum dot may be a Group II-VI compound, a Group III-VI compound, a Group I-III-VI compound, a Group III-V Group compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof. Examples of a Group II-VI compound may further include a Group I metal and/or a Group IV element. Examples of a Group 1-II-VI compound may include CuSnS or CuZnS, and the Group II-IV-VI compound may include ZnSnS and the like. Examples of a Group I-II-IV-VI compound may include quaternary compounds selected from the group consisting of Cu₂ZnSnS₂, Cu₂ZnSnS₄, Cu₂ZnSnSe₄, Ag₂ZnSnS₂, and any mixture thereof.

Examples of a Group III-VI compound may include: a binary compound such as In₂S₃, and In₂Se₃; a ternary compound such as InGaS₃, and InGaSe₃, or any combinations thereof. Examples of a Group I-III-VI compound may include a ternary compound selected from the group consisting of AgInS, AgInS₂, CuInS, CuInS₂, AgGaS₂, CuGaS₂, CuGaO₂, AgGaO₂, AgAlO₂ and mixtures thereof; a quaternary compound such as AgInGaS₂, and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; or any combination thereof. In an embodiment, a Group III-V compound may further include a Group II metal. For example, InZnP, etc. may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof.

Examples of a Group II-IV-V compound may include a ternary compound selected from the group consisting of ZnSnP, ZnSnP₂, ZnSnAs₂, ZnGeP₂, ZnGeAs₂, CdSnP₂, and CdGeP₂, and any mixture thereof.

Examples of a Group IV element may include Si, Ge, and any mixture thereof. Examples of a Group IV compound may include a binary compound selected from the group consisting of SiC, SiGe, and any mixture thereof.

Each element included in the multi-element compound such as a binary compound, a ternary compound, or a quaternary compound may be present in particles at a uniform concentration or at a non-uniform concentration. For example, a formula may indicate elements included in a compound, but an element ratio in the compound may vary. For example, AgInGaS₂ may indicate AgInₓGa₁₋ₓS₂ (where x is a real number between 0 and 1).

In an embodiment, a binary compound, a ternary compound, or a quaternary compound may be present at a uniform concentration in a particle or may be present at a partially different concentration distribution state in a same particle. In an embodiment, a core/shell structure in which one quantum dot wraps another quantum dot may be possible. A quantum dot having a core/shell structure may have a concentration gradient in which the concentration of material that is present in the shell decreases towards the core.

In embodiments, the quantum dot may have the above-described core-shell structure including a core including a nanocrystal and a shell surrounding the core. The shell of the quantum dot may serve as a protection layer for preventing the chemical deformation of the core to maintain semiconductor properties and/or a may serve as charging layer for imparting the quantum dot with electrophoretic properties. The shell may have a single layer or a multilayer. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO; a ternary compound such as MgAl₂O₄, CoFe₂O₄, NiFe₂O₄ and CoMn₂O₄; or any combination thereof, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Within any of the ranges above, color purity or color reproducibility may be improved. Light emitted via such quantum dot may be emitted in all directions, so that a wide viewing angle may be improved.

The shape of the quantum dot may be generally used shapes in the related art, without specific limitation. For example, a quantum dot may have a spherical shape, a pyramidal shape, a multi-arm shape, or a cubic shape, of the quantum dot may be in the form of a nanoparticle, a nanotube, a nanowire, a nanofiber, a nanoplate particle, etc.

As the size of the quantum dot or the ratio of elements in the quantum dot compound is regulated, the energy band gap may be accordingly controlled to obtain light of various wavelengths from a quantum dot emission layer. Therefore, by using the quantum dots as described above (for example, using quantum dots of different sizes or having different element ratios in the quantum dot compound), a light emitting device emitting light of various wavelengths may be obtained. For example, the size of the quantum dots or the ratio of elements in the quantum dot compound may be regulated to emit red, green, and/or blue light. For example, the quantum dots may be configured to emit white light by combining light of various colors.

In the light emitting element ED according to an embodiment, as shown in each of FIG. 3 to FIG. 6, the electron transport region ETR may be provided on the emission layer EML. The electron transport region ETR may include at least one of an electron blocking layer HBL, an electron transport layer ETL, and an electron injection layer EIL. However, embodiments are not limited thereto.

The electron transport region ETR may be a layer consisting of a single material, a layer including different materials, or a structure having multiple layers including different materials.

For example, the electron transport region ETR may have a single layer structure of an electron injection layer EIL or an electron transport layer ETL, or may have a single layer structure formed using an electron injection material and an electron transport material. In other embodiments, the electron transport region ETR may have a single layer structure formed of multiple different materials, or a structure stacked from the emission layer EML of electron transport layer ETL/electron injection layer EIL, or hole blocking layer HBL/electron transport layer ETL/electron injection layer EIL, without limitation. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2.

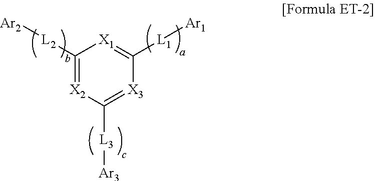

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each independently 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), CNNPTRZ (4′-(4-(4-(4,6-diphenyl-1,3,5-triazin-2-yl)phenyl)naphthalen-1-yl)-[1,1′-biphenyl]-4-carbonitrile), or any mixture thereof, without limitation.

In an embodiment, the electron transport region ETR may include any one of the compounds in Compound Group 3.

In an embodiment, the electron transport region ETR may include at least one of Compounds ET1 to ET36.

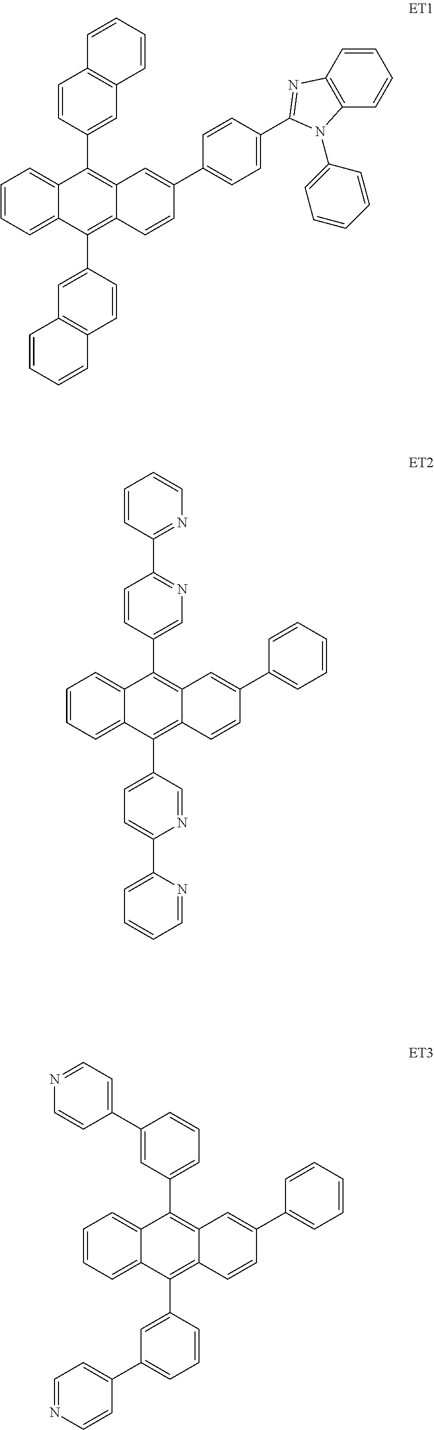 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

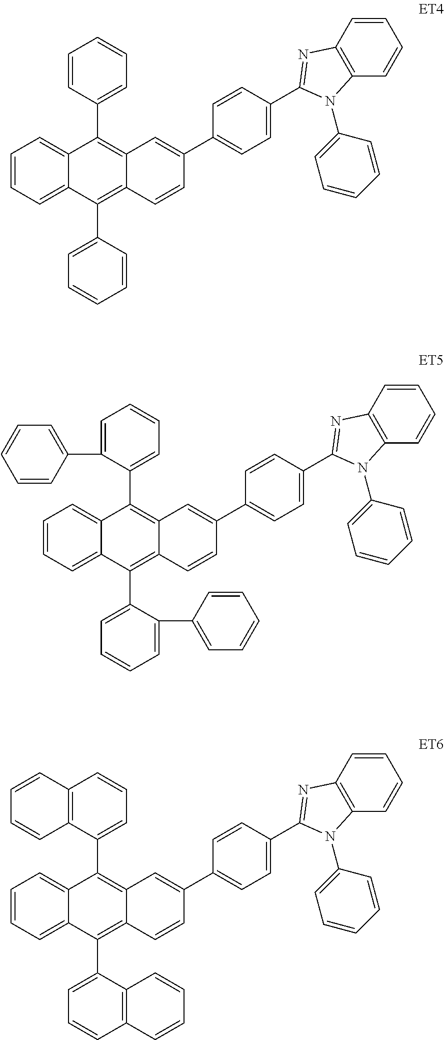 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

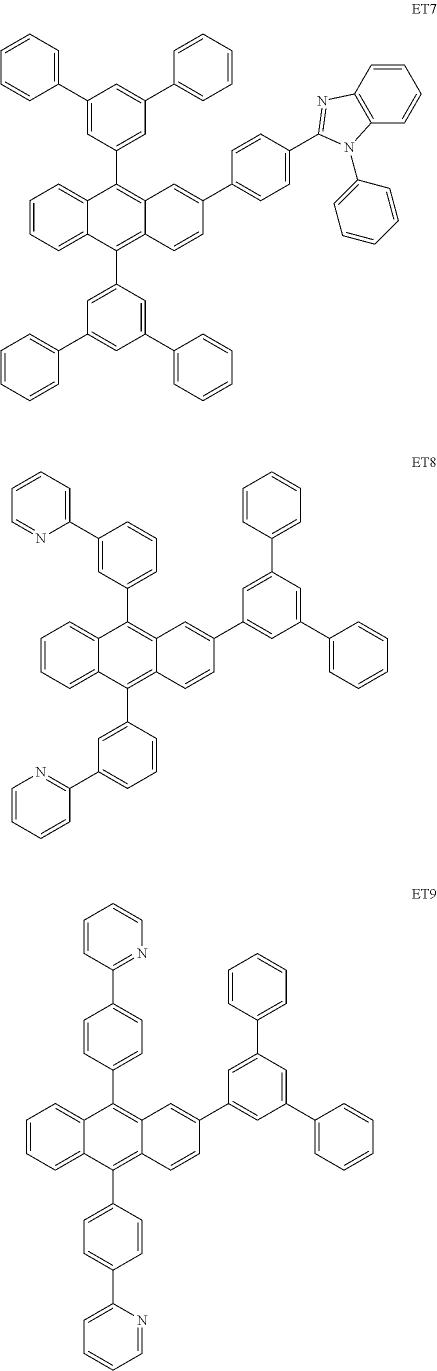 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

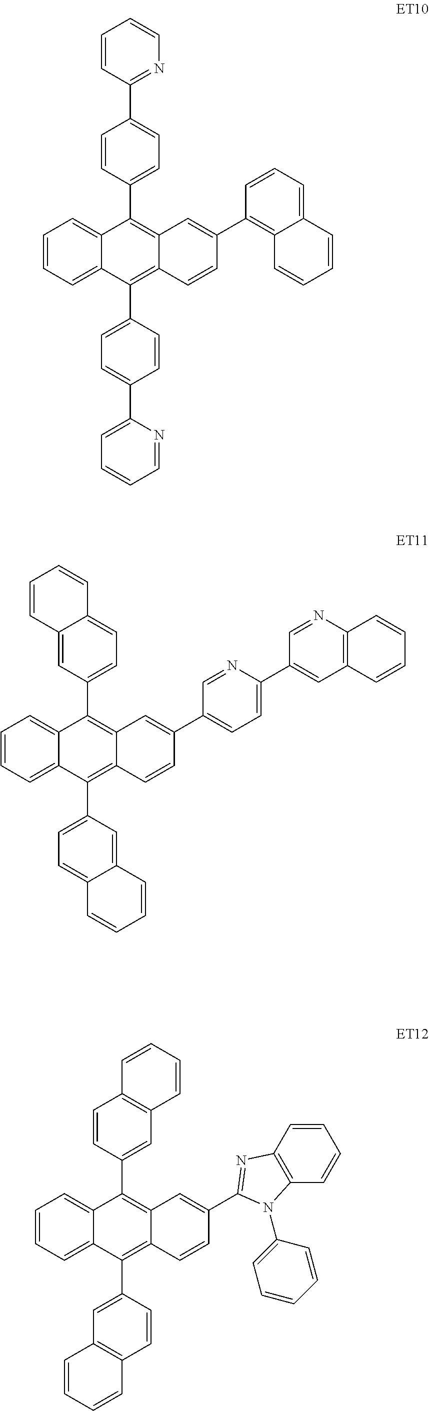 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

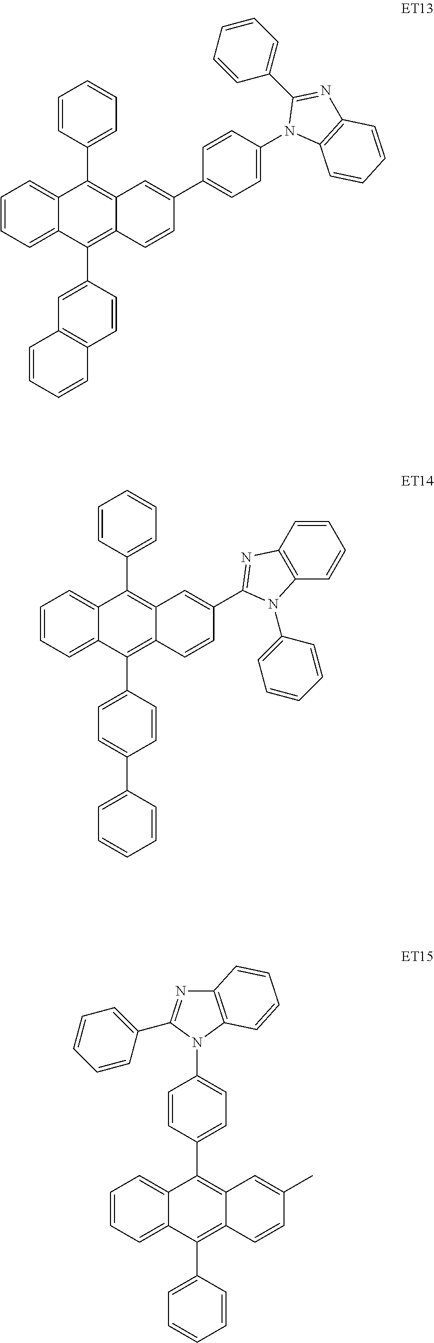 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

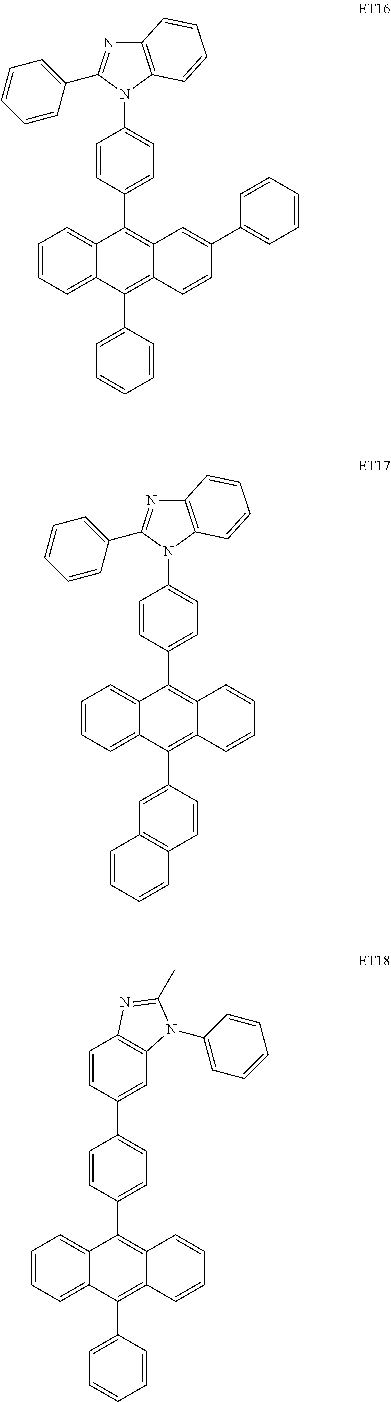 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

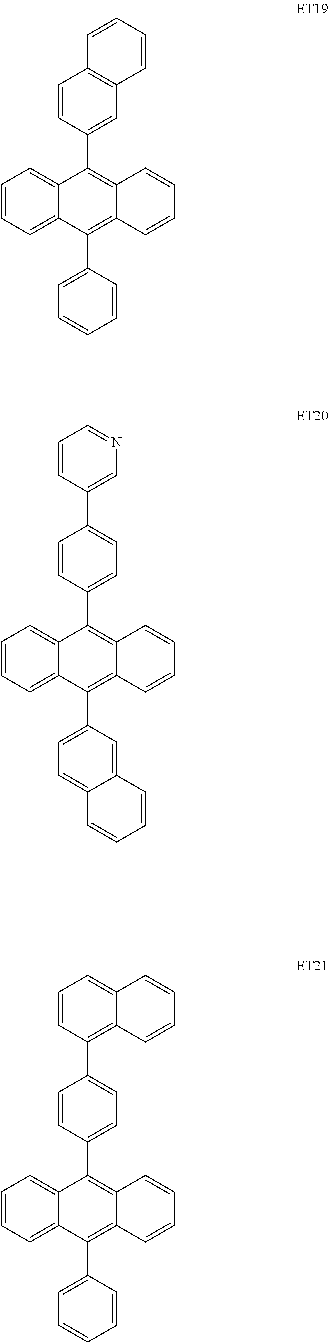

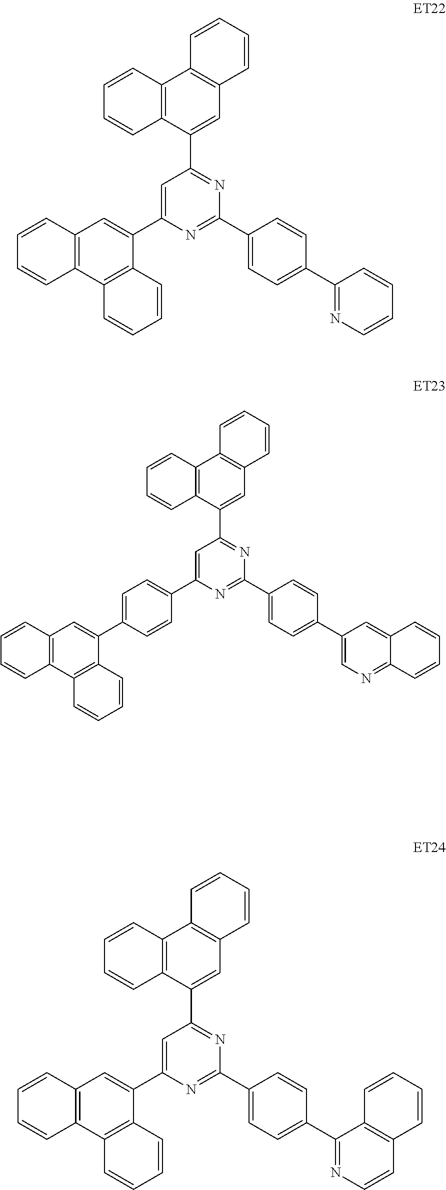 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

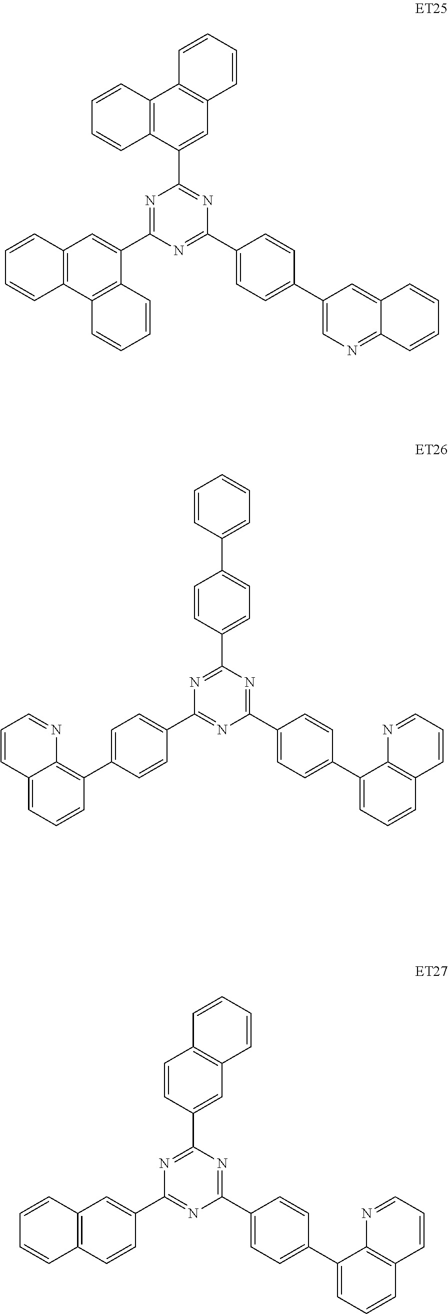 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

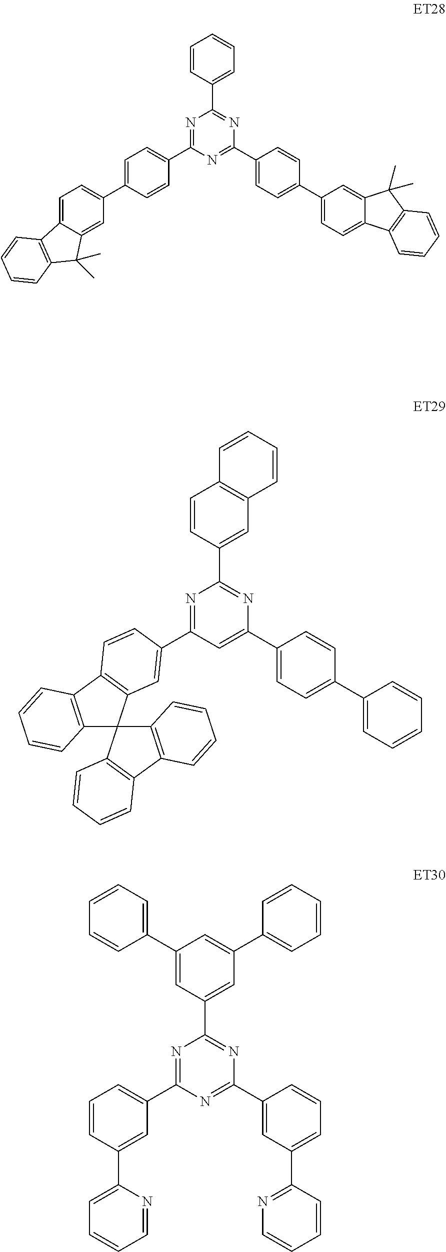 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

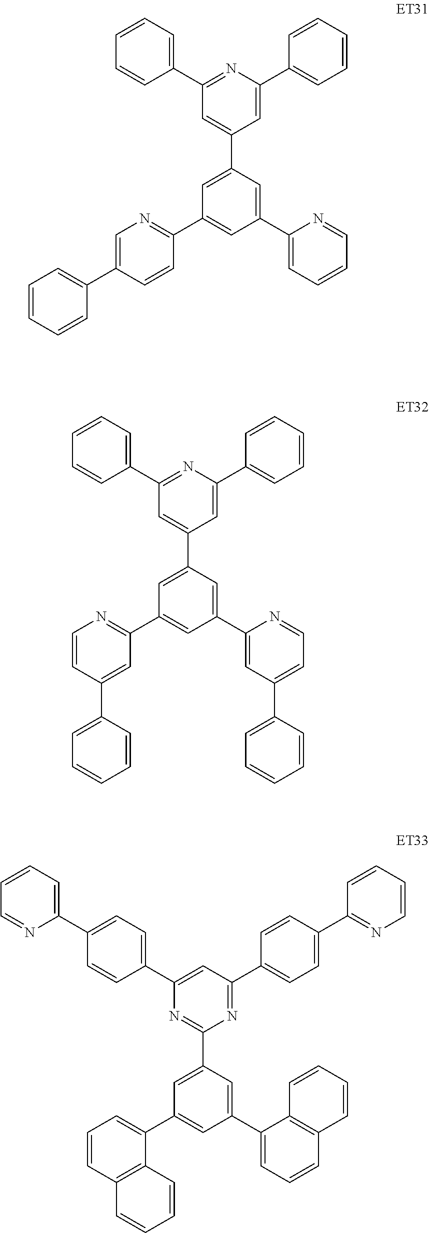 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

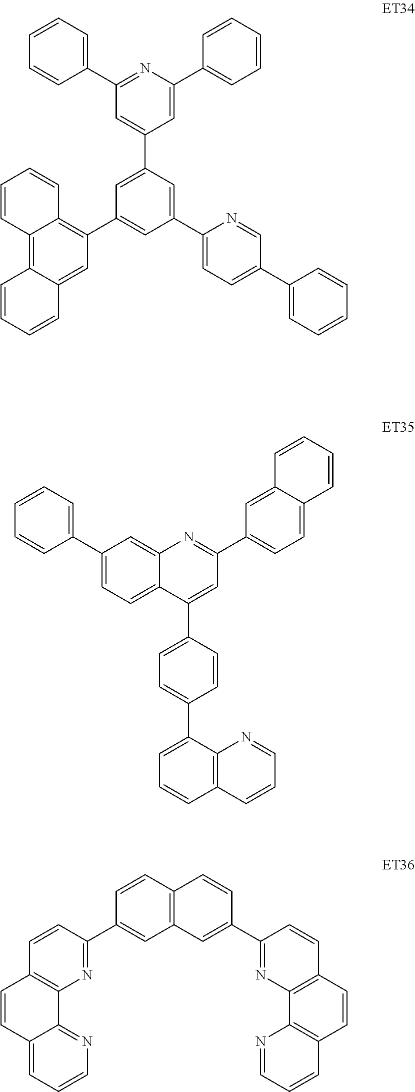 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport region ETR may include a metal halide such as LiF, NaCl, CsF, RbCl, RbI, CuI and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR may also include a mixture material of an electron transport material and an insulating organometallic salt. The organometallic salt may be a material having an energy band gap greater than or equal to about 4 eV. For example, the organometallic salt may include, for example, metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) and 4,7-diphenyl-1,10-phenanthroline (Bphen) in addition to the aforementioned materials. However, embodiments are not limited thereto.

The electron transport region ETR may include the compounds of the electron transport region in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the electron transport layer ETL may have a thickness in a range of about 150 Å to about 500 Å. If the thickness of the electron transport layer ETL satisfies any of the above-described ranges, satisfactory electron transport properties may be obtained without substantial increase of a driving voltage. If the electron transport region ETR includes an electron injection layer EIL, a thickness of the electron injection layer EIL may be in a range of about 1 Å to about 100 Å. For example, a thickness of the electron injection layer EIL may be in a range of about 3 Å to about 90 Å. If the thickness of the electron injection layer EIL satisfies any of the above described ranges, satisfactory electron injection properties may be obtained without inducing substantial increase of a driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds thereof, or mixtures thereof (for example, AgMg, AgYb, or MgYb). In an embodiment, the second electrode EL2 may have a multilayer structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to the auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or an epoxy resin, or an acrylate such as methacrylate. In an embodiment, a capping layer CPL may include at least one of Compounds P1 to P5, but embodiments are not limited thereto.

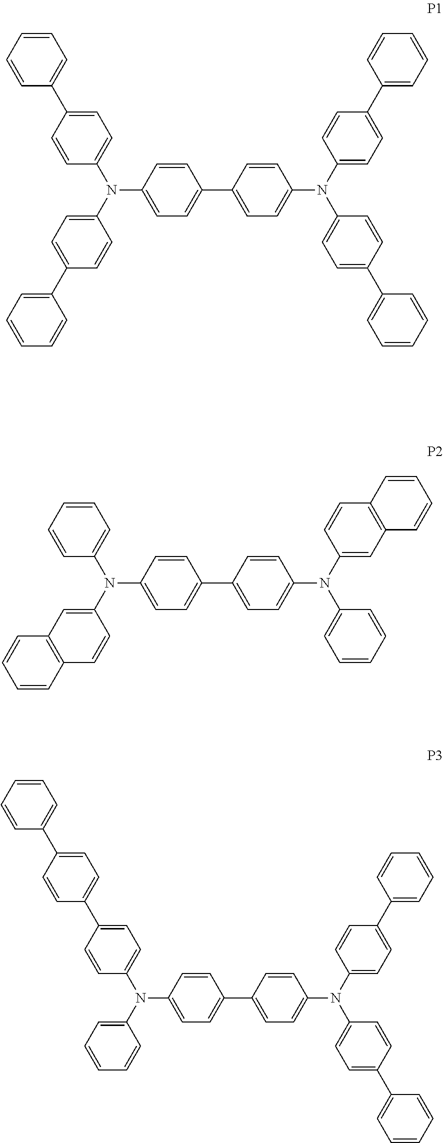 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

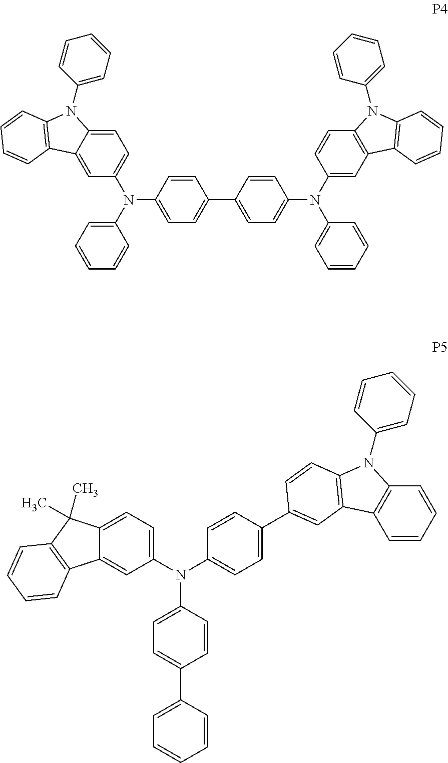 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be greater than or equal to about 1.6. For example, a refractive index of the capping layer CPL, with respect to light in a wavelength range of about 550 nm to about 660 nm, may be greater than or equal to about 1.6.

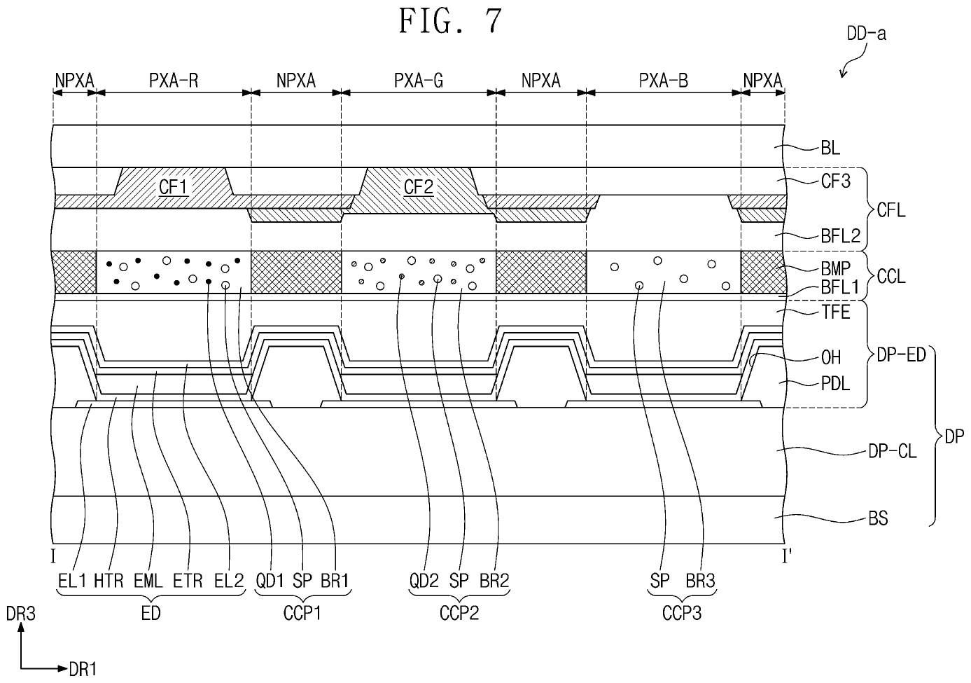

FIG. 7 to FIG. 10 are each a schematic cross-sectional view of a display device according to an embodiment. In the explanation of the display devices according to embodiments in reference to FIG. 7 to FIG. 10, the features which have been described above with reference to FIG. 1 to FIG. 6 will not be explained again, and the differing features will be described.

Referring to FIG. 7, the display device DD-a according to an embodiment may include a display panel DP including a display device layer DP-ED, a light controlling layer CCL disposed on the display panel DP and a color filter layer CFL.

In an embodiment shown in FIG. 7, the display panel DP may include a base layer BS, a circuit layer DP-CL provided on the base layer BS and a display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiment, a structure of the light emitting element shown in FIG. 7 may be the same structure of a light emitting element according to one of FIG. 3 to FIG. 6 as described herein.

The emission layer EML of the light emitting element ED included in the display device DD-a according to an embodiment may include the above-described fused polycyclic compound according to an embodiment described.

Referring to FIG. 7, the emission layer EML may be disposed in an opening part OH defined in a pixel definition layer PDL. For example, the emission layer EML which is separated by the pixel definition layer PDL and correspondingly provided to each of luminous areas PXA-R, PXA-G and PXA-B may emit light in a same wavelength region. In the display device DD-a, the emission layer EML may emit blue light. Although not shown in the drawings, in an embodiment, the emission layer EML may be provided as a common layer for each of the luminous areas PXA-R, PXA-G and PXA-B.

The light controlling layer CCL may be disposed on the display panel DP. The light controlling layer CCL may include a light converter. The light converter may be a quantum dot or a phosphor. The light converter may convert the wavelength of provided light and emit the resulting light. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be disposed between the separated light controlling parts CCP1, CCP2 and CCP3, but embodiments are not limited thereto. In FIG. 7, the partition pattern BMP is shown not to overlap the light controlling parts CCP1, CCP2 and CCP3, but the edges of the light controlling parts CCP1, CCP2 and CCP3 may overlap at least a portion of the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits first color light. In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light controlling layer CCL may further include a scatterer SP. The first light controlling part CCP1 may include the first quantum dot QD1 and a scatterer SP, the second light controlling part CCP2 may include the second quantum dot QD2 and a scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or the scatterer SP may be a mixture of two or more materials selected from TiO₂, ZnO, Al₂O₃, SiO₂, and hollow silica.

The first light controlling part CCP1, the second light controlling part CCP2, and the third light controlling part CCP3 may each include base resins BR1, BR2 and BR3 dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2 and BR3 may each be a medium in which the quantum dots QD1 and QD2 and the scatterer SP are dispersed, and may be composed of various resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play block the penetration of moisture and/or oxygen (hereinafter, will be referred to as “humidity/oxygen”). The barrier layer BFL1 may block the exposure of the light controlling parts CCP1, CCP2 and CCP3 to humidity/oxygen. The barrier layer BFL1 may cover the light controlling parts CCP1, CCP2 and CCP3. A color filter layer CFL, which will be explained later, may include a barrier layer BFL2 disposed on the light controlling parts CCP1, CCP2 and CCP3.

The barrier layers BFL1 and BFL2 may each include at least one inorganic layer. For example, the barrier layers BFL1 and BFL2 may be formed by including an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, or a metal thin film securing light transmittance. The barrier layers BFL1 and BFL2 may further include an organic layer. The barrier layers BFL1 and BFL2 may be composed of a single layer or composed of multiple layers.

In the display device DD-a, the color filter layer CFL may be disposed on the light controlling layer CCL. The color filter layer CFL may be disposed (e.g., directly disposed) on the light controlling layer CCL. For example barrier layer BFL2 may be omitted.

The color filter layer CFL may include filters CF1, CF2 and CF3. The first to third filters CF1, CF2 and CF3 may each be disposed corresponding to a red luminous area PXA-R, a green luminous area PXA-G, and a blue luminous area PXA-B, respectively.

The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2 and CF3 may each include a polymer photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include the pigment or dye. The third filter CF3 may include a polymer photosensitive resin and may not include a pigment or dye. The third filter CF3 may be transparent. The third filter CF3 may be formed using a transparent photosensitive resin.

In an embodiment, the first filter CF1 and the second filter CF2 may each be yellow filters. The first filter CF1 and the second filter CF2 may be provided in one body without distinction.

Although not shown in the drawings, the color filter layer CFL may further include a light blocking part (not shown). The light blocking part (not shown) may be a black matrix. The light blocking part (not shown) may include an organic light blocking material or an inorganic light blocking material including a black pigment or black dye. The light blocking part (not shown) may prevent light leakage phenomenon and divide the boundaries among adjacent filters CF1, CF2 and CF3.

On the color filter layer CFL, a base substrate BL may be disposed. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may be an inorganic layer, an organic layer, or a composite material layer. Although not shown in the drawings, in an embodiment, the base substrate BL may be omitted.

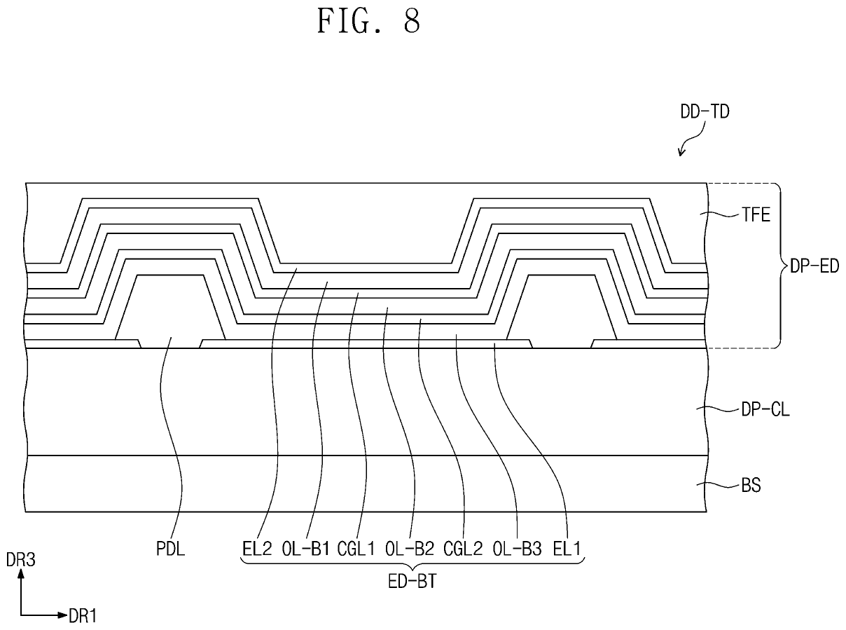

FIG. 8 is a schematic cross-sectional view of a portion of the display device according to an embodiment. In a display device DD-TD according to an embodiment, the light emitting element ED-BT may include multiple light emitting structures OL-B1, OL-B2 and OL-B3. The light emitting device ED-BT may include oppositely disposed first electrode EL1 and second electrode EL2. The multiple light emitting structures OL-B1, OL-B2 and OL-B3 may be stacked in order in a thickness direction and provided between the first electrode EL1 and the second electrode EL2. The light emitting structures OL-B1, OL-B2 and OL-B3 may each include an emission layer EML (FIG. 7), and a hole transport region HTR and an electron transport region ETR disposed with the emission layer EML (FIG. 7) therebetween.

For example, the light emitting element ED-BT included in the display device DD-TD may be a light emitting element having a tandem structure including multiple emission layers.

In an embodiment shown in FIG. 8, light emitted from the light emitting structures OL-B1, OL-B2 and OL-B3 may each be blue light. However, embodiments are not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be disposed. Charge generating layers CGL1 and CGL2 may each independently include a p-type charge generating layer and/or an n-type charge generating layer.

At least one of the light emitting structures OL-B1, OL-B2, and OL-B3 included in the display device DD-TD may include above-described the fused polycyclic compound according to an embodiment. For example, at least one of the emission layers included in the light emitting element ED-BT may include the fused polycyclic compound.

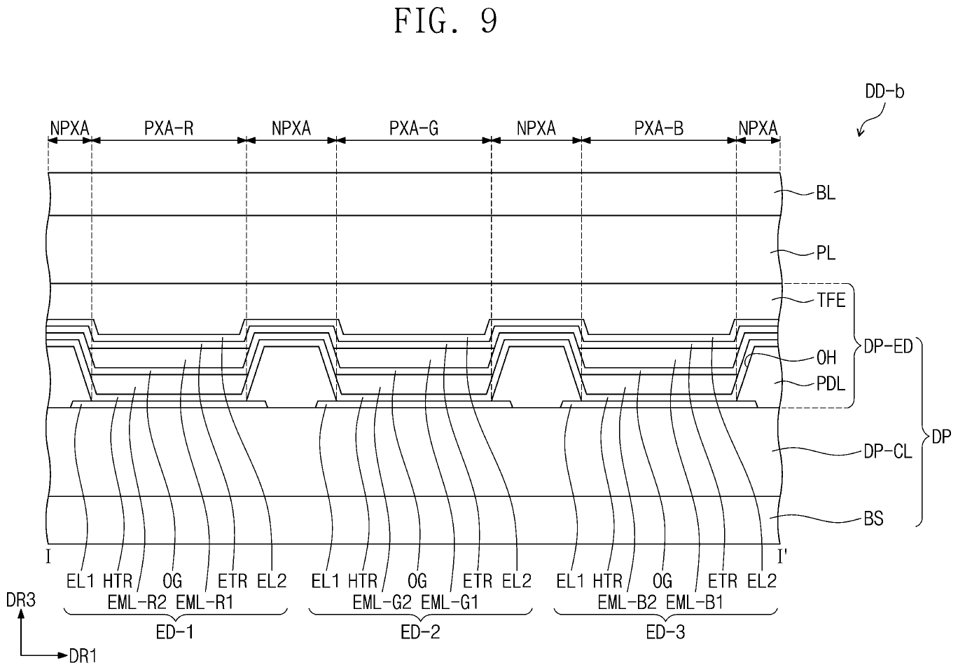

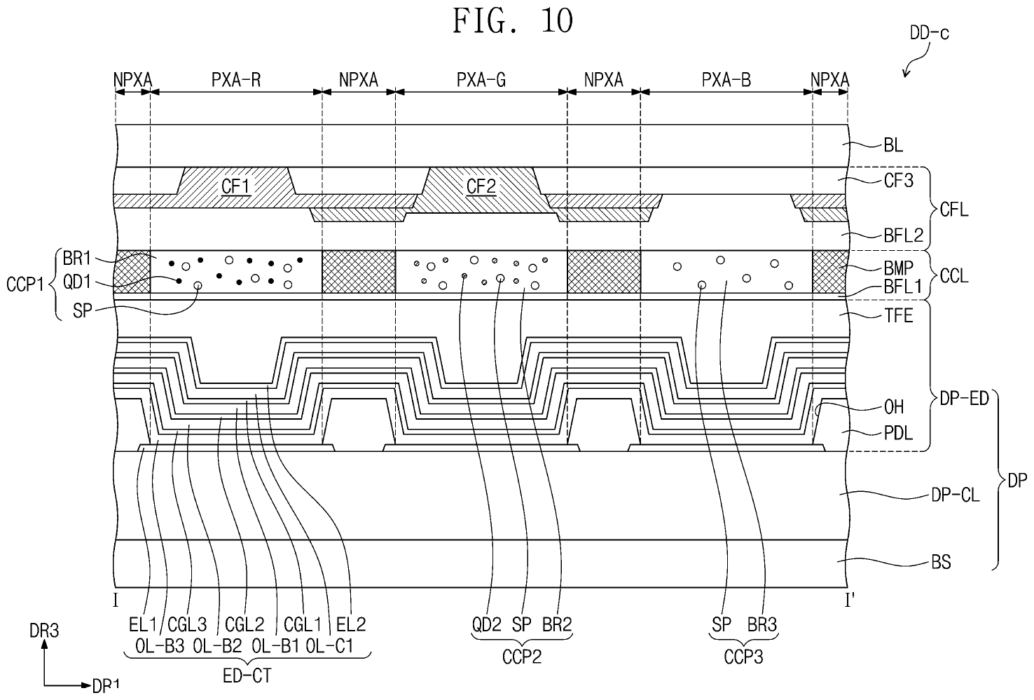

FIG. 9 is a schematic cross-sectional view of a display device according to an embodiment. FIG. 10 is a schematic cross-sectional view of a display apparatus according to an embodiment.

FIG. 9 is a schematic cross-sectional view of a display device DD-b according to an embodiment. The display device DD-b may include light emitting elements ED-1, ED-2, and ED-3, formed by stacking two emission layers. In comparison to the display device DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generating layer. For example, the emission auxiliary part OG may include an electron transport region, a charge generating layer, and a hole transport region which may be stacked in that order. The emission auxiliary part OG may be provided as a common layer for all of the first to third light emitting elements ED-1, ED-2, and ED-3. However, embodiments are not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may each be disposed between the electron transport region ETR and the emission auxiliary part OG. The second red emission layer EML-R2, the second green emission layer EML-G2 and the second blue emission layer EML-B2 may each be disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in that order.

An optical auxiliary layer PL may be disposed on a display device layer DP-ED. The optical auxiliary layer PL may include a polarization layer. The optical auxiliary layer PL may be disposed on a display panel DP and may control light reflected at the display panel DP from an external light. Although not shown in the drawings, in an embodiment the optical auxiliary layer PL may be omitted from the display device DD-b.

At least one emission layer included in a display device DD-b according to an embodiment shown in FIG. 9 may include the fused polycyclic compound of an embodiment described above. For example, at least one of the first blue emission layer EML-B1 or the second blue emission layer EML-B2 may include the fused polycyclic compound according to an embodiment.

In contrast to FIG. 8 and FIG. 9, a display apparatus DD-c in FIG. 10 is shown that is different at least in that it includes four light emitting structures OL-B1, OL-B2, OL-B3 and OL-C1. A light emitting element ED-CT may include oppositely disposed first electrode EL1 and second electrode EL2, and first to fourth light emitting structures OL-B1, OL-B2, OL-B3 and OL-C1 stacked in order in a thickness direction between the first electrode EL1 and the second electrode EL2. The third light emitting structures OL-B3, the second light emitting structures OL-B2, the first light emitting structures OL-B1, and the fourth light emitting structures OL-C1 may be stacked in that order in a thickness direction. Between the first to fourth light emitting structures OL-B1, OL-B2, OL-B3 and OL-C1, charge generating layers CGL1, CGL2 and CGL3 may each be disposed. For example, a first charge generating layer CGL1 may be disposed between the first light emitting structures OL-B1 and the fourth light emitting structures OL-C1. A second charge generating layer CGL2 may be disposed between the first light emitting structures OL-B1 and the second light emitting structures OL-B2. A third charge generating layer CGL3 may be disposed between the second light emitting structures OL-B2 and the third light emitting structures OL-B3.

Among the four light emitting structures, the first to third light emitting structures OL-B1, OL-B2 and OL-B3 may each emit blue light, and the fourth light emitting structure OL-C1 may emit green light. However, embodiments are not limited thereto, and the first to fourth light emitting structures OL-B1, OL-B2, OL-B3 and OL-C1 may emit light in wavelength regions that are different from each other.

Charge generating layers CGL1, CGL2 and CGL3 may each independently include a p-type charge generating layer and/or an n-type charge generating layer.

At least one of light emitting structures OL-B1, OL-B2, OL-B3 and OL-C1, included in the display device DD-c according to an embodiment may include the above-described fused polycyclic compound. For example, in an embodiment, at least one of light emitting structures OL-B1, OL-B2, and OL-B3 may include the above-described fused polycyclic compound.

In an embodiment, the light emitting element ED may include the polycyclic compound represented by Formula 1 in at least one functional layer disposed between a first electrode EL1 and a second electrode EL2, and may show excellent emission efficiency and improved lifetime characteristics. For example, the polycyclic compound may be included in the emission layer EML of the light emitting element ED, and the light emitting element may show long-life characteristics.

In an embodiment, an electronic apparatus may include a display device including multiple light emitting elements and a control part controlling the display device. The electronic apparatus according to an embodiment may be an apparatus activated according to electrical signals. The electronic apparatus may include display devices according to various embodiments. For example, the electronic apparatus may include televisions, monitors, large-size display apparatuses such as outside billboards, but examples of an electronic apparatus may also include small-sized and medium-sized display apparatuses such as personal computers, laptop computers, personal digital terminals, display devices for automobiles, game consoles, portable electronic devices, and cameras.

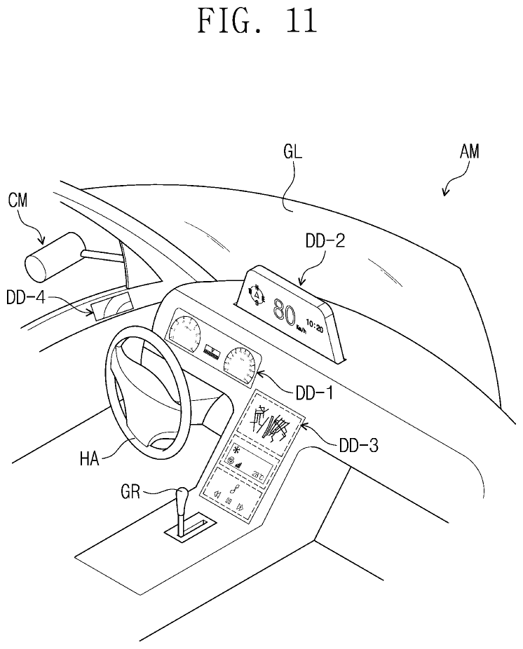

FIG. 11 is a schematic perspective view of an automobile AM in which first to fourth display devices DD-1, DD-2, DD-3, and DD-4 are disposed. At least one of the first to fourth display apparatuses DD-1, DD-2, DD-3, and DD-4 may have a structure according to one of the display devices DD, DD-TD, DD-a, DD-b, and DD-c according to embodiments as described with reference to FIGS. 1, 2, and 7 to 10.

FIG. 11 shows a schematic perspective view of an interior of an automobile AM, but this is only an example, and the first to fourth display apparatuses DD-1, DD-2, DD-3, and DD-4 may be disposed on other transport means such as bicycles, motorcycles, trains, ships, and airplanes. At least one of the first to fourth display devices DD-1, DD-2, DD-3, and DD-4 may have a structure according to one of the display devices DD, DD-TD, DD-a, DD-b and DD-c and, according to an embodiment, may be introduced in personal computers, laptop computers, personal digital terminals, game consoles, portable electronic devices, televisions, monitors, external billboards, or the like. However, these are provided only as examples, and the display device may be included in other electronic devices.

At least one of the first to fourth display devices DD-1, DD-2, DD-3, and DD-4 may include the light emitting element ED according to an embodiment, explained referring to FIG. 3 to FIG. 6. The light emitting element ED according to an embodiment may include the fused polycyclic compound according to an embodiment. At least one of the first to fourth display devices DD-1, DD-2, DD-3, and DD-4 may include the light emitting element ED which includes the fused polycyclic compound according to an embodiment and may show improved display lifetime.

Referring to FIG. 11, an automobile AM may include a steering wheel HA for the operation of the automobile AM and a gearshift GR. The automobile AM may include a front window GL disposed to face a driver.

A first display device DD-1 may be disposed in a first region overlapping with the steering wheel HA. For example, the first display device DD-1 may be a digital cluster displaying the first information of the automobile AM. The first information may include a first graduation showing the running speed of the automobile AM, a second graduation showing an engine speed (for example, as revolutions per minute (RPM)), and images showing a fuel state. The first graduation and the second graduation may be represented by digital images.

A second display device DD-2 may be disposed in a second region facing a driver's seat and overlapping with the front window GL. The driver's seat may be a seat where the steering wheel HA is disposed. For example, the second display device DD-2 may be a head up display (HUD) showing the second information of the automobile AM. The second display apparatus DD-2 may be optically clear. The second information may include digital numbers showing the running speed of the automobile AM and may further include information including the current time. Although not shown in the drawings, the second information of the second display device DD-2 may be projected and displayed on the front window GL.

A third display device DD-3 maybe disposed in a third region adjacent to the gearshift GR. For example, the third display device DD-3 may be a center information display (CID) for an automobile, disposed between a driver's seat and a passenger seat and showing third information. The passenger seat may be a seat that is separated from the driver's seat with the gearshift GR therebetween. The third information may include information about road conditions (for example, navigation information), playing music or radio, playing a dynamic image (or image), the temperature in the automobile AM, or the like.

A fourth display device DD-4 may be disposed in a fourth region separated from the steering wheel HA and the gearshift GR and adjacent to the side of the automobile AM. For example, the fourth display device DD-4 may be a digital wing mirror displaying fourth information. The fourth display device DD-4 may display an external image of the automobile AM, taken by a camera module CM disposed outside of the automobile AM. The fourth information may include the external image of the automobile AM.

The first to fourth information as described herein are examples, and the first to fourth display devices DD-1, DD-2, DD-3, and DD-4 may further display information on the interior and exterior of the automobile. The first to fourth information may include information that is different from each other. However, embodiments are not limited thereto, and a portion of the first to fourth information may include the same information.

Hereinafter, the fused polycyclic compound according to an embodiment and the light emitting element according to an embodiment will be explained with reference to the Examples and the Comparative Examples. The examples described below are only provided as illustrations to assist the understanding of the disclosure, and the scope thereof is not limited thereto.

### EXAMPLES

### 1. Synthesis of Fused Polycyclic Compound

A synthesis method of the fused polycyclic compound according to embodiments will be explained by describing synthesis methods for Compounds 10, 20, 21, 27, 30, 40, 50, 62, and 73. The synthesis methods of the fused polycyclic compounds as explained hereinafter are provided only as examples, and the synthesis methods of the fused polycyclic compounds according to embodiments are not limited to the Examples below.

### (1) Synthesis of Compound 10

### Synthesis of Intermediate 10-a

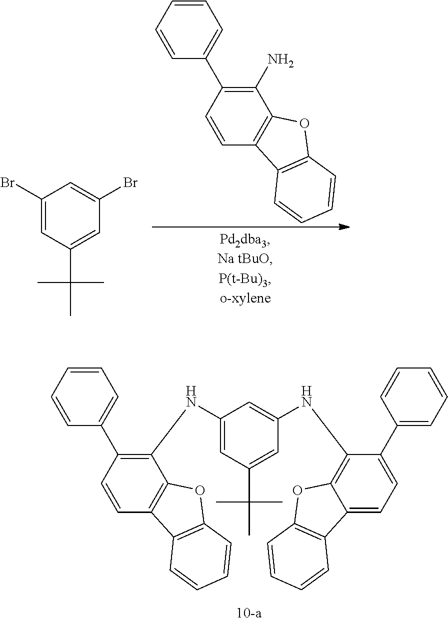 [SMILES: CC(C)(C)c1cc(Br)cc(Br)c1 ; Nc1c(-c2ccccc2)ccc2c1oc1ccccc12 ; CC(C)(C)c1cc(Nc2c(-c3ccccc3)ccc3c2oc2ccccc23)cc(Nc2c(-c3ccccc3)ccc3c2oc2ccccc23)c1]

Under an argon atmosphere, to a 2 L flask, 1,3-dibromo-5-(tert-butyl)benzene (10 g, 34 mmol), 3-phenyldibenzo[b,d]furan-4-amine (17.7 g, 68 mmol), pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 10-a (white solid, 16 g, 74%).

ESI-LCMS: [M]⁺: C₄₆H₃₆N₂O₂. 648.2842.

### Synthesis of Intermediate 10-b

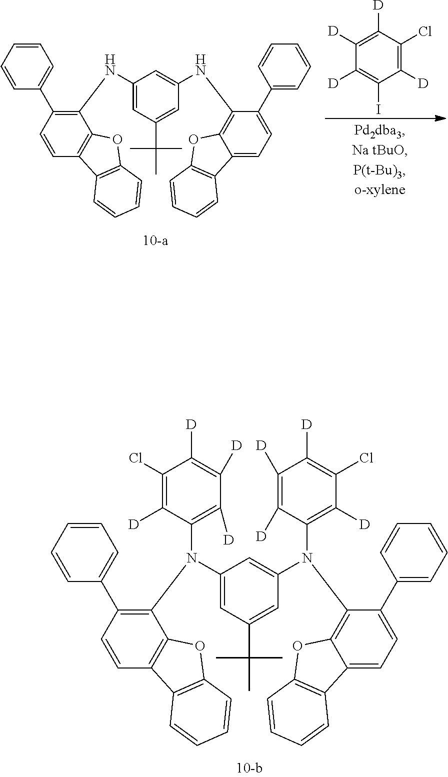

Under an argon atmosphere, to a 2 L flask, Intermediate 10-a (16 g, 25 mmol), 1-chloro-3-iodobenzene-2,4,5,6-d4 (12 g, 50 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 10-b (white solid, 15 g, 70%).

ESI-LCMS: [M]⁺: C₅₈H₃₄D₈Cl₂N₂O₂. 876.0310.

### Synthesis of Intermediate 10-c

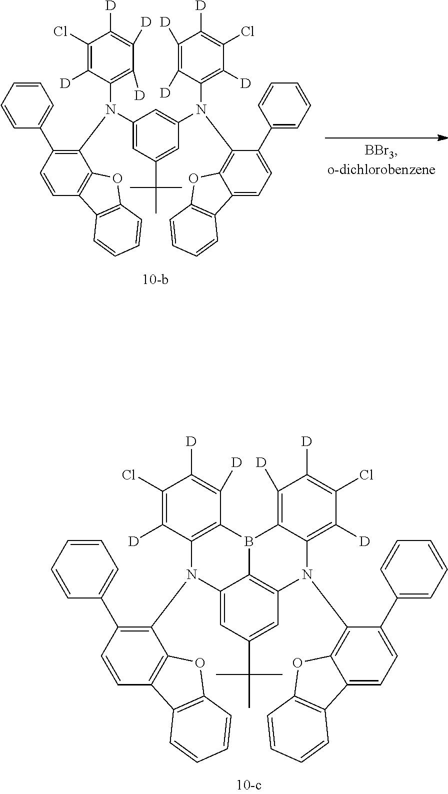 [SMILES: [2H]c1c([2H])c(Cl)c([2H])c(N(c2cc(N(c3c([2H])c([2H])c([2H])c(Cl)c3[2H])c3c(-c4ccccc4)ccc4c3oc3ccccc34)cc(C(C)(C)C)c2)c2c(-c3ccccc3)ccc3c2oc2ccccc23)c1[2H] ; [2H]c1c([2H])c2c(c([2H])c1Cl)N(c1c(-c3ccccc3)ccc3c1oc1ccccc13)c1cc(C(C)(C)C)cc3c1B2c1c([2H])c([2H])c(Cl)c([2H])c1N3c1c(-c2ccccc2)ccc2c1oc1ccccc12]

Under an argon atmosphere, to a 1 L flask, Intermediate 10-b (15 g, 17 mmol) was put and dissolved in 200 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 10-c (yellow solid, 3.8 g, 21%).

ESI-LCMS: [M]⁺: C₅₈H₃₃D₆BCl₂N₂O₂. 882.2099.

### Synthesis of Compound 10

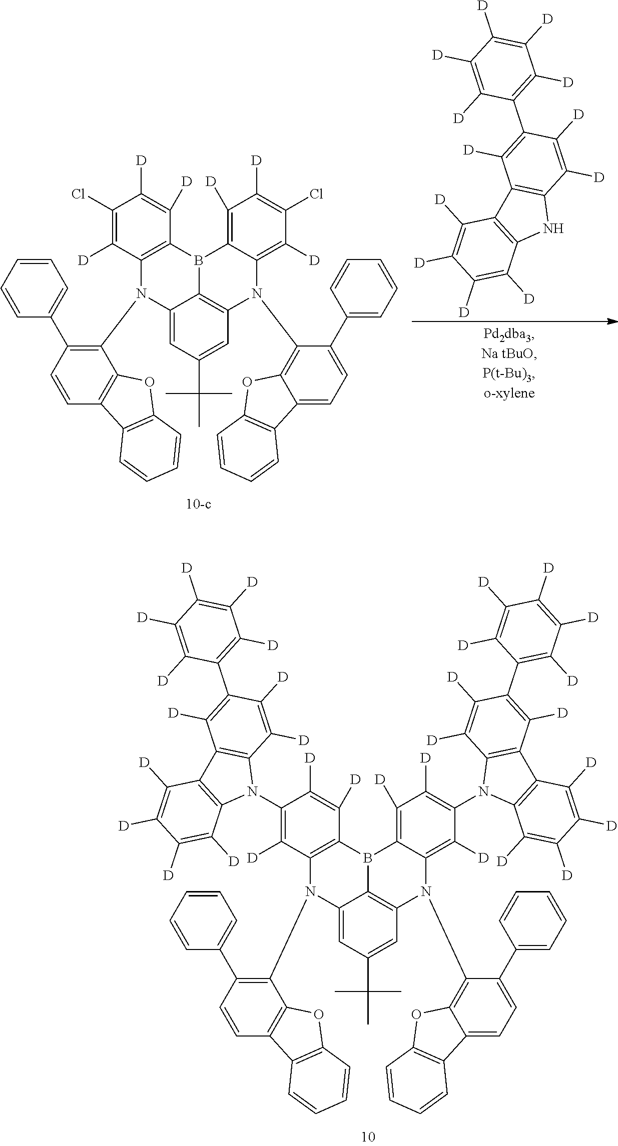

Under an argon atmosphere, to a 1 L flask, Intermediate 10-c (3.8 g, 4.3 mmol), 3-(phenyl-d5)-9H-carbazole-1,2,4,5,6,7,8-d7 (2.2 g, 8.6 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 10 (yellow solid, 4.2 g, 74%).

ESI-LCMS: [M]⁺: C₉₄H₃₃D₃₀BN₄O₂. 1320.6907

1H-NMR (CDCl₃): d=7.98 (d, 4H), 7.78 (d, 2H), 7.69 (d, 2H), 7.54 (d, 2H), 7.43 (m, 10H), 7.04 (d, 4H), 6.92 (s, 2H), 1.39 (s, 18H).

### (2) Synthesis of Compound 20

### Synthesis of Intermediate 20-a

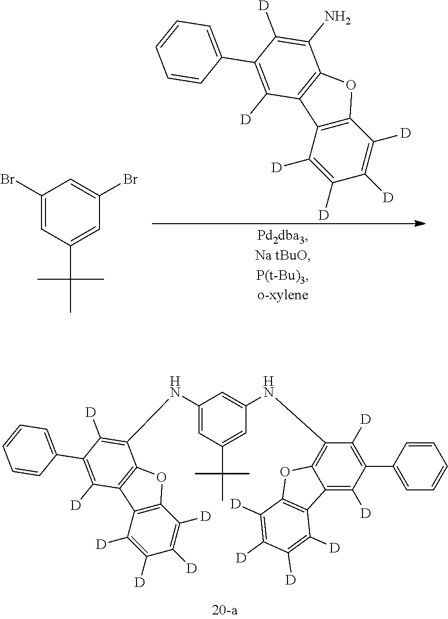 [SMILES: CC(C)(C)c1cc(Br)cc(Br)c1 ; [2H]c1c([2H])c([2H])c2c(oc3c(N)c([2H])c(-c4ccccc4)c([2H])c32)c1[2H] ; [2H]c1c([2H])c([2H])c2c(oc3c(Nc4cc(Nc5c([2H])c(-c6ccccc6)c([2H])c6c5oc5c([2H])c([2H])c([2H])c([2H])c56)cc(C(C)(C)C)c4)c([2H])c(-c4ccccc4)c([2H])c32)c1[2H]]

Under an argon atmosphere, to a 2 L flask, 1,3-dibromo-5-(tert-butyl)benzene (10 g, 34 mmol), 2-phenyldibenzo[b,d]furan-1,3,6,7,8,9-d6-4-amine (18 g, 68 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 20-a (white solid, 17.3 g, 77%).

ESI-LCMS: [M]⁺: C₄₆H₂₄D₁₂N₂O₂. 660.3512.

### Synthesis of Intermediate 20-b

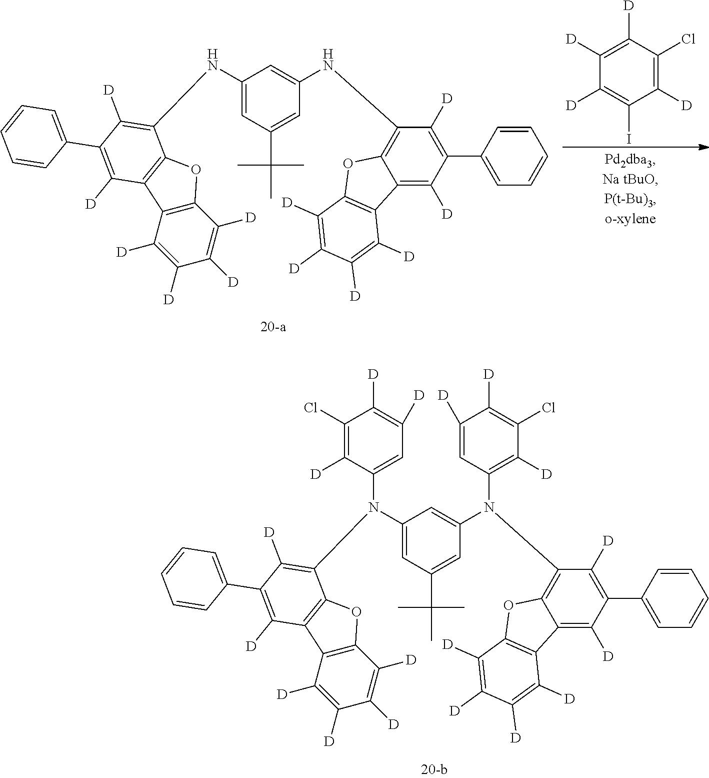

Under an argon atmosphere, to a 2 L flask, Intermediate 20-a (17 g, 25.7 mmol), 1-chloro-3-iodobenzene-2,4,5,6-d4 (12 g, 50 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 20-b (white solid, 16.6 g, 73%).

ESI-LCMS: [M]⁺: C₅₈H₂₄D₁₈C₁₂N₂O₂. 886.0388.

### Synthesis of Intermediate 20-c

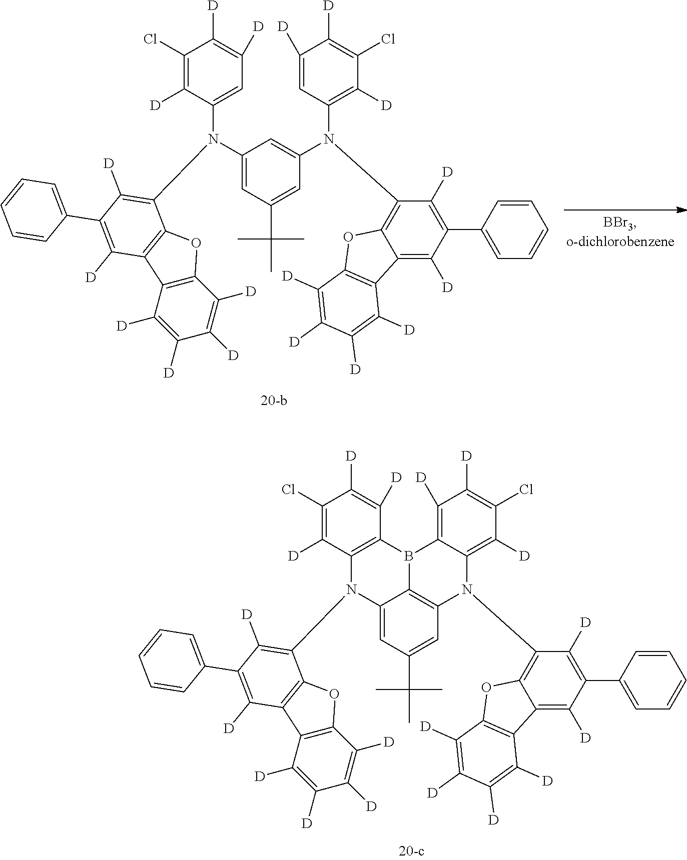 [SMILES: [2H]c1cc(N(c2cc(N(c3cc([2H])c([2H])c(Cl)c3[2H])c3c([2H])c(-c4ccccc4)c([2H])c4c3oc3c([2H])c([2H])c([2H])c([2H])c34)cc(C(C)(C)C)c2)c2c([2H])c(-c3ccccc3)c([2H])c3c2oc2c([2H])c([2H])c([2H])c([2H])c23)c([2H])c(Cl)c1[2H] ; [2H]c1c([2H])c2c(c([2H])c1Cl)N(c1c([2H])c(-c3ccccc3)c([2H])c3c1oc1c([2H])c([2H])c([2H])c([2H])c13)c1cc(C(C)(C)C)cc3c1B2c1c([2H])c([2H])c(Cl)c([2H])c1N3c1c([2H])c(-c2ccccc2)c([2H])c2c1oc1c([2H])c([2H])c([2H])c([2H])c12]

Under an argon atmosphere, to a 1 L flask, Intermediate 20-b (16 g, 18 mmol) was put and dissolved in 200 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 20-c (yellow solid, 3.7 g, 23%).

ESI-LCMS: [M]⁺: C₅H₂₁D₁₈BCl₂N₂O₂. 894.6033.

### Synthesis of Compound 20

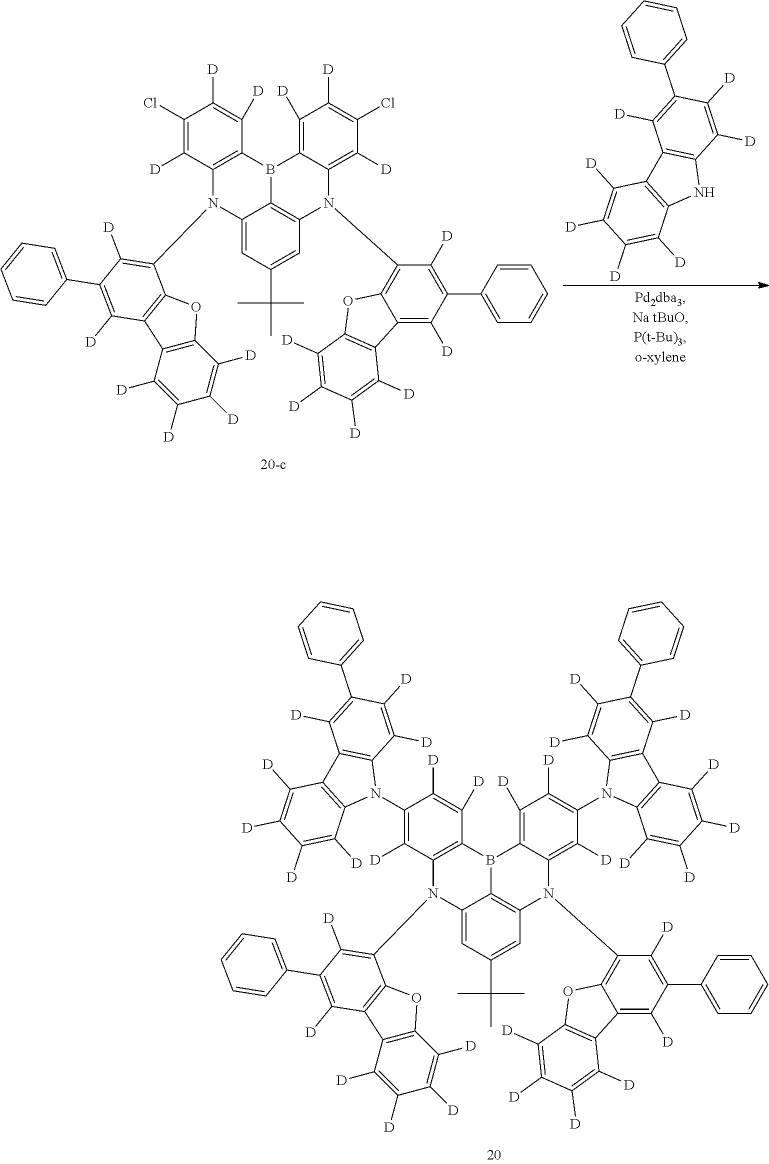

Under an argon atmosphere, to a 1 L flask, Intermediate 20-c (3.7 g, 4.1 mmol), 3-phenyl-9H-carbazole-1,2,4,5,6,7,8-d7 (2.1 g, 8.2 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 20 (yellow solid, 4 g, 75%).

ESI-LCMS: [M]⁺: C₉₄H₃₁D₃₂BN₄O₂. 1322.7170

1H-NMR (CDCl₃): d=7.45 (m, 20H), 7.01 (s, 2H), 1.32 (s, 18H).

### (3) Synthesis of Compound 21

### Synthesis of Intermediate 21-a

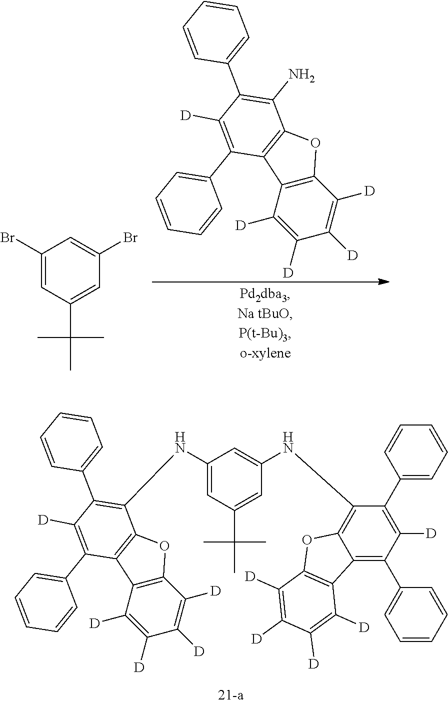

Under an argon atmosphere, to a 2 L flask, 1,3-dibromo-5-(tert-butyl)benzene (10 g, 34 mmol), 1,3-diphenyldibenzo[b,d]furan-2,6,7,8,9-d5-4-amine (23 g, 68 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 21-a (white solid, 20 g, 72%).

ESI-LCMS: [M]⁺: C₅₈H₃₄D₁₀N₂O₂. 810.4104.

### Synthesis of Intermediate 21-b

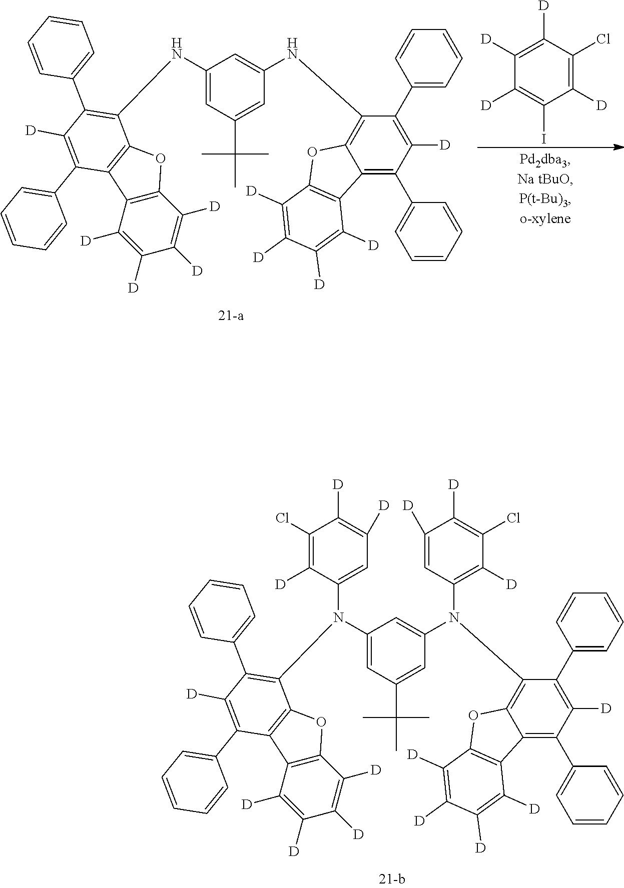

Under an argon atmosphere, to a 2 L flask, Intermediate 21-a (20 g, 25 mmol), 1-chloro-3-iodobenzene-2,4,5,6-d4 (12 g, 50 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 21-b (white solid, 18 g, 70%).

ESI-LCMS: [M]⁺: C₇₀H₃₄D₁₆C₂N₂O₂. 1036.4321.

### Synthesis of Intermediate 21-c

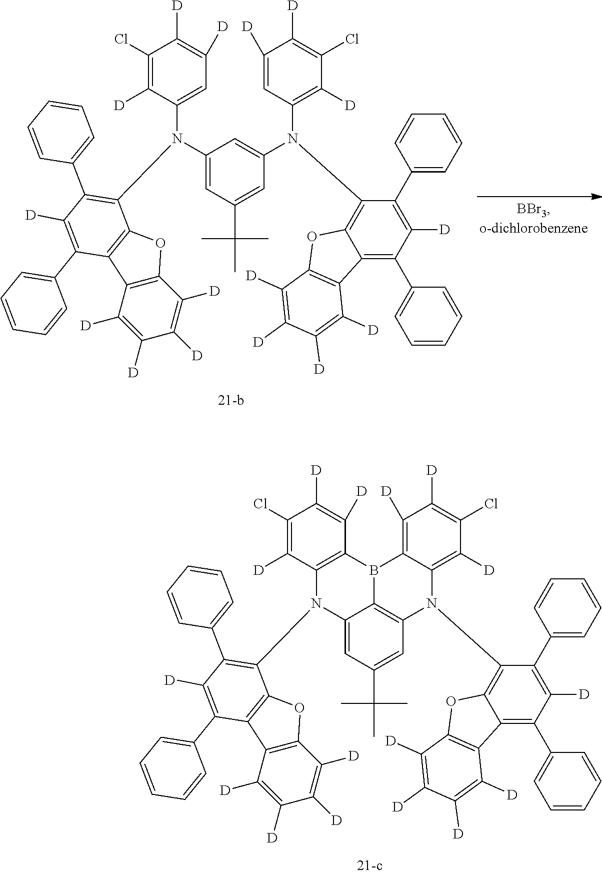 [SMILES: [2H]c1cc(N(c2cc(N(c3cc([2H])c([2H])c(Cl)c3[2H])c3c(-c4ccccc4)c([2H])c(-c4ccccc4)c4c3oc3c([2H])c([2H])c([2H])c([2H])c34)cc(C(C)(C)C)c2)c2c(-c3ccccc3)c([2H])c(-c3ccccc3)c3c2oc2c([2H])c([2H])c([2H])c([2H])c23)c([2H])c(Cl)c1[2H] ; [2H]c1c([2H])c2c(c([2H])c1Cl)N(c1c(-c3ccccc3)c([2H])c(-c3ccccc3)c3c1oc1c([2H])c([2H])c([2H])c([2H])c13)c1cc(C(C)(C)C)cc3c1B2c1c([2H])c([2H])c(Cl)c([2H])c1N3c1c(-c2ccccc2)c([2H])c(-c2ccccc2)c2c1oc1c([2H])c([2H])c([2H])c([2H])c12]

Under an argon atmosphere, to a 1 L flask, Intermediate 21-b (18 g, 17 mmol) was put and dissolved in 200 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 21-c (yellow solid, 4 g, 22%).

ESI-LCMS: [M]⁺: C₇₀H₃₁D₁₆BCl₂N₂O₂. 1044.4001.

### Synthesis of Compound 21

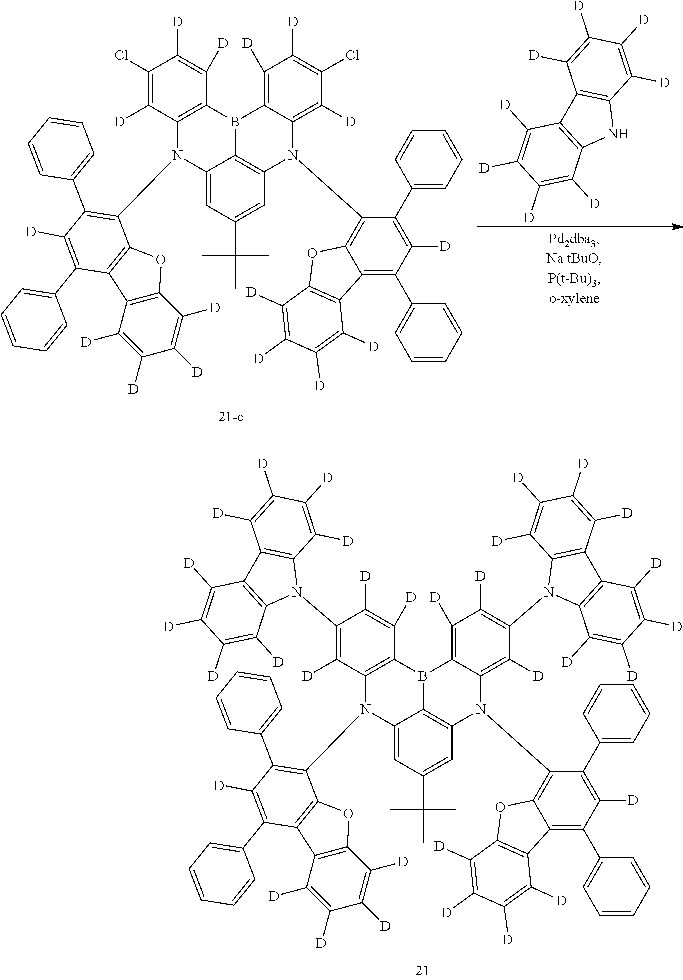

Under an argon atmosphere, to a 1 L flask, Intermediate 21-c (4 g, 3.8 mmol), 9H-carbazole-1,2,3,4,5,6,7,8-d8 (1.3 g, 7.6 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 21 (yellow solid, 3.5 g, 71%).

ESI-LCMS: [M]⁺: C₉₄H₃₁D₃₂BN₄O₂. 1322.7170

1H-NMR (CDCl₃): d=7.51 (m, 20H), 6.98 (s, 2H), 1.34 (s, 18H).

### (4) Synthesis of Compound 27

### Synthesis of Intermediate 27-a

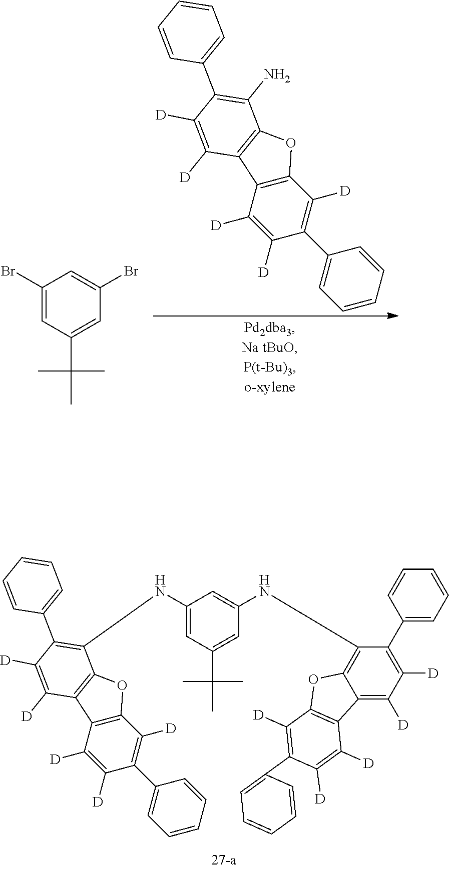 [SMILES: CC(C)(C)c1cc(Br)cc(Br)c1 ; [2H]c1c(-c2ccccc2)c([2H])c2oc3c(N)c(-c4ccccc4)c([2H])c([2H])c3c2c1[2H] ; [2H]c1c(-c2ccccc2)c([2H])c2oc3c(Nc4cc(Nc5c(-c6ccccc6)c([2H])c([2H])c6c5oc5c([2H])c(-c7ccccc7)c([2H])c([2H])c56)cc(C(C)(C)C)c4)c(-c4ccccc4)c([2H])c([2H])c3c2c1[2H]]

Under an argon atmosphere, to a 2 L flask, 1,3-dibromo-5-(tert-butyl)benzene (10 g, 34 mmol), 3,7-diphenyldibenzo[b,d]furan-1,2,6,8,9-d5-4-amine (23 g, 68 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 27-a (white solid, 22.8 g, 83%).

ESI-LCMS: [M]⁺: C₅₈H₃₄D₁₀N₂O₂. 810.4030.

### Synthesis of Intermediate 27-b

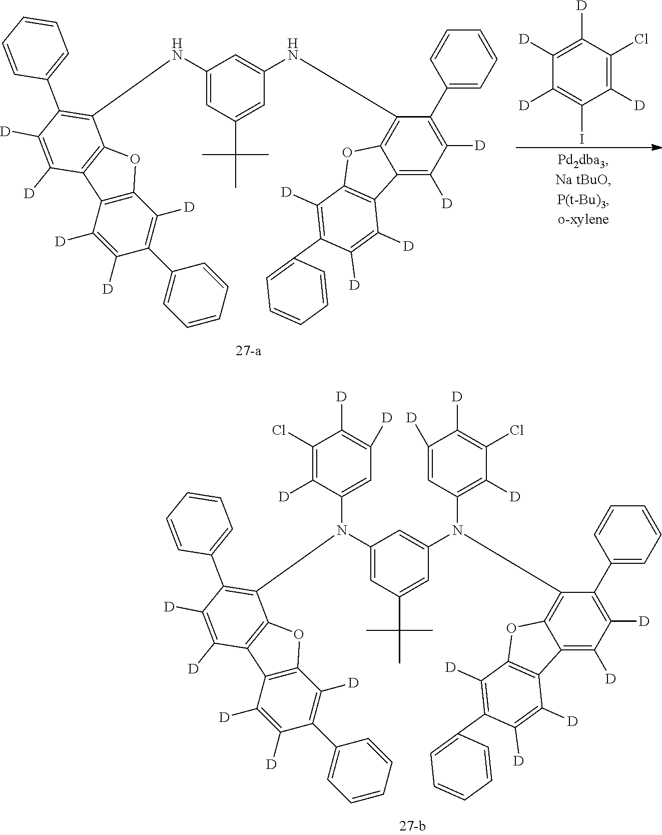

Under an argon atmosphere, to a 2 L flask, Intermediate 73-a (22 g, 27 mmol), 1-chloro-3-iodobenzene-2,4,5,6-d4 (13 g, 54 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 27-b (white solid, 15 g, 54%).

ESI-LCMS: [M]⁺: C₇₀H₃₄D₁₆Cl₂N₂O₂. 1036.4327.

### Synthesis of Intermediate 27-c

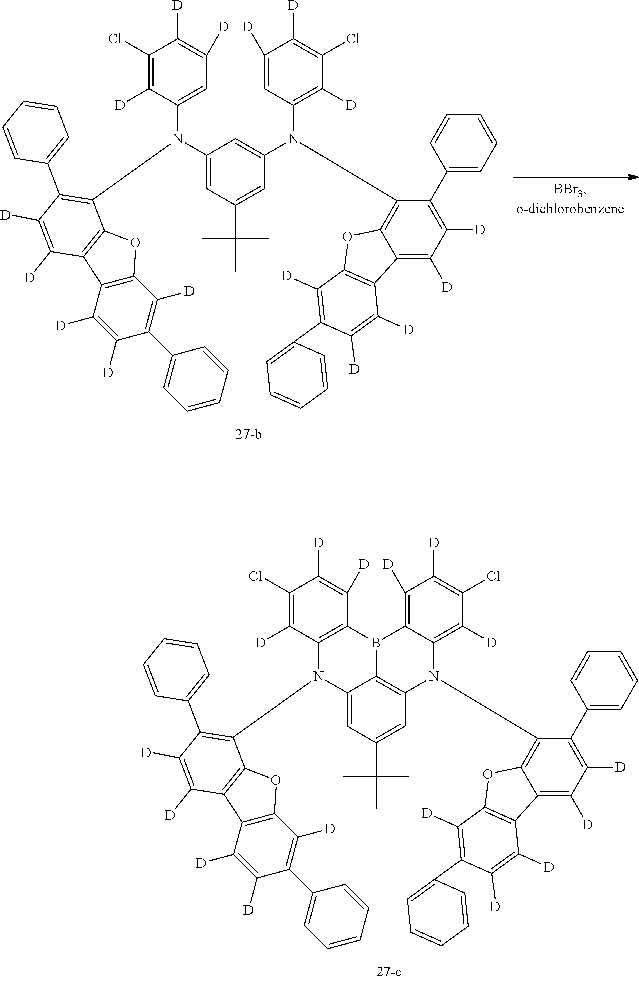 [SMILES: [2H]c1cc(N(c2cc(N(c3cc([2H])c([2H])c(Cl)c3[2H])c3c(-c4ccccc4)c([2H])c([2H])c4c3oc3c([2H])c(-c5ccccc5)c([2H])c([2H])c34)cc(C(C)(C)C)c2)c2c(-c3ccccc3)c([2H])c([2H])c3c2oc2c([2H])c(-c4ccccc4)c([2H])c([2H])c23)c([2H])c(Cl)c1[2H] ; [2H]c1c([2H])c2c(c([2H])c1Cl)N(c1c(-c3ccccc3)c([2H])c([2H])c3c1oc1c([2H])c(-c4ccccc4)c([2H])c([2H])c13)c1cc(C(C)(C)C)cc3c1B2c1c([2H])c([2H])c(Cl)c([2H])c1N3c1c(-c2ccccc2)c([2H])c([2H])c2c1oc1c([2H])c(-c3ccccc3)c([2H])c([2H])c12]

Under an argon atmosphere, to a 1 L flask, Intermediate 27-b (15 g, 14.5 mmol) was put and dissolved in 150 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 27-c (yellow solid, 3.3 g, 22%).

ESI-LCMS: [M]⁺: C₇₀H₃₁D₁₆BCl₂N₂O₂. 1044.4136.

### Synthesis of Compound 27

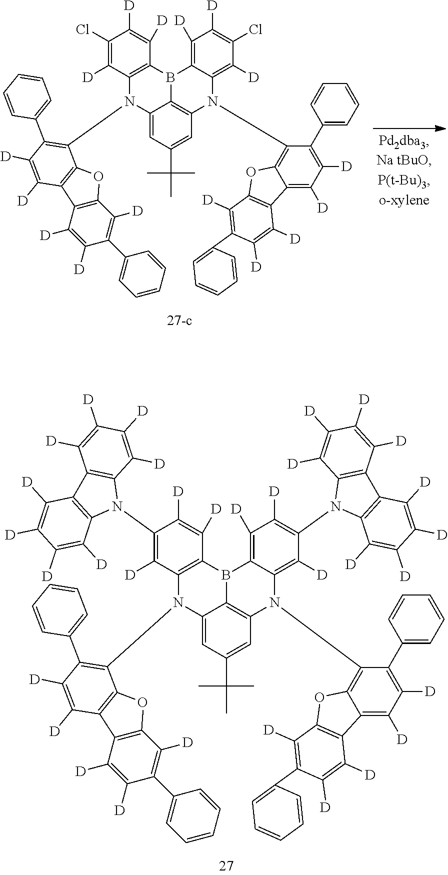

Under an argon atmosphere, to a 1 L flask, Intermediate 27-c (3.3 g, 3.1 mmol), 9H-carbazole-1,2,4,5,6,7,8-d7 (1.1 g, 6.2 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 27 (yellow solid, 3.1 g, 77%).

ESI-LCMS: [M]⁺: C₉₄H₃₁D₃₂BN₄O₂. 1322.7007

1H-NMR (CDCl₃): d=7.51 (m, 20H), 7.06 (s, 2H), 1.32 (s, 9H).

### (5) Synthesis of Compound 30

### Synthesis of Intermediate 30-a

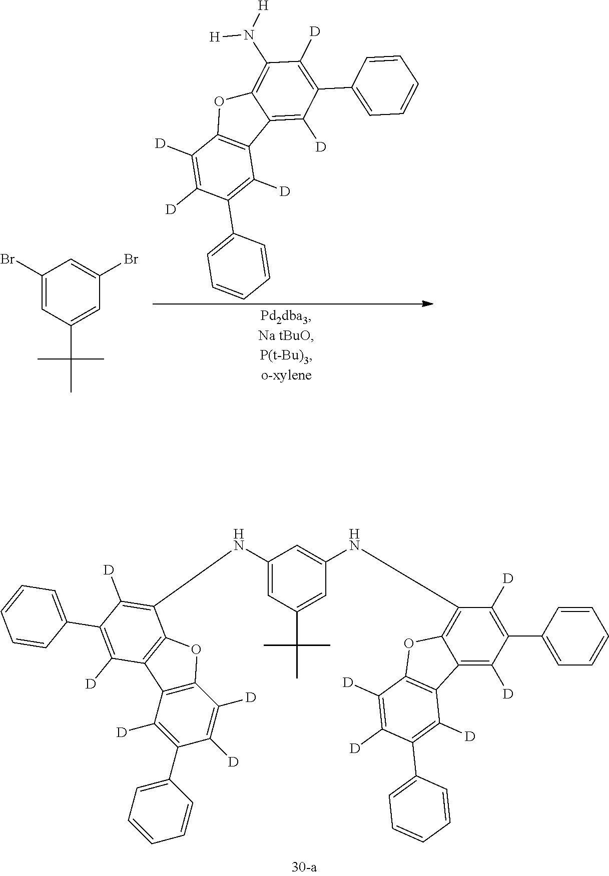 [SMILES: CC(C)(C)c1cc(Br)cc(Br)c1 ; [2H]c1c(-c2ccccc2)c([2H])c2c(oc3c(N)c([2H])c(-c4ccccc4)c([2H])c32)c1[2H] ; [2H]c1c(-c2ccccc2)c([2H])c2c(oc3c(Nc4cc(Nc5c([2H])c(-c6ccccc6)c([2H])c6c5oc5c([2H])c([2H])c(-c7ccccc7)c([2H])c56)cc(C(C)(C)C)c4)c([2H])c(-c4ccccc4)c([2H])c32)c1[2H]]

Under an argon atmosphere, to a 2 L flask, 1,3-dibromo-5-(tert-butyl)benzene (10 g, 34 mmol), 2,8-diphenyldibenzo[b,d]furan-1,3,6,7,9-d5-4-amine (23 g, 68 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 30-a (white solid, 22 g, 80%).

ESI-LCMS: [M]⁺: C₅₈H₃₄D₁₀N₂O₂. 810.3337.

### Synthesis of Intermediate 30-b

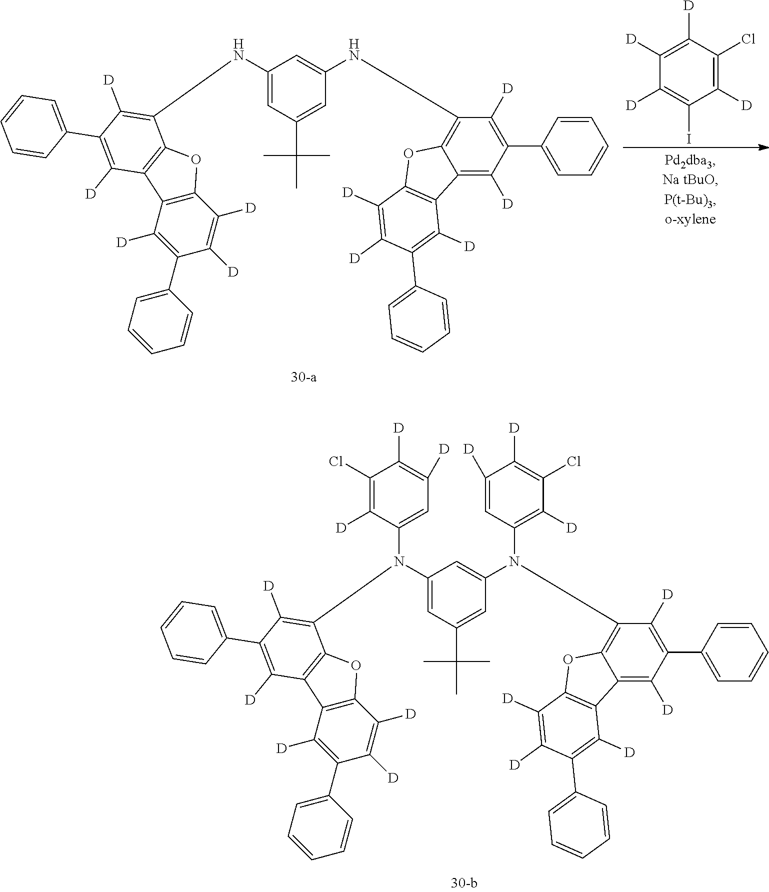

Under an argon atmosphere, to a 2 L flask, Intermediate 30-a (22 g, 27 mmol), 1-chloro-3-iodobenzene-2,4,5,6-d4 (13 g, 54 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 30-b (white solid, 16 g, 57%).

ESI-LCMS: [M]⁺: C₇₀H₃₄D₁₆C₂N₂O₂. 1036.1237.

### Synthesis of Intermediate 30-c

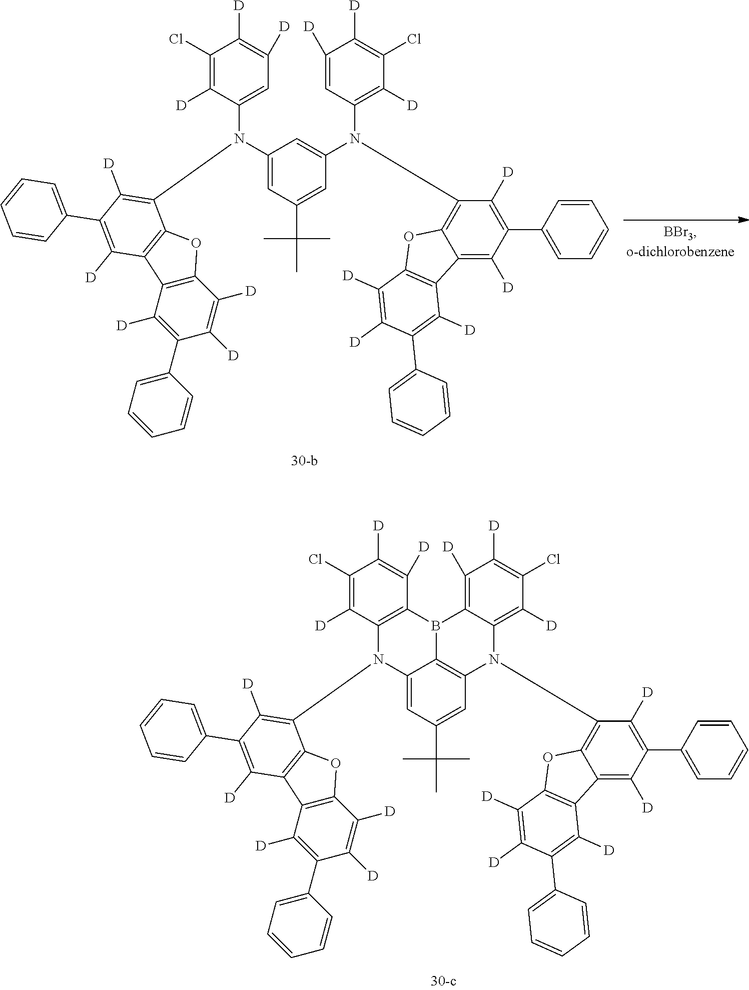 [SMILES: [2H]c1cc(N(c2cc(N(c3cc([2H])c([2H])c(Cl)c3[2H])c3c([2H])c(-c4ccccc4)c([2H])c4c3oc3c([2H])c([2H])c(-c5ccccc5)c([2H])c34)cc(C(C)(C)C)c2)c2c([2H])c(-c3ccccc3)c([2H])c3c2oc2c([2H])c([2H])c(-c4ccccc4)c([2H])c23)c([2H])c(Cl)c1[2H] ; [2H]c1c([2H])c2c(c([2H])c1Cl)N(c1c([2H])c(-c3ccccc3)c([2H])c3c1oc1c([2H])c([2H])c(-c4ccccc4)c([2H])c13)c1cc(C(C)(C)C)cc3c1B2c1c([2H])c([2H])c(Cl)c([2H])c1N3c1c([2H])c(-c2ccccc2)c([2H])c2c1oc1c([2H])c([2H])c(-c3ccccc3)c([2H])c12]

Under an argon atmosphere, to a 1 L flask, Intermediate 30-b (15 g, 14.5 mmol) was put and dissolved in 150 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 30-c (yellow solid, 2.87 g, 19%).

ESI-LCMS: [M]⁺: C₇₀H₃₁D₁₆BCl₂N₂O₂. 1044.1113.

### Synthesis of Compound 30

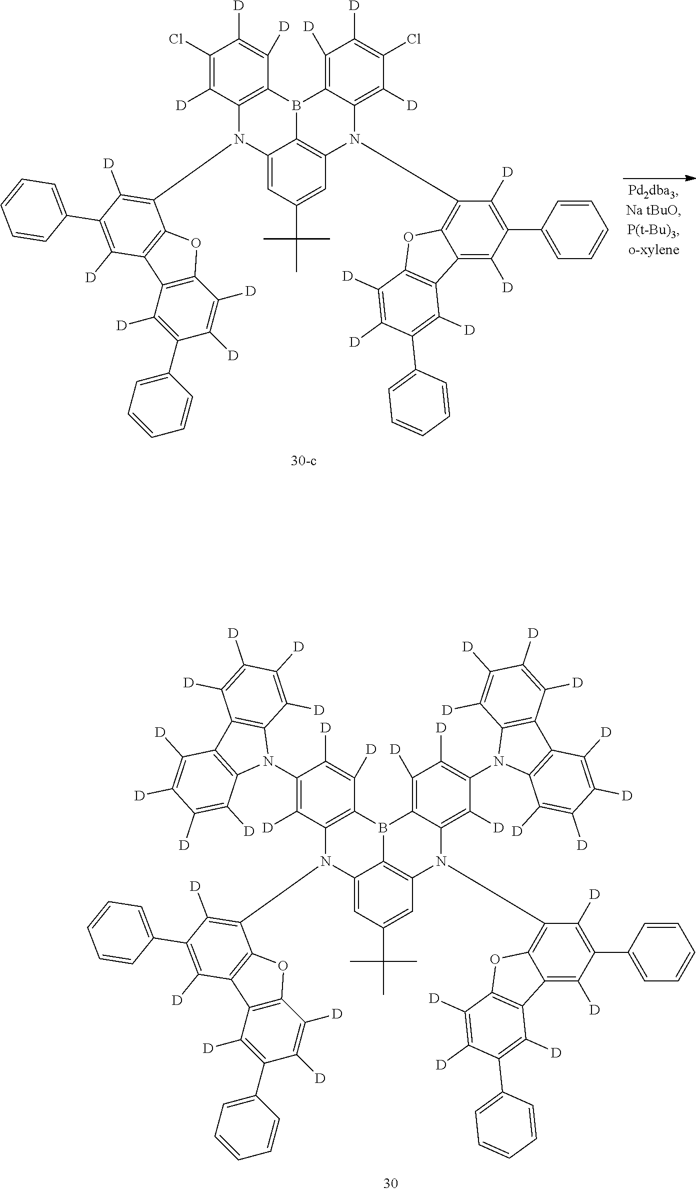

Under an argon atmosphere, to a 1 L flask, Intermediate 30-c (2.5 g, 2.4 mmol), 9H-carbazole-1,2,4,5,6,7,8-d7 (0.84 g, 4.8 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 30 (yellow solid, 2.3 g, 73%).

ESI-LCMS: [M]⁺: C₉₄H₃₁D₃₂BN₄O₂. 1322.6952

1H-NMR (CDCl₃): d=7.43 (m, 20H), 6.96 (s, 2H), 1.38 (s, 9H).

### (6) Synthesis of Compound 40

### Synthesis of Intermediate 40-a

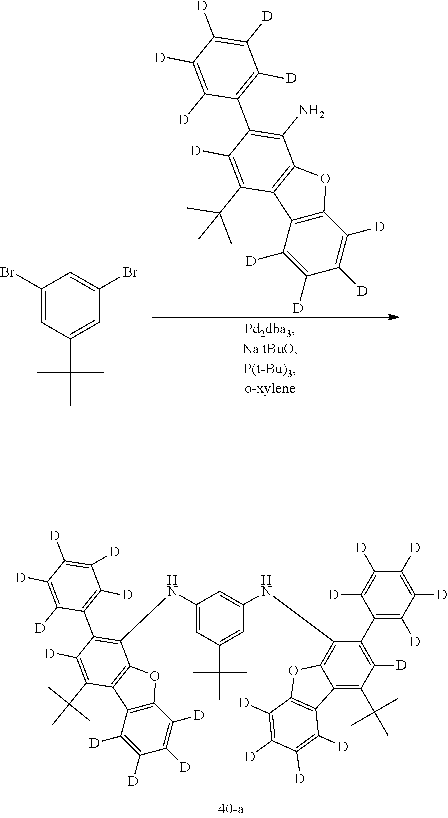 [SMILES: CC(C)(C)c1cc(Br)cc(Br)c1 ; [2H]c1c([2H])c([2H])c(-c2c([2H])c(C(C)(C)C)c3c(oc4c([2H])c([2H])c([2H])c([2H])c43)c2N)c([2H])c1[2H] ; [2H]c1c([2H])c([2H])c(-c2c([2H])c(C(C)(C)C)c3c(oc4c([2H])c([2H])c([2H])c([2H])c43)c2Nc2cc(Nc3c(-c4c([2H])c([2H])c([2H])c([2H])c4[2H])c([2H])c(C(C)(C)C)c4c3oc3c([2H])c([2H])c([2H])c([2H])c34)cc(C(C)(C)C)c2)c([2H])c1[2H]]

Under an argon atmosphere, to a 2 L flask, 1,3-dibromo-5-(tert-butyl)benzene (10 g, 34 mmol), 1-(tert-butyl)-3-(phenyl-d5)dibenzo[b,d]furan-2,6,7,8,9-d5-4-amine (22 g, 68 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 40-a (white solid, 19 g, 73%).

ESI-LCMS: [M]⁺: C₅₄H₃₂D₂₀N₂O₂. 780.5234.

### Synthesis of Intermediate 40-b

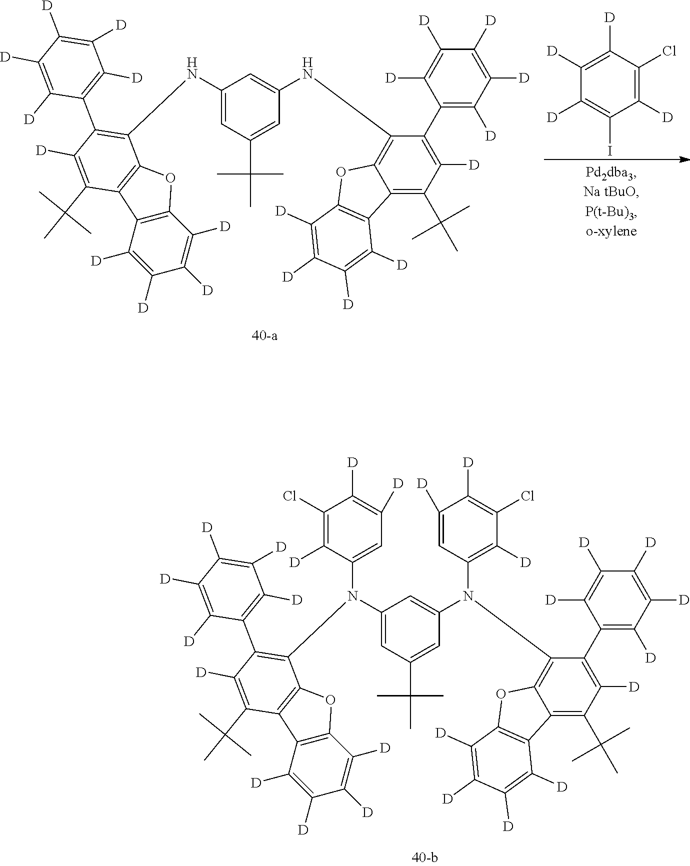

Under an argon atmosphere, to a 2 L flask, Intermediate 40-a (19 g, 24 mmol), 1-chloro-3-iodobenzene-2,4,5,6-d4 (12 g, 50 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 40-b (white solid, 17.6 g, 72%).

ESI-LCMS: [M]⁺: C₆₆H₃₂D₂₆Cl₂N₂O₂. 1006.5527.

### Synthesis of Intermediate 40-c

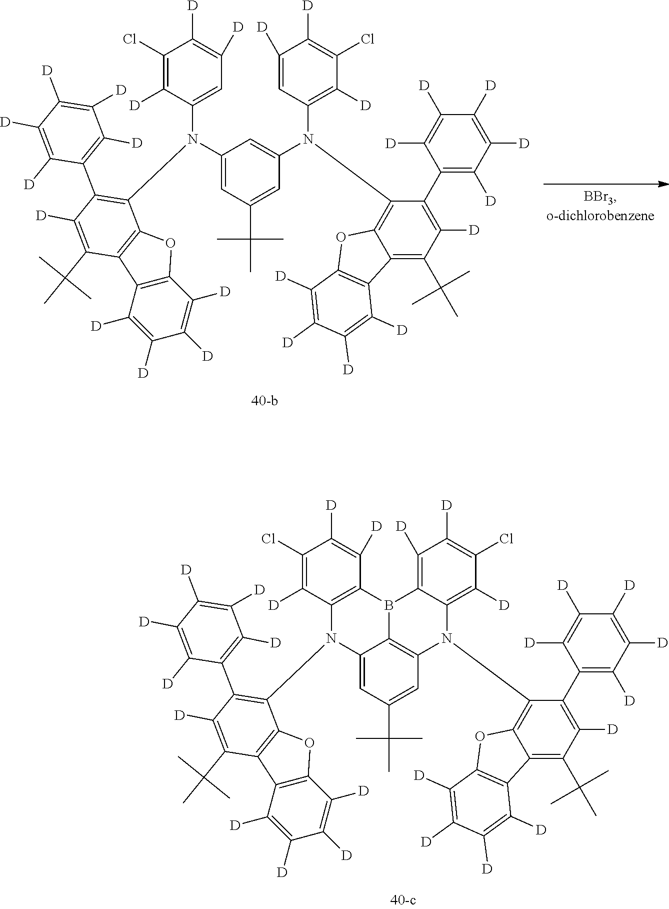

Under an argon atmosphere, to a 1 L flask, Intermediate 40-b (17.6 g, 17 mmol) was put and dissolved in 200 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 40-c (yellow solid, 3.7 g, 21%).

ESI-LCMS: [M]⁺: C₆₆H₂₉D₂₆BCl₂N₂O₂. 1014.5437.

### Synthesis of Compound 40

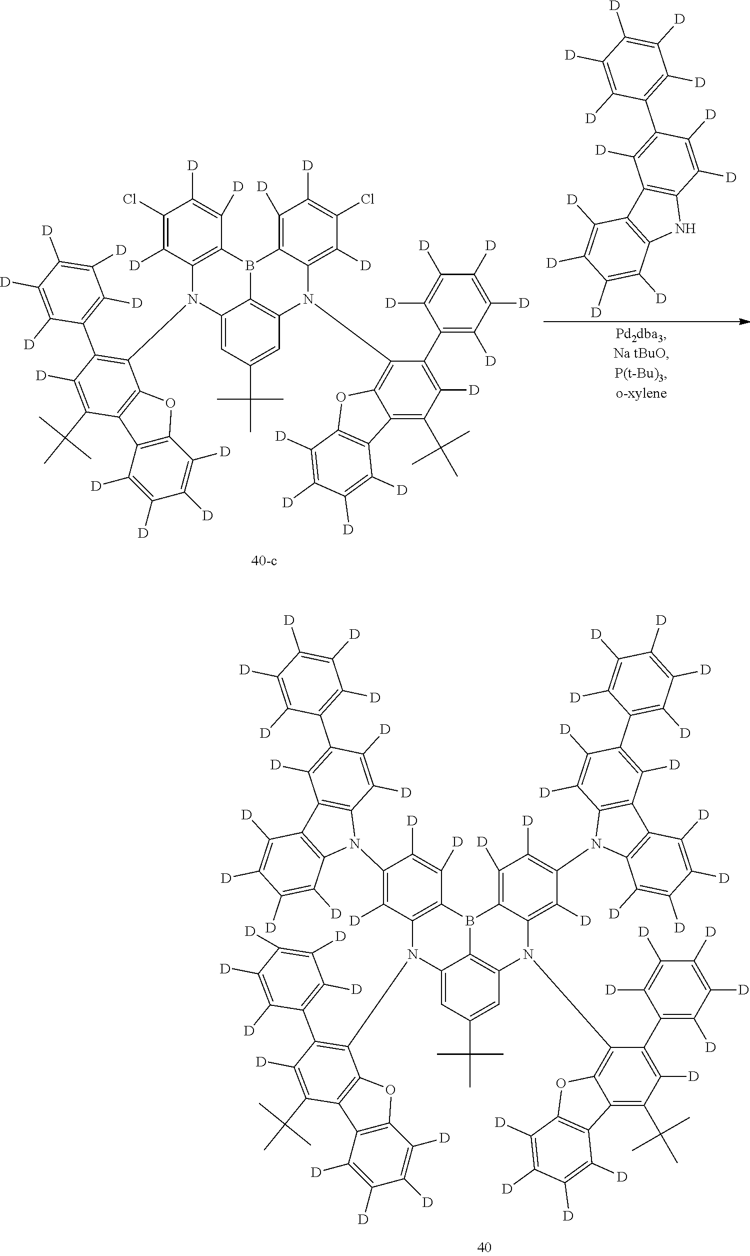

Under an argon atmosphere, to a 1 L flask, Intermediate 40-c (3.7 g, 3.6 mmol), 3-(phenyl-d5)-9H-carbazole-1,2,4,5,6,7,8-d7 (1.9 g, 7.2 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 40 (yellow solid, 3.7 g, 70%).

ESI-LCMS: [M]⁺: C₁₀₂H₂₉D₅₀BN₄O₂. 1452.3694

### (7) Synthesis of Compound 50

### Synthesis of Intermediate 50-a

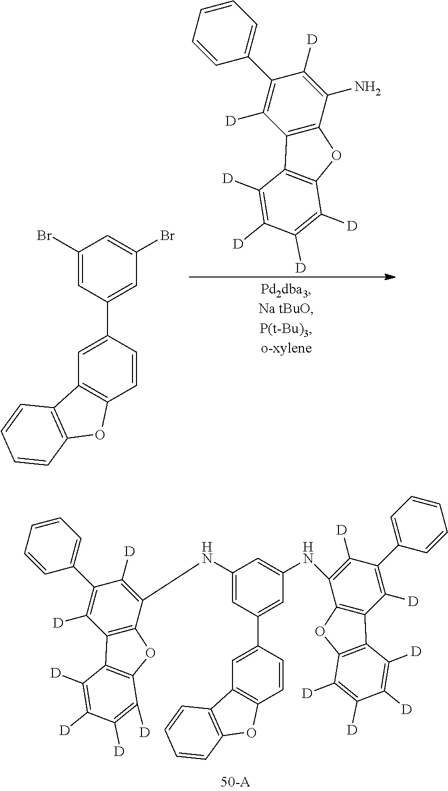 [SMILES: Brc1cc(Br)cc(-c2ccc3oc4ccccc4c3c2)c1 ; [2H]c1c([2H])c([2H])c2c(oc3c(N)c([2H])c(-c4ccccc4)c([2H])c32)c1[2H] ; [2H]c1c([2H])c([2H])c2c(oc3c(Nc4cc(Nc5c([2H])c(-c6ccccc6)c([2H])c6c5oc5c([2H])c([2H])c([2H])c([2H])c56)cc(-c5ccc6oc7ccccc7c6c5)c4)c([2H])c(-c4ccccc4)c([2H])c32)c1[2H]]

Under an argon atmosphere, to a 2 L flask, 2-(3,5-dibromophenyl)dibenzo[b,d]furan (10 g, 25 mmol), 2-phenyldibenzo[b,d]furan-1,3,6,7,8,9-d6-4-amine (13 g, 50 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 50-a (white solid, 14.5 g, 75%).

ESI-LCMS: [M]⁺: C₅₄H₂₂D₁₂N₂O₃. 770.3233.

### Synthesis of Intermediate 50-b

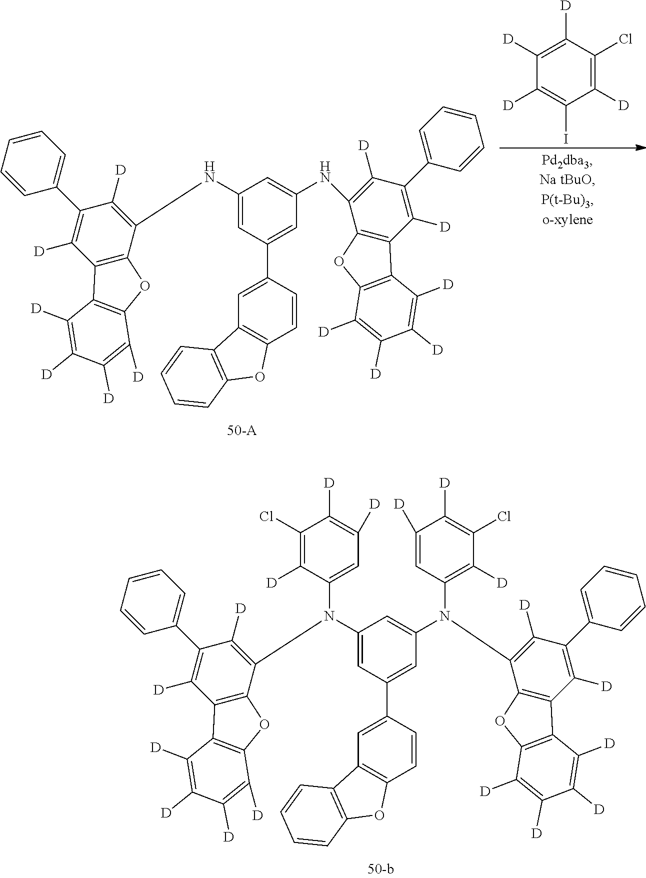

Under an argon atmosphere, to a 2 L flask, Intermediate 50-a (14 g, 18 mmol), 1-chloro-3-iodobenzene-2,4,5,6-d4 (12 g, 50 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 50-b (white solid, 12.7 g, 70%).

ESI-LCMS: [M]⁺: C₆₆H₂₂D₁₈C₂N₂O₃. 998.0717.

### Synthesis of Intermediate 50-c

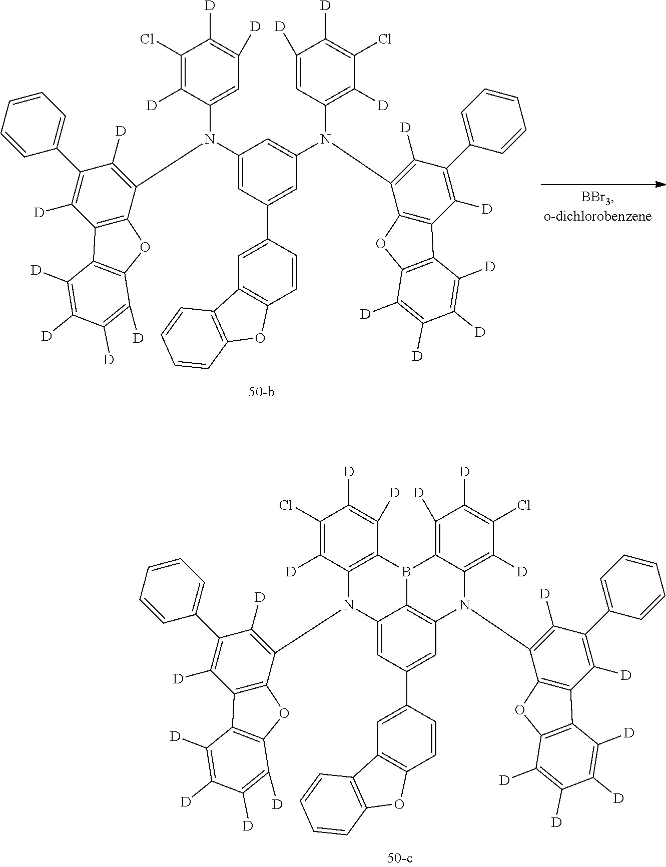 [SMILES: [2H]c1cc(N(c2cc(-c3ccc4oc5ccccc5c4c3)cc(N(c3cc([2H])c([2H])c(Cl)c3[2H])c3c([2H])c(-c4ccccc4)c([2H])c4c3oc3c([2H])c([2H])c([2H])c([2H])c34)c2)c2c([2H])c(-c3ccccc3)c([2H])c3c2oc2c([2H])c([2H])c([2H])c([2H])c23)c([2H])c(Cl)c1[2H] ; [2H]c1c([2H])c2c(c([2H])c1Cl)N(c1c([2H])c(-c3ccccc3)c([2H])c3c1oc1c([2H])c([2H])c([2H])c([2H])c13)c1cc(-c3ccc4oc5ccccc5c4c3)cc3c1B2c1c([2H])c([2H])c(Cl)c([2H])c1N3c1c([2H])c(-c2ccccc2)c([2H])c2c1oc1c([2H])c([2H])c([2H])c([2H])c12]

Under an argon atmosphere, to a 1 L flask, Intermediate 50-b (12 g, 12 mmol) was put and dissolved in 150 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 50-c (yellow solid, 2.9 g, 24%).

ESI-LCMS: [M]⁺: C₆₆H₁₉D₁₈BCl₂N₂O₃. 1004.7348.

### Synthesis of Compound 50

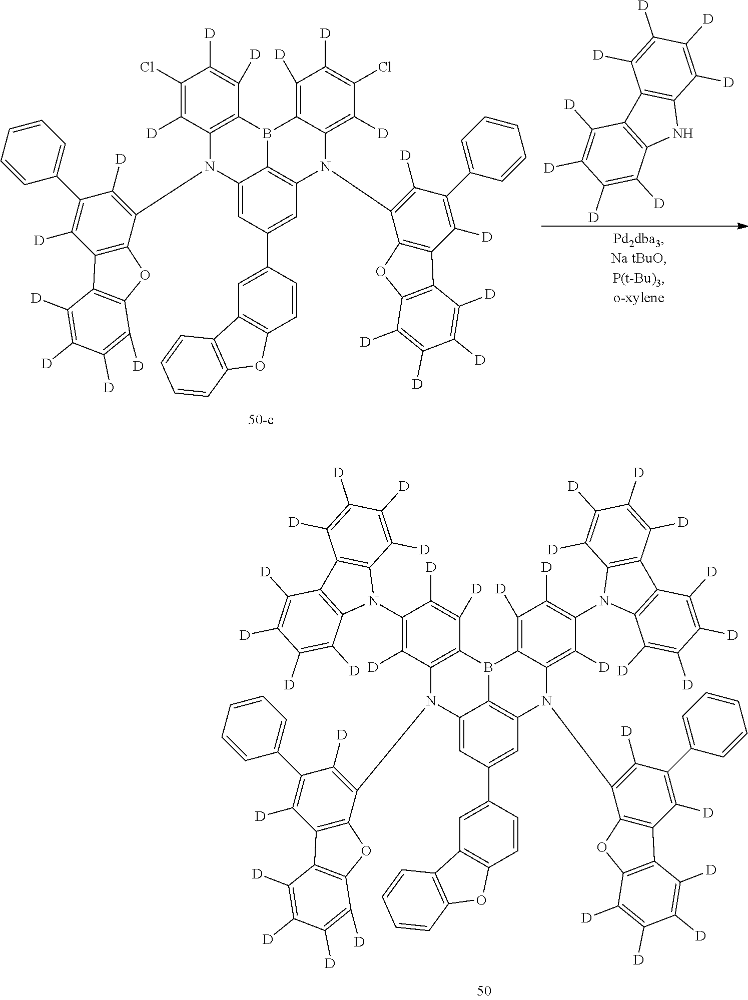

Under an argon atmosphere, to a 1 L flask, Intermediate 50-c (2.9 g, 2.8 mmol), 3-(phenyl-d5)-9H-carbazole-1,2,4,5,6,7,8-d7 (1.1 g, 5.6 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 50 (yellow solid, 2.6 g, 73%).

ESI-LCMS: [M]⁺: C₉₀H₁₉D₃₄BN₄O₃. 1282.6137

1H-NMR (CDCl₃): d=7.98 (d, 1H), 7.80 (m, 3H), 7.43 (m, 10H), 7.32 (m, 3H), 6.99 (s, 2H).

### (8) Synthesis of Compound 62

### Synthesis of Intermediate 62-a

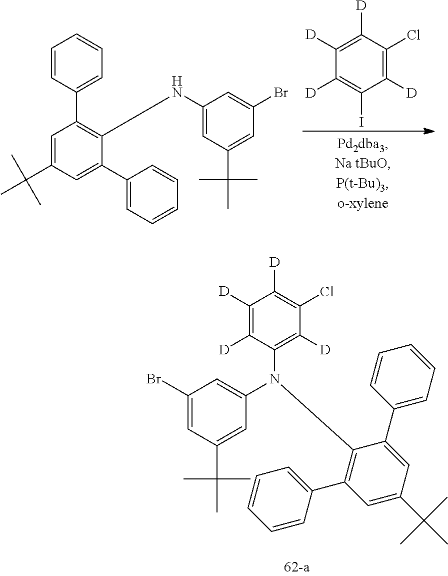

Under an argon atmosphere, to a 2 L flask, N-(3-bromo-5-(tert-butyl)phenyl)-5′-(tert-butyl)-[1,1′: 3′,1″-terphenyl]-2′-amine (10 g, 20 mmol), 1-chloro-3-iodobenzene-2,4,5,6-d4 (4.7 g, 20 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 62-a (white solid, 9.2 g, 74%).

ESI-LCMS: [M]⁺: C₃₈H₃₃D₄BrClN. 625.2033.

### Synthesis of Intermediate 62-b

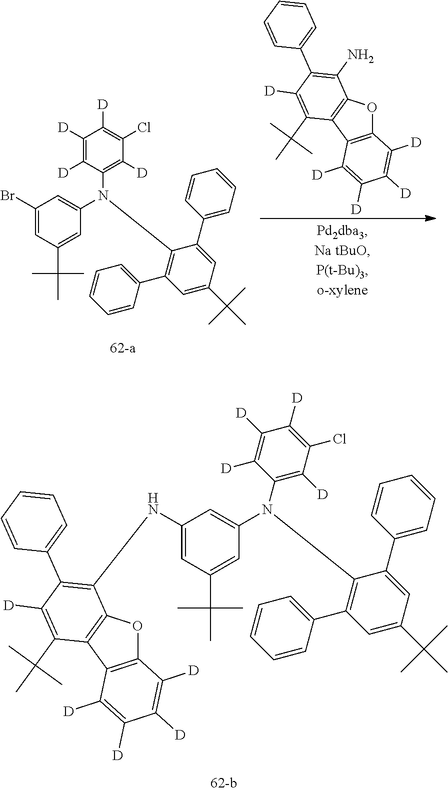 [SMILES: [2H]c1c([2H])c(Cl)c([2H])c(N(c2cc(Br)cc(C(C)(C)C)c2)c2c(-c3ccccc3)cc(C(C)(C)C)cc2-c2ccccc2)c1[2H] ; [2H]c1c([2H])c([2H])c2c(oc3c(N)c(-c4ccccc4)c([2H])c(C(C)(C)C)c32)c1[2H] ; [2H]c1c([2H])c(Cl)c([2H])c(N(c2cc(Nc3c(-c4ccccc4)c([2H])c(C(C)(C)C)c4c3oc3c([2H])c([2H])c([2H])c([2H])c34)cc(C(C)(C)C)c2)c2c(-c3ccccc3)cc(C(C)(C)C)cc2-c2ccccc2)c1[2H]]

Under an argon atmosphere, to a 2 L flask, Intermediate 62-a (9 g, 14 mmol), 1-(tert-butyl)-3-phenyldibenzo[b,d]furan-2,6,7,8,9-d5-4-amine (4.6 g, 14 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 62-b (white solid, 8.5 g, 70%).

ESI-LCMS: [M]⁺: C₆₀H₄₈D₉ClN₂O. 865.4763.

### Synthesis of Intermediate 62-c

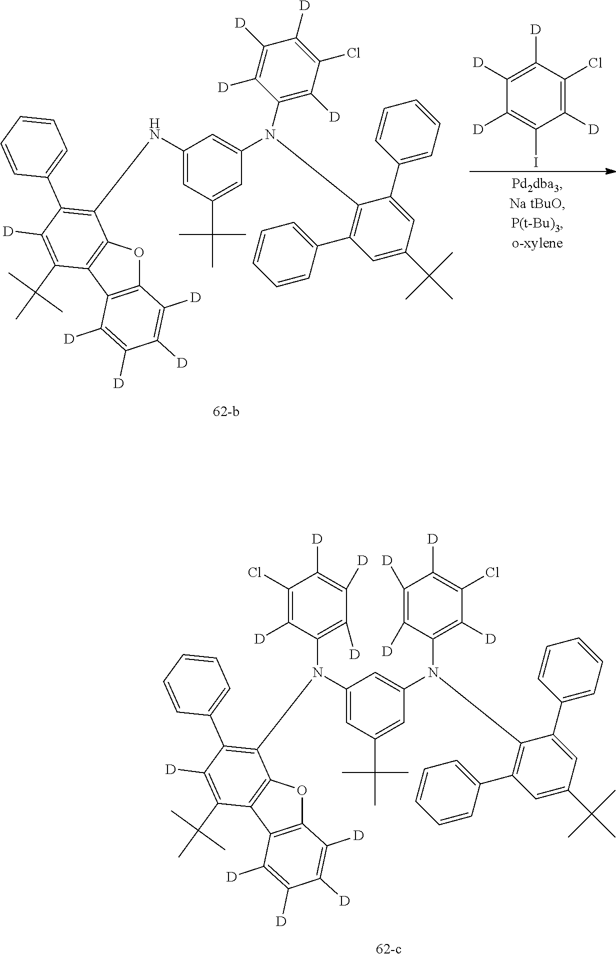

Under an argon atmosphere, to a 2 L flask, Intermediate 62-b (8.5 g, 10 mmol), 1-(tert-butyl)-3-phenyldibenzo[b,d]furan-2,6,7,8,9-d5-4-amine (2.4 g, 10 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 62-c (white solid, 7.1 g, 73%).

ESI-LCMS: [M]⁺: C₆₆H₄₇D₁₃Cl₂N₂O. 981.2047.

### Synthesis of Intermediate 62-d

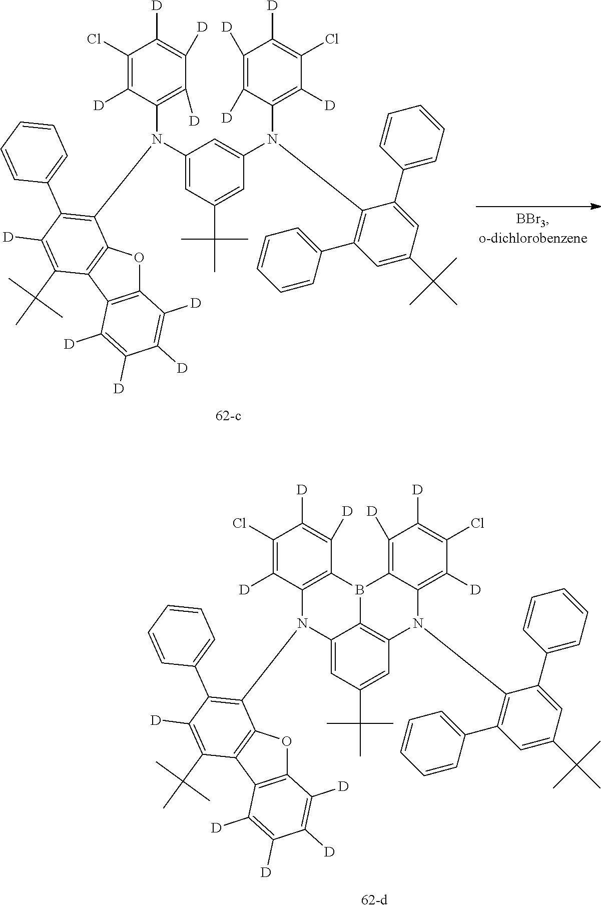 [SMILES: [2H]c1c([2H])c(Cl)c([2H])c(N(c2cc(N(c3c([2H])c([2H])c([2H])c(Cl)c3[2H])c3c(-c4ccccc4)c([2H])c(C(C)(C)C)c4c3oc3c([2H])c([2H])c([2H])c([2H])c34)cc(C(C)(C)C)c2)c2c(-c3ccccc3)cc(C(C)(C)C)cc2-c2ccccc2)c1[2H] ; [2H]c1c([2H])c2c(c([2H])c1Cl)N(c1c(-c3ccccc3)cc(C(C)(C)C)cc1-c1ccccc1)c1cc(C(C)(C)C)cc3c1B2c1c([2H])c([2H])c(Cl)c([2H])c1N3c1c(-c2ccccc2)c([2H])c(C(C)(C)C)c2c1oc1c([2H])c([2H])c([2H])c([2H])c12]

Under an argon atmosphere, to a 1 L flask, Intermediate 62-c (7 g, 7.1 mmol) was put and dissolved in 150 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 62-d (yellow solid, 1.8 g, 26%).

ESI-LCMS: [M]⁺: C₆₆H₄₆D₁₁BCl₂N₂O. 985.4677.

### Synthesis of Compound 62

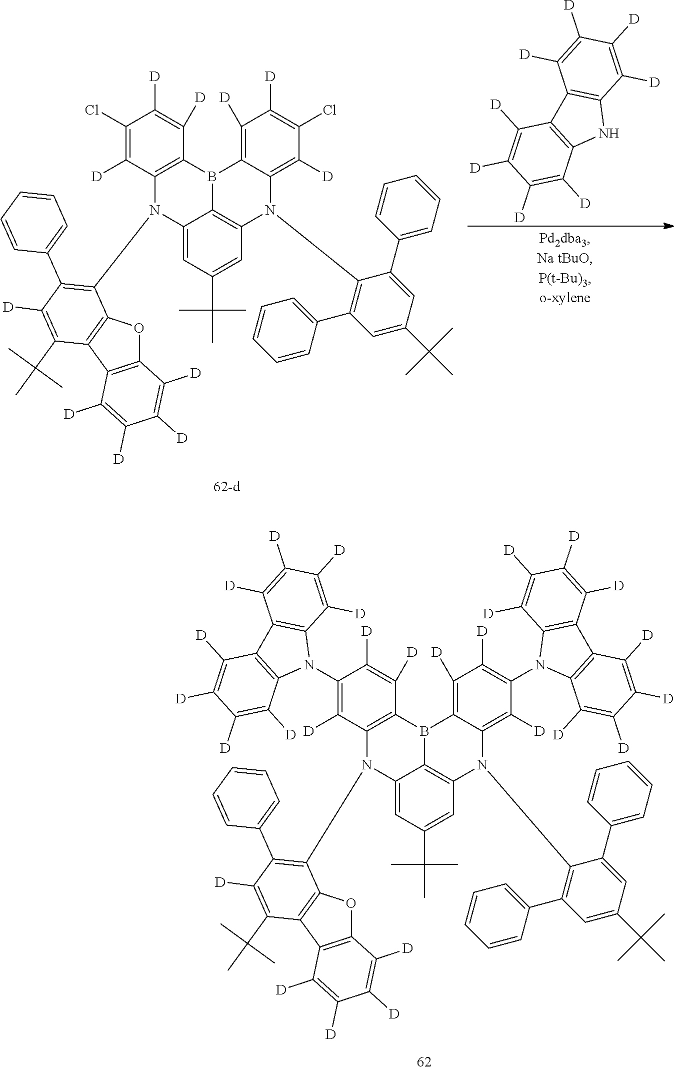

Under an argon atmosphere, to a 1 L flask, Intermediate 62-d (1.8 g, 1.8 mmol), 9H-carbazole-1,2,4,5,6,7,8-d7 (0.6 g, 3.6 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 62 (yellow solid, 1.7 g, 76%).

ESI-LCMS: [M]⁺: C₉₀H₄₆D₂₇BN₄O. 1263.6761

1H-NMR (CDCl₃): d=7.44 (s, 2H), 7.43 (m, 11H), 7.08 (m, 4H), 6.93 (s, 2H).

### (9) Synthesis of Compound 73

### Synthesis of Intermediate 73-a

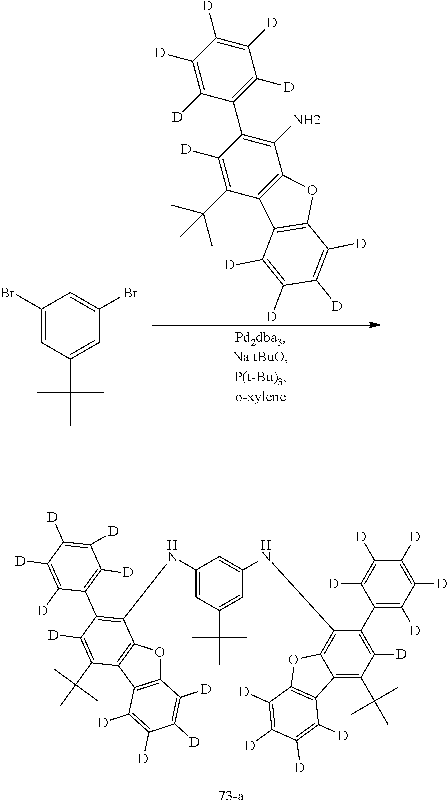 [SMILES: CC(C)(C)c1cc(Br)cc(Br)c1 ; [2H]c1c([2H])c([2H])c(-c2c([2H])c(C(C)(C)C)c3c(oc4c([2H])c([2H])c([2H])c([2H])c43)c2N)c([2H])c1[2H] ; [2H]c1c([2H])c([2H])c(-c2c([2H])c(C(C)(C)C)c3c(oc4c([2H])c([2H])c([2H])c([2H])c43)c2Nc2cc(Nc3c(-c4c([2H])c([2H])c([2H])c([2H])c4[2H])c([2H])c(C(C)(C)C)c4c3oc3c([2H])c([2H])c([2H])c([2H])c34)cc(C(C)(C)C)c2)c([2H])c1[2H]]

Under an argon atmosphere, to a 2 L flask, 1,3-dibromo-5-(tert-butyl)benzene (10 g, 34 mmol), 1-(tert-butyl)-3-(phenyl-d5)dibenzo[b,d]furan-2,6,7,8,9-d5-4-amine (22 g, 68 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 73-a (white solid, 19 g, 72%).

ESI-LCMS: [M]⁺: C₅₄H₃₂D₂₀N₂O₂. 780.5320.

### Synthesis of Intermediate 73-b

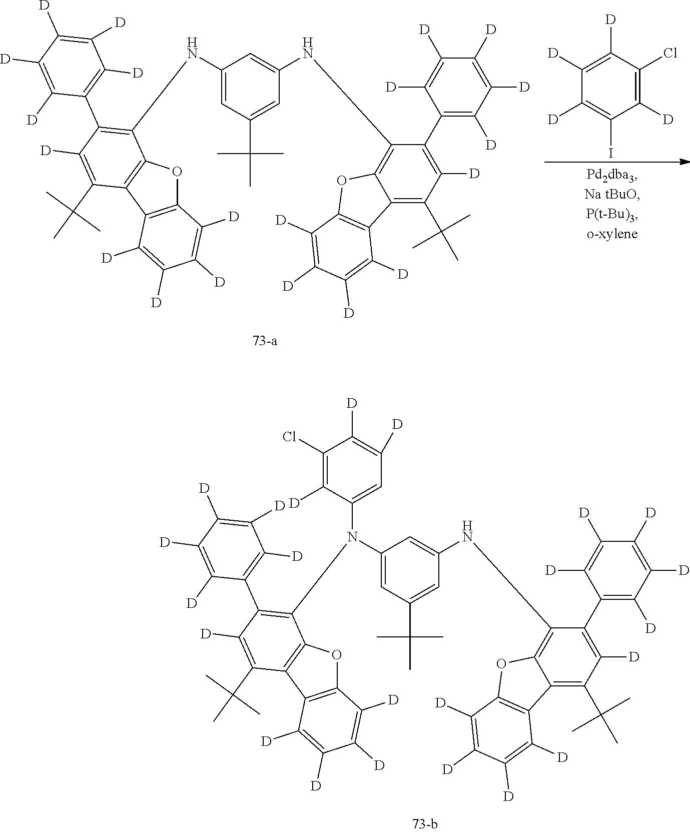

Under an argon atmosphere, to a 2 L flask, Intermediate 73-a (19 g, 24 mmol), 1-(tert-butyl)-3-phenyldibenzo[b,d]furan-2,6,7,8,9-d5-4-amine (5.9 g, 24 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 73-b (white solid, 14 g, 65%).

ESI-LCMS: [M]⁺: C₆₀H₃₂D₂₃ClN₂O₂. 893.5447.

### Synthesis of Intermediate 73-c

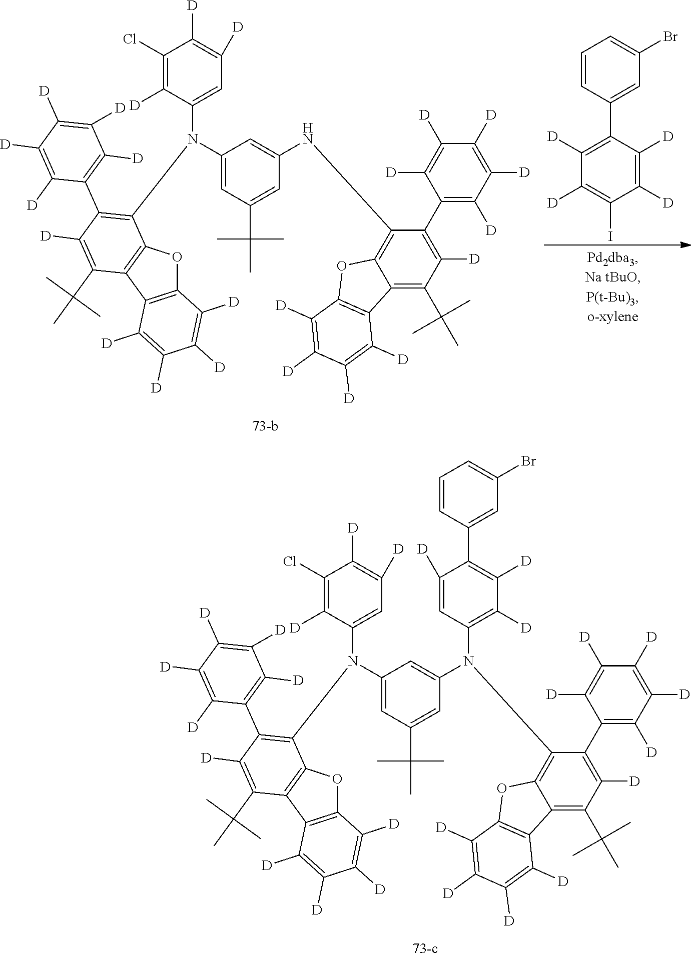

Under an argon atmosphere, to a 2 L flask, Intermediate 73-b (14 g, 15 mmol), 3-bromo-4′-iodo-1,1′-biphenyl-2′,3′,5′,6′-d4 (5.7 g, 15 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 73-c (white solid, 13 g, 77%).

ESI-LCMS: [M]⁺: C₇₂H₃₆D₂₆BrClN₂O₂. 1126.5347.

### Synthesis of Intermediate 73-d

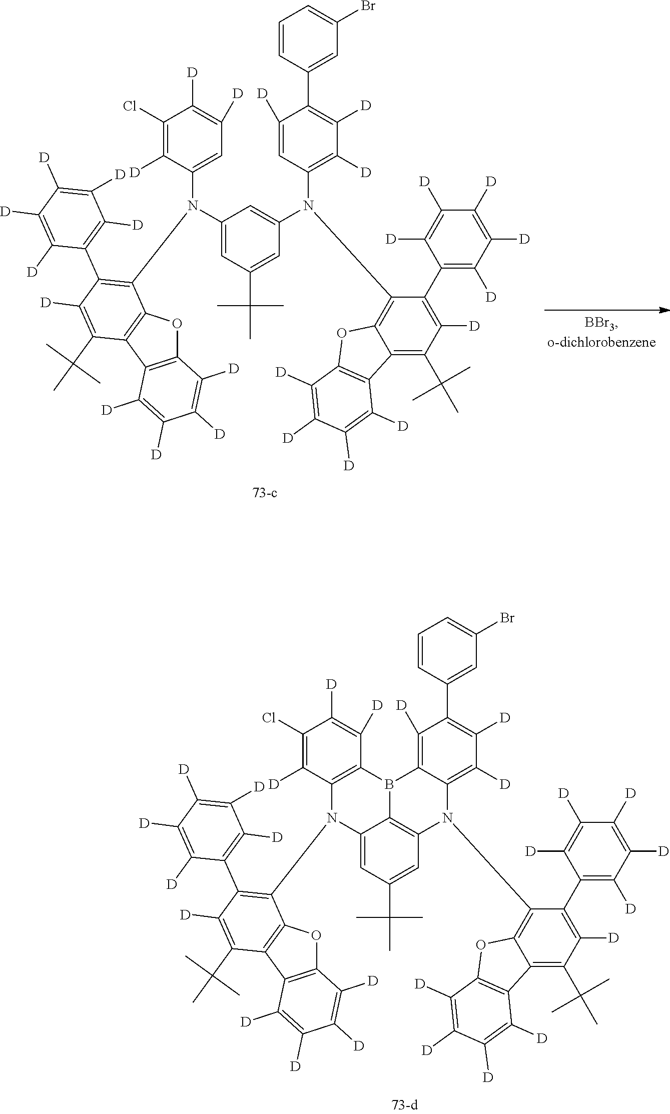

Under an argon atmosphere, to a 1 L flask, Intermediate 73-c (13 g, 11.5 mmol) was put and dissolved in 150 mL of o-dichlorobenzene, and BBr₃ (1.5 equiv.) was added thereto. The reaction solution was stirred at about 140 degrees for about 12 hours. After cooling, triethylamine was added to quench the reaction, and the solvent was removed under a reduced pressure, and the solid thus obtained was separated and purified by column chromatography using silica gel and using CH₂Cl₂ and hexane as developing solutions to obtain Intermediate 73-d (yellow solid, 3.1 g, 24%).

ESI-LCMS: [M]⁺: C₇₂H₃₃D₂₆BBrClN₂O₂. 1134.5237.

### Synthesis of Intermediate 73-e

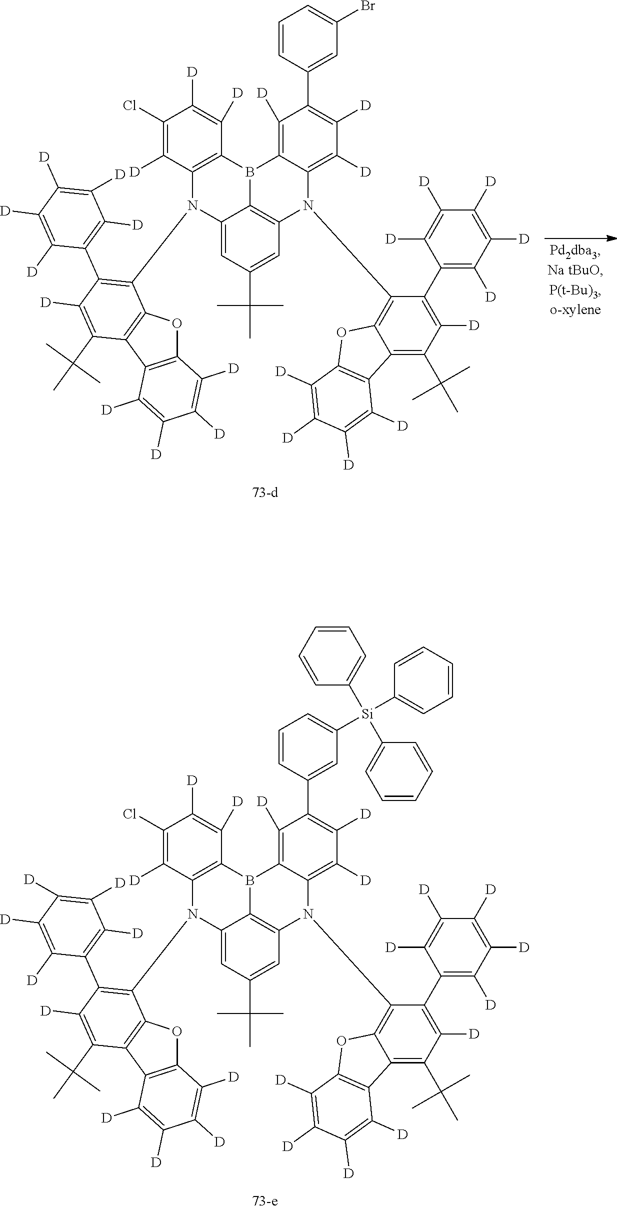

Under an argon atmosphere, to a 2 L flask, Intermediate 73-d (3 g, 2.6 mmol), triphenylsilane (0.7 g, 2.6 mmol), Pd₂dba₃ (1.6 g, 1.9 mmol), tris-tert-butyl phosphine (1.6 mL, 3.8 mmol), and sodium tert-butoxide (11.5 g, 120 mmol) were put and dissolved in 300 mL of o-xylene, and the reaction solution was stirred at about 140 degrees for about 2 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Intermediate 73-e (white solid, 1.8 g, 54%).

ESI-LCMS: [M]⁺: C₉₀H₄₈D₂₆BClN₂O₂Si. 1314.6953.

### Synthesis of Compound 73

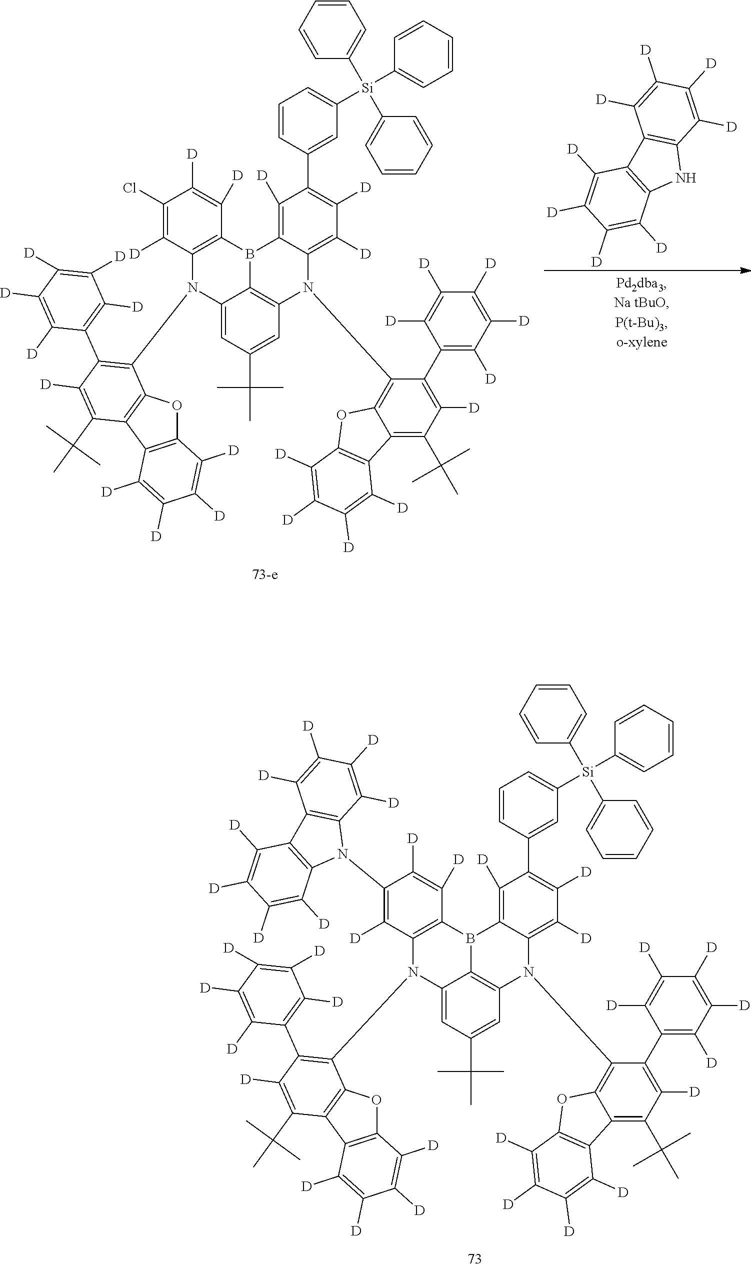

Under an argon atmosphere, to a 1 L flask, Intermediate 73-e (1.8 g, 1.4 mmol), 9H-carbazole-1,2,4,5,6,7,8-d7 (0.24 g, 1.4 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put and dissolved in 100 mL of xylene, and the reaction solution was stirred at about 140 degrees for about 12 hours. After cooling, water (1 L) and ethyl acetate (300 mL) were added, extraction was conducted, and organic layers were collected, dried over MgSO₄, and filtered. The solvent in the filtrate solution was removed under a reduced pressure, and the solid thus obtained was separated and purified by column chromatography using silica gel and using CH₂Cl₂ and hexane as developing solutions to obtain Compound 73 (yellow solid, 1.5 g, 74%).

ESI-LCMS: [M]⁺: C₁₀₂H₄₈D₃₄BN₃O₂Si. 1453.8490

1H-NMR (CDCl₃): d=7.88 (s, 1H), 7.64 (d, 2H), 7.46 (m, 4H), 7.35 (m, 11H), 6.95 (s, 2H), 1.35 (s, 18H), 1.22 (s, 9H).

### 2. Manufacture and Evaluation of Light Emitting Element

The light emitting element of an embodiment, including the fused polycyclic compound of an embodiment in an emission layer was manufactured by a method below. Light emitting elements of Example 1 to Example 9 were manufactured using the fused polycyclic compounds of Example Compounds 10, 20, 21, 27, 30, 40, 50, 62, and 73 as the dopant materials of an emission layer. Comparative Example 1 to Comparative Example 8 correspond to light emitting elements manufactured using Comparative Compound C1 to Comparative Compound C8 as the dopant materials of an emission layer.

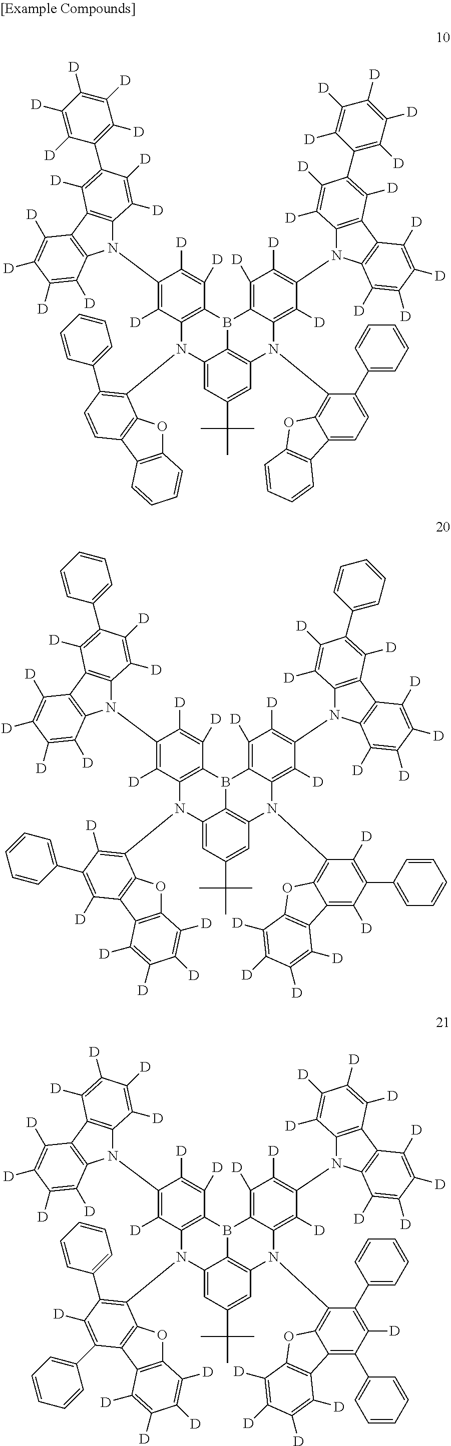

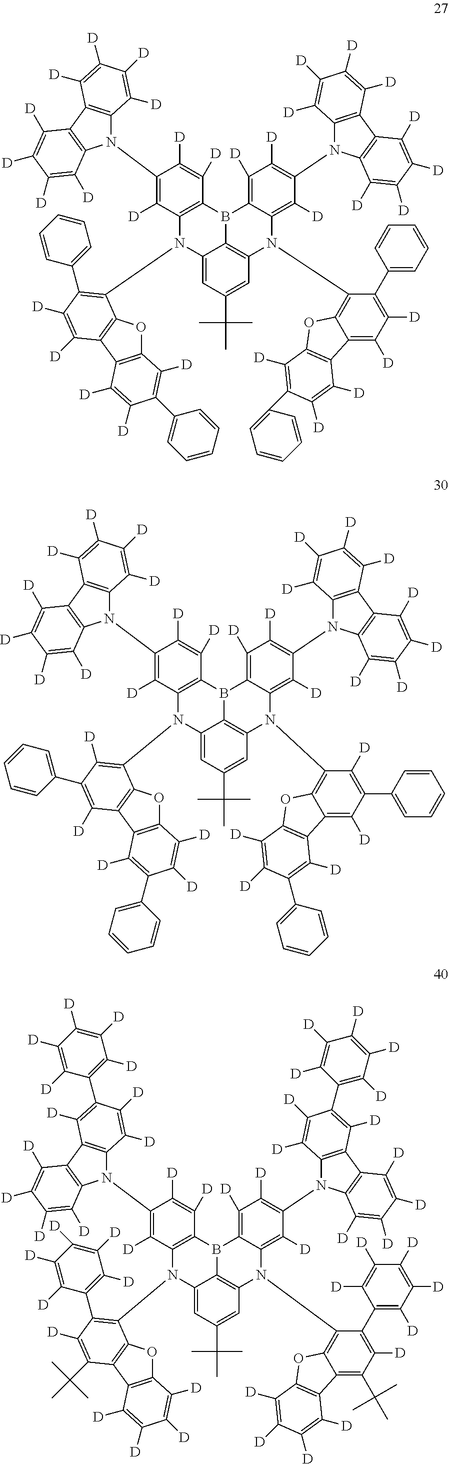

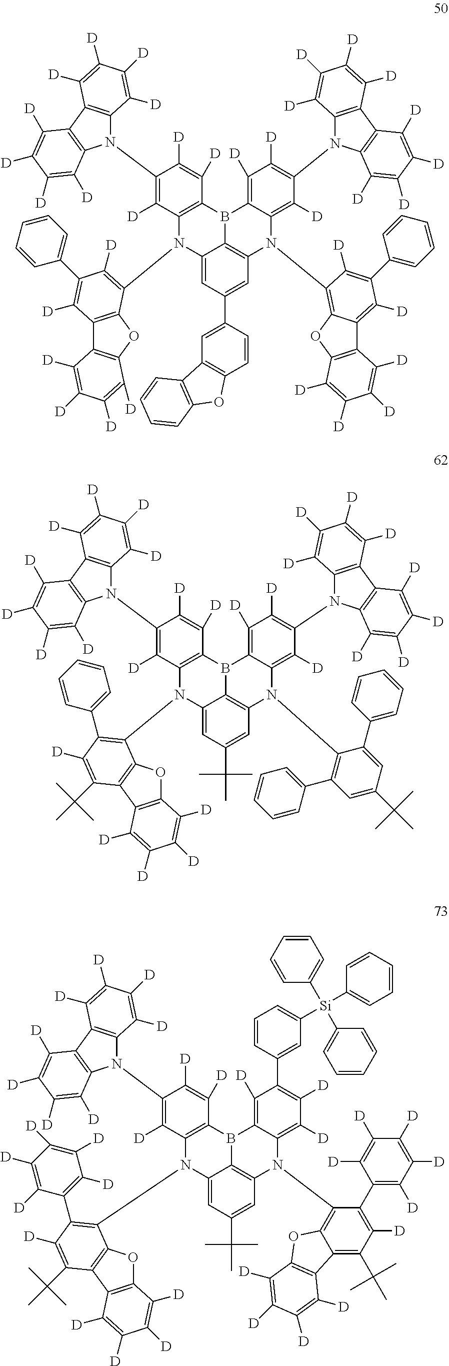

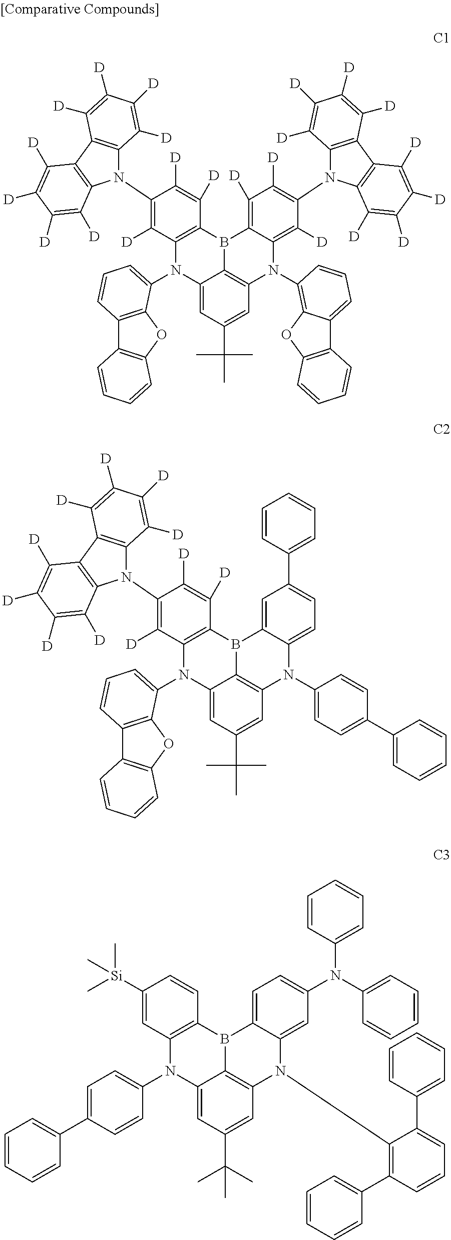

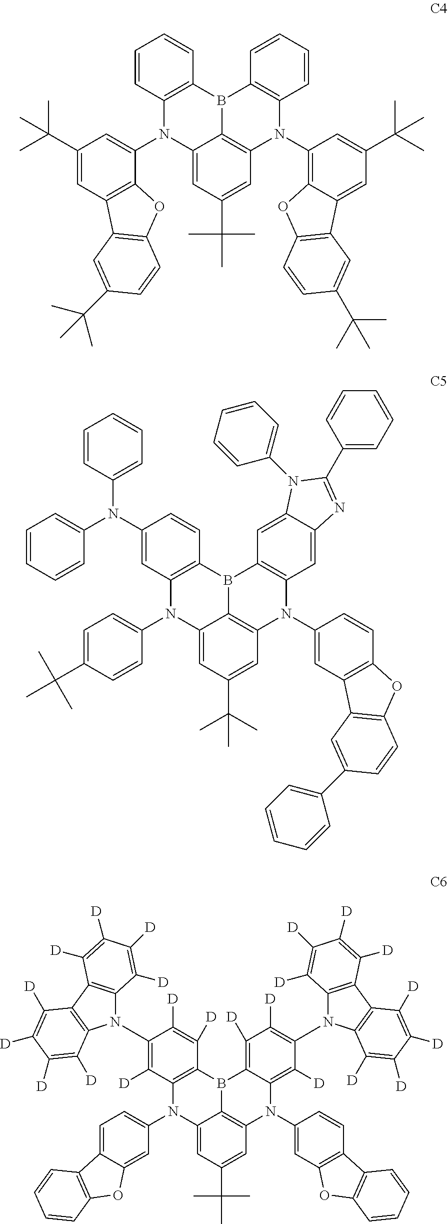

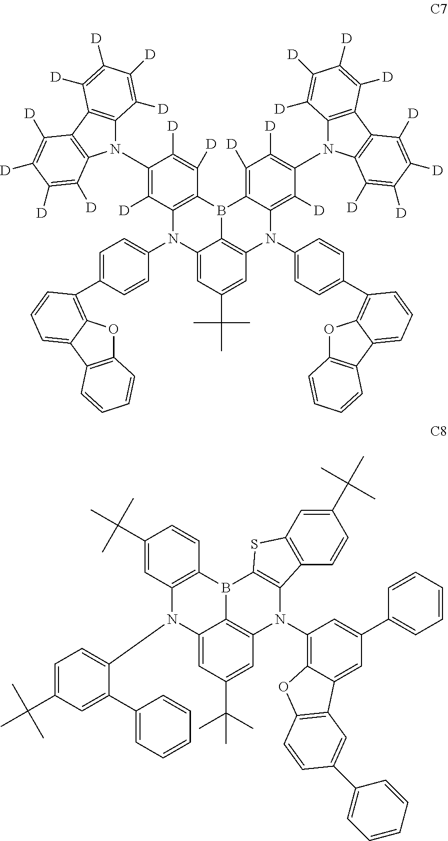 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N(c3ccc(-c4cccc5c4oc4ccccc45)cc3)c3c([2H])c(-n4c5c([2H])c([2H])c([2H])c([2H])c5c5c([2H])c([2H])c([2H])c([2H])c54)c([2H])c([2H])c31)N2c1ccc(-c2cccc3c2oc2ccccc23)cc1 ; CC(C)(C)c1ccc(N2c3cc(C(C)(C)C)ccc3B3c4sc5cc(C(C)(C)C)ccc5c4N(c4cc(-c5ccccc5)cc5c4oc4ccc(-c6ccccc6)cc45)c4cc(C(C)(C)C)cc2c43)c(-c2ccccc2)c1]

### (Manufacture of Light Emitting Element)

For the manufacture of the light emitting elements of the Examples and Comparative Examples, a glass substrate on which an ITO electrode of about 15 Ω/cm² (1200 Å) was formed (a product of Corning Co.) was cut to a size of about 50 mm×50 mm×0.7 mm, cleansed with ultrasonic waves using isopropyl alcohol and pure water for about 5 minutes each, exposed to ultraviolet for about 30 minutes, cleansed by exposing to ozone to form an anode, and the anode was installed in a vacuum evaporation apparatus.

On the anode, NPD was deposited to form a hole injection layer with a thickness of about 300 Å, and on the hole injection layer, Compound H-1-19 was deposited to form a hole transport layer with a thickness of about 200 Å. On the hole transport layer, CzSi was deposited to form an emission auxiliary layer with a thickness of about 100 Å.

A host mixture obtained by mixing the second compound and the third compound according to an embodiment at a ratio of about 1:1, the fourth compound, and an Example Compound or a Comparative Compound, were co-deposited at a weight ratio of about 85:14:1 to form an emission layer with a thickness of about 200 Å. On the emission layer, TSPO1 was deposited to form a hole blocking layer with a thickness of about 200 Å. On the hole blocking layer, TPBi was deposited to form an electron transport layer with a thickness of about 300 Å, and on the electron injection layer, LiF was deposited to form an electron injection layer with a thickness of about 10 Å. A second electrode with a thickness of about 3000 Å was formed using Al, to form a LiF/Al electrode. On the electrode, a capping layer with a thickness of about 700 Å was formed on the electrode.

All layers were formed by a vacuum deposition method. From among the compounds in Compound Group 2, Compound HT1 was used as the second compound. From among the compounds in Compound Group 3, Compound ETH66 was used as the third compound. From among the compounds in Compound Group 4, Compound AD-39 was used as the fourth compound.

The compounds used for the manufacture of the light emitting elements of the Examples and Comparative Examples are shown below. The materials below were used after purchasing commercial products and performing sublimation purification.

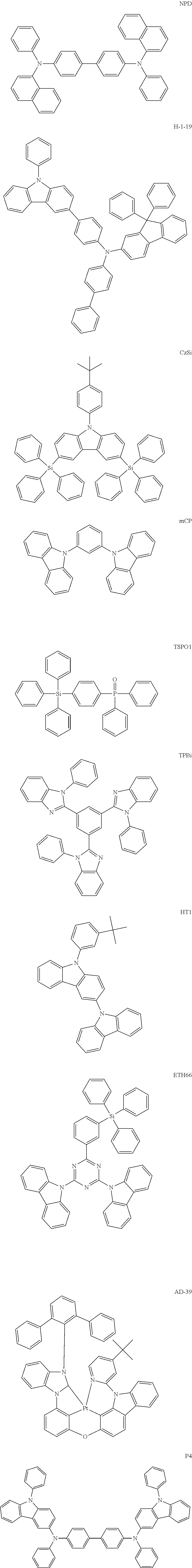

### (Evaluation of Physical Properties of the Compounds of the Examples and Comparative Examples)

In Table 1, the physical properties of Compounds 10, 20, 21, 27, 30, 40, 50, 62, and 73, as the Example Compounds, and Comparative Compounds C1 to C8, as Comparative Compounds were evaluated and shown.

In Table 1, the highest occupied molecular orbital (HOMO) energy level, the absorption wavelength (λ_{Abs}) and the emission wavelength (λₑₘᵢ) in a solution phase, Stokes-shift, the full width at quarter maximum (FWQM), and the emission efficiency (photoluminescence quantum yield, PLQY) of the Example Compounds and Example Compounds were measured and shown.

TABLE 1

| | | HOMO | λ_{Abs} | λₑₘᵢ | Stokes- | FWQM | PLQY |
|---|---|---|---|---|---|---|---|
| | Dopant | (eV) | (nm) | (nm) | shift | (nm) | (%) |
| Example 1 | Compound 10 | −5.50 | 449 | 458 | 9 | 32 | 99 |
| Example 2 | Compound 20 | −5.48 | 449 | 459 | 10 | 32 | 98 |
| Example 3 | Compound 21 | −5.53 | 450 | 458 | 8 | 33 | 97 |
| Example 4 | Compound 27 | −5.48 | 448 | 447 | 9 | 32 | 99 |
| Example 5 | Compound 30 | −5.50 | 449 | 448 | 9 | 32 | 98 |
| Example 6 | Compound 40 | −5.51 | 450 | 459 | 9 | 32 | 99 |
| Example 7 | Compound 50 | −5.55 | 451 | 460 | 9 | 34 | 98 |
| Example 8 | Compound 62 | −5.54 | 447 | 457 | 10 | 31 | 99 |
| Example 9 | Compound 73 | −5.43 | 451 | 461 | 10 | 32 | 97 |
| Comparative | Comparative | −5.35 | 439 | 453 | 14 | 40 | 88 |
| Example 1 | Compound C1 | | | | | | |
| Comparative | Comparative | −5.30 | 445 | 458 | 13 | 38 | 85 |
| Example 2 | Compound C2 | | | | | | |
| Comparative | Comparative | −5.15 | 440 | 456 | 16 | 42 | 81 |
| Example 3 | Compound C3 | | | | | | |
| Comparative | Comparative | −5.22 | 434 | 448 | 14 | 46 | 72 |
| Example 4 | Compound C4 | | | | | | |
| Comparative | Comparative | −5.18 | 440 | 463 | 23 | 52 | 83 |
| Example 5 | Compound C5 | | | | | | |
| Comparative | Comparative | −5.35 | 449 | 462 | 13 | 40 | 90 |
| Example 6 | Compound C6 | | | | | | |
| Comparative | Comparative | −5.38 | 450 | 462 | 12 | 39 | 92 |
| Example 7 | Compound C7 | | | | | | |
| Comparative | Comparative | −5.20 | 440 | 453 | 13 | 43 | 89 |
| Example 8 | Compound C8 | | | | | | |

Referring to Table 1, it can be confirmed that the compounds of Example 1 to Example 9 showed smaller Stokes-shift and higher photoluminescence quantum yield (PLQY) than the compounds of Comparative Example 1 and Comparative Example 8. Considering the full width at quarter maximum (FWQM), it can be confirmed that the full width at quarter maximum of the Example Compounds included in Example 1 to Example 9 was smaller than the full width at quarter maximum of Comparative Compound C1 to Comparative Compound C8, included in Comparative Example 1 to Comparative Example 8.

It can be confirmed that the Example Compounds showed blue-shifted wavelength of the emission wavelength (λₑₘᵢ) and color purity close to neutral blue. In comparison to Example 1 to Example 9, it can be confirmed that the emission wavelengths of Comparative Compound C5 and Comparative Compound C6, included in Comparative Example 5 and Comparative Example 6 were red shifted. The Example Compounds are different from Comparative Compounds C5 and C6 in the position connected of the dibenzofuran moiety with the nitrogen atom. Comparative Compound C5 and Comparative Compound C6 include a dibenzofuran moiety connected with the fused ring core, but connected with the nitrogen atom via not carbon at position 4 but carbon at position 2 or 3 of the dibenzofuran moiety, and were red shifted compared to the Example Compounds. The Example Compounds have a structure in which carbon at position 4 of the dibenzofuran moiety is connected with the nitrogen atom of the fused ring core, and the emission wavelength can be blue shifted, and accordingly, high color purity may be shown in a blue light wavelength region. The fine control of a target emission wavelength can be achieved without changing optical and physical properties significantly through changing the type of the substituent connected with the fused ring core.

### (Evaluation of Properties of Light Emitting Elements)

The element efficiency and element lifetime of the light emitting elements manufactured by using Compounds 10, 20, 21, 27, 30, 40, 50, 62, and 73 and Comparative Compounds C1 to C8 were evaluated. In Table 2, the evaluation results on the light emitting elements of Examples 1 to 9, and Comparative Examples 1 to 8 are shown. For the evaluation of the properties of the light emitting elements manufactured in the Examples and Comparative Examples, a driving voltage and a current density were measured using V7000 OLED IVL Test System (Polaronix). For the evaluation of the properties of the light emitting elements manufactured in Examples 1 to 9 and Comparative Examples 1 to 8, a driving voltage at a current density of about 10 mA/cm², and efficiency (cd/A) were measured. The time consumed from an initial value to about 95% luminance deterioration, while continuously driven at a current density of about 10 mA/cm² was set to relative element lifetime on the basis of Comparative Example 1 for evaluation.

TABLE 2

| | Host (second | | | Driving | | Emission | | |
|---|---|---|---|---|---|---|---|---|
| | compound:third | Fourth | First | voltage | Efficiency | wavelength | Lifetime | |
| | compound = 5:5) | compound | compound | (V) | (cd/A) | (nm) | (T95) | CIEy |
| Example 1 | HT1/ETH66 | AD-39 | Compound 10 | 4.1 | 550 | 459 | 8.5 | 0.051 |
| Example 2 | HT1/ETH66 | AD-39 | Compound 20 | 4.0 | 565 | 460 | 7.4 | 0.052 |
| Example 3 | HT1/ETH66 | AD-39 | Compound 21 | 4.1 | 575 | 459 | 9.5 | 0.051 |
| Example 4 | HT1/ETH66 | AD-39 | Compound 27 | 3.8 | 550 | 460 | 8.8 | 0.055 |
| Example 5 | HT1/ETH66 | AD-39 | Compound 30 | 3.8 | 580 | 461 | 8.3 | 0.056 |
| Example 4 | HT1/ETH66 | AD-39 | Compound 40 | 4.1 | 580 | 460 | 10.4 | 0.053 |
| Example 5 | HT1/ETH66 | AD-39 | Compound 50 | 4.0 | 585 | 461 | 5.9 | 0.055 |
| Example 6 | HT1/ETH66 | AD-39 | Compound 62 | 4.0 | 570 | 458 | 6.3 | 0.049 |
| Example 7 | HT1/ETH66 | AD-39 | Compound 73 | 4.0 | 560 | 462 | 7.7 | 0.058 |
| Comparative | HT1/ETH66 | AD-39 | Comparative | 4.1 | 400 | 458 | 1 | 0.055 |
| Example 1 | | | Compound C1 | | | | | |
| Comparative | HT1/ETH66 | AD-39 | Comparative | 4.2 | 450 | 463 | 0.3 | 0.059 |
| Example 2 | | | Compound C2 | | | | | |
| Comparative | HT1/ETH66 | AD-39 | Comparative | 4.5 | 350 | 462 | 0.1 | 0.058 |
| Example 3 | | | Compound C3 | | | | | |
| Comparative | HT1/ETH66 | AD-39 | Comparative | 4.3 | 360 | 450 | 0.03 | 0.043 |
| Example 4 | | | Compound C4 | | | | | |
| Comparative | HT1/ETH66 | AD-39 | Comparative | 4.2 | 320 | 465 | 0.01 | 0.060 |
| Example 5 | | | Compound C5 | | | | | |
| Comparative | HT1/ETH66 | AD-39 | Comparative | 4.4 | 420 | 465 | 1.2 | 0.063 |
| Example 6 | | | Compound C6 | | | | | |
| Comparative | HT1/ETH66 | AD-39 | Comparative | 4.3 | 440 | 464 | 1.5 | 0.062 |
| Example 7 | | | Compound C7 | | | | | |

| | | | | | | | |
|---|---|---|---|---|---|---|---|
| Comparative | HT1/ETH66 | AD-39 | Comparative | 4.4 | 280 | 456 | 0.001 0.048 |
| Example 8 | | | Compound C8 | | | | |

Referring to the results of Table 2, it can be confirmed that the Examples of the light emitting elements using the fused polycyclic compounds according to embodiments of the inventive concept as light emitting materials, showed improved emission efficiency and lifetime characteristics when compared to the Comparative Examples. The Example Compounds include a first substituent at the nitrogen atom constituting a fused ring, and a boron atom can be effectively protected, and high efficiency and long lifetime can be achieved. The Example Compounds introduce the first substituent, and intermolecular interaction is suppressed, the formation of excimer or exciplex can be controlled, and the emission efficiency can be increased. The red shift of the emission wavelength can be suppressed. In the Example Compounds, due to a structure having large steric hindrance, a distance between adjacent molecules is increased, and dexter energy transfer is suppressed, and lifetime deterioration because of the increase of the concentration of triplet can be suppressed.

Comparative Example 1, Comparative Example 2, Comparative Example 6, and Comparative Example 7 showed degraded results of element lifetime and efficiency when compared to the Examples. Comparative Compound C1, Comparative Compound C2, Comparative Compound C6, and Comparative Compound C7, used in Comparative Example 1, Comparative Example 2, Comparative Example 6, and Comparative Example 7 have a structure in which a dibenzofuran moiety is connected with the fused ring core, but do not include an aromatic substituent connected with the dibenzofuran moiety like in the Examples, and the steric protection effects of a boron atom in the plate-type structure of the fused ring core are deteriorated, and the intermolecular interaction effects are difficult to predict. In the case of Comparative Compound C6, it can be confirmed that the dibenzofuran moiety is connected with the nitrogen atom through not carbon at position 4 but carbon at position 2 or 3, to induce red shift when compared to the Example Compounds.

Considering Comparative Example 3, Comparative Compound C3 has a fused ring structure with one boron atom and two nitrogen atoms in the center, but does not include the first and second substituents suggested in the inventive concept in a fused ring skeleton, and when applied to an element, it can be confirmed that the emission efficiency and lifetime were degraded in contrast to the Examples.

Considering Comparative Example 4, Comparative Compound C4 includes a fused ring structure fused via a boron atom and two nitrogen atoms, but does not include the first and second substituents suggested in the inventive concept in a fused ring skeleton, and it can be confirmed that the emission efficiency and lifetime were degraded in contrast to the Examples. Comparative Compound C4 used in Comparative Example 4 has a structure in which an alkyl group is substituted at the dibenzofuran moiety, but the steric hindrance effects of the alkyl group is insufficient, and when applied to an element, it is considered that the emission efficiency and lifetime were degraded in contrast to the Examples. Since Comparative Compound C4 does not include the second substituent suggested in the inventive concept, multiple resonance effects and boron atom protection effects can be degraded in contrast to the Example Compounds.

Comparative Example 5 showed degraded results of element lifetime and efficiency when compared to the Examples. Comparative Compound C5 used in Comparative Example 5 has a structure in which a dibenzofuran moiety substituted with a phenyl group is connected with the fused ring core, but it can be confirmed that emission efficiency and lifetime were reduced in contrast to the Examples. Comparative Compound C5 has a structure in which a phenyl group is connected with a benzene ring which is not connected with the nitrogen atom among benzene rings constituting the dibenzofuran moiety, and it is difficult to show sufficient steric hindrance effects when compared to the Example Compounds, and when applied to a light emitting element, it is considered that emission efficiency and lifetime characteristics were degraded.

Comparative Example 8 showed degraded efficiency, particularly markedly degraded lifetime when compared to the Examples. Comparative Compound C8 included in Comparative Example 8 has a fused structure of 5-member heterocycle including a sulfur (S) atom in the fused ring core. If a 5-member heterocycle is fused with the fused ring core as in Comparative Compound C8, chemical stability may be degraded, and accordingly, if applied to a light emitting element, emission efficiency and element lifetime can be degraded.

The light emitting element according to an embodiment may show improved element properties of high efficiency and long lifetime.

The fused polycyclic compound according to an embodiment may be included in the emission layer of a light emitting element and may contribute to the increase of the efficiency and lifetime of the light emitting element.

The display device of an embodiment may show excellent display quality.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element, comprising:
a first electrode;
a second electrode disposed on the first electrode; and
an emission layer disposed between the first electrode and the second electrode, and comprising a first compound represented by Formula 1: 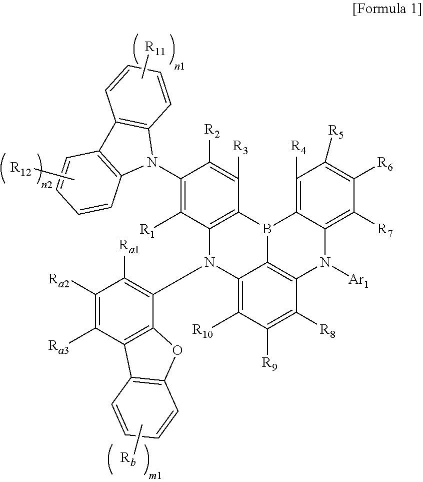
wherein in Formula 1,
R₁ to R₁₀ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
Rₐ₁ to Rₐ₃ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
except that at least one of Rₐ₁ to R₃ is each independently a substituted or unsubstituted aryl group of 6 to 30 ring-forming carbon atoms or a substituted or unsubstituted heteroaryl group of 2 to 30 ring-forming carbon atoms,
R_{b}, R₁₁, and R₁₂ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
Ar₁ is a substituted or unsubstituted aryl group of 6 to 30 ring-forming carbon atoms or a substituted or unsubstituted heteroaryl group of 2 to 30 ring-forming carbon atoms, and
m1, n1, and n2 are each independently an integer from 0 to 4.

2. The light emitting element of claim 1, wherein the first compound is represented by one of Formula 2-1 to Formula 2-3: 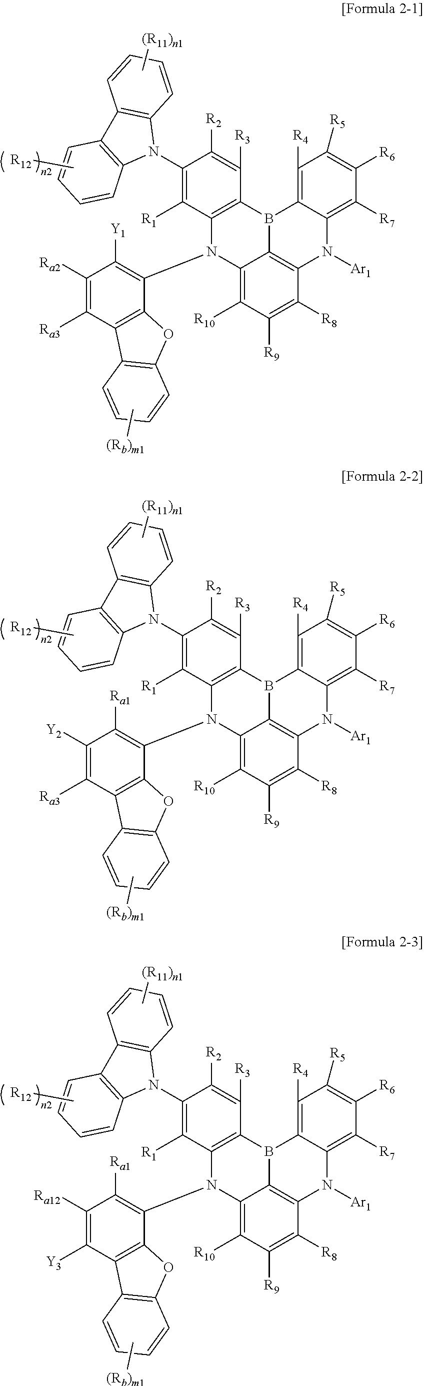
wherein in Formula 2-1 to Formula 2-3,
Y₁ to Y₃ are each independently a substituted or unsubstituted aryl group of 6 to 30 ring-forming carbon atoms or a substituted or unsubstituted heteroaryl group of 2 to 30 ring-forming carbon atoms, and
Ar₁, R₁ to R₁₂, Rₐ₁ to Rₐ₃, R_{b}, m1, n1, and n2 are the same as defined in Formula 1.

3. The light emitting element of claim 1, wherein the first compound is represented by Formula 3: 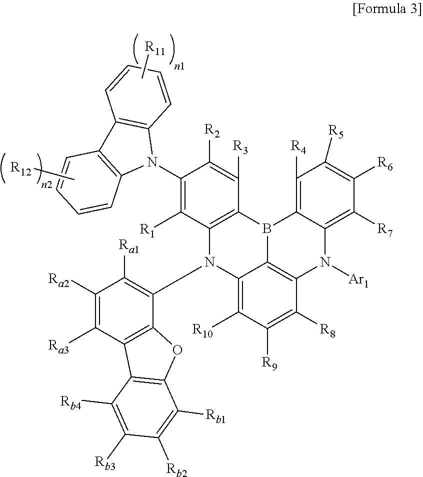
wherein in Formula 3,
R_{b1} to R_{b4} are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted cycloalkyl group of 3 to 20 ring-forming carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
except that at least one of R_{b1} to R_{b4} is each independently a substituted or unsubstituted aryl group of 6 to 30 ring-forming carbon atoms or a substituted or unsubstituted heteroaryl group of 2 to 30 ring-forming carbon atoms, and
Ar₁, R₁ to R₁₂, Rₐ₁ to Rₐ₃, n1, and n2 are the same as defined in Formula 1.

4. The light emitting element of claim 1, wherein the first compound is represented by Formula 4-1 or Formula 4-2: 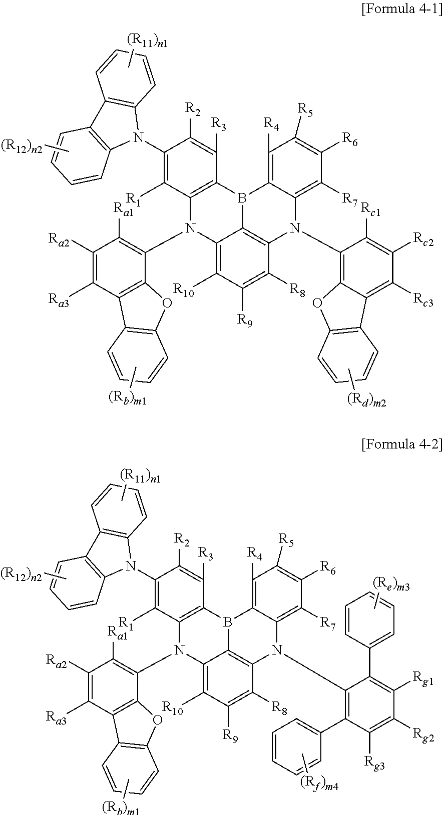
wherein in Formula 4-1 and Formula 4-2,
R_{c1} to R_{c3}, R_{d}, Rₑ, R_{f}, and R_{g1} to R_{g3} are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m2 is an integer from 0 to 4, and
m3 and m4 are each independently an integer from 0 to 5,
wherein in Formula 4-1,
at least one of R_{c1} to R_{c3} is each independently a substituted or unsubstituted aryl group of 6 to 30 ring-forming carbon atoms or a substituted or unsubstituted heteroaryl group of 2 to 30 ring-forming carbon atoms, and
wherein in Formula 4-1 and Formula 4-2,
R₁ to R₁₂, Rₐ₁ to Rₐ₃, R_{b}, m1, n1, and n2 are the same as defined in Formula 1.

5. The light emitting element of claim 1, wherein the first compound is represented by Formula 5: 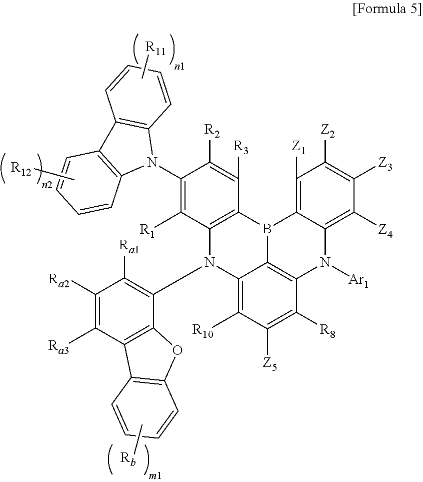
wherein in Formula 5,
Z₁ to Z₅ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
except that at least one of Z₁ to Z₅ is each independently a substituted or unsubstituted alkyl group of 1 to 10 carbon atoms, or a group represented by one of Formula A-1 to Formula A-5: 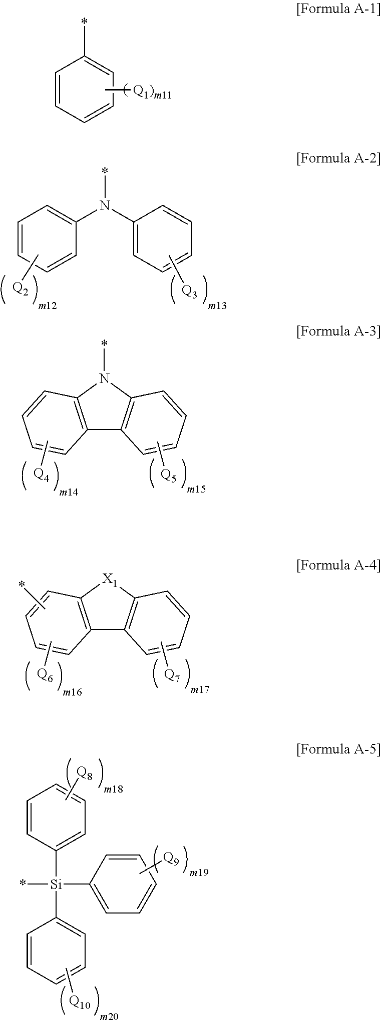
wherein in Formula A-1 to Formula A-5,
X₁ is O, S, Se, N(Q₁₁), or C(Q₁₂)(Q₁₃),
Q₁ to Q₁₃ are each independently a hydrogen atom, a deuterium atom, a halogen atom, a cyano group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11 to m13 and m18 to m20 are each independently an integer from 0 to 5,
m14, m15, and m17 are each independently an integer from 0 to 4, and
m16 is an integer from 0 to 3, and
wherein in Formula 5,
Ar₁, R₁ to R₃, R₈, R₁₀ to R₁₂, Rₐ₁ to Rₐ₃, R_{b}, m1, n1, and n2 are the same as defined in Formula 1.

6. The light emitting element of claim 5, wherein at least one of Z₁ to Z₅ is each independently a group selected from Substituent Group 1:

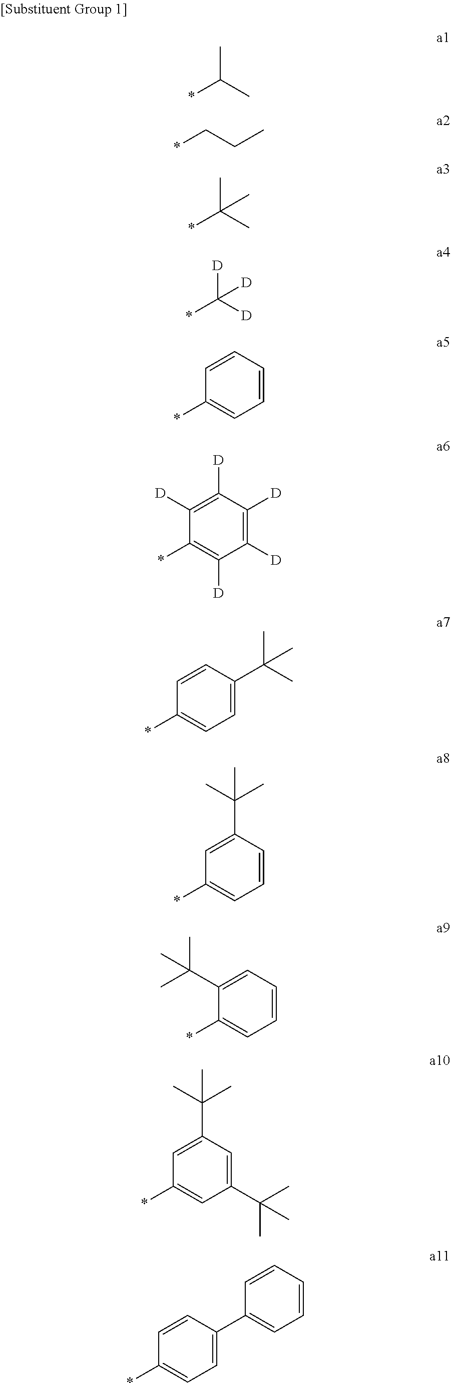

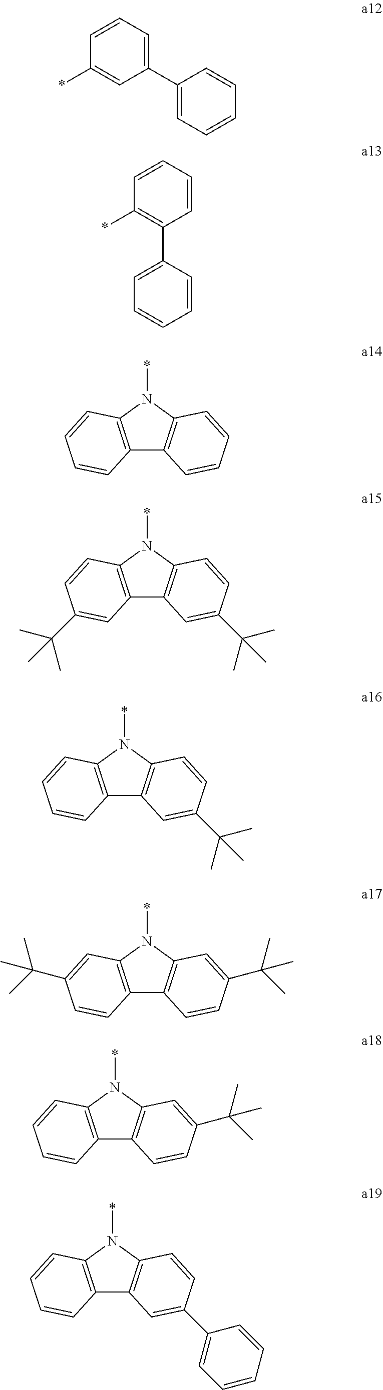

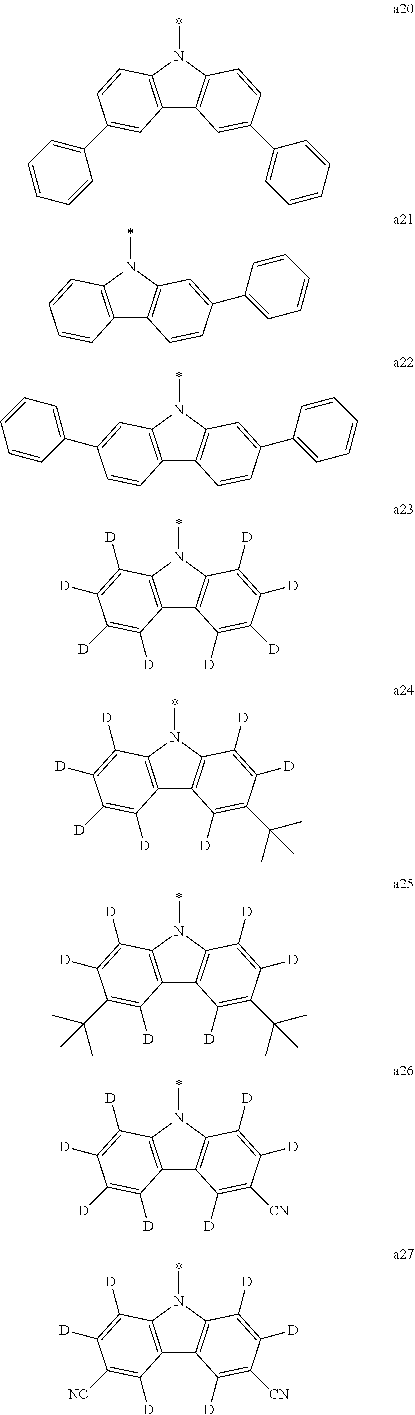

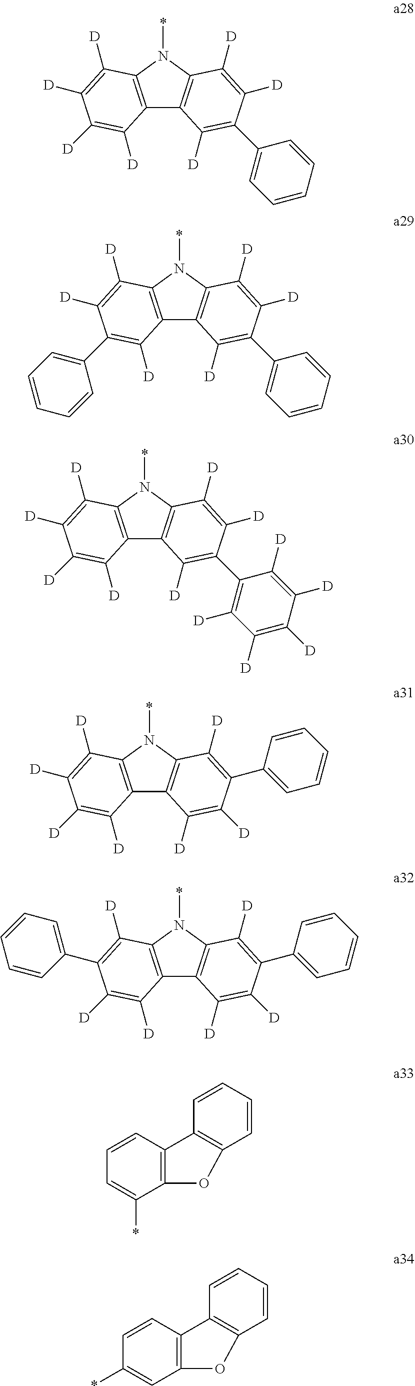

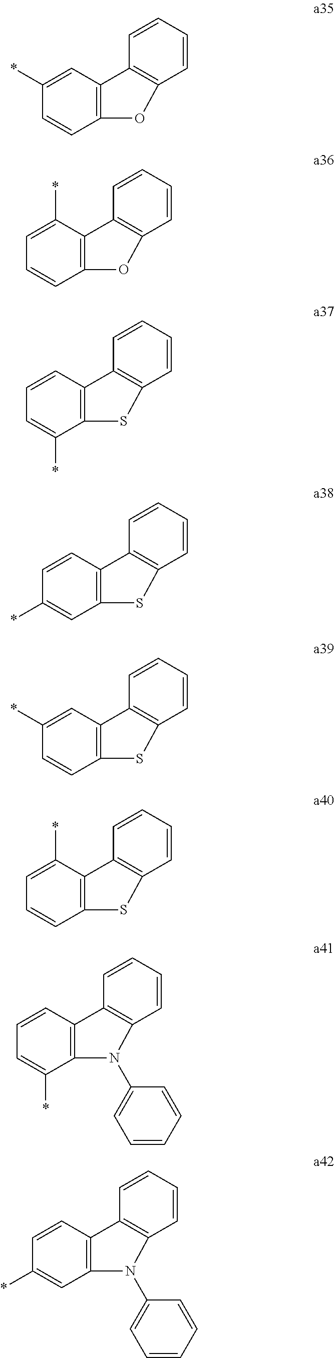

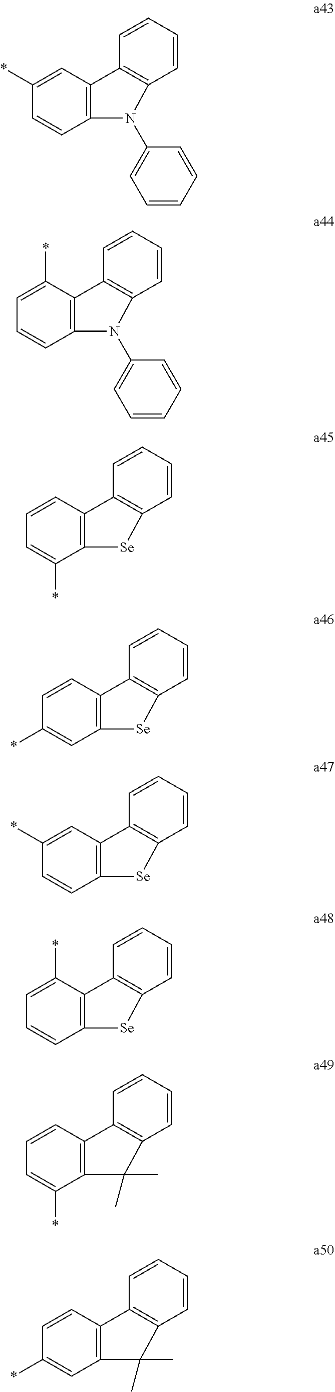

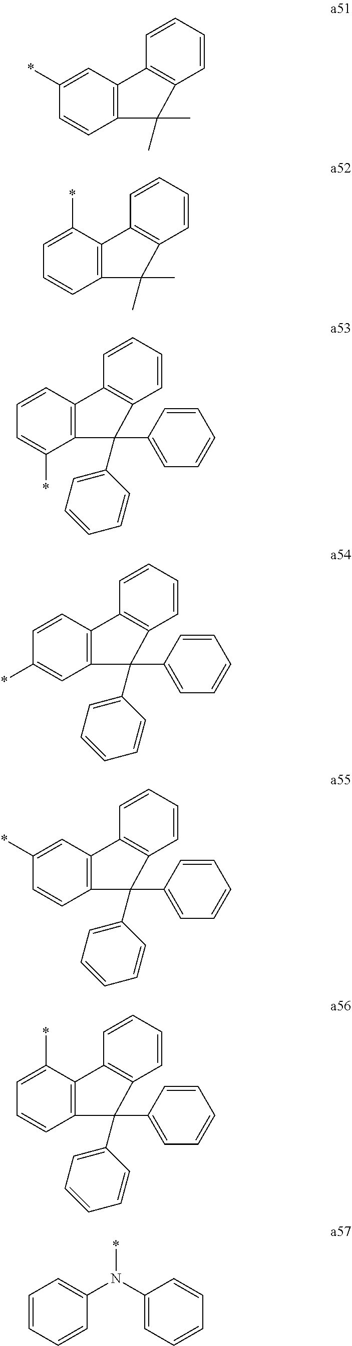

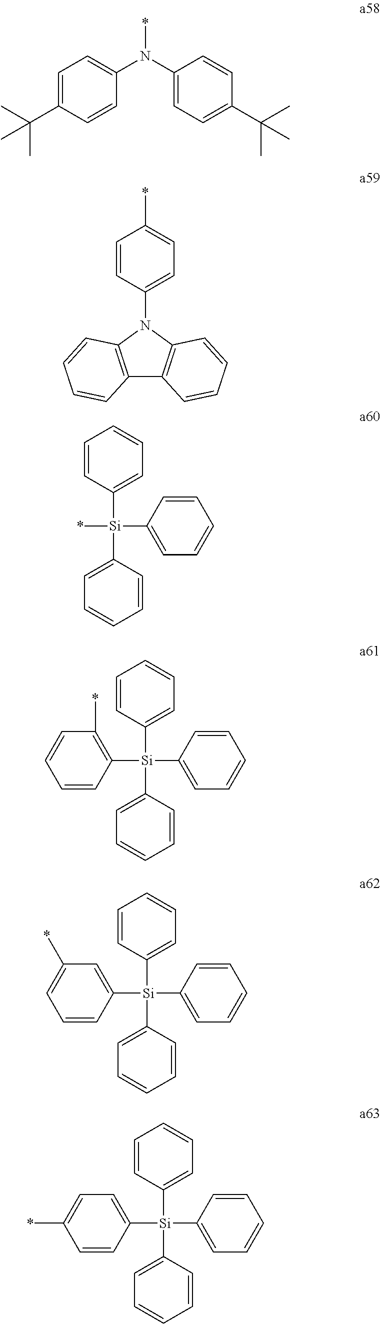

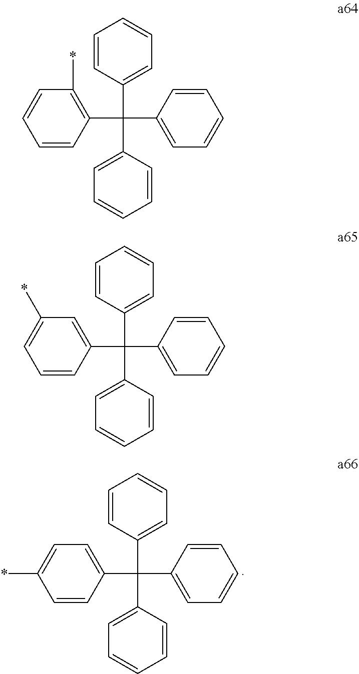

7. The light emitting element of claim 1, wherein the first compound is represented by Formula 6-1 or Formula 6-2: 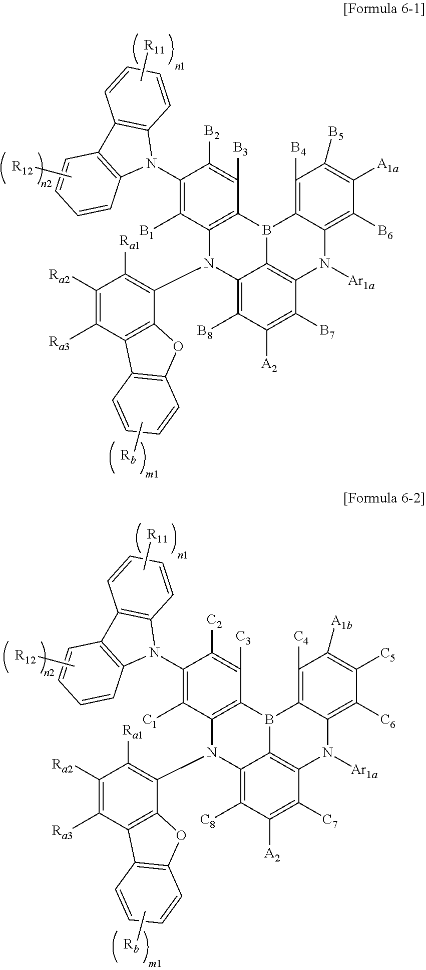
wherein in Formula 6-1 and Formula 6-2,
A₁ₐ and A_{1b} are each independently a cyano group, a substituted or unsubstituted amine group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms,
A₂ is a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms,
B₁ to B₈ and C₁ to C₈ are each independently a hydrogen atom or a deuterium atom, and
Ar₁ₐ is a group represented by Formula B-1 or Formula B-2: 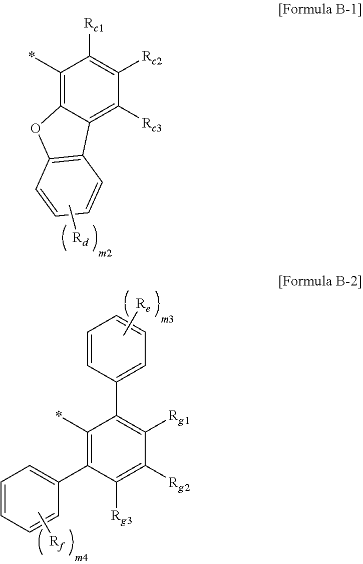
wherein in Formula B-1 and Formula B-2,
R_{c1} to R_{c3}, R_{d}, Rₑ, R_{f}, and R_{g1} to R_{g3} are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m2 is an integer from 0 to 4, and
m3 and m4 are each independently an integer from 0 to 5,
wherein in Formula B-1,
at least one of R_{c1} to R_{c3} is each independently a substituted or unsubstituted aryl group of 6 to 30 ring-forming carbon atoms, or a substituted or unsubstituted heteroaryl group of 2 to 30 ring-forming carbon atoms, and
wherein in Formula 6-1 and Formula 6-2,
R₁₁, R₁₂, Rₐ₁ to Rₐ₃, R_{b}, m1, n1, and n2 are the same as defined in Formula 1.

8. The light emitting element of claim 1, wherein the first compound is represented by Formula 7-1 or Formula 7-2: 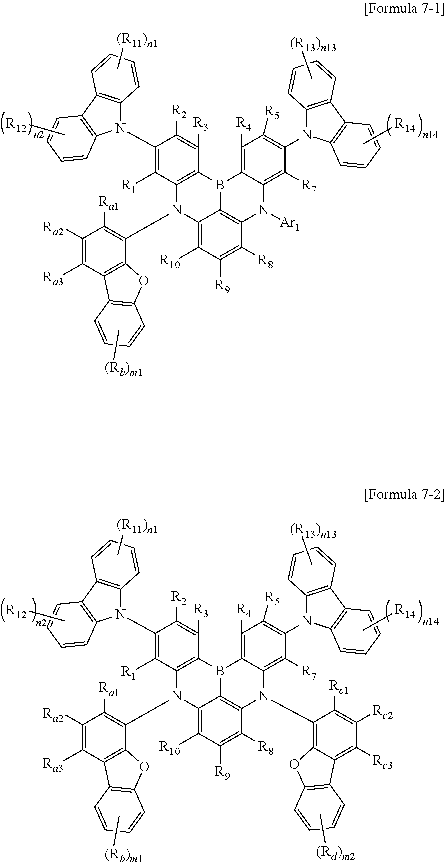
wherein in Formula 7-1 and Formula 7-2,
R₁₃, R₁₄, R_{c1} to R_{c3}, and R_{d} are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n13, n14, and m2 are each independently an integer from 0 to 4, and
Ar₁, R₁ to R₅, R₇ to R₁₂, Rₐ₁ to Rₐ₃, R_{b}, m1, n1, and n2 are the same as defined in Formula 1.

9. The light emitting element of claim 1, wherein the emission layer further comprises at least one of a second compound represented by Formula HT-1, a third compound represented by Formula ET-1, and a fourth compound represented by Formula D-1: 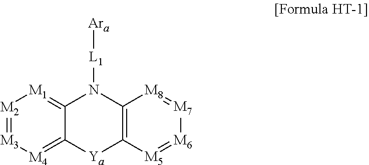
wherein in Formula HT-1,
M₁ to M₈ are each independently N or C(R₅₁),
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, C(R₅₂)(R₅₃), or Si(R₅₄)(R₅₅),
Arₐ is a substituted or unsubstituted aryl group of 6 to 30 ring-forming carbon atoms or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring; 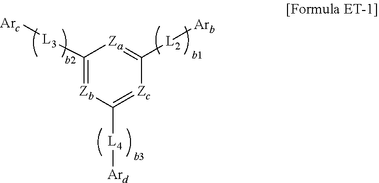
wherein in Formula ET-1,
at least one of Zₐ to Z_{c} is N,
the remainder of Zₐ to Z_{c} are each independently C(R₅₆),
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer from 0 to 10,
Ar_{b} to Ar_{d} are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms; and 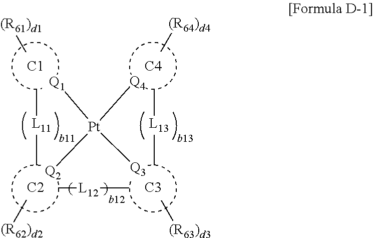
wherein in Formula D-1,
Q₁ to Q₄ are each independently C or N,
C1 to C4 are each independently a substituted or unsubstituted hydrocarbon ring of 5 to 30 ring-forming carbon atoms or a substituted or unsubstituted heterocycle of 2 to 30 ring-forming carbon atoms,
L₁₁ to L₁₃ are each independently a direct linkage, 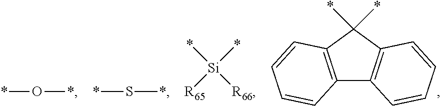
a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and
d1 to d4 are each independently an integer from 0 to 4.

10. A display device comprising:
a circuit layer disposed on a base layer; and
a display device layer disposed on the circuit layer and comprising a light emitting element, wherein
the light emitting element comprises:
a first electrode;
a second electrode disposed on the first electrode; and
an emission layer disposed between the first electrode and the second electrode and comprising a first compound represented by Formula 1: 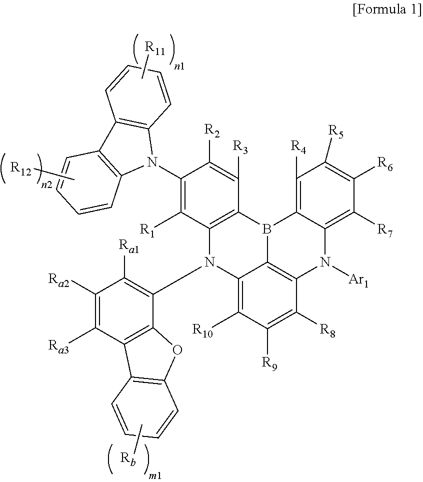
wherein in Formula 1,
R₁ to R₁₀ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
Rₐ₁ to Rₐ₃ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
except that at least one of Rₐ₁ to R₃ is each independently a substituted or unsubstituted aryl group of 6 to 30 ring-forming carbon atoms or a substituted or unsubstituted heteroaryl group of 2 to 30 ring-forming carbon atoms,
R_{b}, R₁₁, and R₁₂ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
Ar₁ is a substituted or unsubstituted aryl group of 6 to 30 ring-forming carbon atoms or a substituted or unsubstituted heteroaryl group of 2 to 30 ring-forming carbon atoms, and
m1, n1, and n2 are each independently an integer from 0 to 4.

11. The display device of claim 10, wherein
the light emitting element further comprises a capping layer disposed on the second electrode, and
a refractive index of the capping layer is greater than or equal to about 1.6, with respect to light in a wavelength range of about 550 nm to about 660 nm.

12. The display device of claim 11, wherein
the display device further comprises a light controlling layer disposed on the display device layer and comprising a quantum dot,
the light emitting element emits first color light, and
the light controlling layer comprises:
a first light controlling part comprising a first quantum dot that converts the first color light into second color light in a wavelength region that is greater than the first color light;
a second light controlling part comprising a second quantum dot that converts the first color light into third color light in a wavelength region that is greater than the first color light and the second color light; and
a third light controlling part that transmits the first color light.

13. The display device of claim 12, wherein
the display device further comprises a color filter layer disposed on the light controlling layer, and
the color filter layer comprises:
a first filter transmitting the second color light;
a second filter transmitting the third color light; and
a third filter transmitting the first color light.

14. A fused polycyclic compound represented by Formula 1: 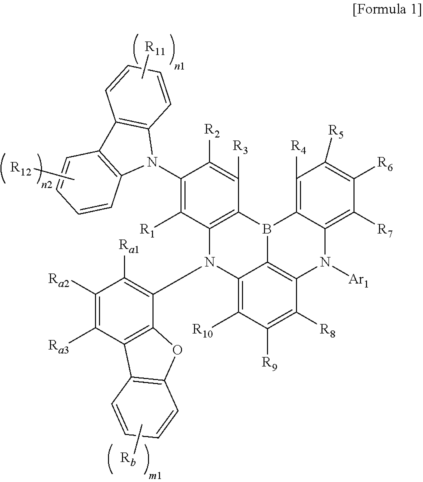
wherein in Formula 1,
R₁ to R₁₀ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
Rₐ₁ to Rₐ₃ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
except that at least one of Rₐ₁ to R₃ is each independently a substituted or unsubstituted aryl group of 6 to 30 ring-forming carbon atoms or a substituted or unsubstituted heteroaryl group of 2 to 30 ring-forming carbon atoms,
R_{b}, R₁₁, and R₁₂ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
Ar₁ is a substituted or unsubstituted aryl group of 6 to 30 ring-forming carbon atoms or a substituted or unsubstituted heteroaryl group of 2 to 30 ring-forming carbon atoms, and
m1, n1, and n2 are each independently an integer from 0 to 4.

15. The fused polycyclic compound of claim 14, wherein the fused polycyclic compound is represented by Formula 4-1 or Formula 4-2: 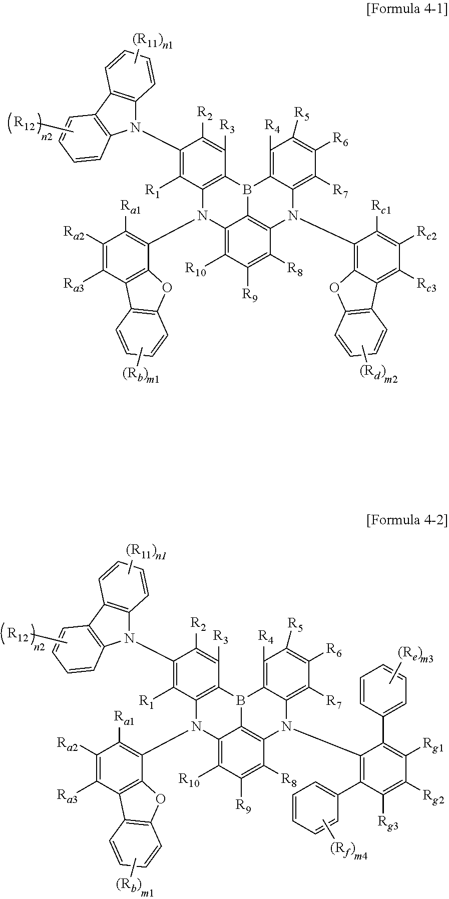
wherein in Formula 4-1 and Formula 4-2,
R_{c1} to R_{c3}, R_{d}, Rₑ, R_{f}, and R_{g1} to R_{g3} are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m2 is an integer from 0 to 4, and
m3 and m4 are each independently an integer from 0 to 5,
wherein in Formula 4-1,
at least one of R_{c1} to R_{c3} is each independently a substituted or unsubstituted aryl group of 6 to 30 ring-forming carbon atoms or a substituted or unsubstituted heteroaryl group of 2 to 30 ring-forming carbon atoms, and
wherein in Formula 4-1 and Formula 4-2,
R₁ to R₁₂, Rₐ₁ to Rₐ₃, R_{b}, m1, n1, and n2 are the same as defined in Formula 1.

16. The fused polycyclic compound of claim 14, wherein the fused polycyclic compound is represented by Formula 5: 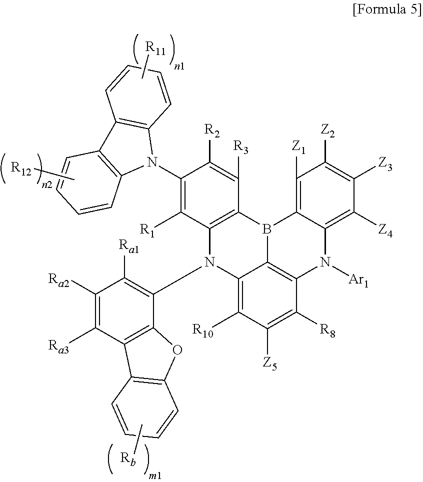
wherein in Formula 5,
Z₁ to Z₅ are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
except that at least one of Z₁ to Z₅ is each independently a substituted or unsubstituted alkyl group of 1 to 10 carbon atoms, or a group represented by one of Formula A-1 to Formula A-5: 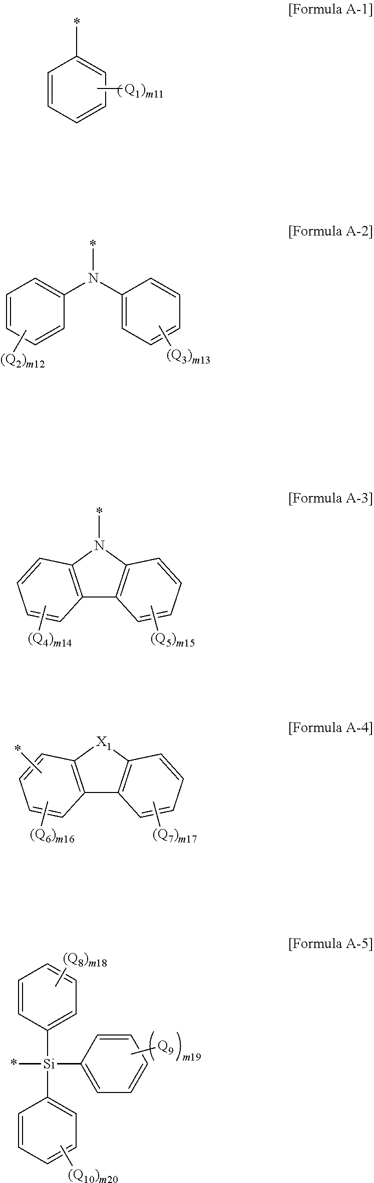
wherein in Formula A-1 to Formula A-5,
X₁ is O, S, Se, N(Q₁₁), or C(Q₁₂)(Q₁₃),
Q₁ to Q₁₃ are each independently a hydrogen atom, a deuterium atom, a halogen atom, a cyano group, a substituted or unsubstituted silyl group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11 to m13 and m18 to m20 are each independently an integer from 0 to 5,
m14, m15, and m17 are each independently an integer from 0 to 4, and
m16 is an integer from 0 to 3, and
wherein in Formula 5,
Ar₁, R₁ to R₃, R₈, R₁₀ to R₁₂, Rₐ₁ to Rₐ₃, R_{b}, m1, n1, and n2 are the same as defined in Formula 1.

17. The fused polycyclic compound of claim 14, wherein the fused polycyclic compound is represented by Formula 6-1 or Formula 6-2: 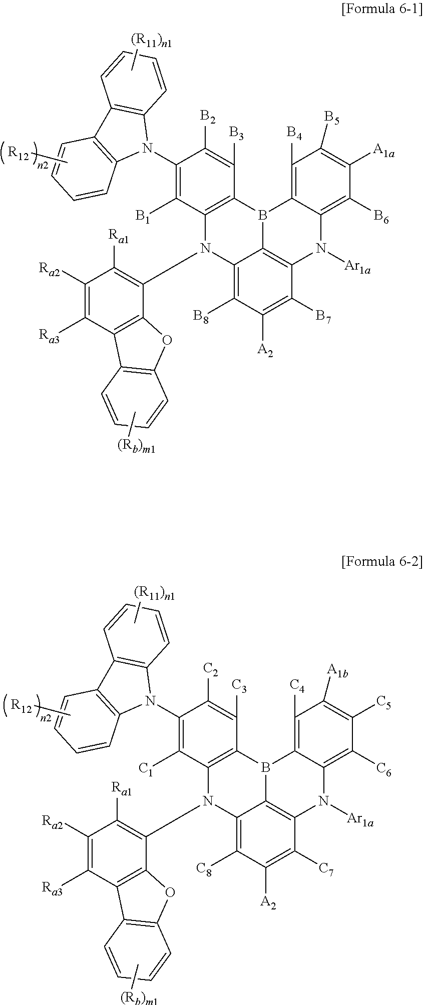
wherein in Formula 6-1 and Formula 6-2,
A₁ₐ and A_{1b} are each independently a cyano group, a substituted or unsubstituted amine group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms,
A₂ is a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms,
B₁ to B₈ and C₁ to C₈ are each independently a hydrogen atom, or a deuterium atom, and
Ar₁ₐ is a group represented by Formula B-1 or Formula B-2: 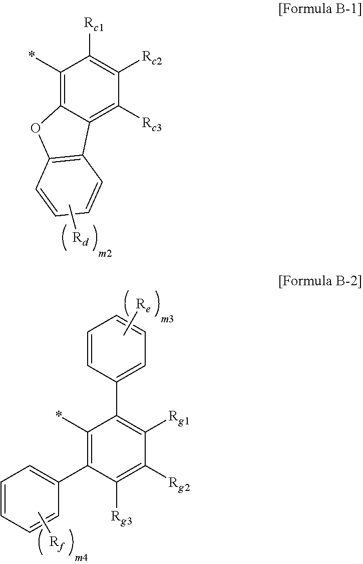
wherein in Formula B-1 and Formula B-2,
R_{c1} to R_{c3}, R_{d}, Rₑ, R_{f}, and R_{g1} to R_{g3} are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m2 is an integer from 0 to 4, and
m3 and m4 are each independently an integer from 0 to 5,
wherein in Formula B-1,
at least one of R_{c1} to R_{c3} is each independently a substituted or unsubstituted aryl group of 6 to 30 ring-forming carbon atoms or a substituted or unsubstituted heteroaryl group of 2 to 30 ring-forming carbon atoms, and
wherein in Formula 6-1 and Formula 6-2,
R₁₁, R₁₂, Rₐ₁ to Rₐ₃, R_{b}, m1, n1, and n2 are the same as defined in Formula 1.

18. The fused polycyclic compound of claim 14, wherein the fused polycyclic compound is represented by Formula 7-1 or Formula 7-2: 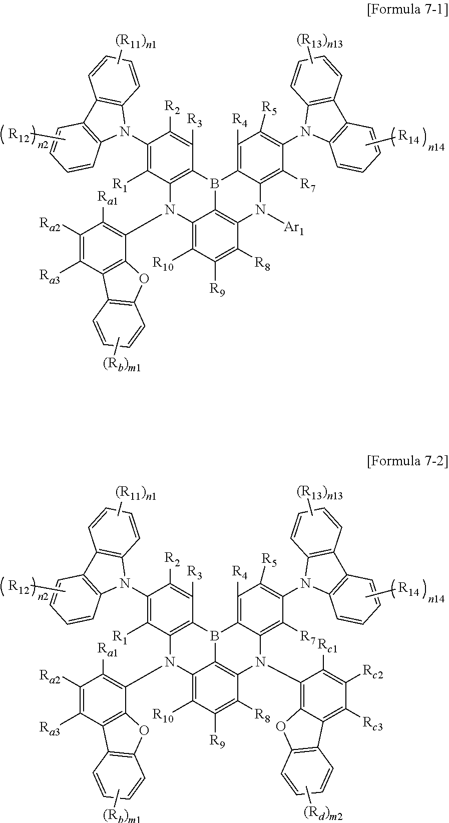
wherein in Formula 7-1 and Formula 7-2,
R₁₃, R₁₄, R_{c1} to R_{c3}, and R_{d} are each independently a hydrogen atom, a deuterium atom, a halogen atom, a cyano group, a nitro group, a hydroxyl group, a substituted or unsubstituted silyl group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n13, n14, and m2 are each independently an integer from 0 to 4, and
Ar₁, R₁ to R₅, R₇ to R₁₂, Rₐ₁ to Rₐ₃, R_{b}, m1, n1, and n2 are the same as defined in Formula 1.

19. The fused polycyclic compound of claim 14, wherein at least one of R₁ to R₁₀ is each independently a group selected from Substituent Group 1:

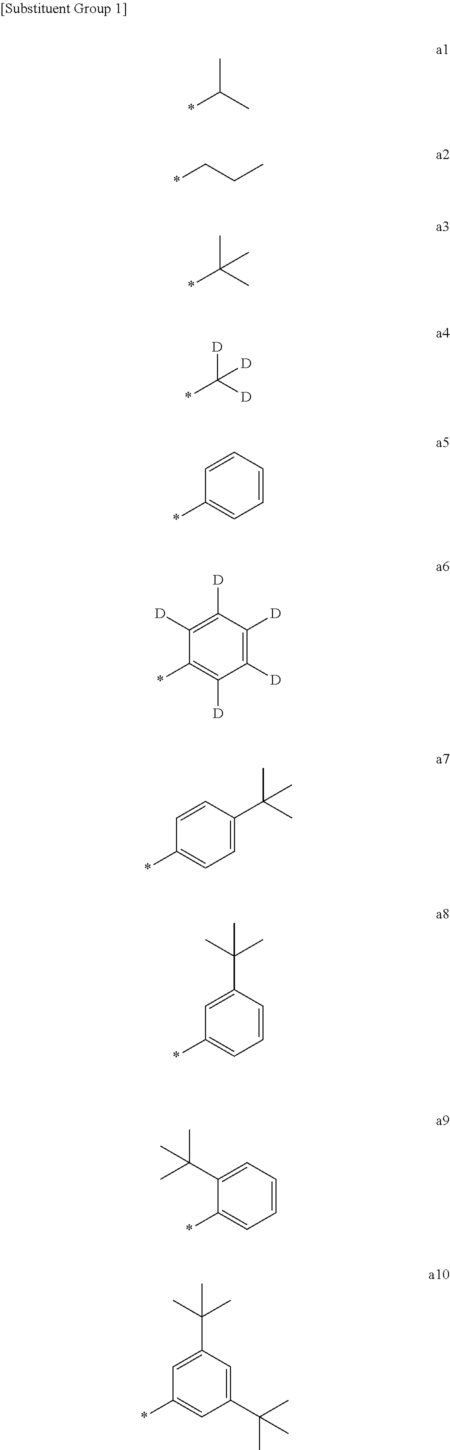

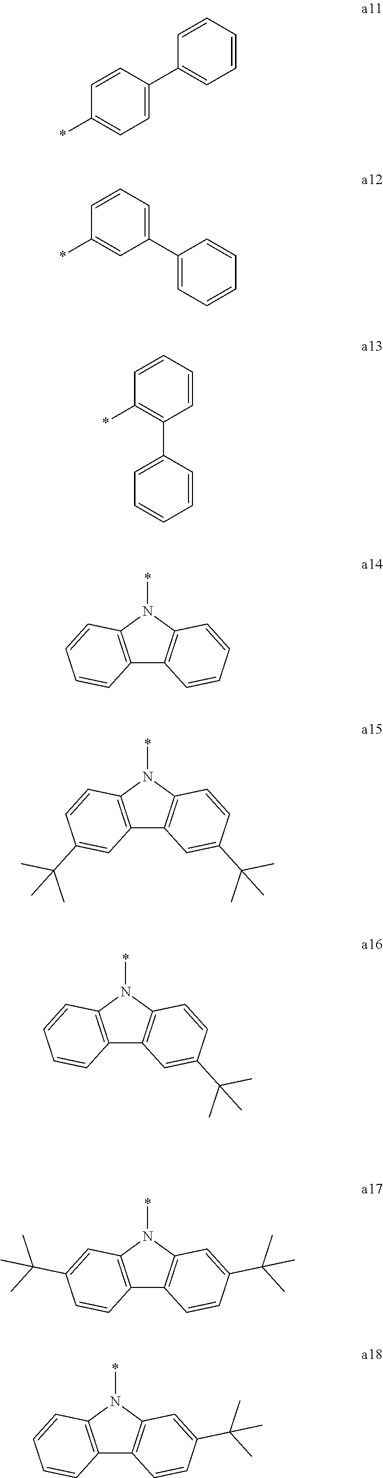

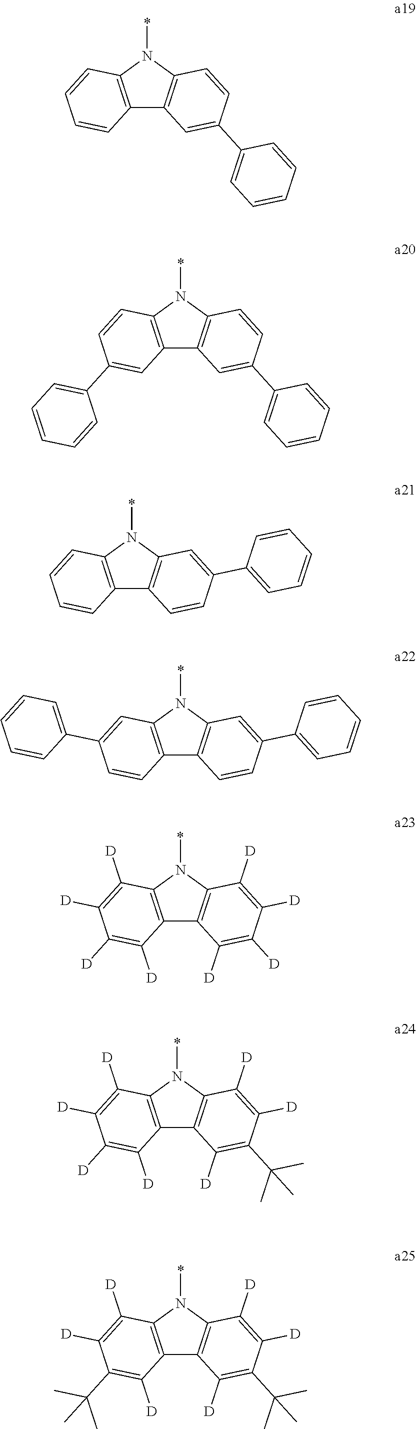

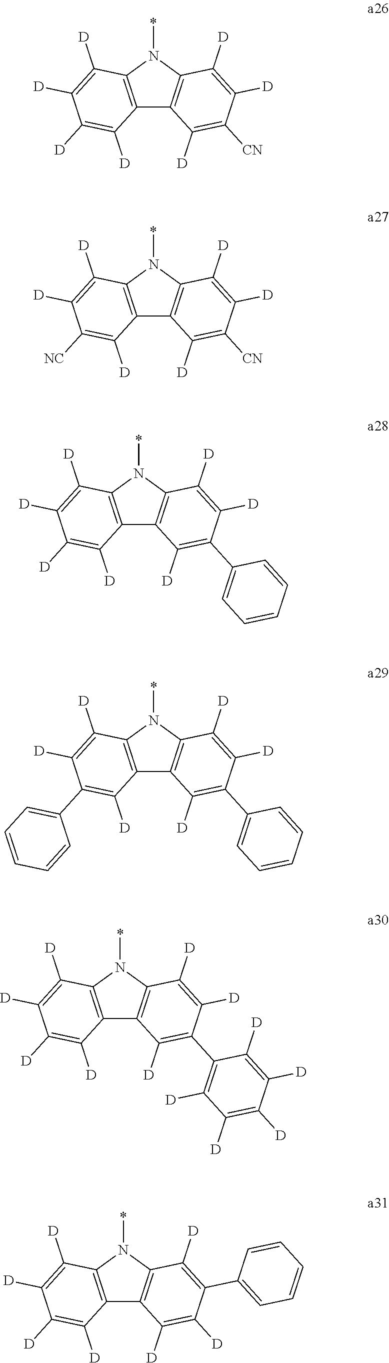 [SMILES: *n1c2c([2H])c([2H])c([2H])c([2H])c2c2c([2H])c(C#N)c([2H])c([2H])c21 ; *n1c2c([2H])c([2H])c(C#N)c([2H])c2c2c([2H])c(C#N)c([2H])c([2H])c21 ; *n1c2c([2H])c([2H])c([2H])c([2H])c2c2c([2H])c(-c3ccccc3)c([2H])c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *n1c2c([2H])c([2H])c([2H])c([2H])c2c2c([2H])c([2H])c(-c3ccccc3)c([2H])c21]

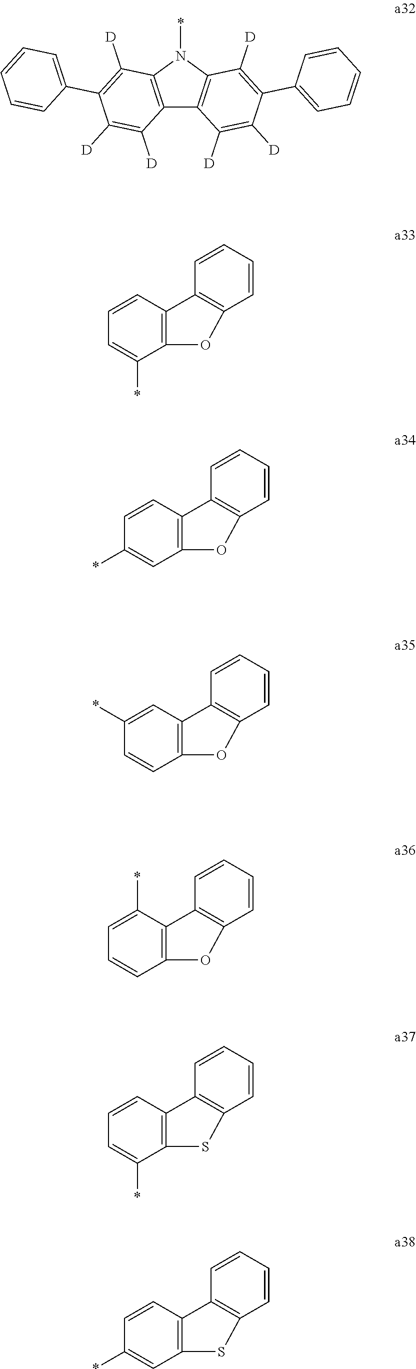

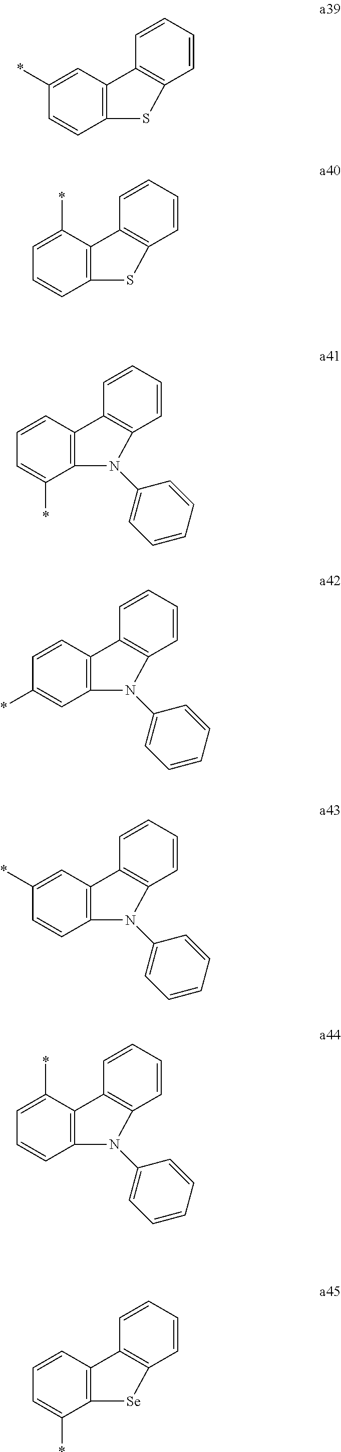

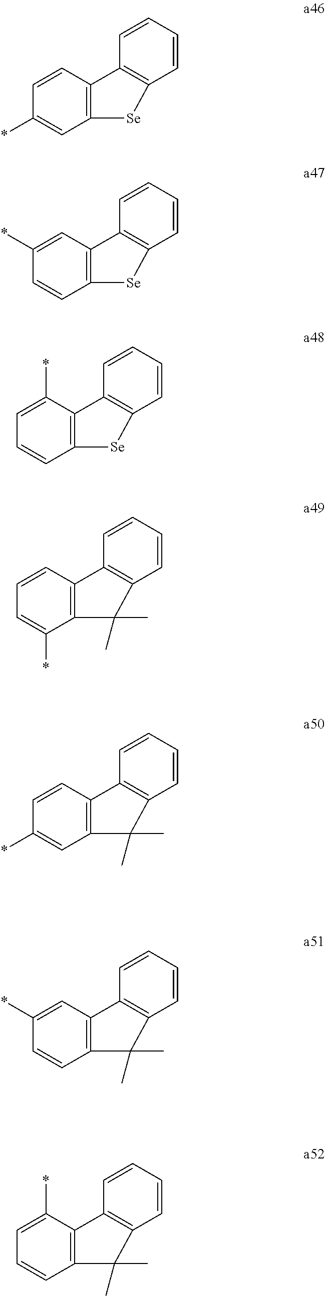

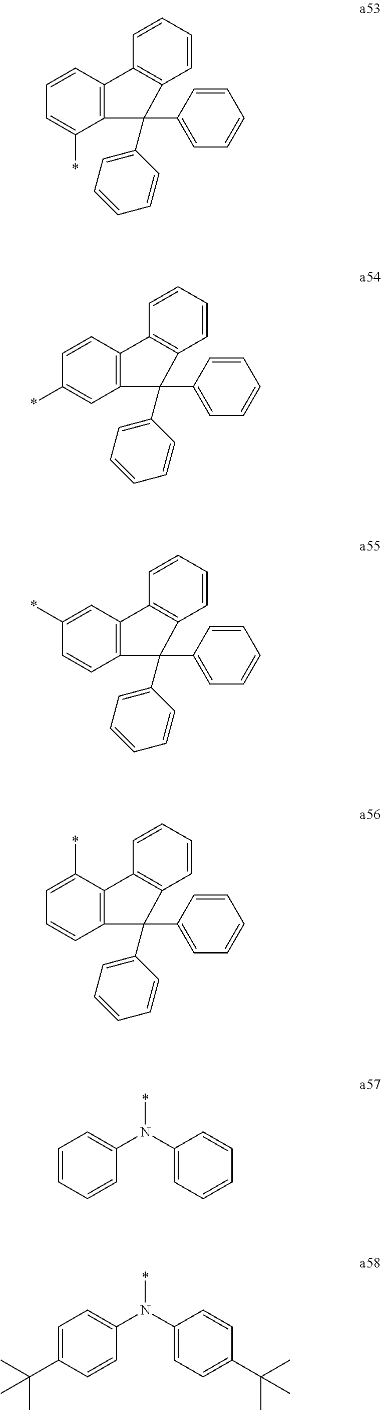 [SMILES: *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1 ; *N(c1ccccc1)c1ccccc1 ; *N(c1ccc(C(C)(C)C)cc1)c1ccc(C(C)(C)C)cc1]

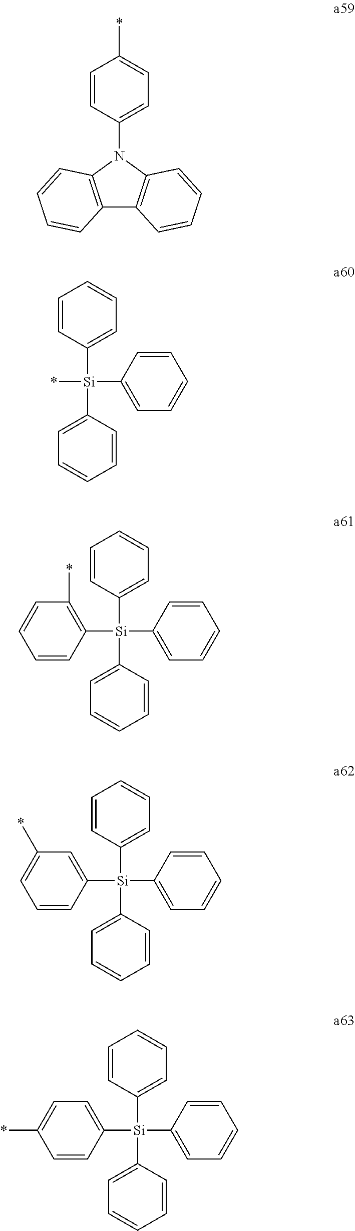 [SMILES: *c1ccc(-n2c3ccccc3c3ccccc32)cc1 ; *[Si](c1ccccc1)(c1ccccc1)c1ccccc1 ; *c1ccccc1[Si](c1ccccc1)(c1ccccc1)c1ccccc1 ; *c1cccc([Si](c2ccccc2)(c2ccccc2)c2ccccc2)c1 ; *c1ccc([Si](c2ccccc2)(c2ccccc2)c2ccccc2)cc1]

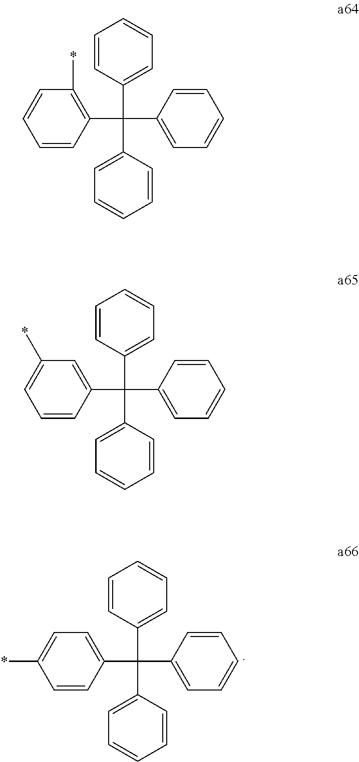 [SMILES: *c1ccccc1C(c1ccccc1)(c1ccccc1)c1ccccc1 ; *c1cccc(C(c2ccccc2)(c2ccccc2)c2ccccc2)c1 ; *c1ccc(C(c2ccccc2)(c2ccccc2)c2ccccc2)cc1]

20. The fused polycyclic compound of claim 14, wherein the fused polycyclic compound is selected from Compound Group 1: 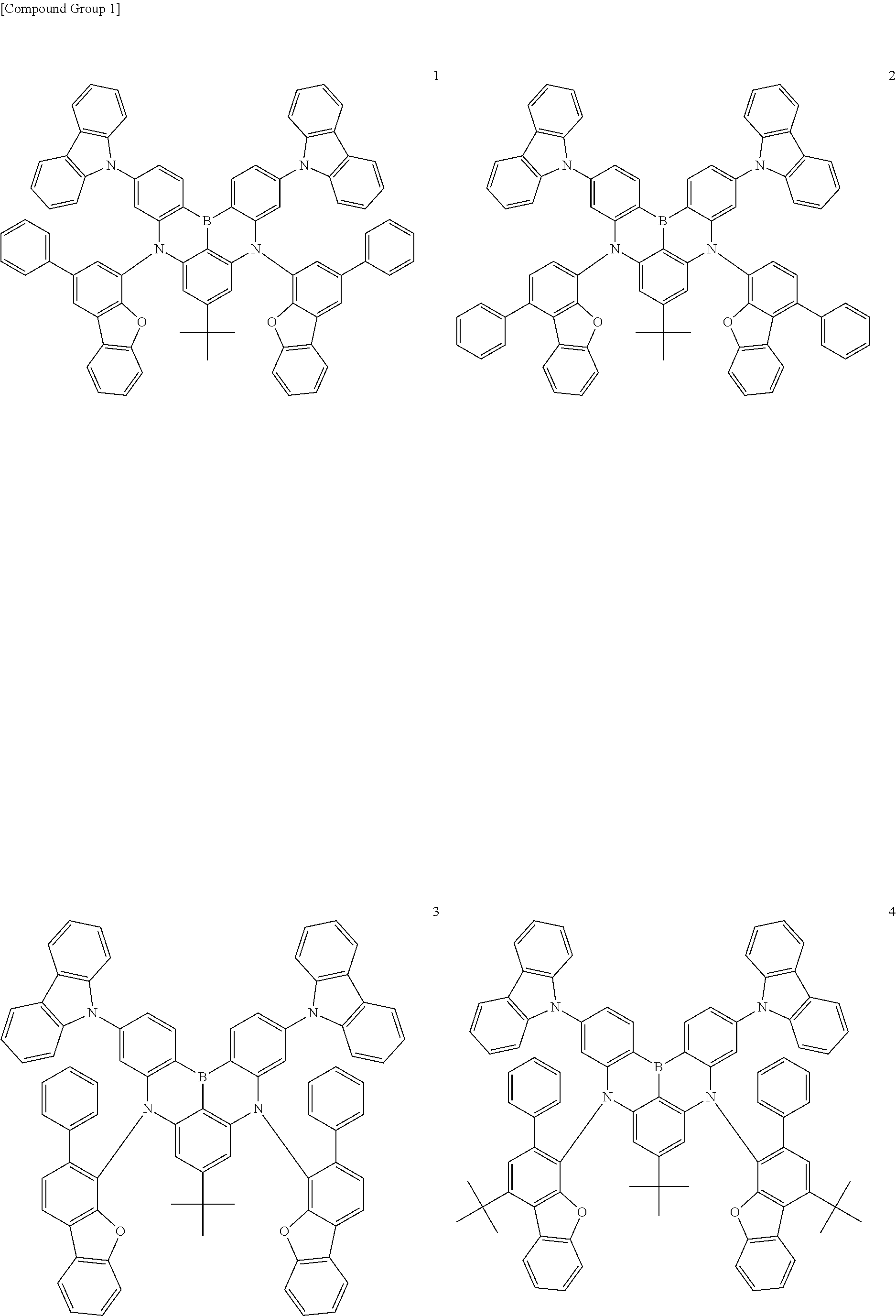 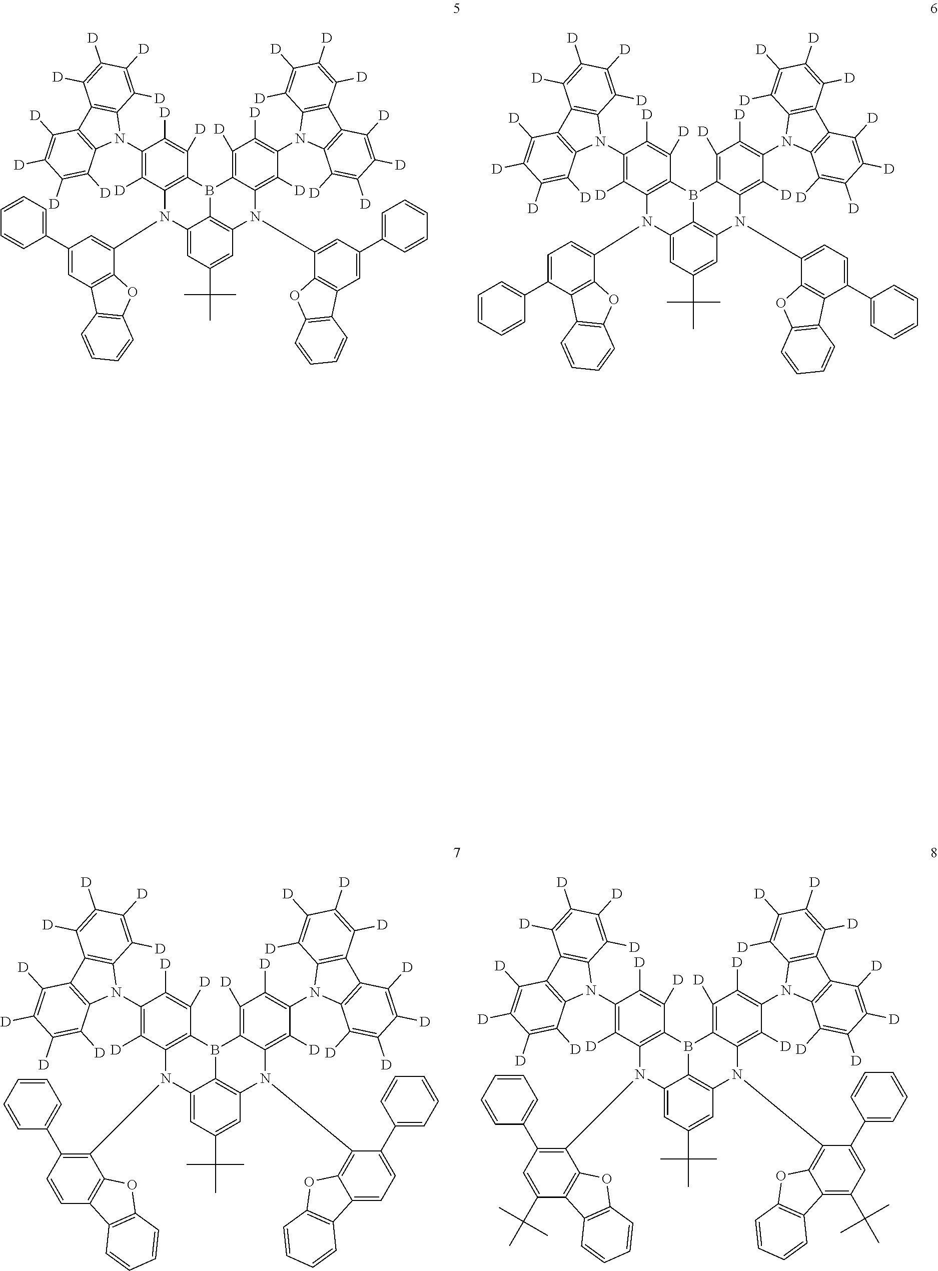 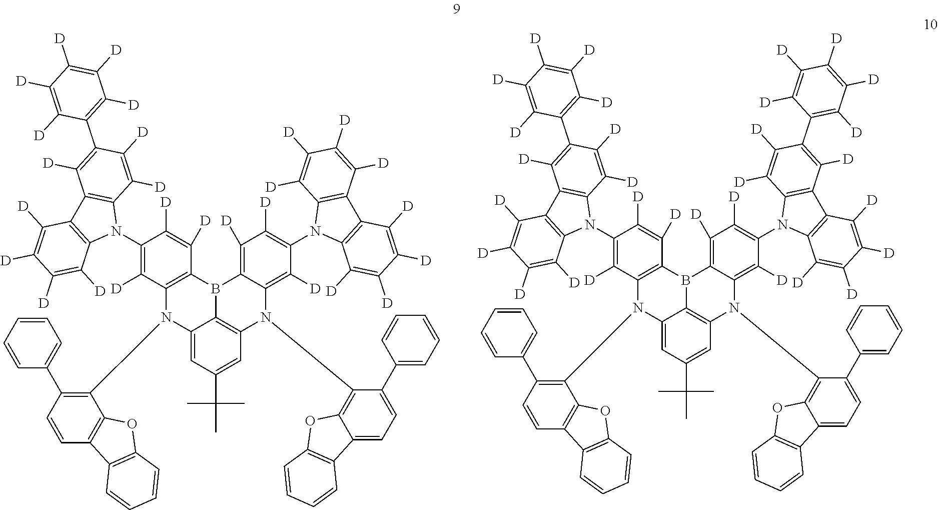 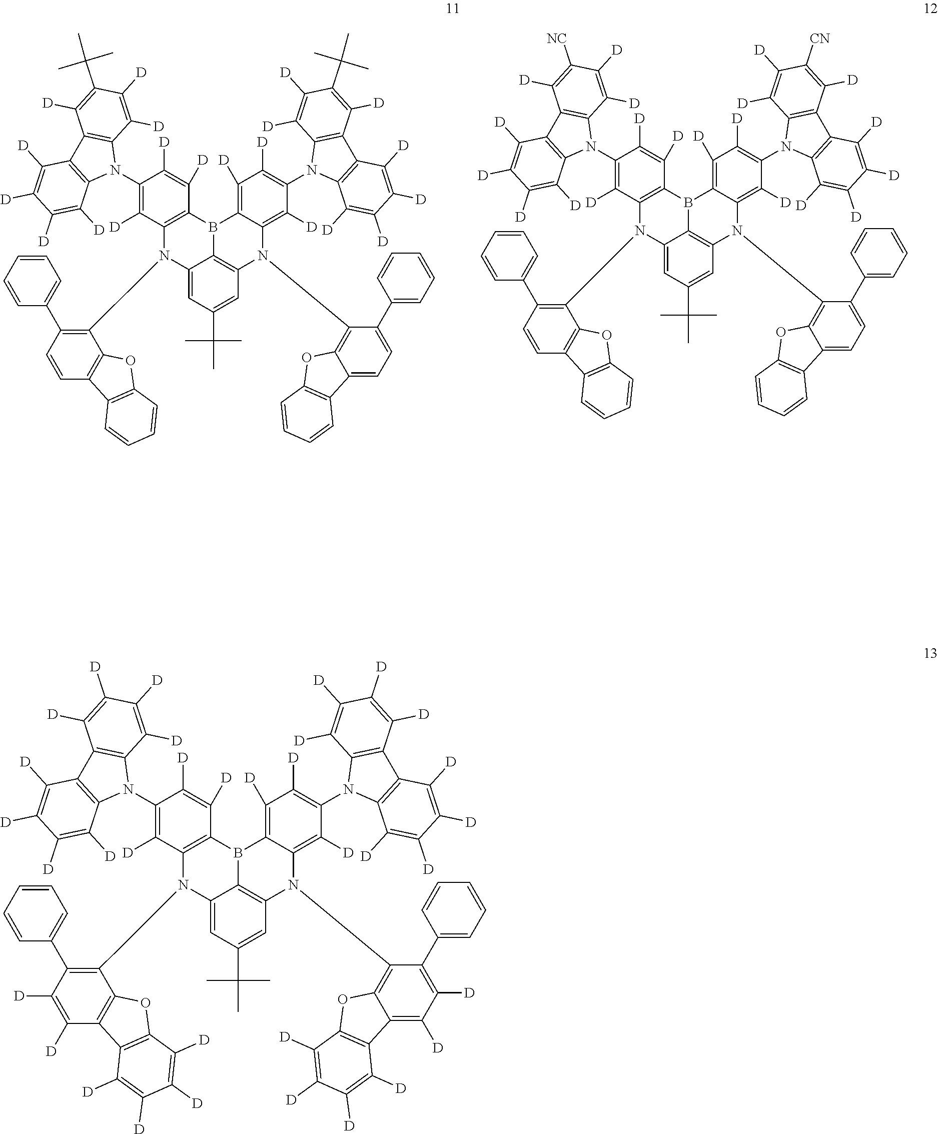 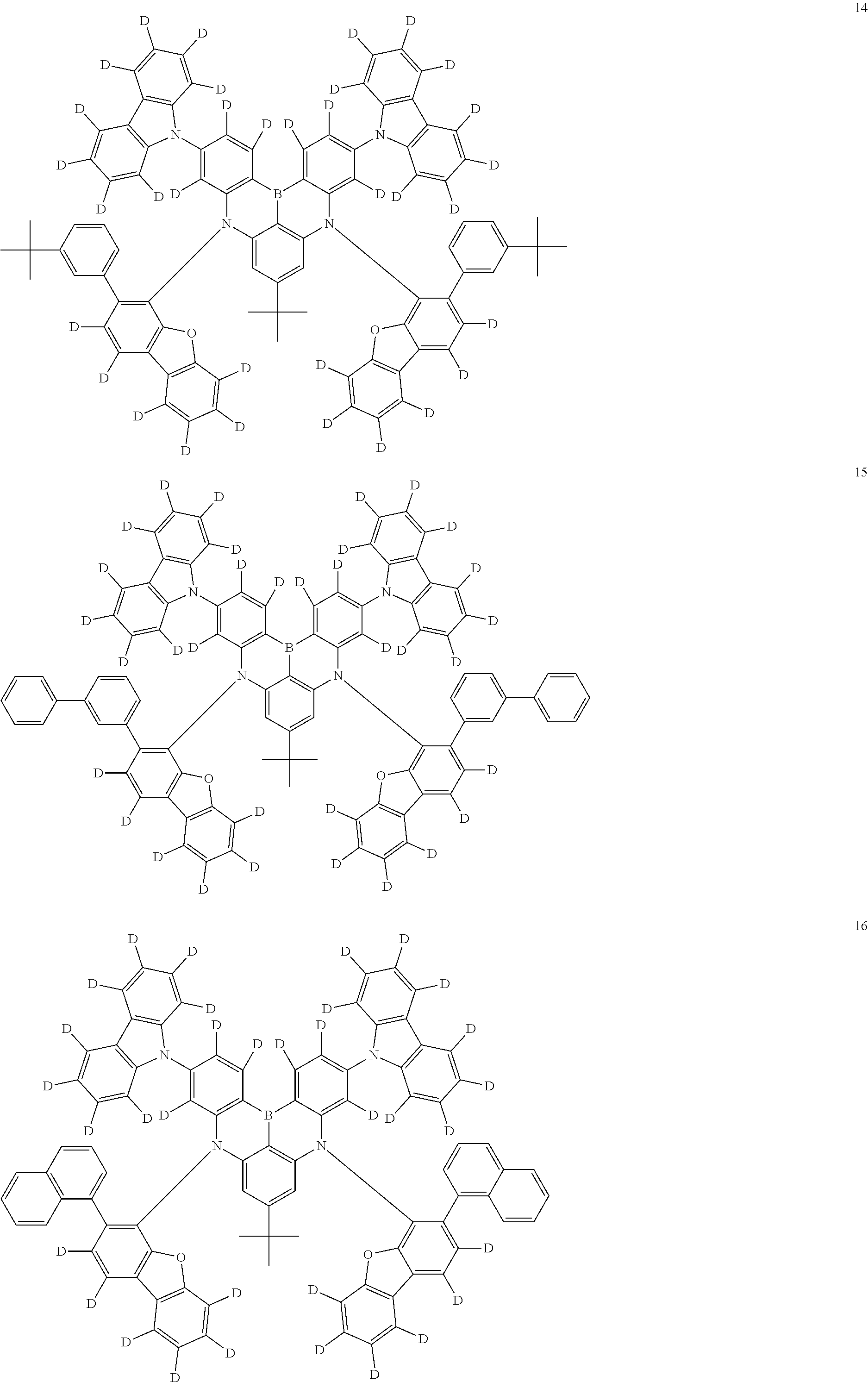 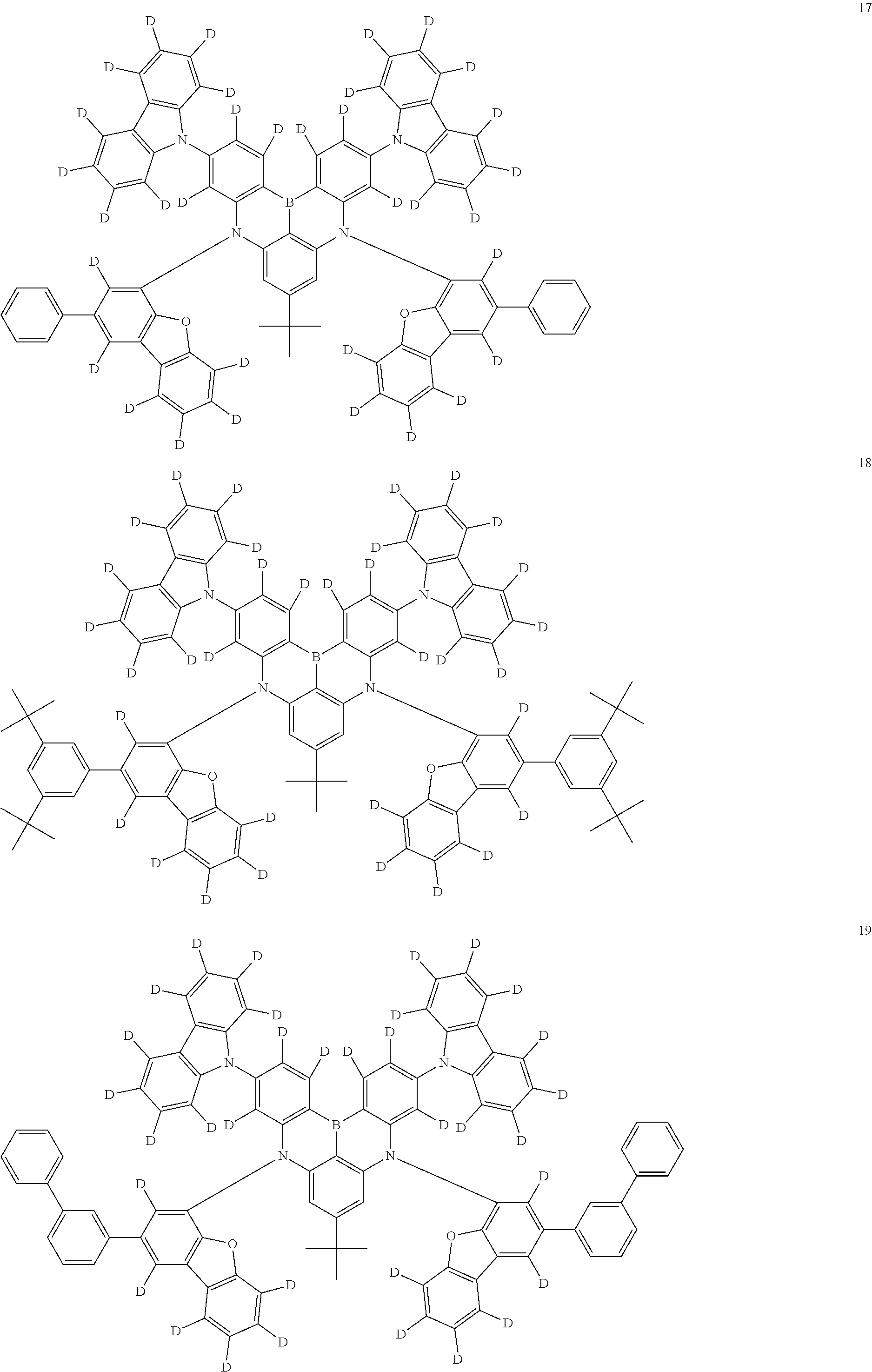 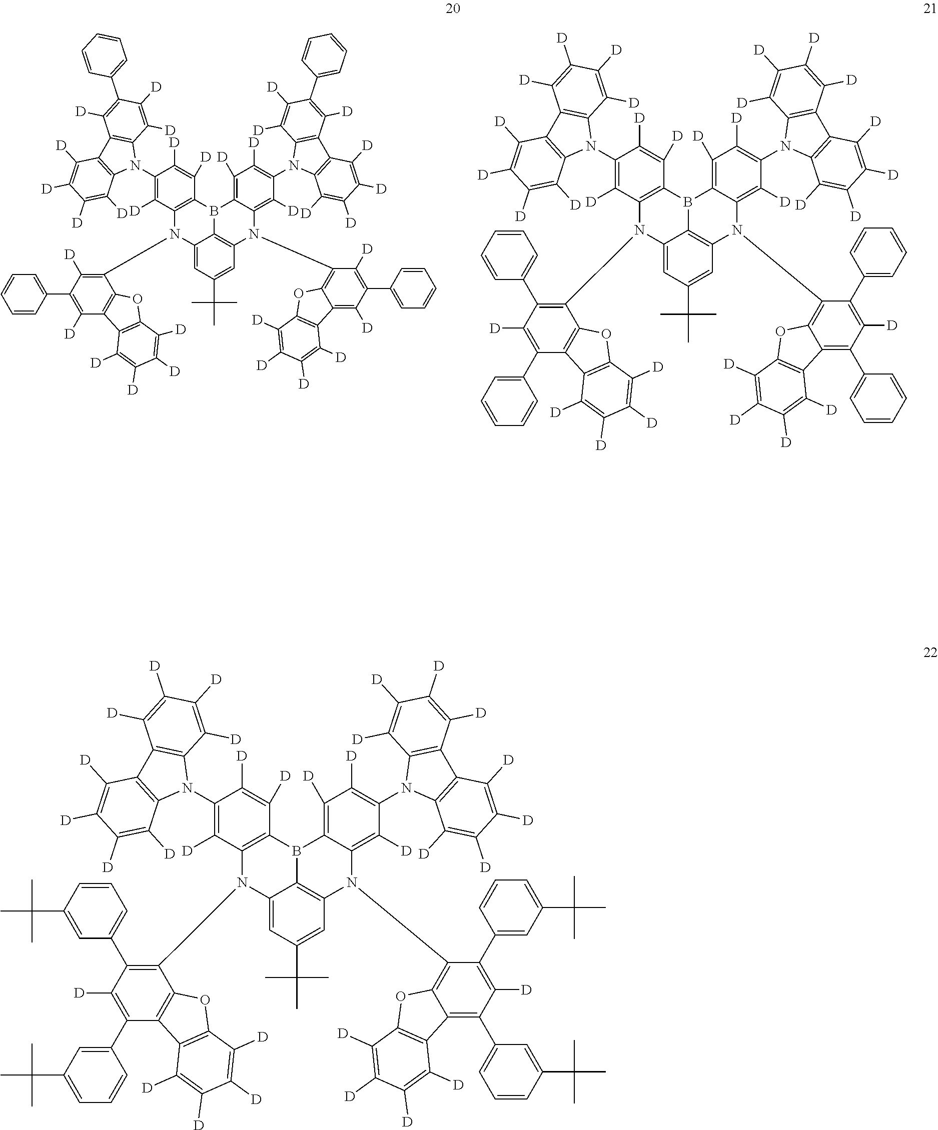 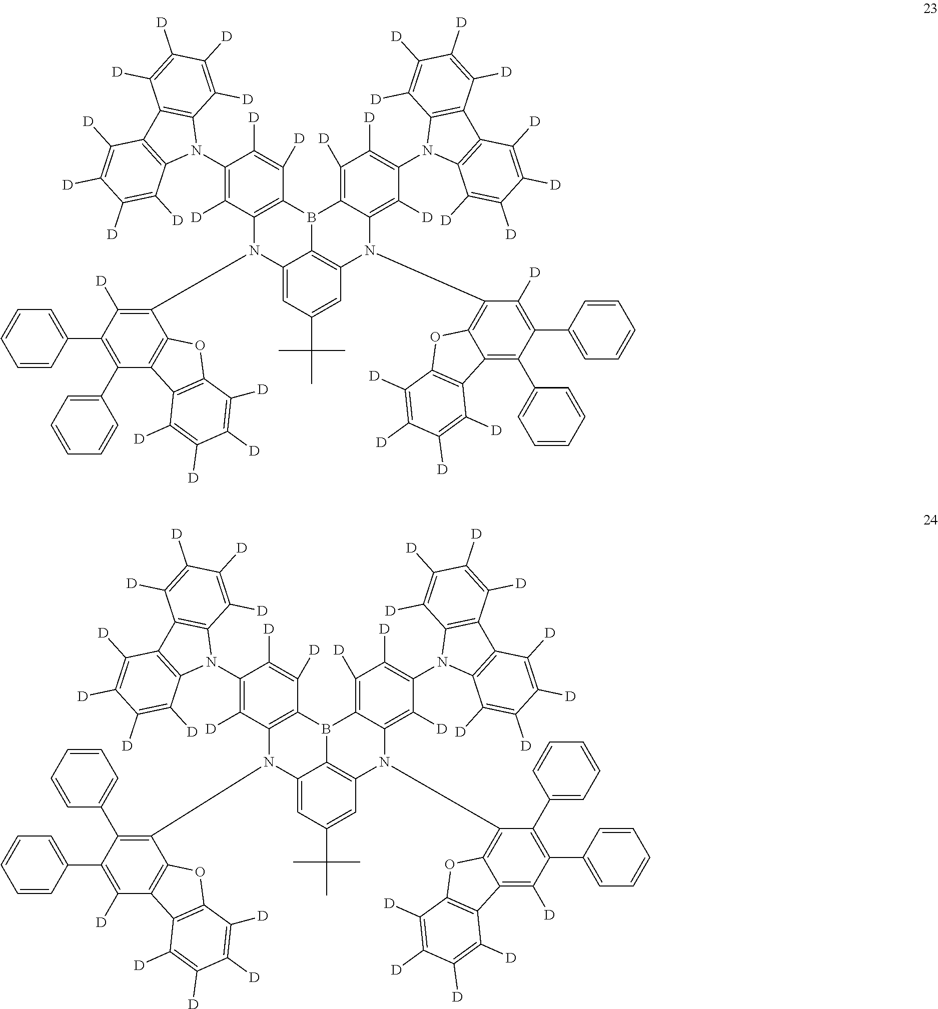 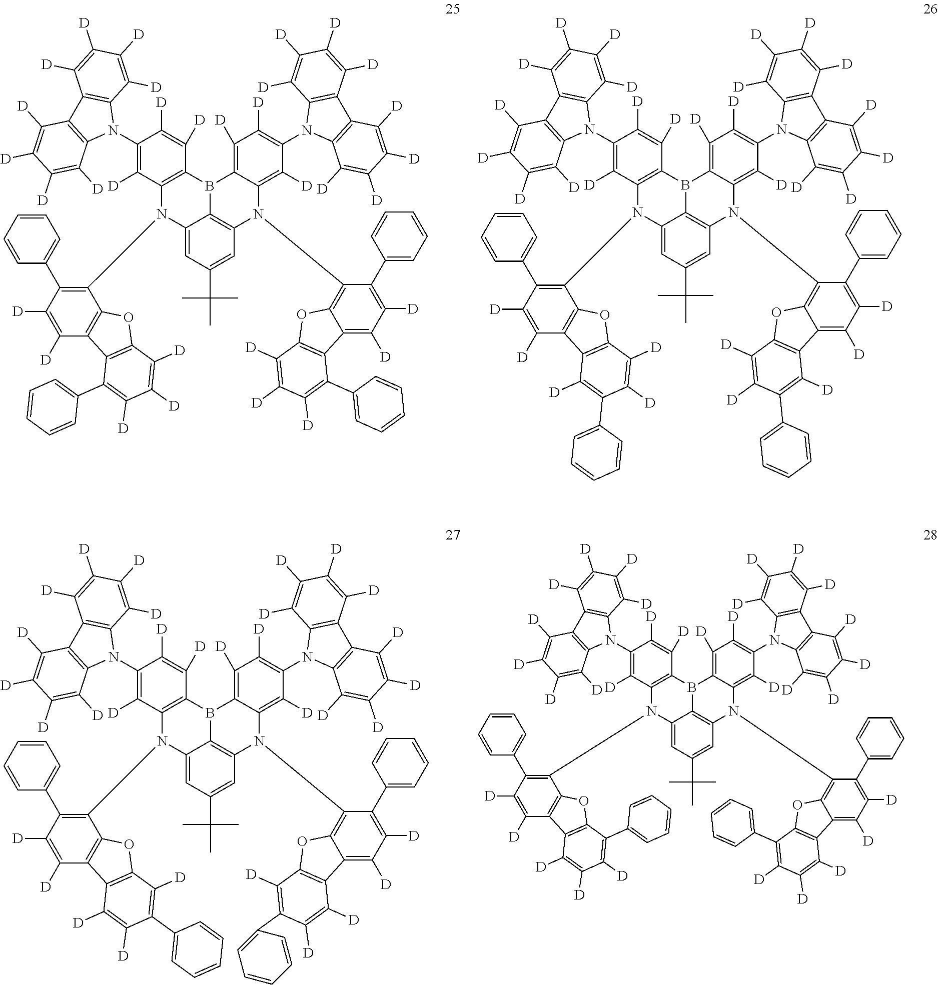 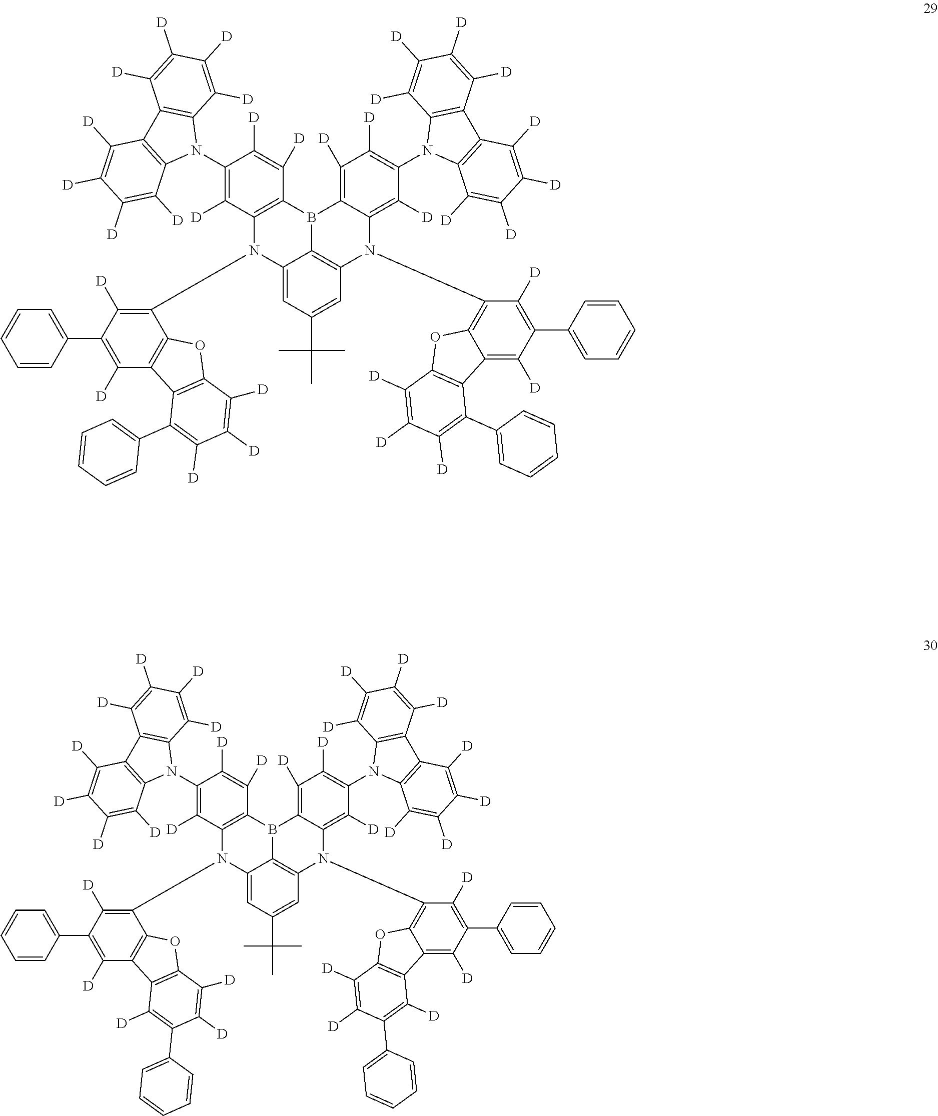 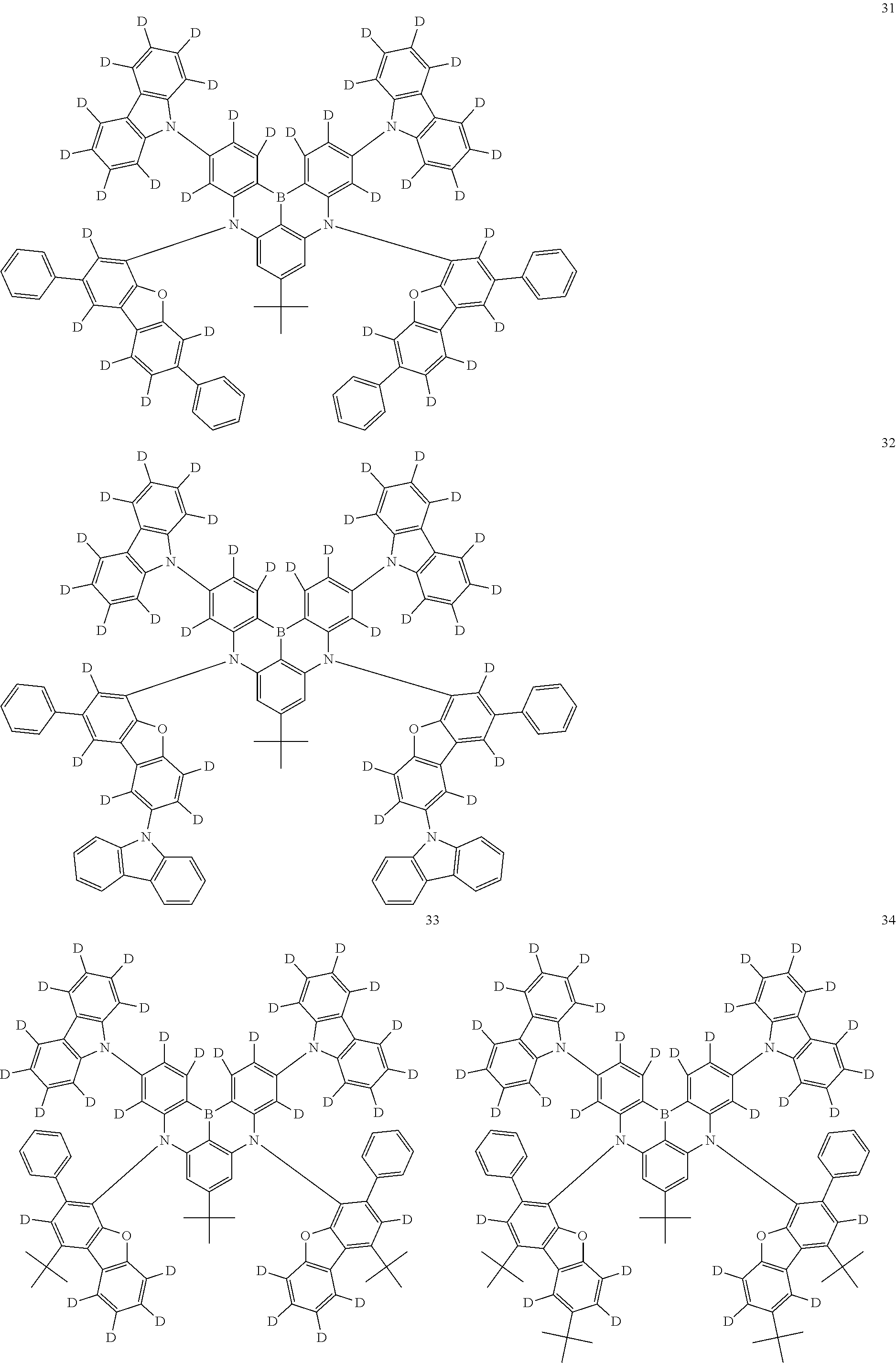 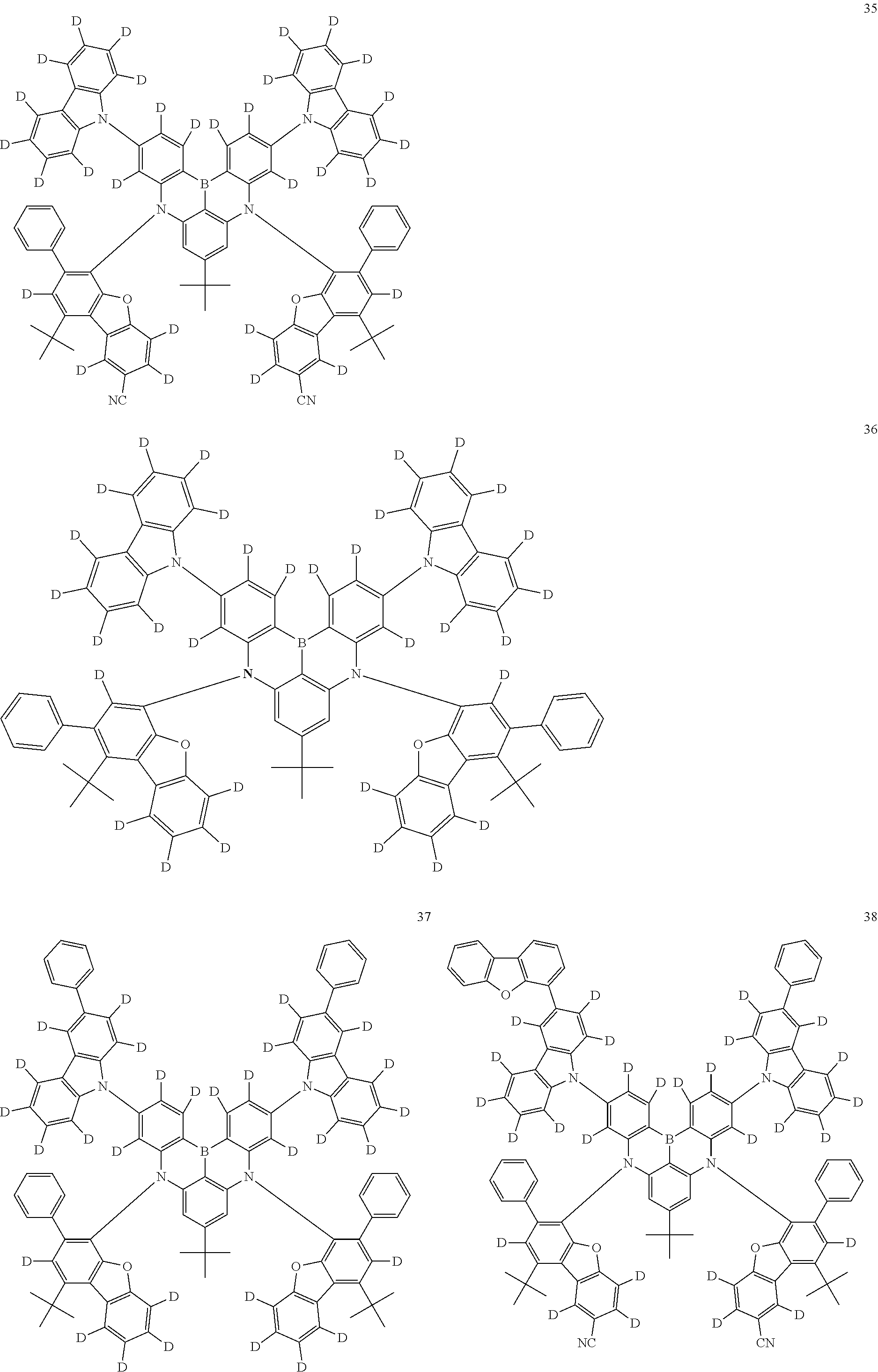 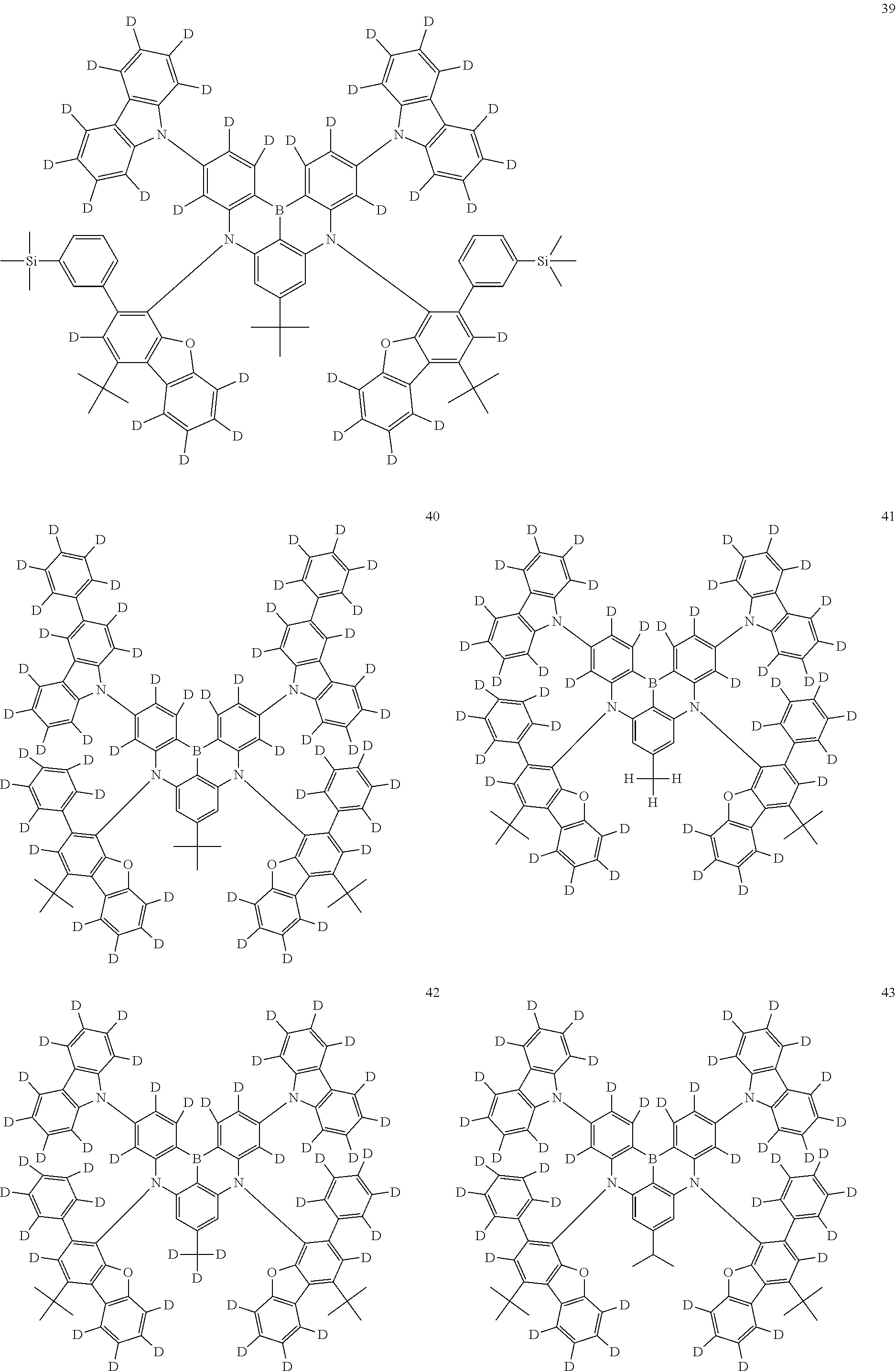 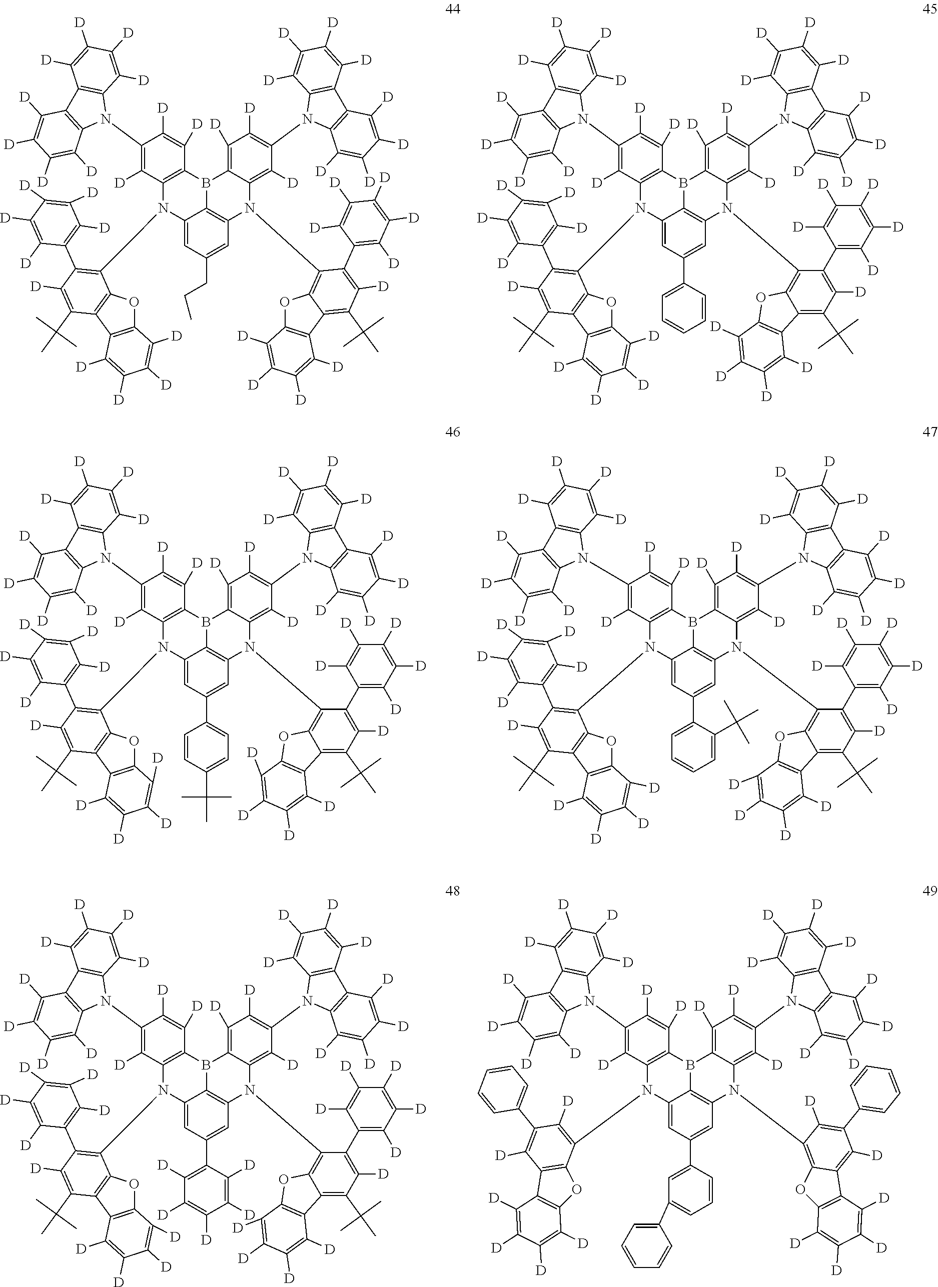 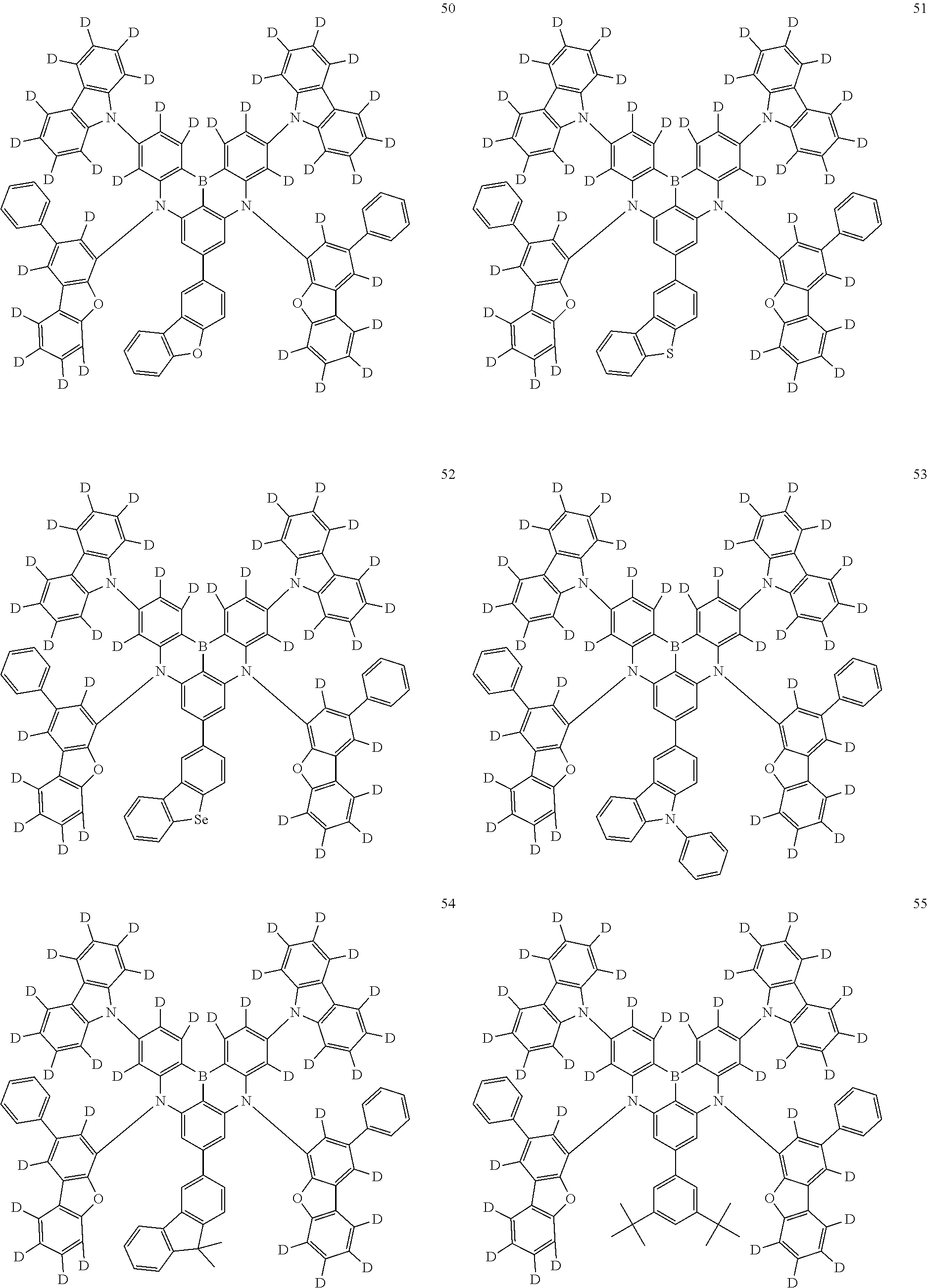 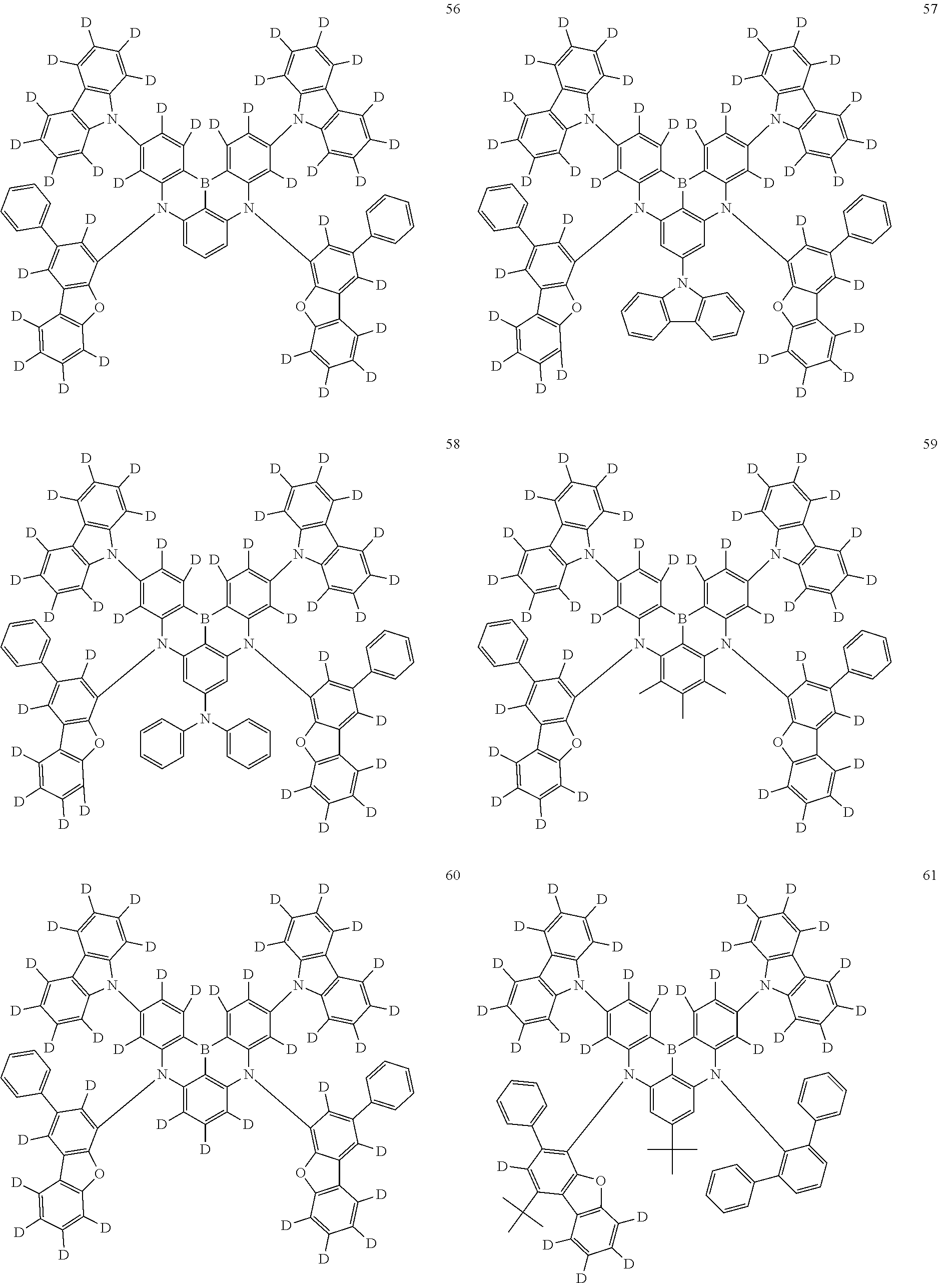 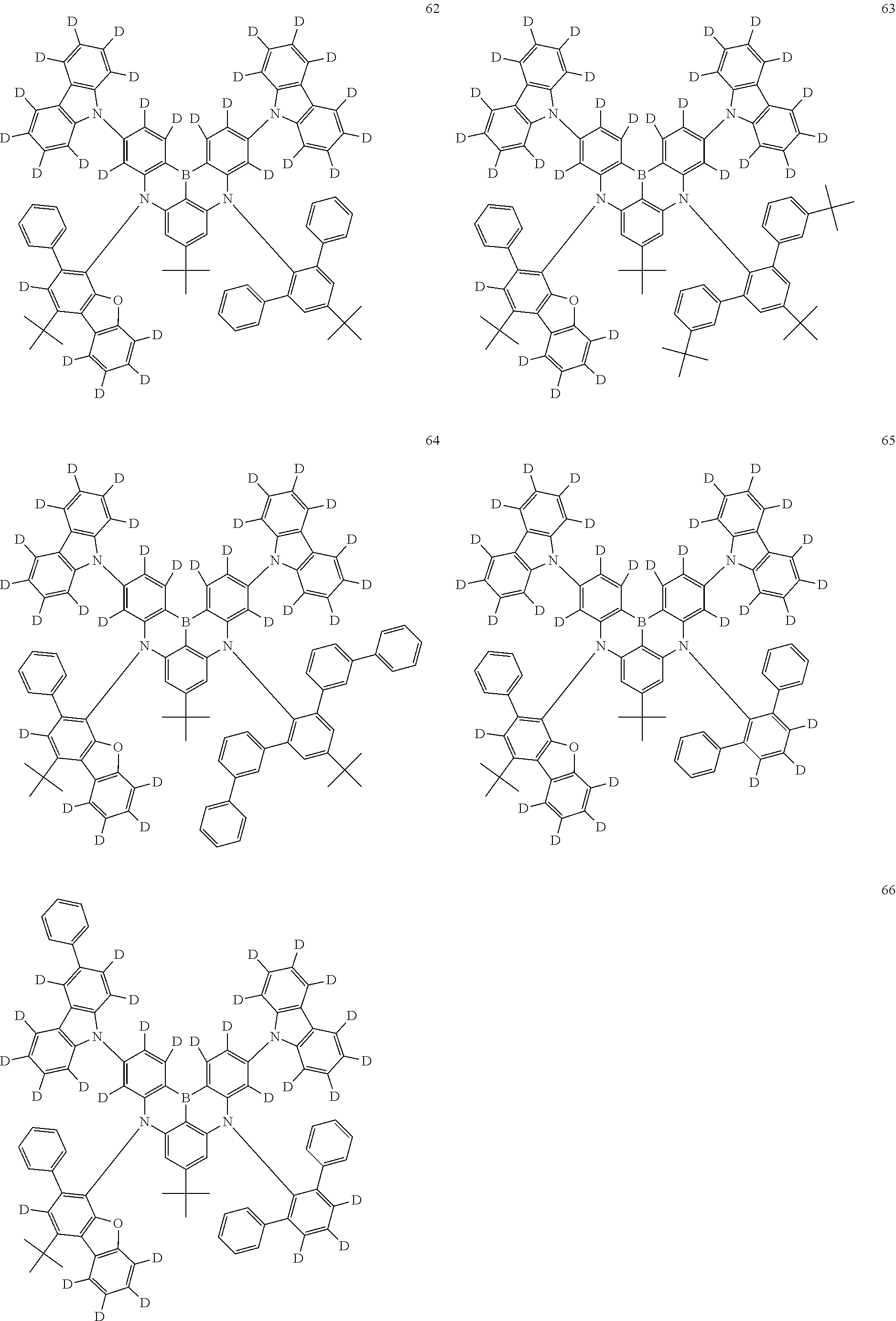 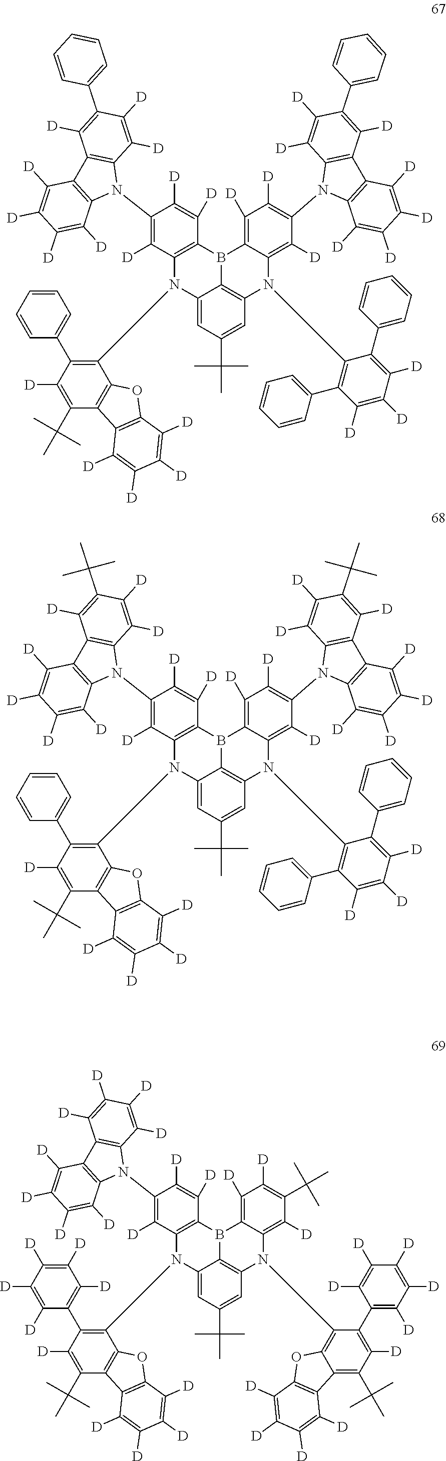 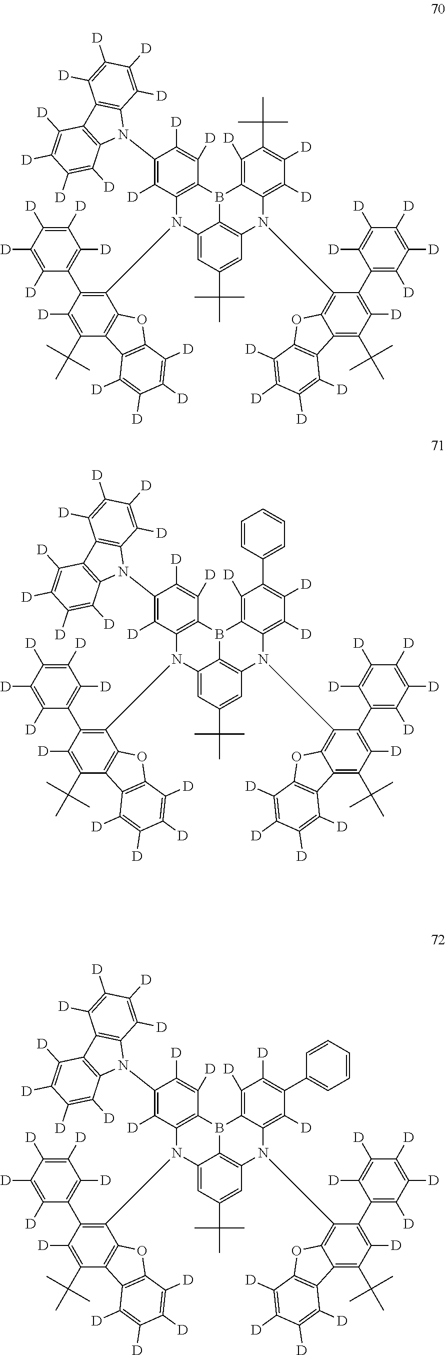 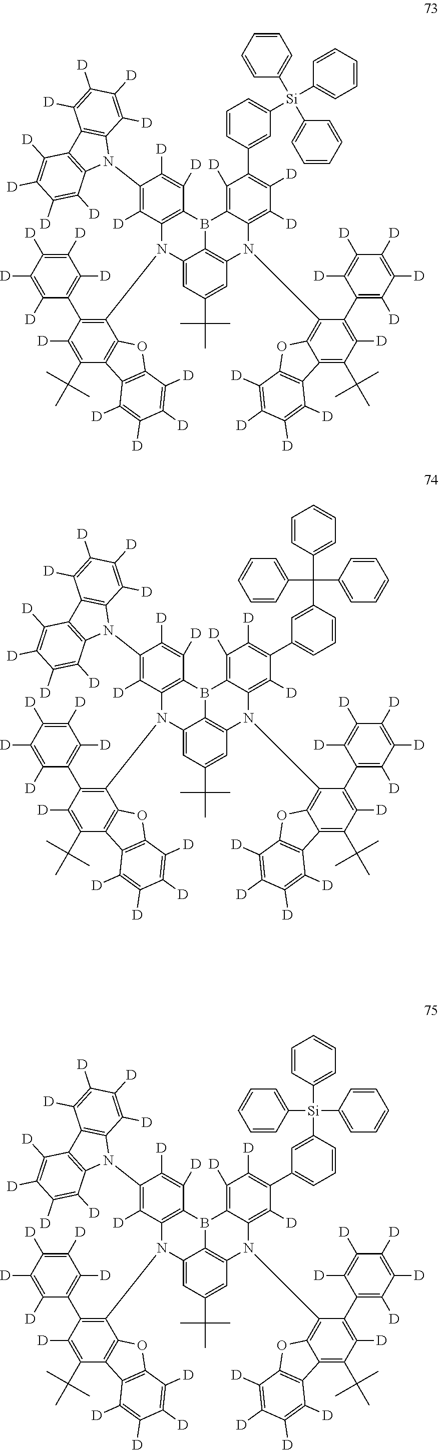 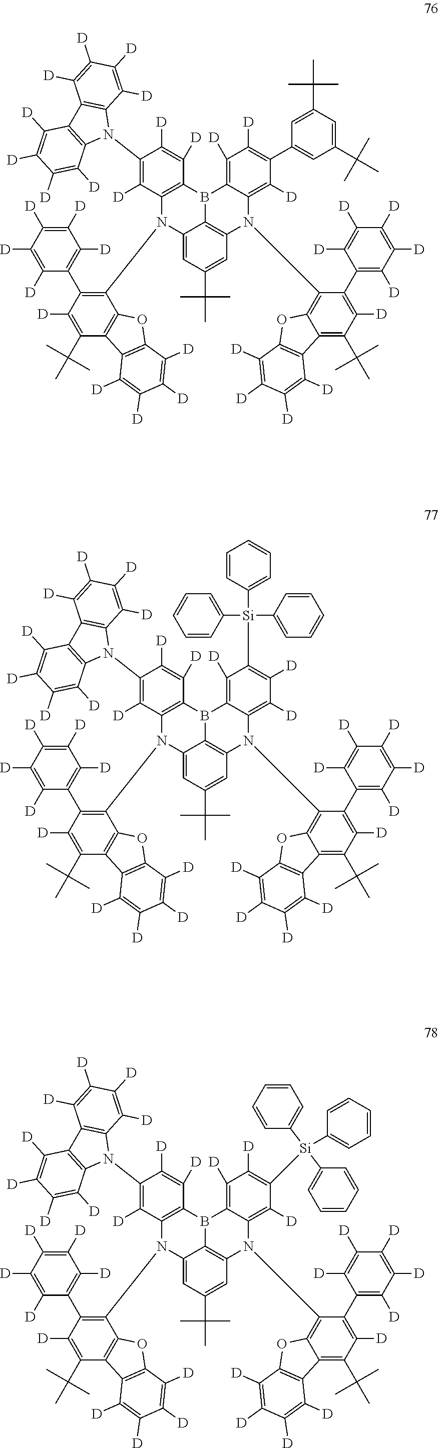 [chemical structure]
